(19) United States
(12) Patent Application Publication
(10) Pub. No.: US 2025/0370342 A1
(43) Pub. Date: Dec. 4, 2025

(54) RESIST COMPOSITION AND PATTERNING PROCESS

(71) Applicant: SHIN-ETSU CHEMICAL CO., LTD., Tokyo (JP)

(72) Inventors: Yutaro OTOMO, Joetsu-shi (JP); Takeshi Sasami, Joetsu-shi (JP); Takahiro Suzuki, Joetsu-shi (JP); Kazuhiro Katayama, Joetsu-shi (JP); Gentaro Hida, Joetsu-shi (JP); Tomohiro Kobayashi, Joetsu-shi (JP)

(73) Assignee: SHIN-ETSU CHEMICAL CO., LTD., Tokyo (JP)

(21) Appl. No.: 19/215,514

(22) Filed: May 22, 2025

(30) Foreign Application Priority Data
Jun. 4, 2024 (JP) 2024-090415

(51) Int. Cl. G03F 7/039; G03F 7/004; G03F 7/16

(52) U.S. Cl. CPC G03F 7/0392; G03F 7/0045; G03F 7/168

(57) ABSTRACT

The present invention is a resist composition, including: a resin (A) represented by the following formula (a1) and including a repeating unit that generates an acid by exposure; a photodegradable quencher represented by the following formula (b1); and an organic solvent, wherein at least one of M1+ in the formula (a1) and M2+ in the formula (b1) represents a sulfonium cation represented by the following formula (1). This can provide a resist composition and a patterning process that yield high sensitivity and high resolution, reduced edge roughness and dimensional deviation, and a good pattern shape after exposure.

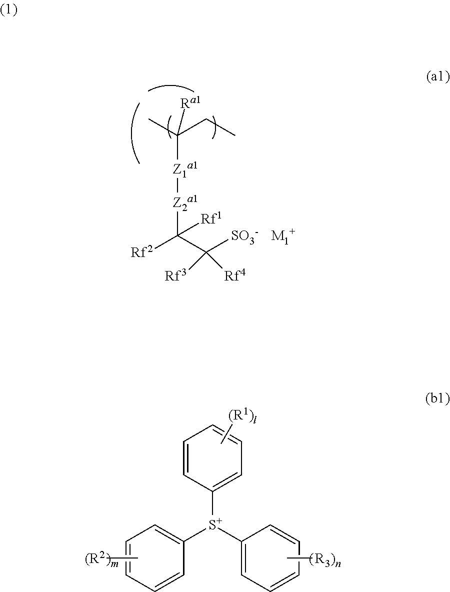

### TECHNICAL FIELD

The present invention relates to a resist composition and a patterning process.

### BACKGROUND ART

As higher integration and higher speed of LSI have been achieved, microfabrication with a pattern rule has rapidly proceeded. This is because high-speed communication with 5G and artificial intelligence (AI) have become widespread, and high-performance devices to process them have been required. As the latest microfabrication technique, 5-nm node devices are industrially produced by using lithography with extreme ultraviolet ray (EUV) having a wavelength of 13.5 nm. Furthermore, investigation using the EUV lithography is progressed for 3-nm node devices, next generation, and 2-nm node devices, next to the next generation.

EUV light sources used in recent years have low output but high energy due to the short wavelength, thereby extremely decreasing a number of photons contained in exposure. Accordingly, a photoacid generator that is photosensitized in the EUV exposure decreases compared with DUV exposure, resulting in ununiform acid distribution in a resist film. It is known that such photon shot noise causes deterioration in LWR performance (Non Patent Document 1).

To improve performance deterioration derived from the decreased number of photons, it is effective to add a photoacid generator having high photosensitivity. For example, Patent Documents 1 and 2 propose an onium salt of a sulfonium cation with a substituted fluorine atom.

The microfabrication in progress causes a problem of blurring an image due to acid diffusion. To achieve resolution with a fine pattern of 45 nm or finer in dimension, proposed are not only importance of improvement of dissolution contrast, conventionally proposed, but also controlling the acid diffusion (Non Patent Document 2). However, since a chemically amplified resist material enhances sensitivity and contrast by the acid diffusion, inhibiting the acid diffusion to the utmost limit with lowering a temperature or shortening a time of post exposure baking (PEB) considerably deteriorates the sensitivity and the contrast.

Pointed out is a triangle trade-off relationship between sensitivity, resolution, and edge roughness. Although inhibiting the acid diffusion is required in order to improve the resolution, shortening a distance of the acid diffusion deteriorates the sensitivity.

It is effective that an acid generator to generate a bulky acid is added to inhibit the acid diffusion. Accordingly, proposed is containing a repeating unit derived from an onium salt having a polymerizable unsaturated bond into a polymer. In this case, the polymer also functions as an acid generator (a polymer-bound acid generator). Patent Document 3 proposes a sulfonium salt and iodonium salt having a polymerizable unsaturated bond to generate a specific sulfonic acid. Patent Document 4 proposes a sulfonium salt in which a sulfonic acid is directly bonded to a main chain.

As an acid-diffusion controlling agent to inhibit diffusion of a strong acid component generated from the photoacid generator, an onium salt of a weak acid is proposed. When the strong acid and the weak acid onium salt are mixed, ion exchange occurs to cause substitution to a weak acid and a strong acid onium salt. The weak acid component substituted as above does not cause an acid-decomposing reaction of a base polymer, and therefore, the weak acid onium salt functions as a quencher. Quenchers that generate a carboxylic acid as the weak acid are proposed. For example, proposed are sulfonium salts of: salicylic acid or a β-hydroxycarboxylic acid (Patent Document 5); a salicylic acid derivative (Patent Documents 6 and 7); an iodine-containing salicylic acid (Patent Document 8); and an α-fluorocarboxylic acid (Patent Documents 9 and 10).

As above, in mass production of devices with 5-nm node by extreme ultraviolet ray (EUV) lithography, which has been required in recent years, the conventional art has a problem of no proposal of a resist composition and a patterning process that simultaneously satisfy the three types of performance: sensitivity, resolution, and edge roughness.

### CITATION LIST

### Patent Literature

Patent Document 1: JP 6442370 B
Patent Document 2: JP 6586303 B
Patent Document 3: JP 2006-045311 A
Patent Document 4: JP 2006-178317 A
Patent Document 5: WO 2018/159560 A1
Patent Document 6: JP 2020-203984 A
Patent Document 7: JP 2020-91404 A
Patent Document 8: JP 2022-77505 A
Patent Document 9: JP 2015-054833 A
Patent Document 10: JP 2021-91666 A

### Non Patent Literature

Non Patent Document 1: SPIE Vol. 3331 p 531 (1998)
Non Patent Document 2: SPIE Vol. 6520 65203L-1 (2007)

### SUMMARY OF INVENTION

### Technical Problem

The present invention has been made in view of the above circumstances. An object of the present invention is to provide: a resist composition that has high sensitivity and high resolution exceeding the conventional resist materials, that causes reduced edge roughness and dimensional deviation, and that yields a good pattern shape after exposure; and a patterning process.

### Solution to Problem

To solvent the above problem, the present invention provides a resist composition including: a resin (A) represented by the following formula (a1) and including a repeating unit that generates an acid by exposure;
a photodegradable quencher represented by the following formula (b1); and
an organic solvent,
wherein at least one of M₁⁺ in the formula (a1) and M₂⁺ in the formula (b1) represents a sulfonium cation represented by the following formula (1),

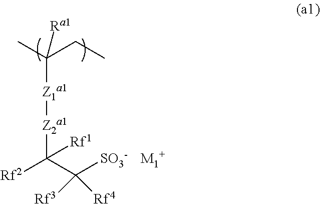

wherein Rai each independently represents a hydrogen atom or a methyl group; Z₁^{a1} represents a single bond or an ester bond; Z₂^{a1} represents a single bond or a divalent organic group having 1 to 20 carbon atoms and optionally having an ester bond, an ether bond, a lactone ring, an aromatic ring, a fluorine atom, a bromine atom, or an iodine atom; Rf¹ to Rf⁴ each independently represent a hydrogen atom, a fluorine atom, or a trifluoromethyl group, provided that at least one of Rf¹ to Rf⁴ represents a fluorine atom; and M₁⁺ represents a sulfonium cation,

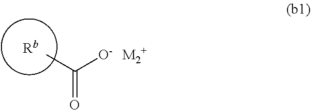

wherein Rb represents an organic group having 1 to 30 carbon atoms and optionally having a substituent; and M₂⁺ represents a sulfonium cation,

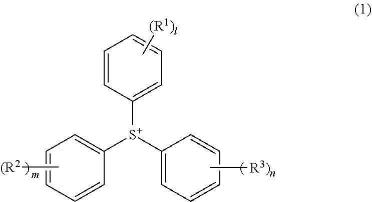

wherein R¹ represents a fluorine atom, an iodine atom, or a perfluoroalkyl group; R² and R³ each independently represent a fluorine atom or a perfluoroalkyl group; “l” represents an integer of 0 to 3; “m” represents an integer of 1 to 3; “n” represents an integer of 1 to 3; when “l”, “m”, or “n” represents an integer of 2 or more, each of R¹, R², and R³ may be same or different; provided that structure of the formula (1) has at least two or more fluorine atoms; when R² or R³ represents a fluorine atom, at least one fluorine atom is substituted at a meta-position relative to a sulfur atom.

The resist composition as above is the resist composition that has high sensitivity and high resolution, that causes reduced edge roughness and dimensional deviation, and that yields a good pattern shape after exposure.

The photodegradable quencher represented by the formula (b1) is preferably represented by the following formula (b1-1),

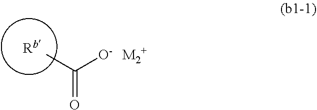

wherein Rb′ represents an organic group having 1 to 22 carbon atoms, optionally having a substituent, and optionally having an ester bond, an ether bond, an amide bond, a lactone ring, a sultone ring, an aromatic cyclic group, an aliphatic cyclic group, a hydroxy group, an alkoxy group, a fluoroalkyl group, a nitro group, a cyano group, a trifluoromethoxy group, a carbonyl group, an amino group, an alkylamino group, a fluorine atom, a bromine atom, or an iodine atom; and M₂⁺ represents a sulfonium cation.

The resist composition as above serves as an excellent quencher (B1-1) as an acid-diffusion controlling agent to inhibit diffusion of the strong acid component generated from the photoacid generator. This action can achieve both increase in acid generation efficiency by exposure and reduction in an acid-diffusion distance to the utmost limit, and simultaneously achieves high sensitivity, excellent edge roughness (LWR), and dimensional deviation.

The resin (A) is preferably a resin further including a repeating unit represented by the following formula (a2),

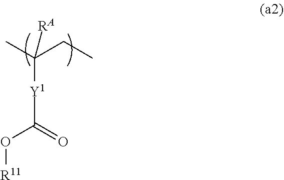

wherein R^{A} each independently represents a hydrogen atom or a methyl group; Y¹ represents a single bond, a phenylene group or a naphthylene group, or a linking group having 1 to 12 carbon atoms and having an ester bond, an ether bond, or a lactone ring; and R¹¹ represents an acid-labile group.

Use of the resin as above can increase dissolution contrast due to the introduced repeating unit in which a hydrogen atom of the carboxy group is substituted with the acid-labile group to achieve high sensitivity and remarkably increased alkali-dissolution rate contrast before and after exposure.

The repeating unit represented by the formula (a1) is preferably represented by the following formula (a1-1),

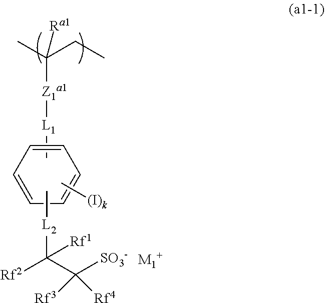

wherein R^{a1} each independently represents a hydrogen atom or a methyl group; Z₁^{a1} represents a single bond or an ester bond; L₁ represents a single bond or a divalent linking group optionally having an ester bond, an ether bond, a lactone ring, an aromatic ring, a fluorine atom, a bromine atom, or an iodine atom; L₂ represents a single bond or a divalent linking group optionally having an ester bond or an ether bond; Rf¹ to Rf⁴ each independently represent a hydrogen atom, a fluorine atom, or a trifluoromethyl group, provided that at least one of Rf¹ to Rf⁴ represents a fluorine atom; “k” represents an integer of 0 to 4; and M₁⁺ represents a sulfonium cation.

The repeating unit with structure as above yields high sensitivity and high resolution, reduced edge roughness and dimensional deviation, and a good pattern shape after exposure.

The repeating unit represented by the formula (a1) is preferably represented by the following formula (a1-2),

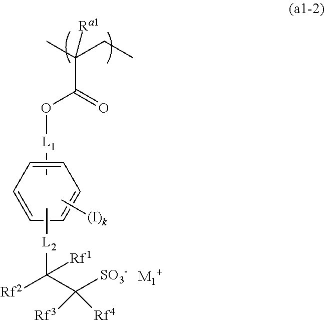

wherein R^{a1} each independently represents a hydrogen atom or a methyl group; L₁ represents a single bond or a divalent linking group optionally having an ester bond, an ether bond, a lactone ring, an aromatic ring, a fluorine atom, a bromine atom, or an iodine atom; L₂ represents a single bond or a divalent linking group optionally having an ester bond or an ether bond; Rf¹ to Rf⁴ each independently represent a hydrogen atom, a fluorine atom, or a trifluoromethyl group, provided that at least one of Rf¹ to Rf⁴ represents a fluorine atom; “k” represents an integer of 0 to 4; and M₁⁺ represents a sulfonium cation.

The resin as above in which the polymerizable group is a methacrylate allows the polymer main chain to be rigid, thereby raising the glass transition temperature. As a result, thermal diffusion of the strong acid component generated from the photoacid generator is inhibited to improve resolution.

An anion moiety in the formula (a1) and the formula (b1) preferably includes an iodine atom.

In the anion moiety having an iodine atom as above, the iodine atom has large absorption of EUV light, and has high ability to efficiently generate secondary electrons from photons given by EUV exposure, resulting in achievement of high sensitivity and high resolution.

Both the M₁⁺ in the formula (a1) and M₂⁺ in the formula (b1) preferably represent the sulfonium cation represented by the formula (1).

The sulfonium cation as above can increase electrophilicity, and can efficiently convert the secondary electrons generated by exposure into the acid, resulting in achievement of high sensitivity and high resolution.

“l” in the formula (1) preferably represents an integer of 1 to 3.

The sulfonium cation as above can more increase electrophilicity, and can efficiently convert the secondary electrons generated by exposure into the acid, resulting in achievement of high sensitivity and high resolution more preferably.

The cation represented by the formula (1) preferably includes an iodine atom.

The iodine atom, which has large absorption of EUV light, can efficiently generate secondary electrons from photons given by EUV exposure, resulting in achievement of high sensitivity and high resolution. In addition, the iodine atom bonded to the triarylsulfonium cation without a linker allows efficient photochemical reaction to proceed.

In addition, the present invention provides a patterning process including steps of:
forming a resist film on a substrate by using the aforementioned resist composition;
exposing the resist film to high-energy ray; and
developing the exposed resist film by using a developer.

The patterning process as above can provide the patterning process that yields high sensitivity and high resolution, and reduced edge roughness (LWR) and dimensional deviation (CDU).

In this case, the high-energy ray used in the exposing step is preferably i-line, KrF excimer laser light, ArF excimer laser light, electron beam, or extreme ultraviolet ray having a wavelength of 3 to 15 nm.

The patterning process as above can be the patterning process that favorably and simultaneously satisfies three of high sensitivity, high resolution, and edge roughness (LWR) and dimensional deviation (CDU) and that can be applied in mass production of 5-nm node devices, which is a fine pattern dealing with higher integration and higher speed of LSI, further applied in mass production of 3-nm node devices, next generation, and 2-nm node devices, next to the next generation.

### Advantageous Effects of Invention

As above, the resist composition and patterning process of the present invention can provide the resist composition and the patterning process that yield high sensitivity and high resolution, and reduced edge roughness (LWR) and dimensional deviation (CDU). In addition, the present invention can provide the resist composition that yields high sensitivity and remarkably high alkali-dissolution rate contrast before and after exposure. Further, the patterning process of the present invention can be the patterning process that can be applied in mass production of 5-nm node devices, which is a fine pattern dealing with higher integration and higher speed of LSI, further applied in mass production of 3-nm node devices, next generation, and 2-nm node devices, next to the next generation.

### DESCRIPTION OF EMBODIMENTS

As noted above, there has been a demand for development of the resist composition and the patterning process that yield high sensitivity and high resolution, and reduced edge roughness (LWR) and dimensional deviation (CDU), which have been desired in recent years.

The present inventors have made earnest study to obtain the resist composition that yields high sensitivity and high resolution, and reduced edge roughness (LWR) and dimensional deviation (CDU), which have been desired in recent years, and consequently found that it needs to increase acid generation efficiency by exposure and reduce an acid diffusion distance to the utmost limit, and it is effective therefor to contain a photosensitive resin containing a sulfonium cation having a specific structure and/or a photodegradable quencher having a sulfonium cation having a specific structure.

Further, it has been found that the resist composition that has high sensitivity, remarkably increased alkali-dissolution rate contrast before and after exposure, high sensitivity, a high effect of inhibiting acid diffusion, and high resolution, that yields a good pattern shape after exposure with reduced edge roughness and dimensional deviation, and that is particularly suitable as a material for super LSI production or fine patterning on a photomask can be obtained by introducing a repeating unit in which a hydrogen atom of a carboxy group is substituted with an acid-labile group in order to improve dissolution contrast. These findings have led to completion of the present invention.

Specifically, the present invention is a resist composition including:
a resin (A) represented by the following formula (a1) and including a repeating unit that generates an acid by exposure;
a photodegradable quencher represented by the following formula (b1); and
an organic solvent,
wherein at least one of M₁⁺ in the formula (a1) and M₂⁺ in the formula (b1) represents a sulfonium cation represented by the following formula (1),

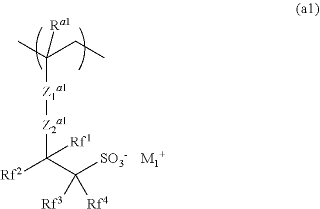

wherein R^{a1} each independently represents a hydrogen atom or a methyl group; Z₁^{a1} represents a single bond or an ester bond; Z₂^{a1} represents a single bond or a divalent organic group having 1 to 20 carbon atoms and optionally having an ester bond, an ether bond, a lactone ring, an aromatic ring, a fluorine atom, a bromine atom, or an iodine atom; Rf¹ to Rf⁴ each independently represent a hydrogen atom, a fluorine atom, or a trifluoromethyl group, provided that at least one of Rf¹ to Rf⁴ represents a fluorine atom; and M₁⁺ represents a sulfonium cation,

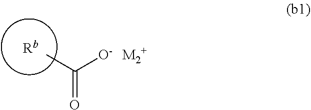

wherein Rb represents an organic group having 1 to 30 carbon atoms and optionally having a substituent; and M₂⁺ represents a sulfonium cation,

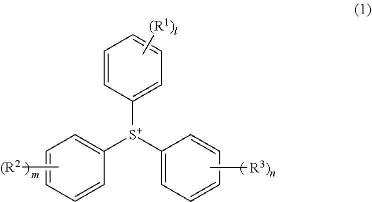

wherein R¹ represents a fluorine atom, an iodine atom, or a perfluoroalkyl group; R² and R³ each independently represent a fluorine atom or a perfluoroalkyl group; “l” represents an integer of 0 to 3; “m” represents an integer of 1 to 3; “n” represents an integer of 1 to 3; when “l”, “m”, or “n” represents an integer of 2 or more, each of R¹, R², and R³ may be same or different; provided that structure of the formula (1) has at least two or more fluorine atoms; when R² or R³ represents a fluorine atom, at least one fluorine atom is substituted at a meta-position relative to a sulfur atom.

Hereinafter, the present invention will be described in detail, but the present invention is not limited thereto.

### Base Polymer

(Repeating Unit (a1))

The base polymer (A) (the resin (A)) in the resist composition of the present invention has a repeating unit represented by the following formula (a1) that generates an acid by exposure.

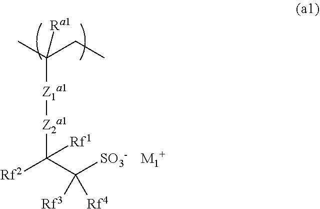

In the formula, Rai each independently represents a hydrogen atom or a methyl group. Z₁^{a1} represents a single bond or an ester bond. Z₂^{a1} represents a single bond or a divalent organic group having 1 to 20 carbon atoms and optionally having an ester bond, an ether bond, a lactone ring, an aromatic ring, a fluorine atom, a bromine atom, or an iodine atom. Rf¹ to Rf⁴ each independently represent a hydrogen atom, a fluorine atom, or a trifluoromethyl group. Provided that at least one of Rf¹ to Rf⁴ represents a fluorine atom. M₁⁺ represents a sulfonium cation.

Rf¹ to Rf⁴ each independently represent a hydrogen atom, a fluorine atom, or a trifluoromethyl group, but at least one of them represents a fluorine atom. Specifically, at least one of Rf³ and Rf⁴ preferably represents a fluorine atom, and both Rf³ and Rf⁴ more preferably represent a fluorine atom.

The repeating unit (a1) is a photoacid generator (PAG) composed of a sulfonate anion and a sulfonium cation. The PAG incorporated in the polymer as the repeating unit reduces the diffusion distance of the strong acid component, thereby inhibiting blurring of an image to improve resolution.

Examples of the anion moiety in the repeating unit (a1) include moieties having a styrene structure as the polymerizable group. Specific examples of the anion moiety in the repeating unit (a1) include, but not limited to, the following moieties.

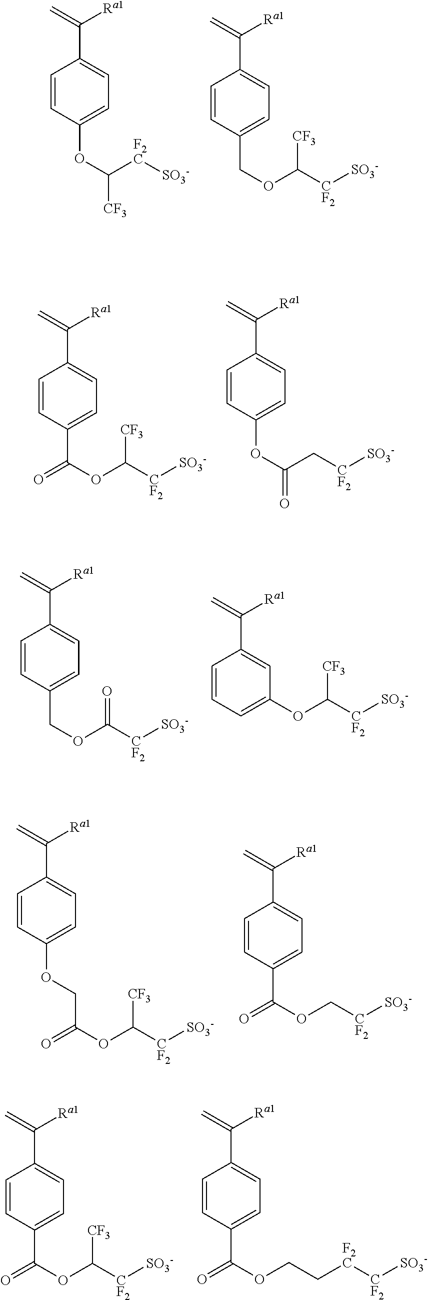

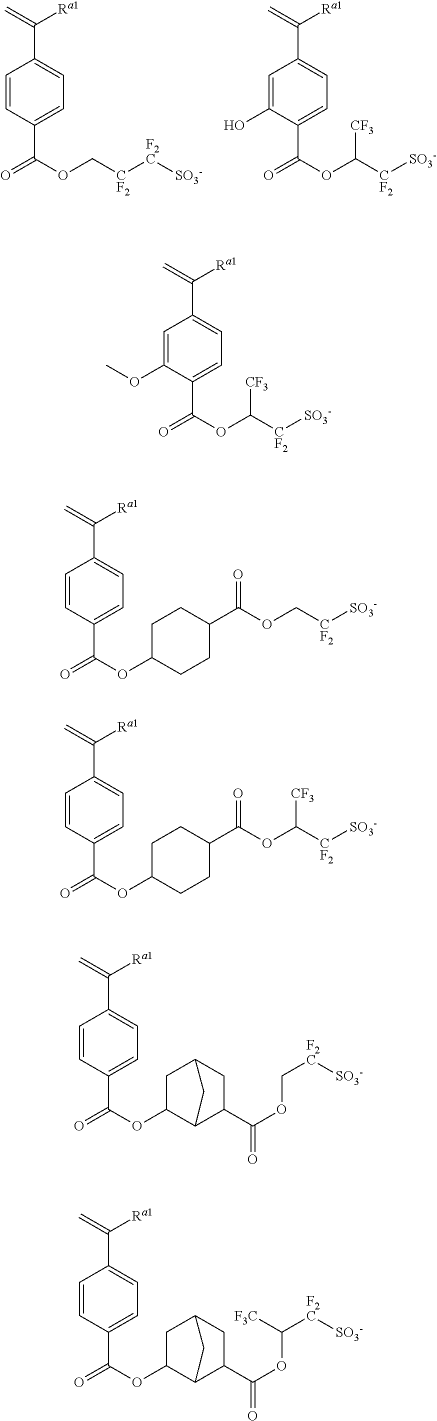

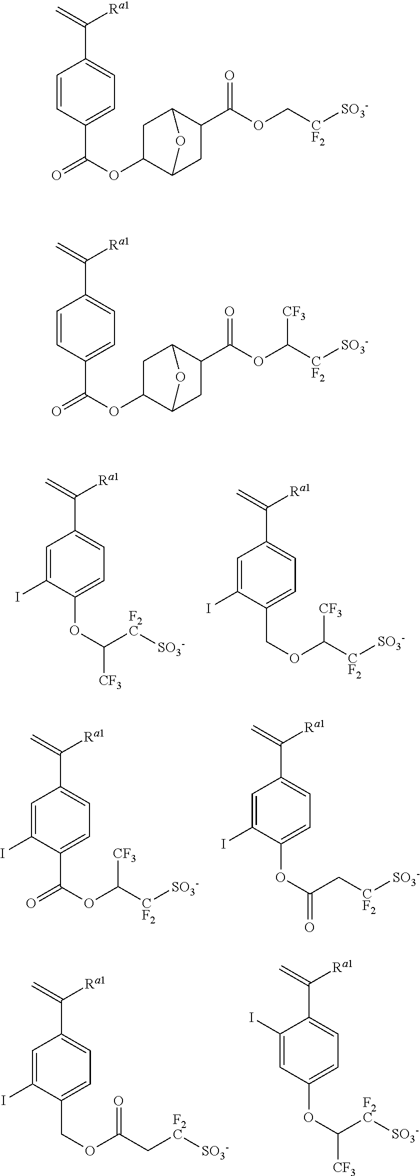

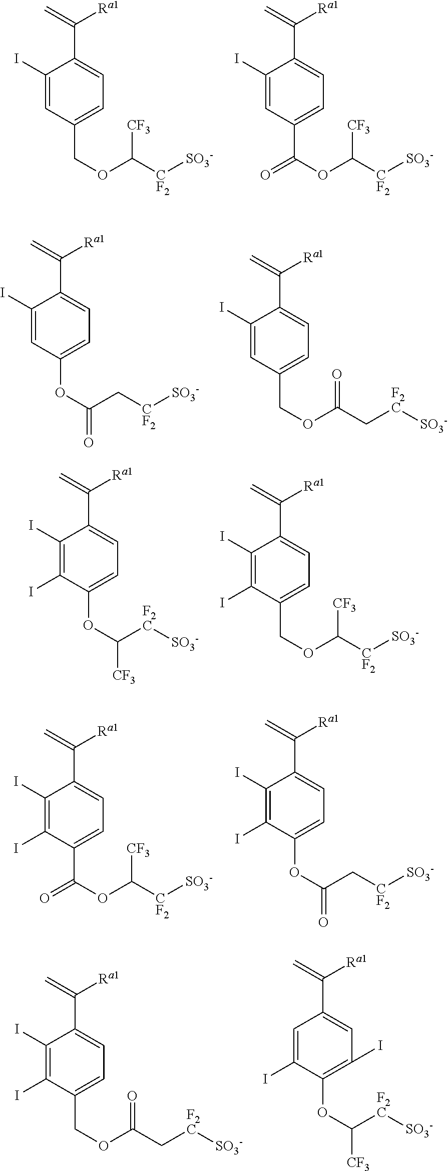

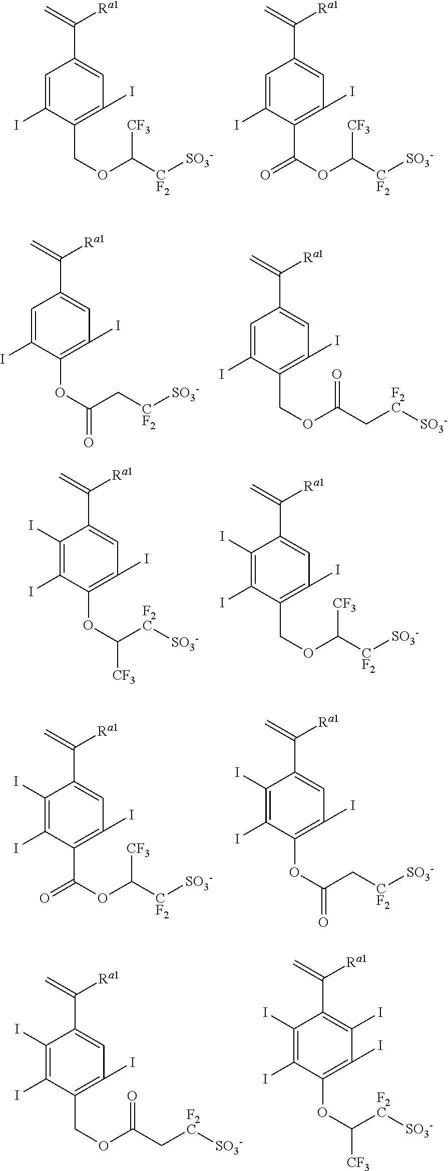

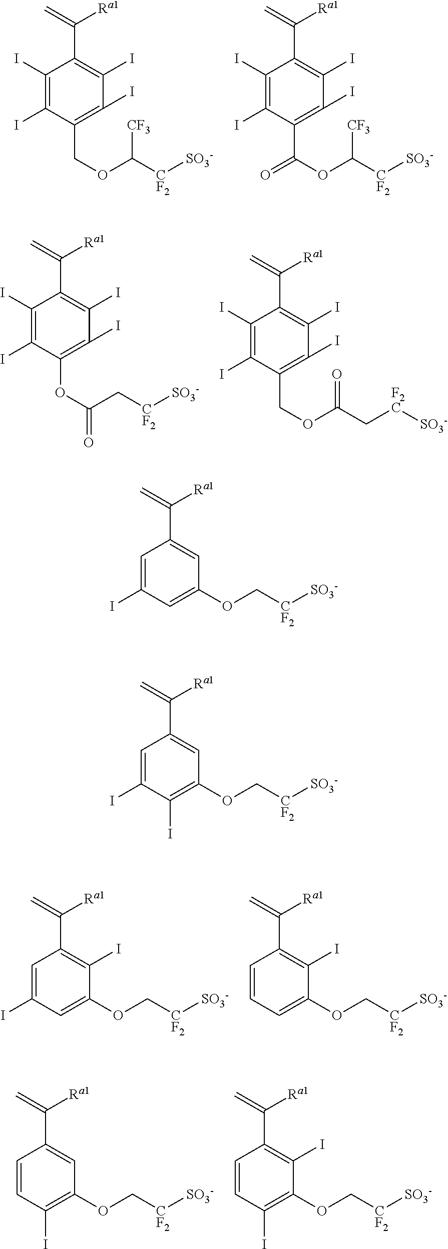

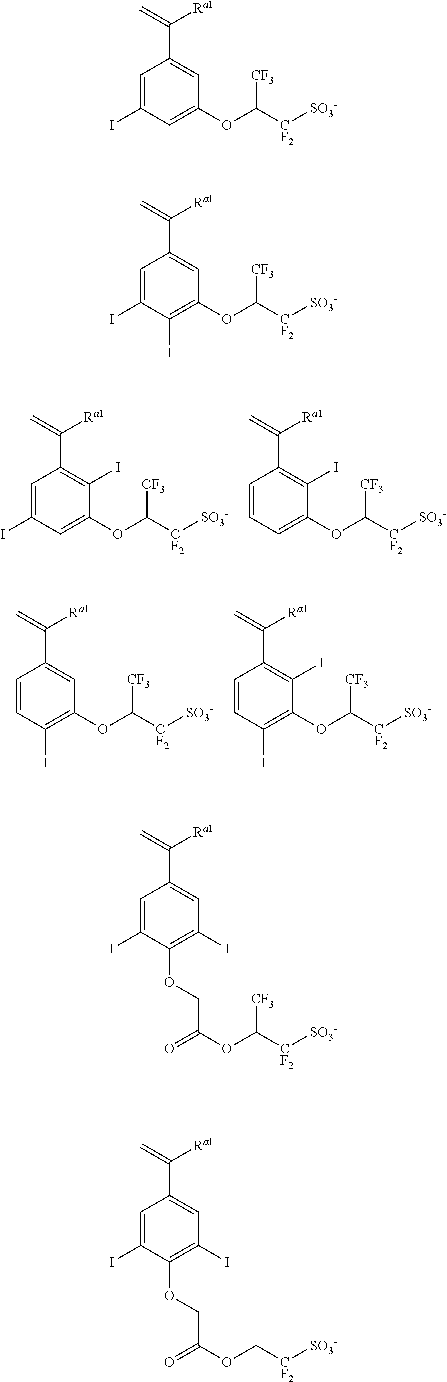

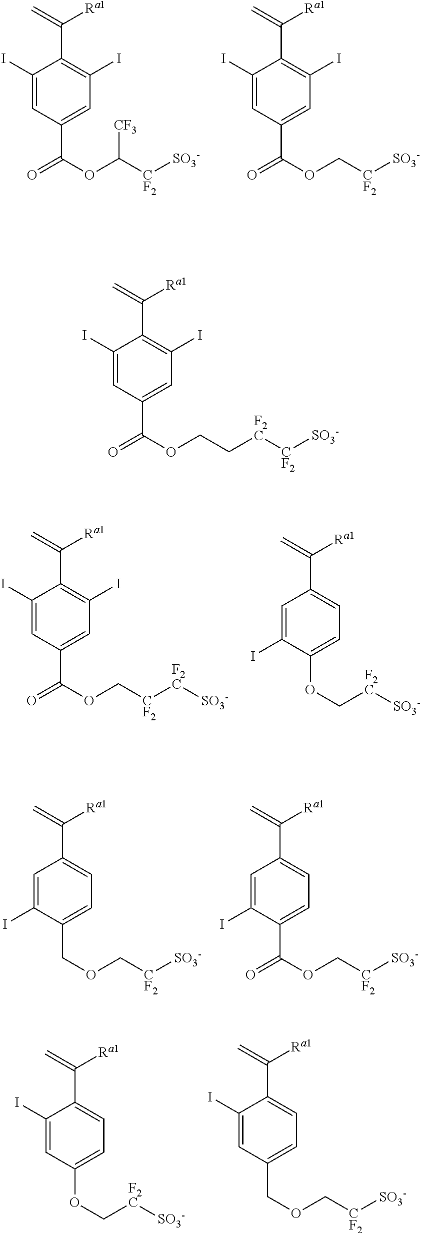

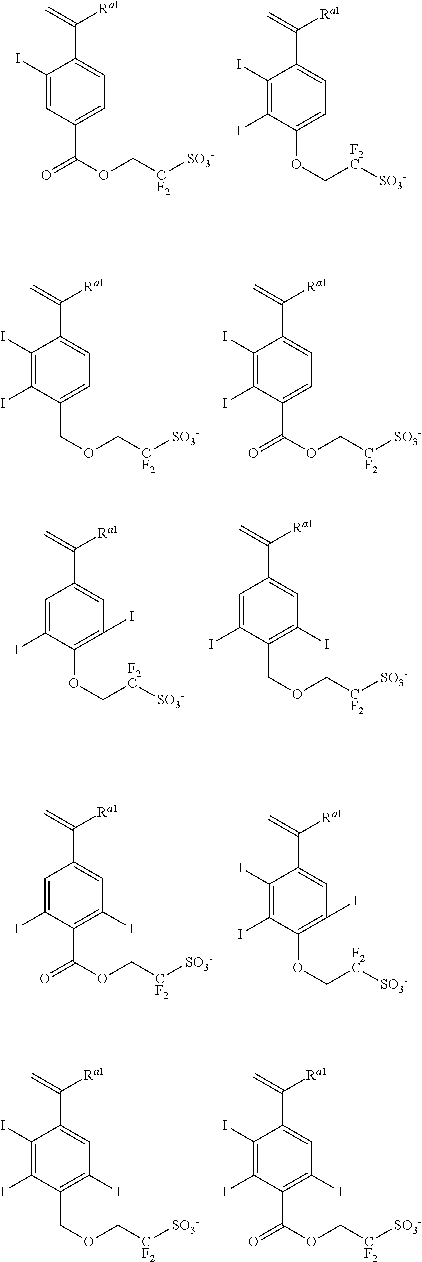

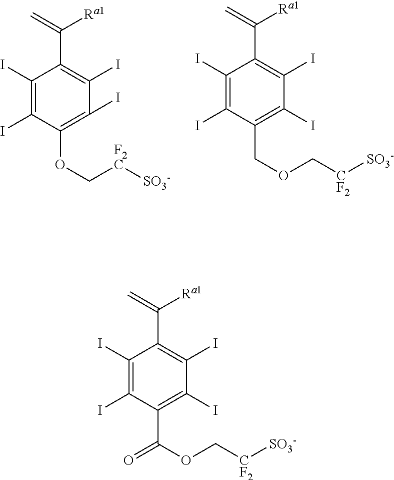

The anion moiety in the repeating unit (a1) preferably has a methacrylate structure as the polymerizable group.

Specific examples of the anion moiety in the repeating unit (a1) include, but not limited to, the following moieties.

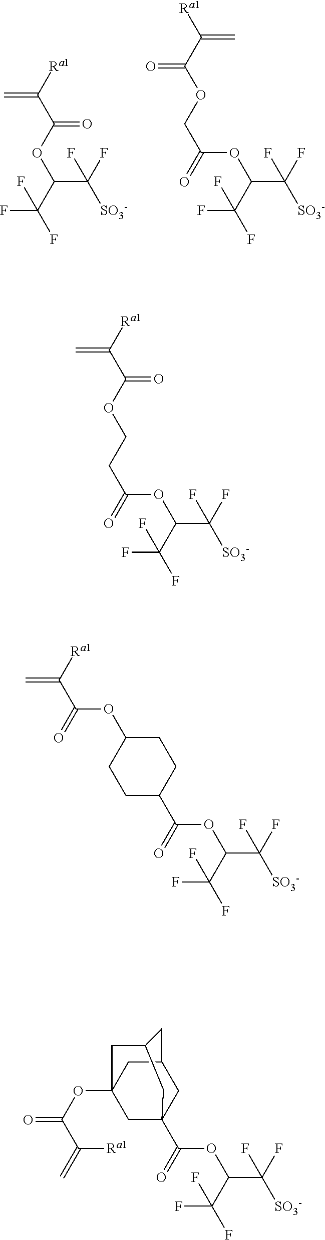

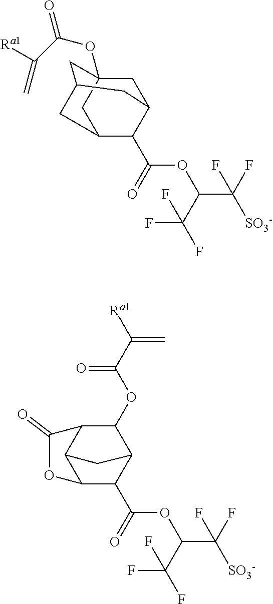

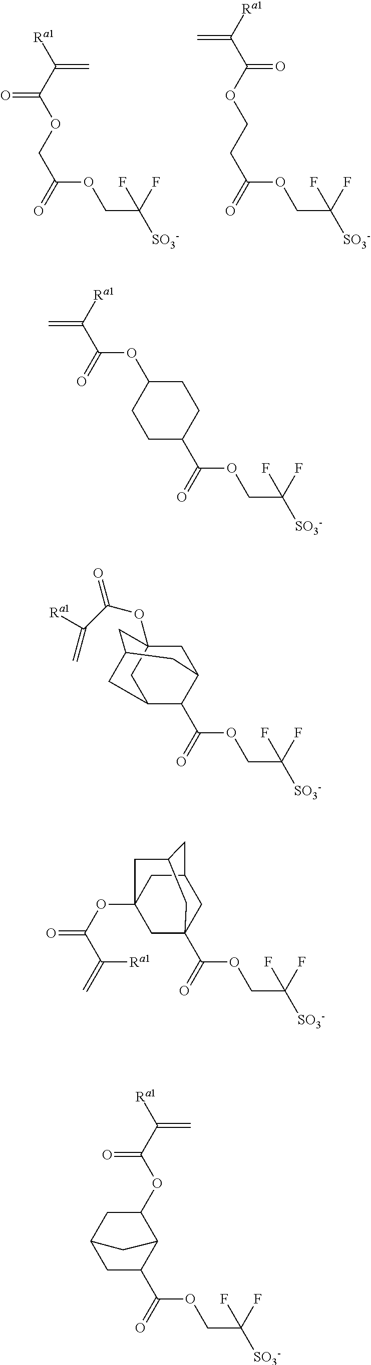

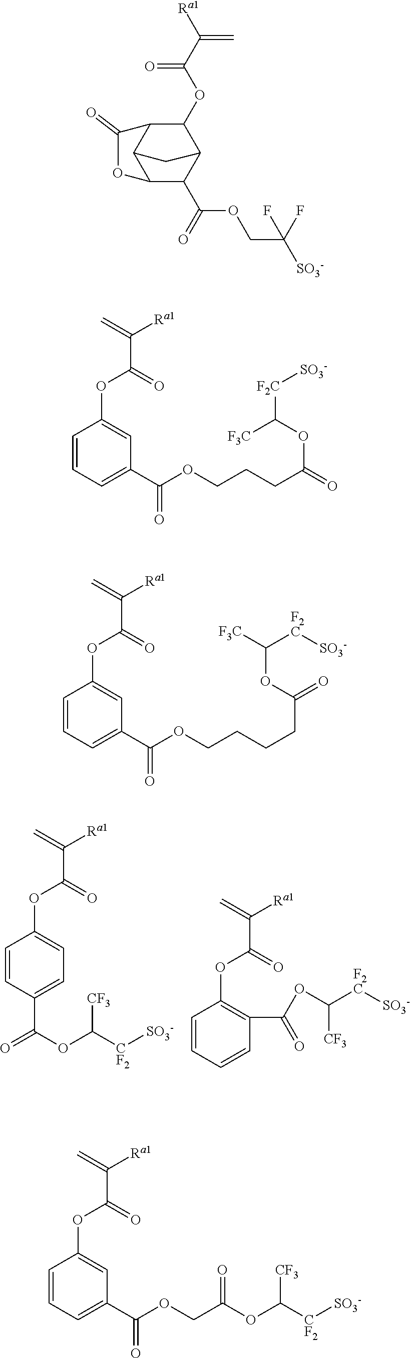

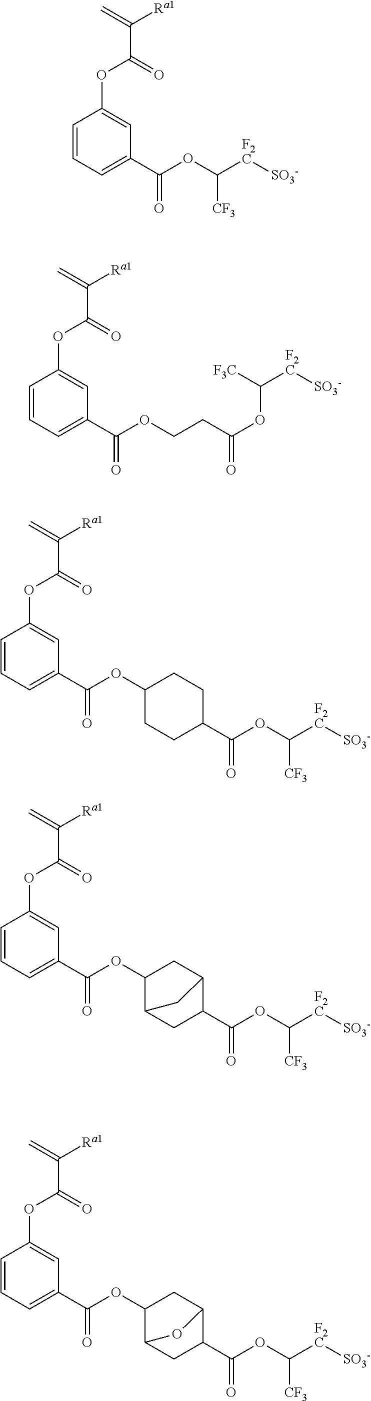

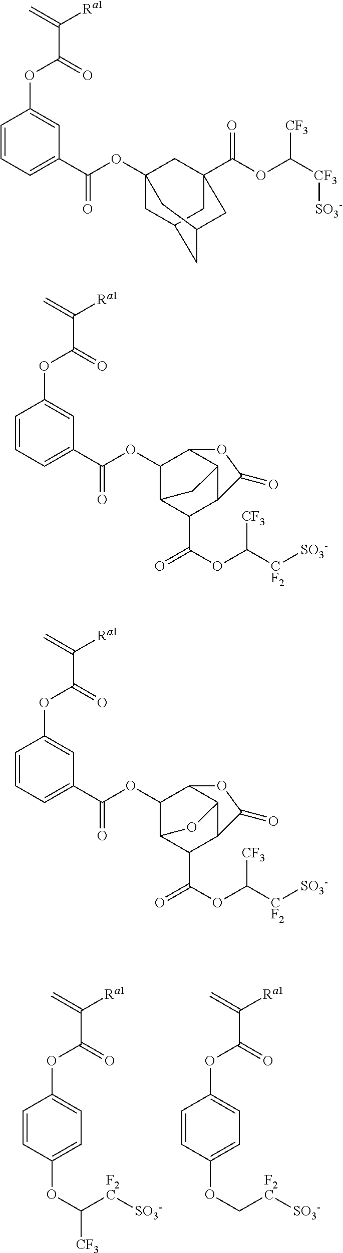

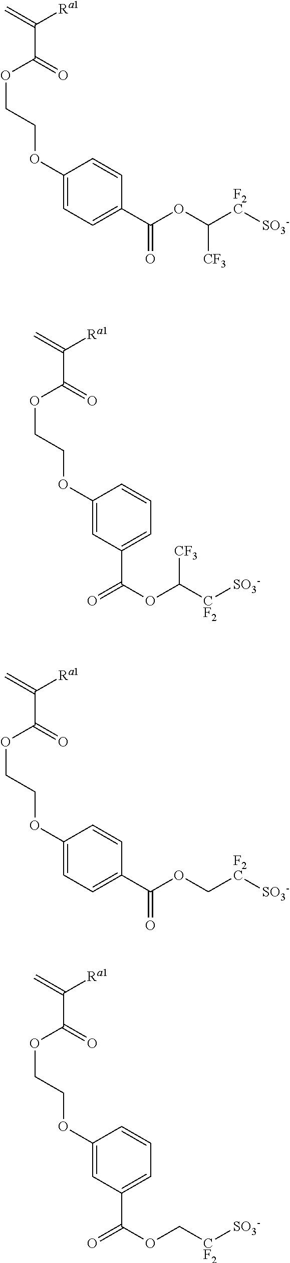

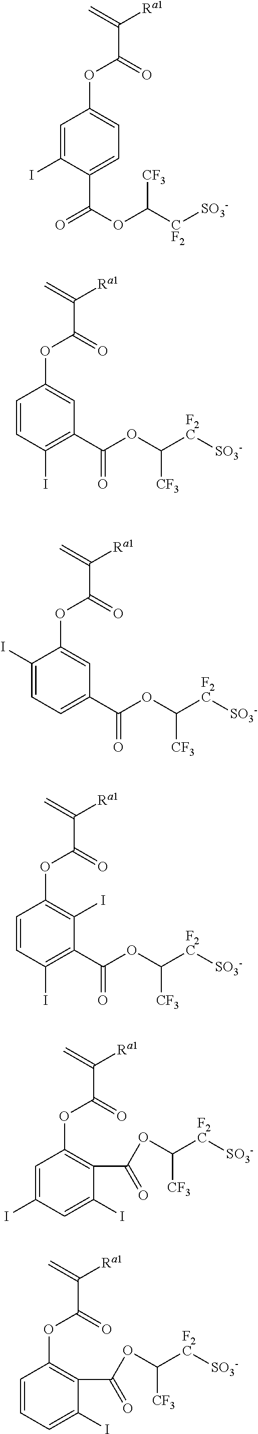

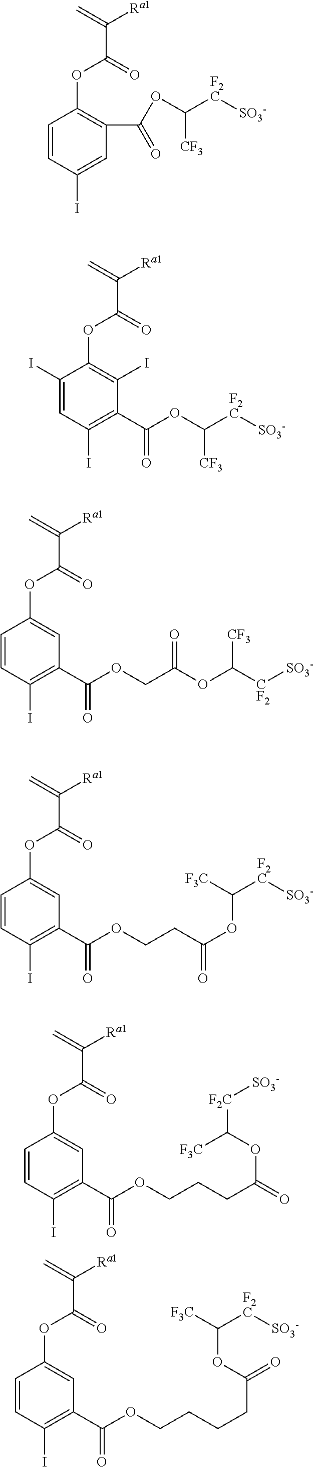

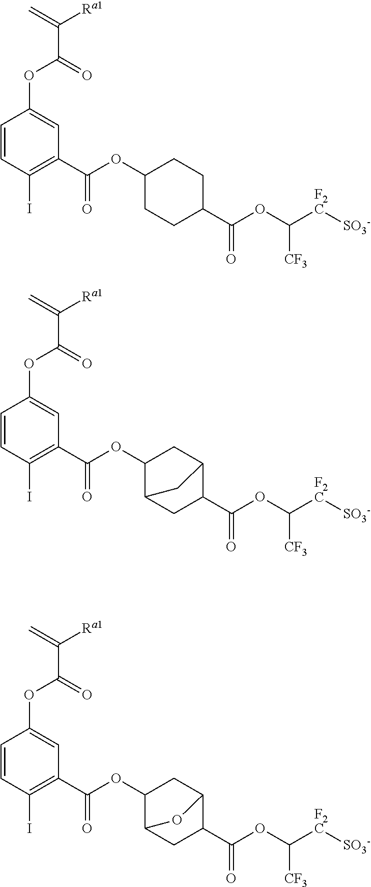

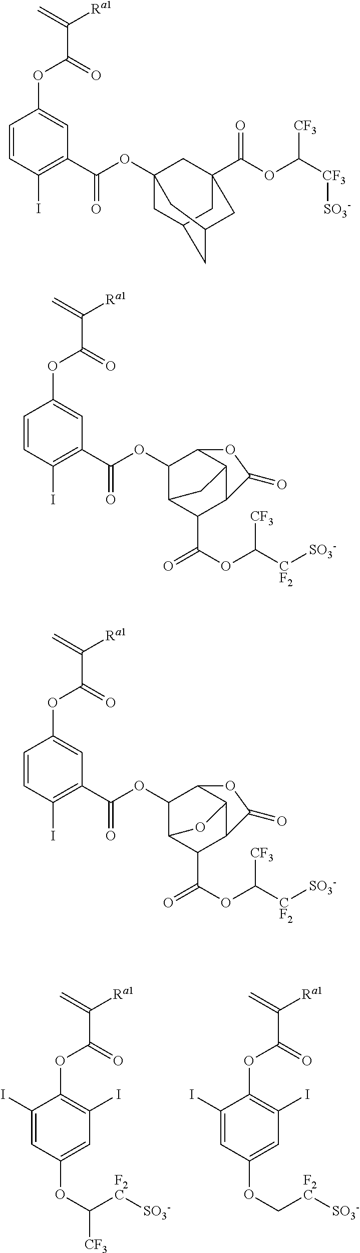

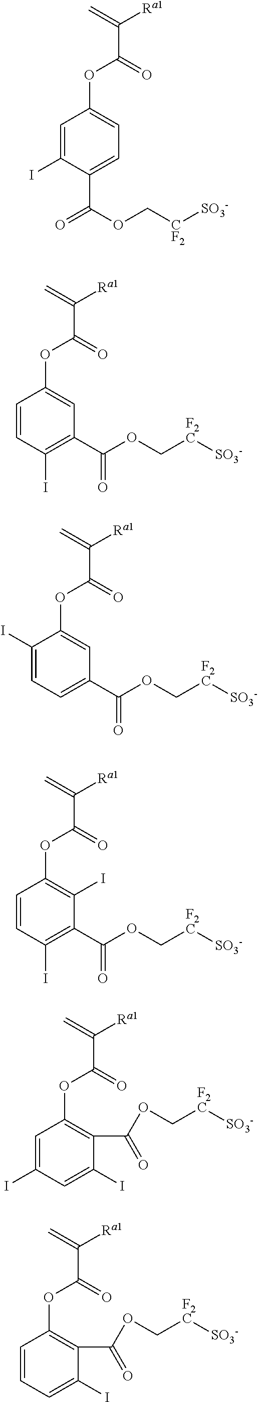

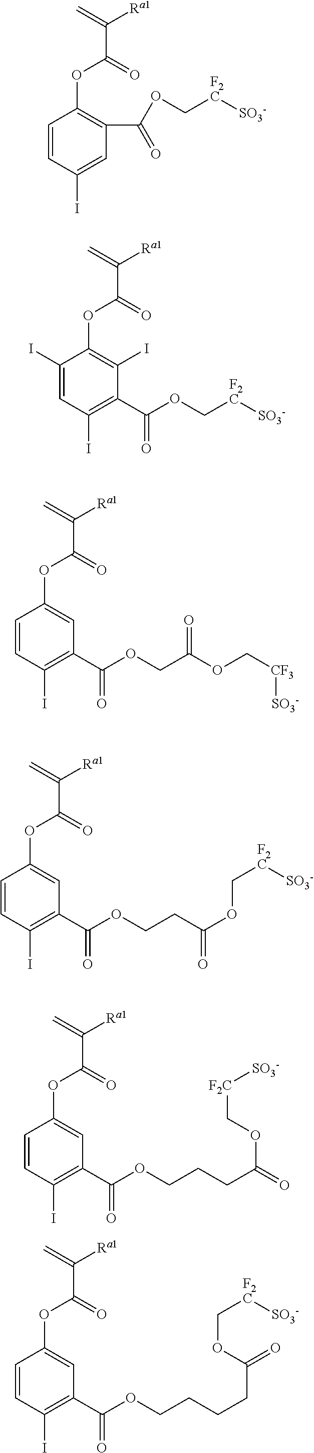

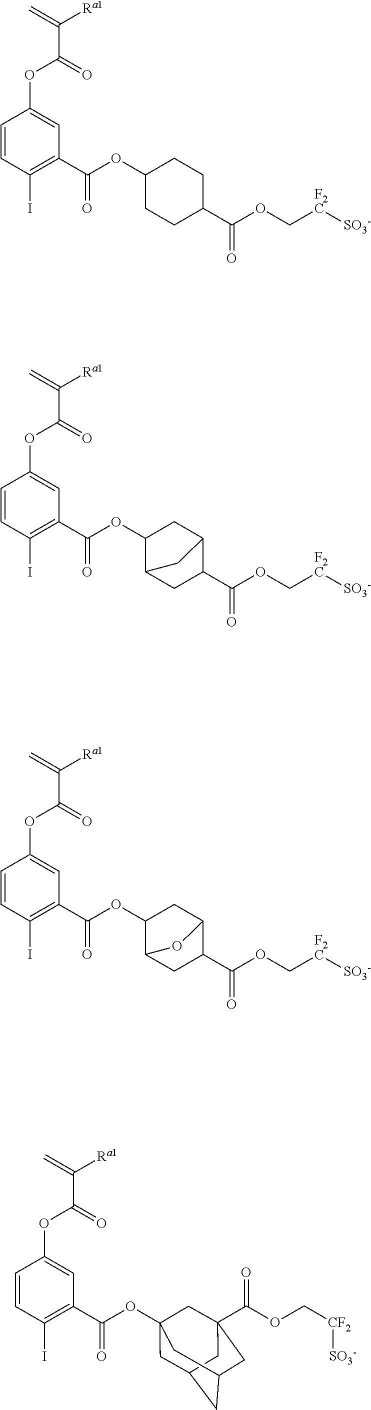

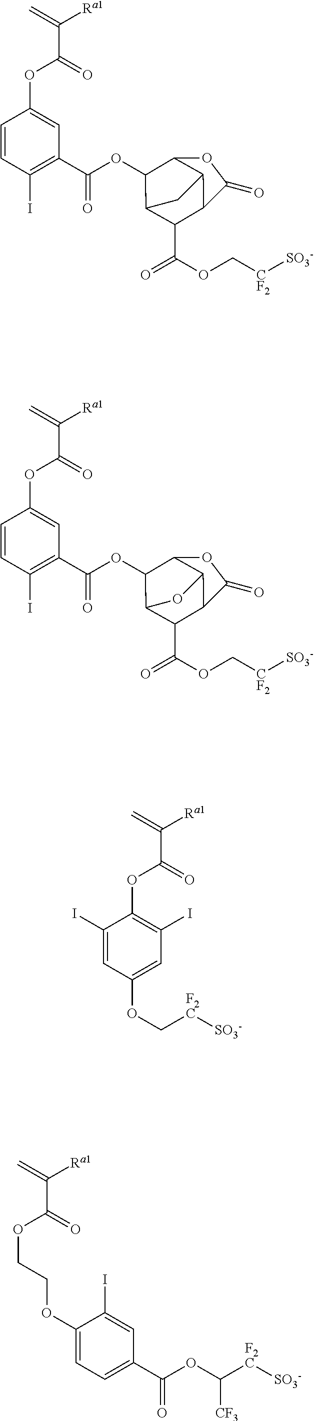

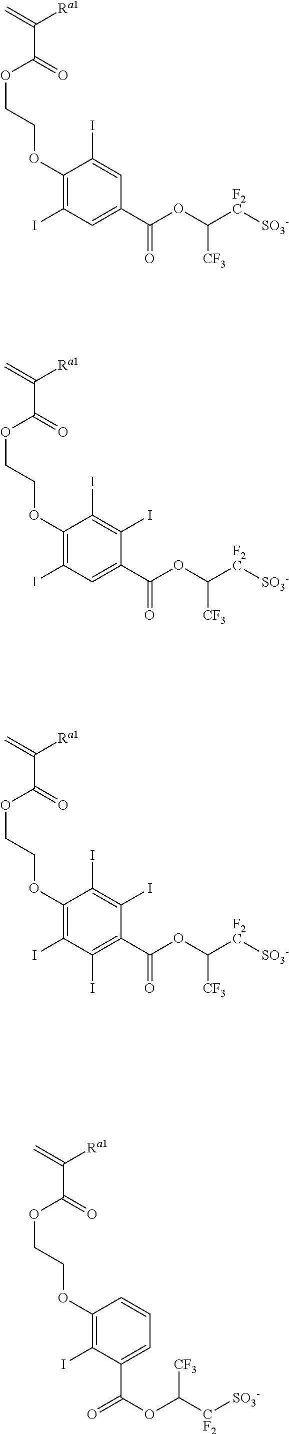

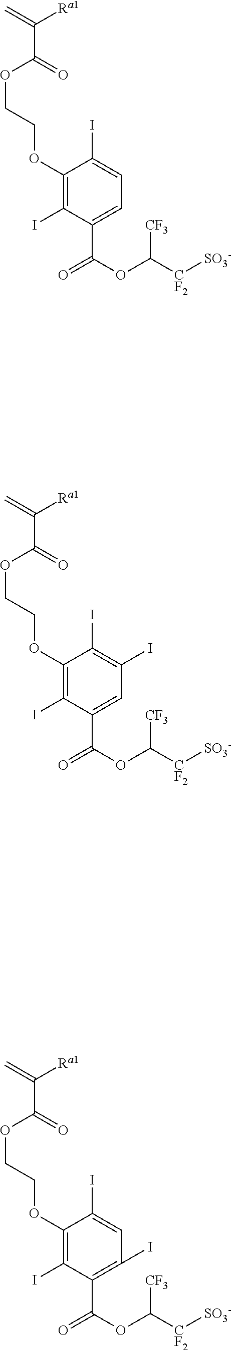

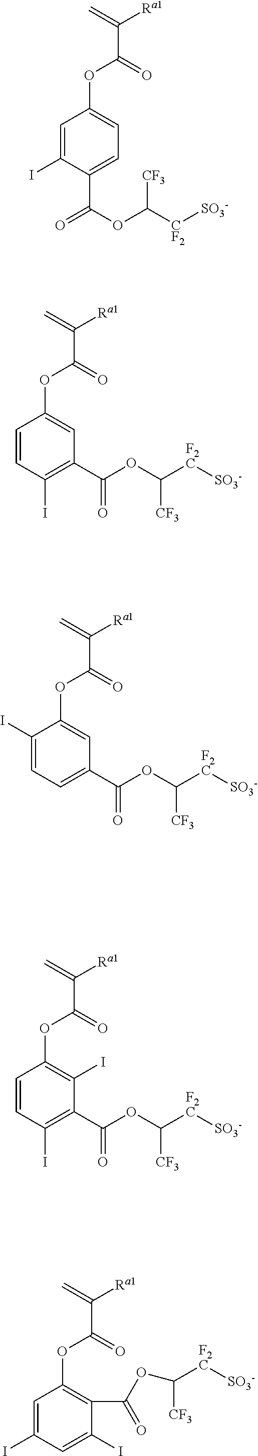

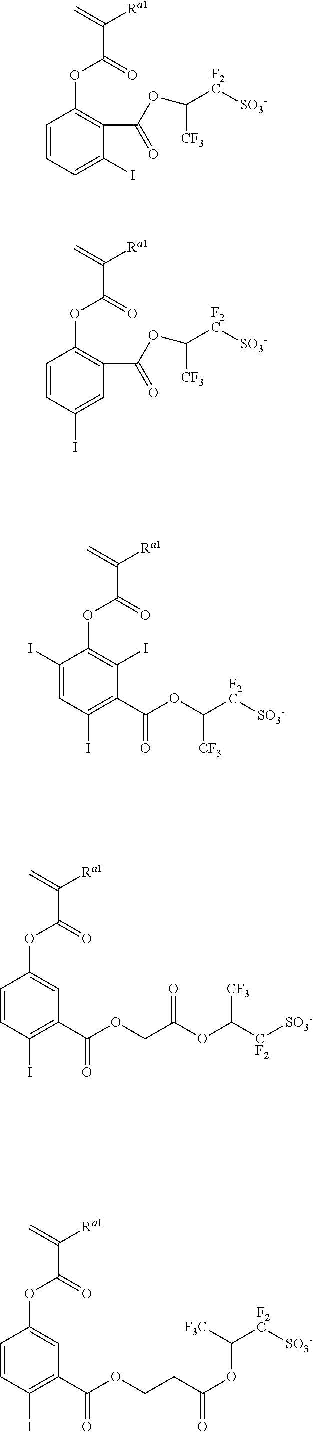

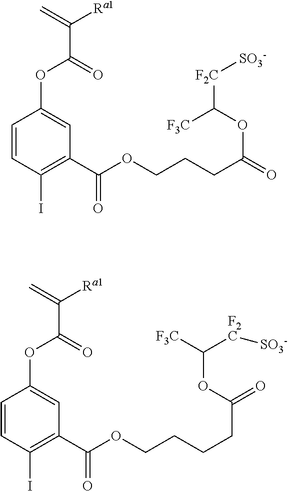

When the polymerizable group is a methacrylate, the polymer main chain becomes rigid, thereby raising the glass transition temperature. As a result, thermal diffusion of the strong acid component generated from the photoacid generator is inhibited to improve resolution.

(M₁⁺ in Repeating Unit (a1))

M₁⁺ in the repeating unit (a1) is a sulfonium cation, and preferably has an iodine atom. The iodine atom, which has large absorption of EUV light, can efficiently generate secondary electrons from photons given by EUV exposure, and therefore, high sensitivity and high resolution are expected.

Specific examples of M₁⁺ in the repeating unit (a1) include, but not limited to, the following sulfonium cations.

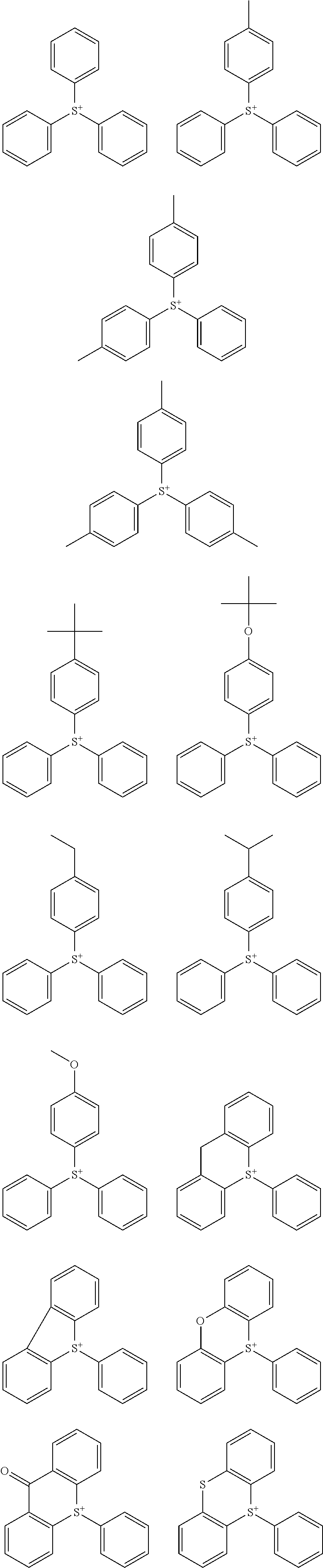

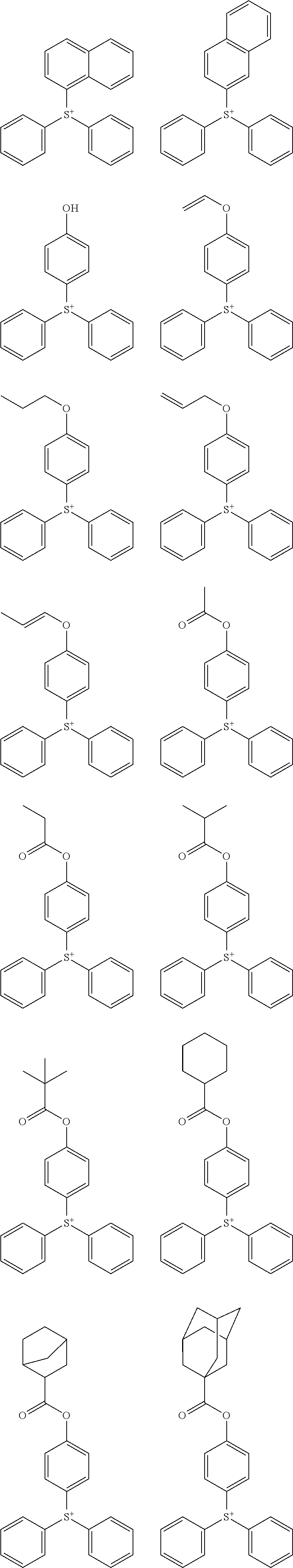

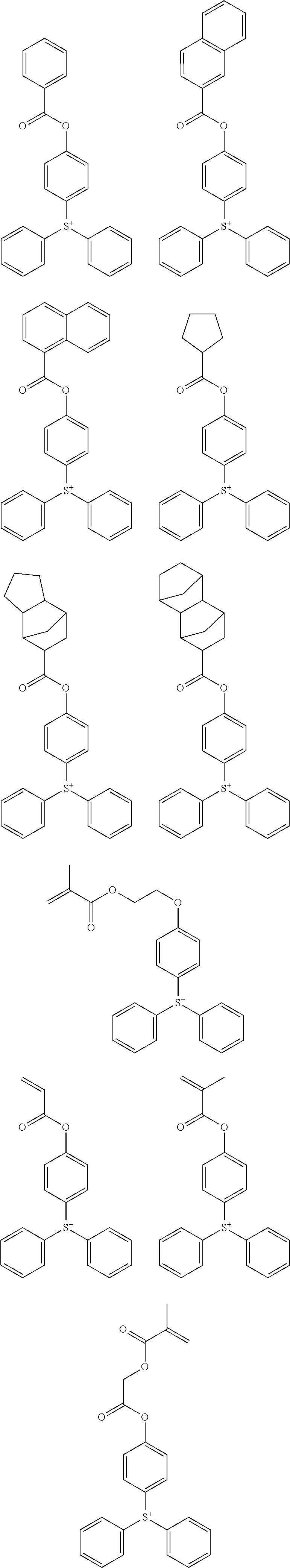

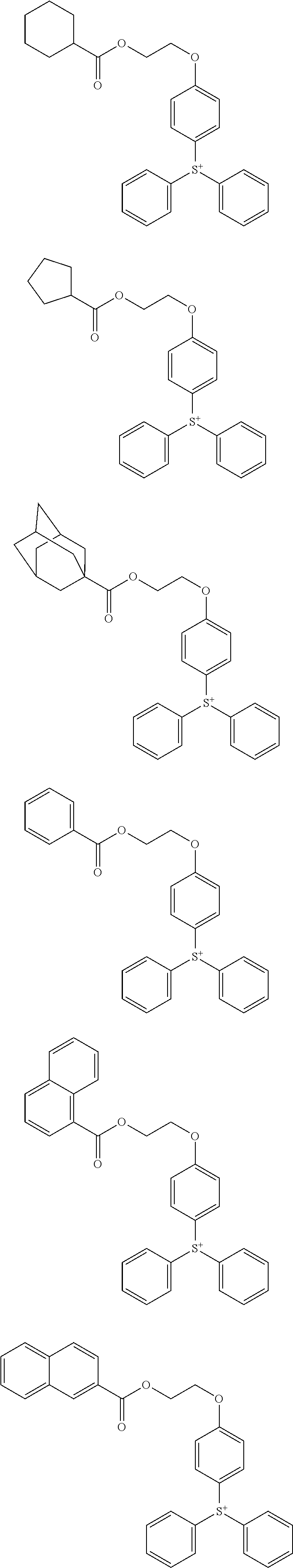

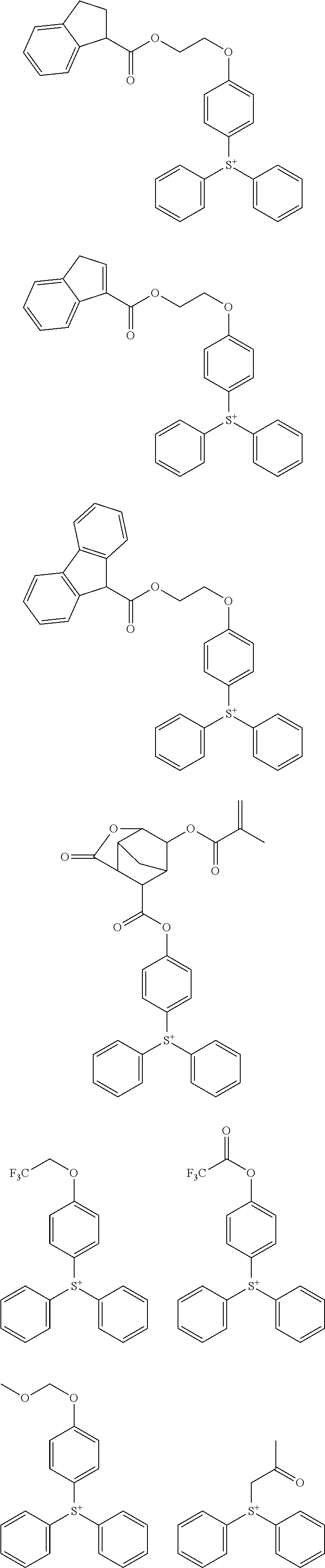

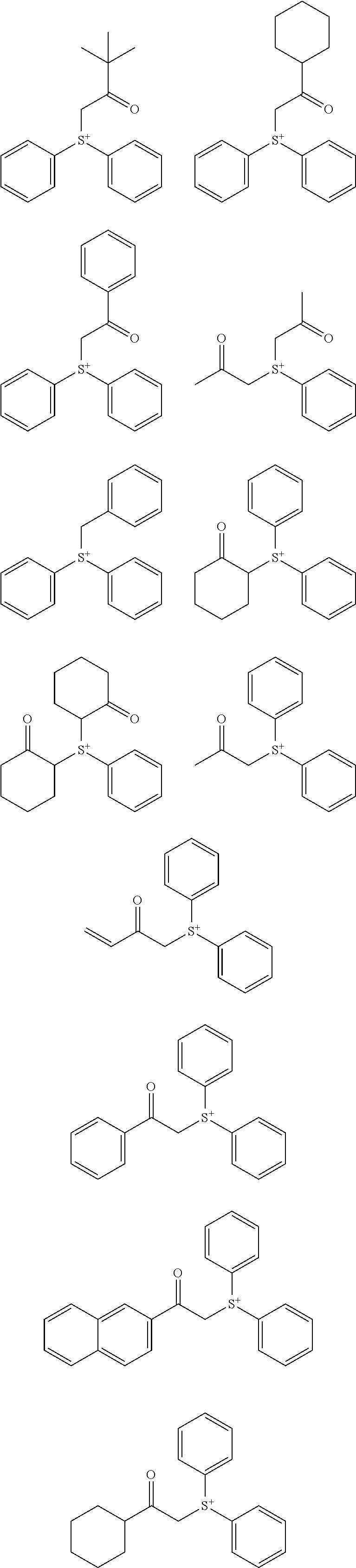

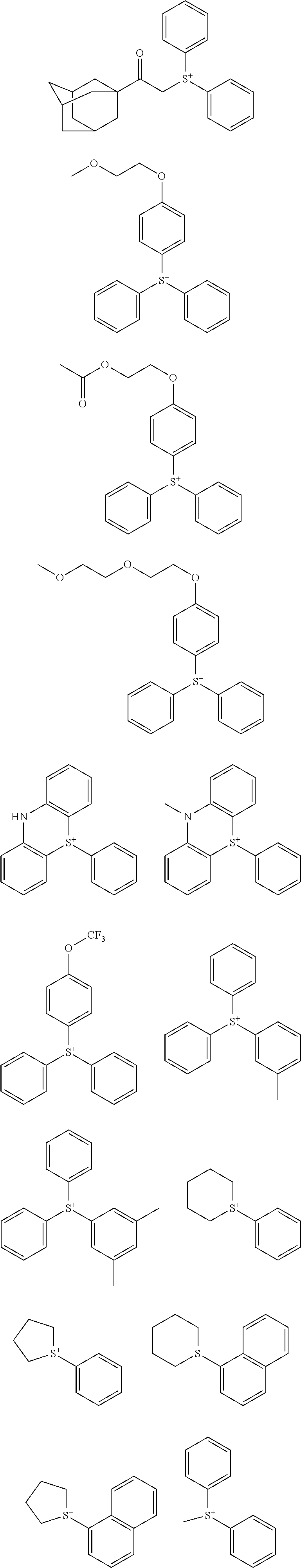

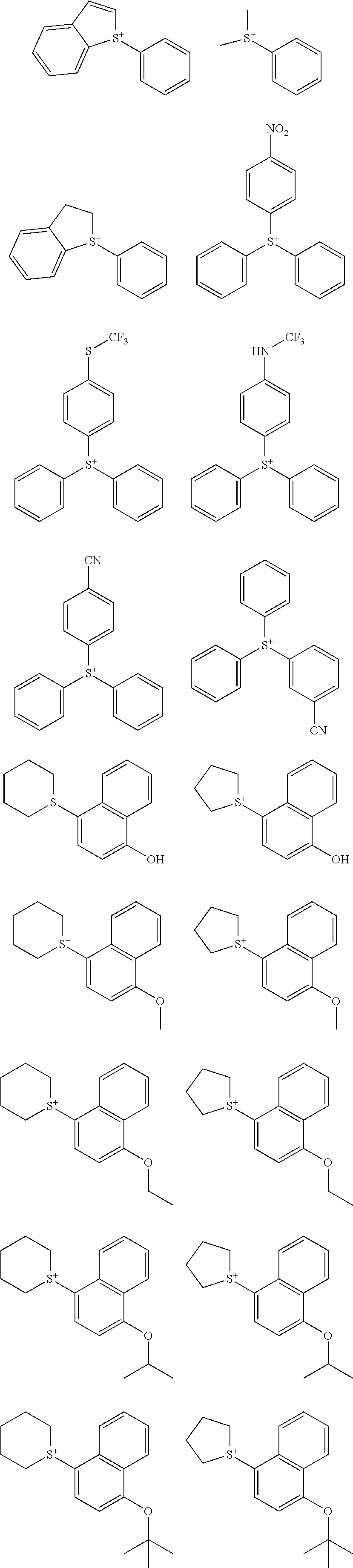

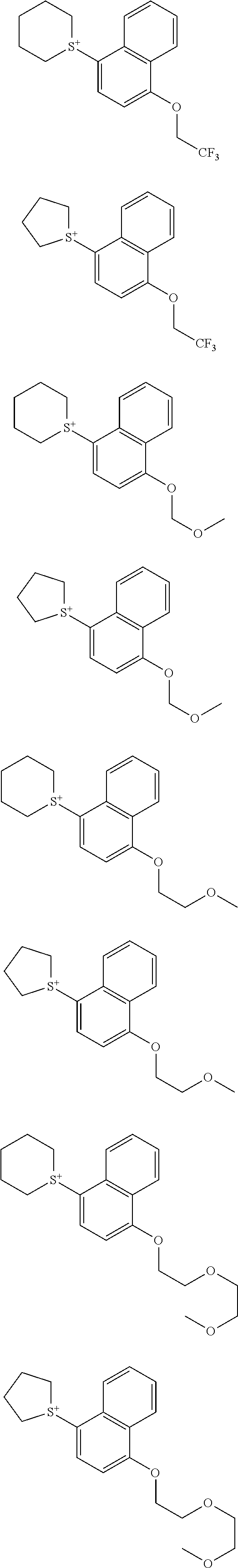

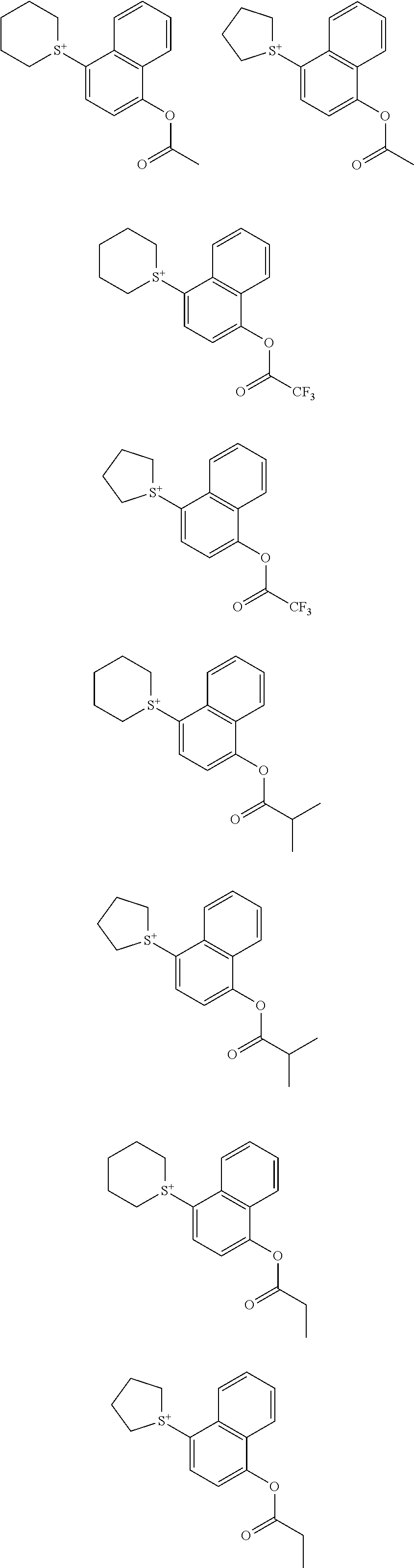

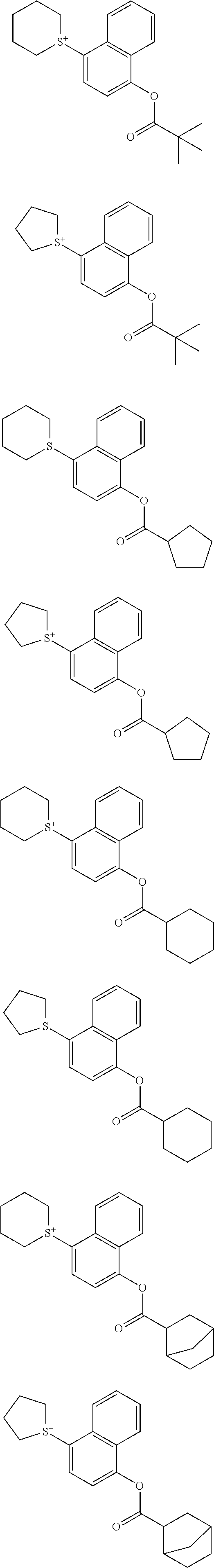

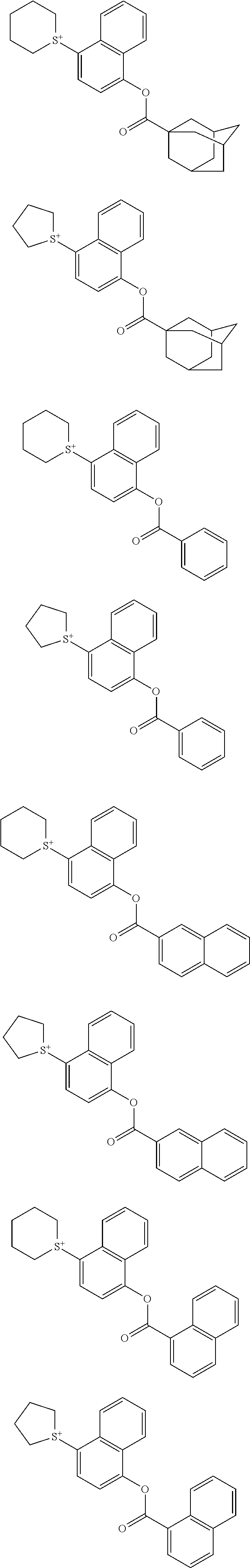

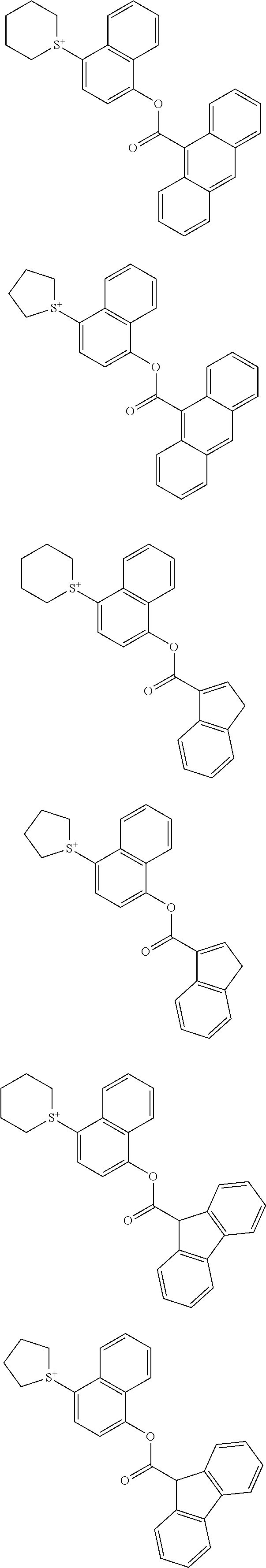

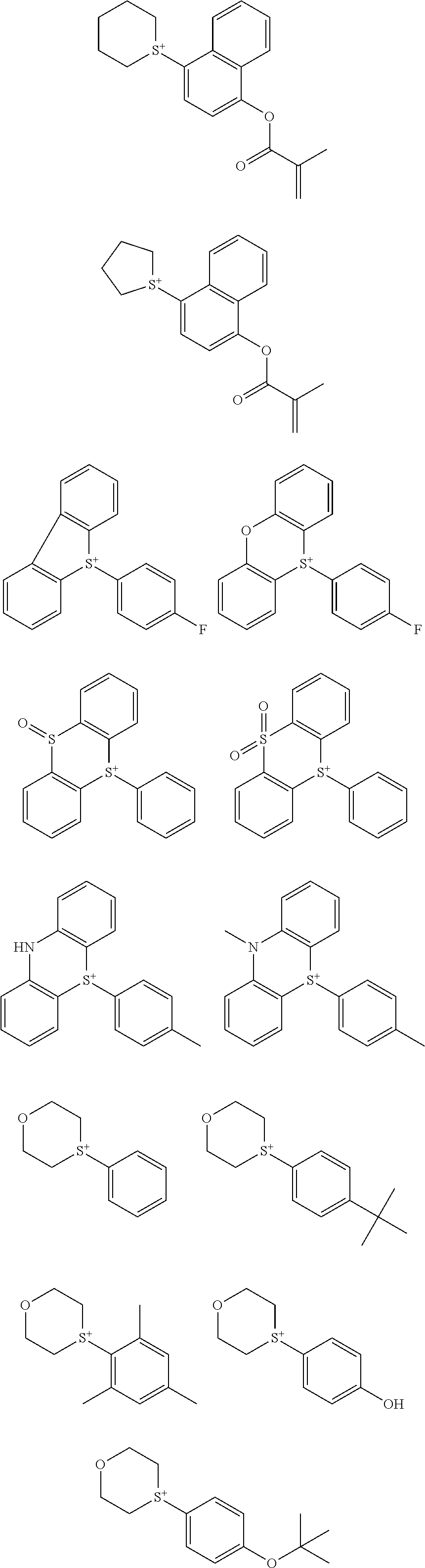

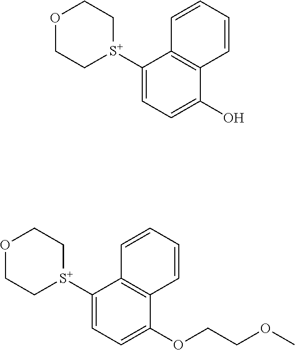

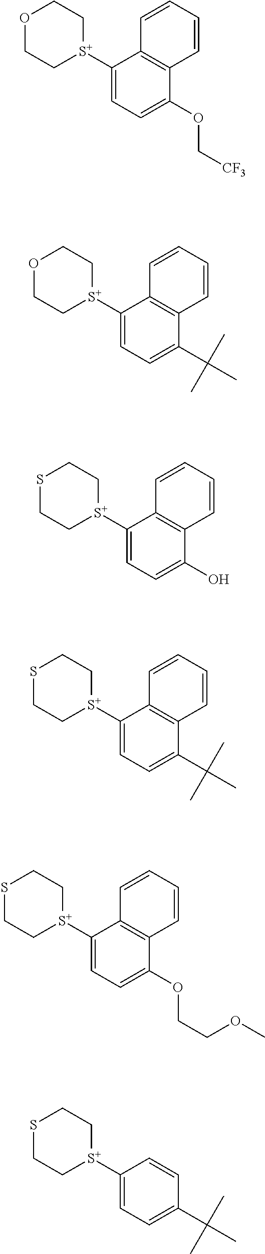

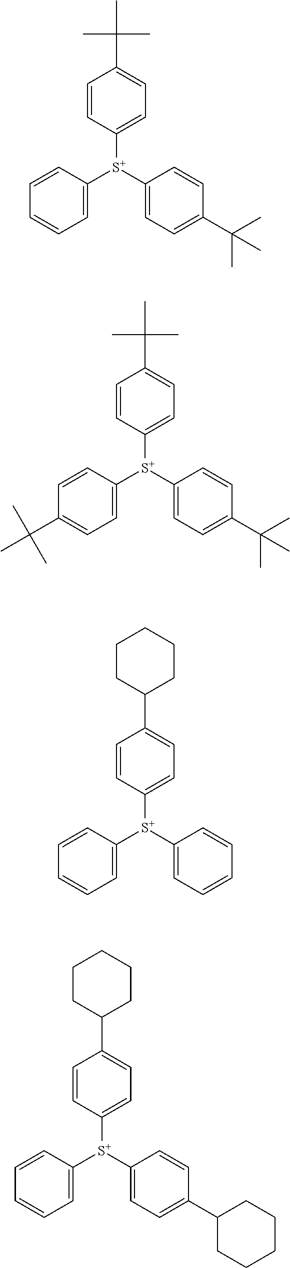

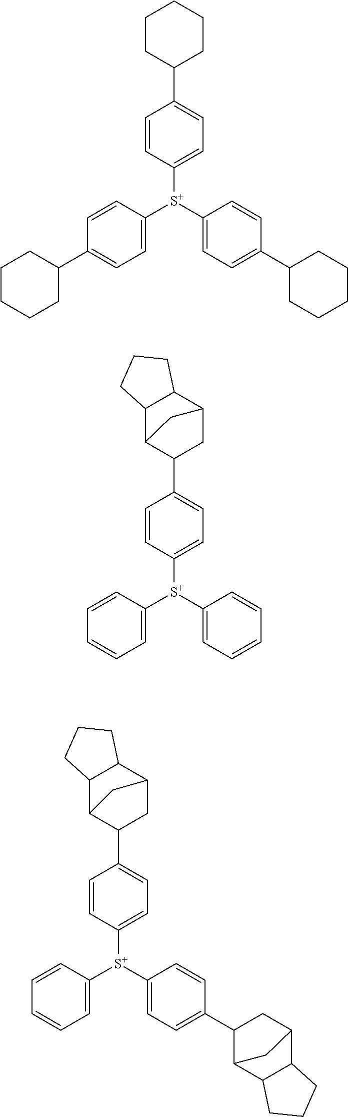

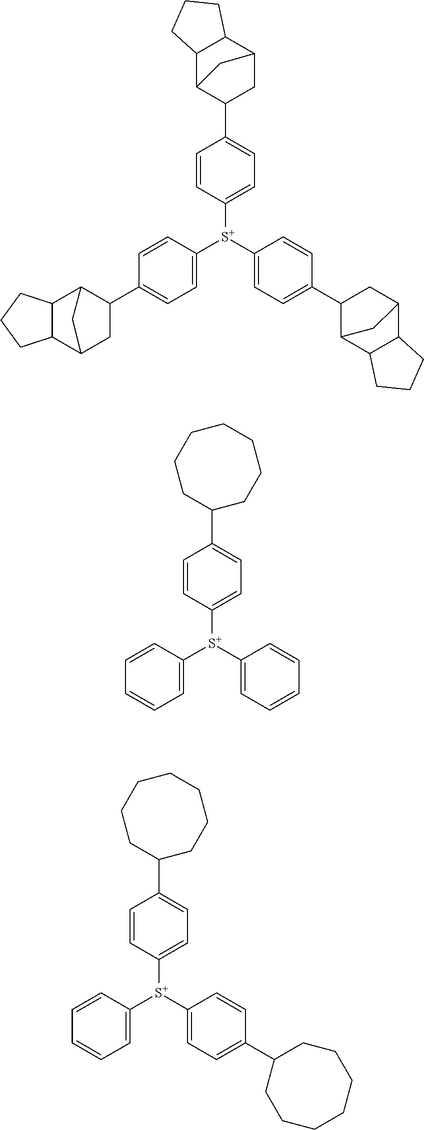

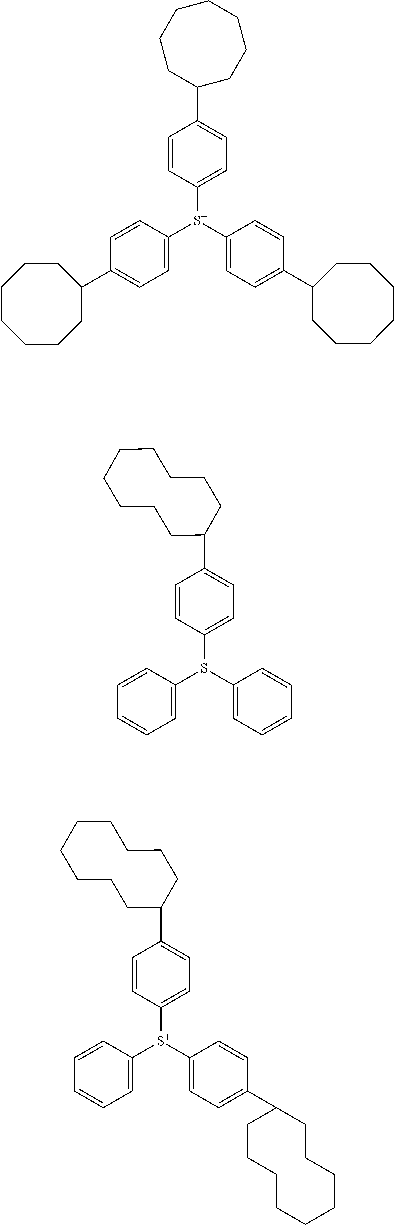

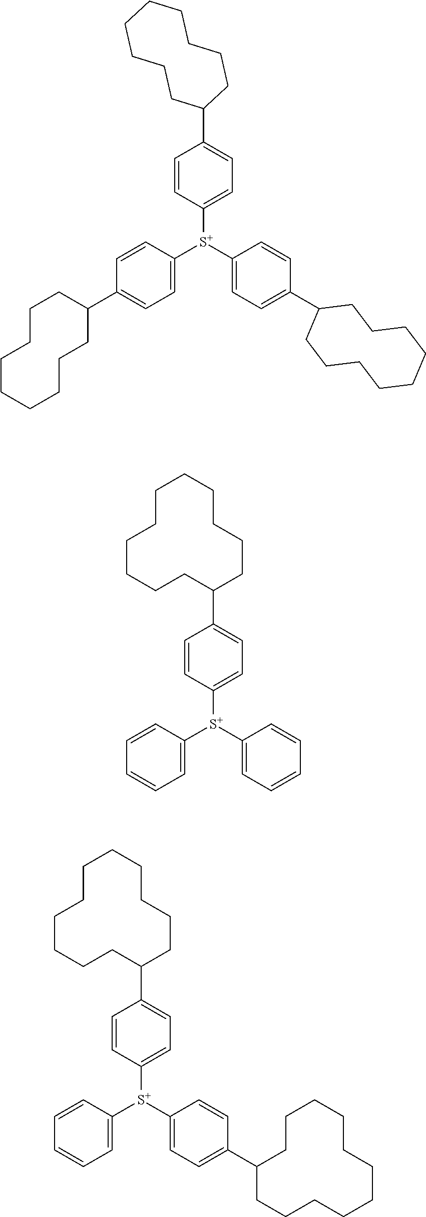

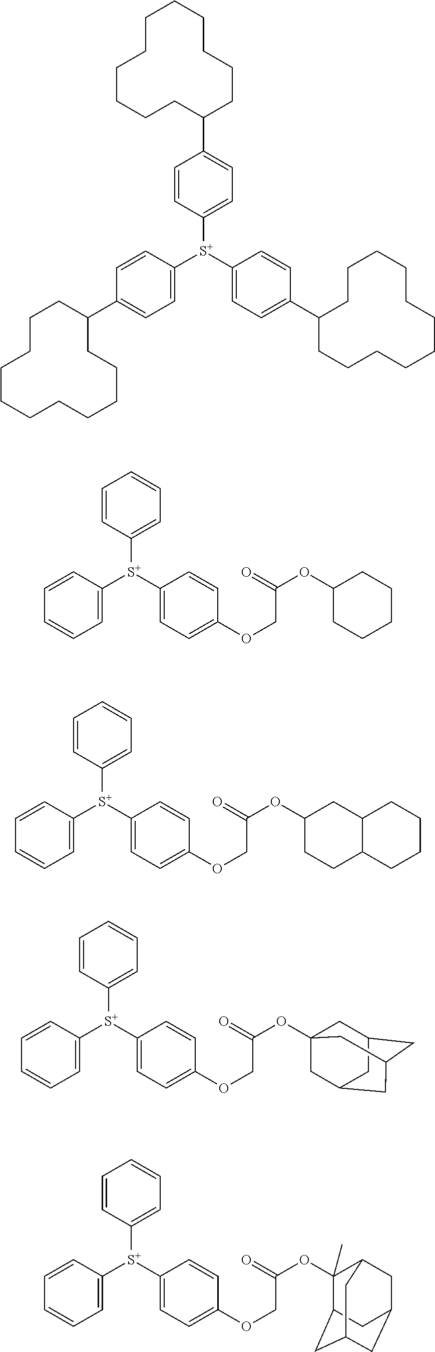

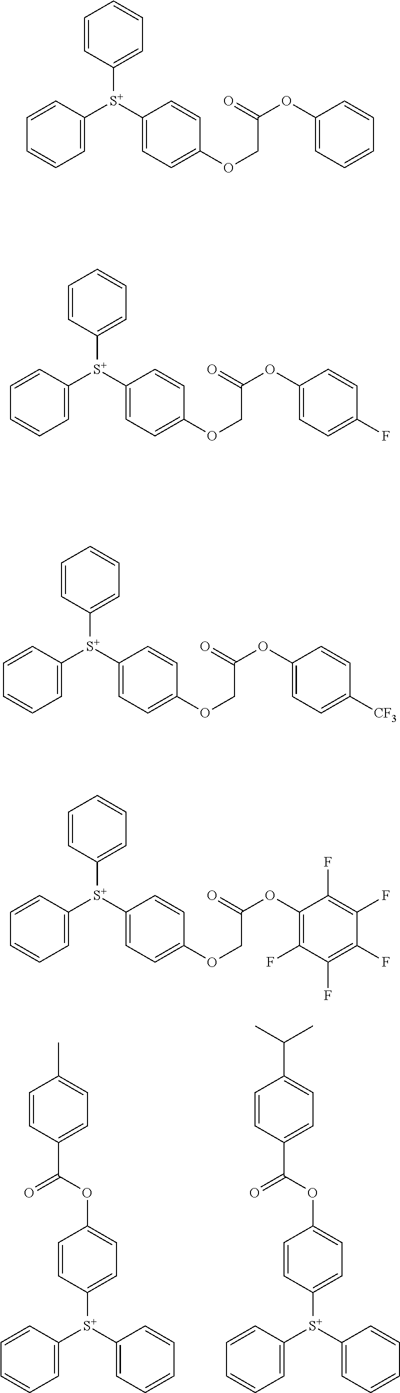

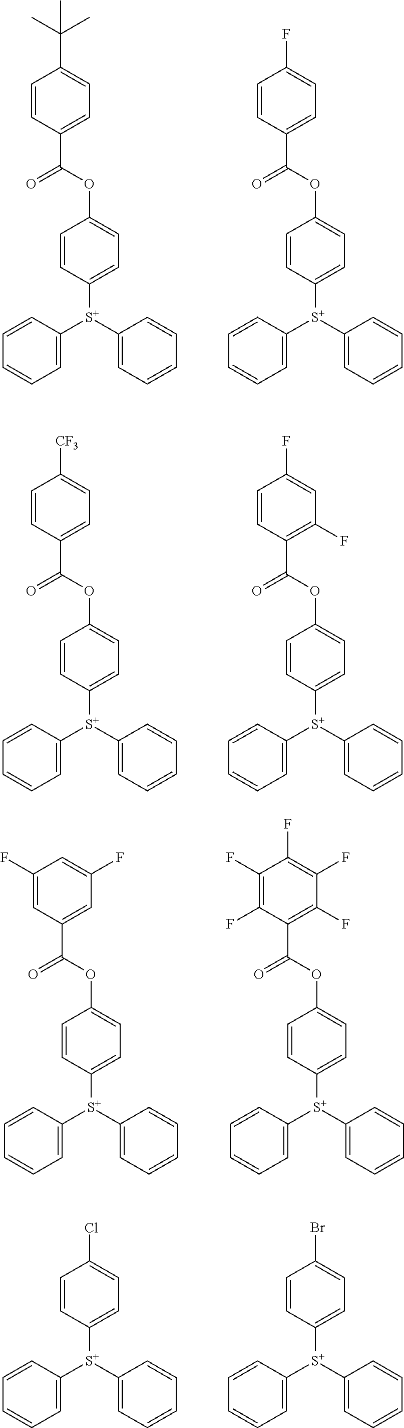

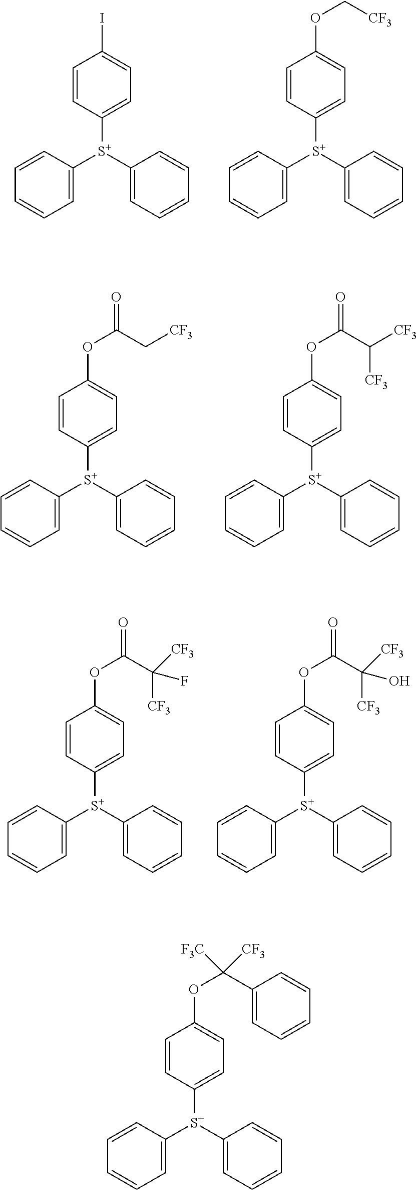

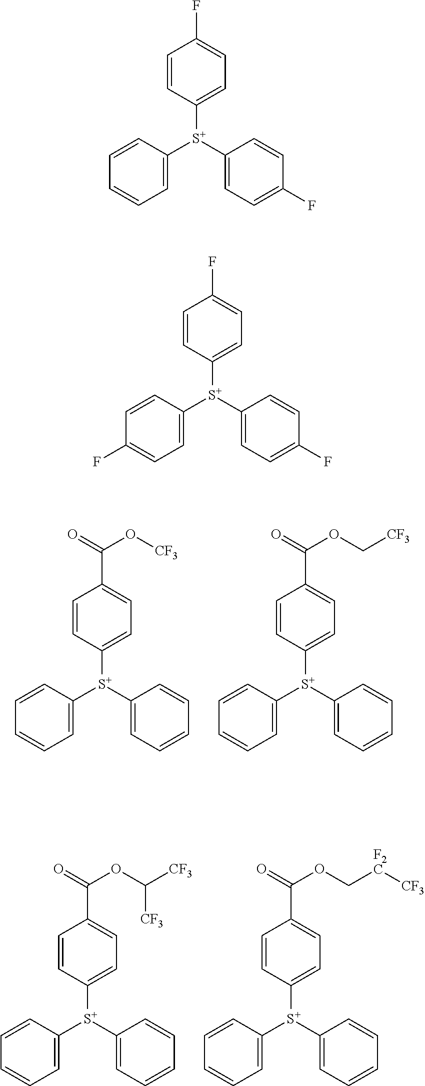

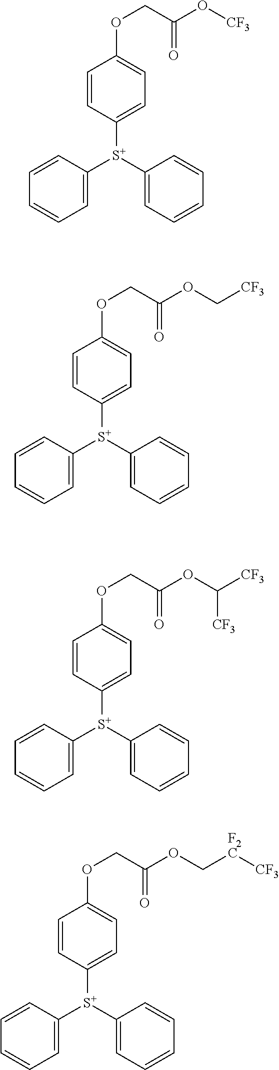

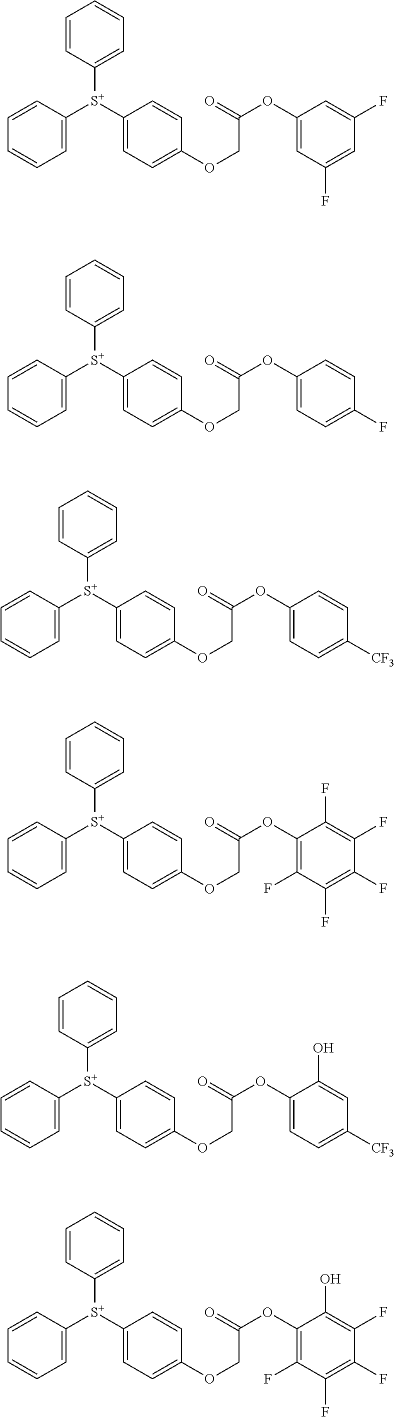

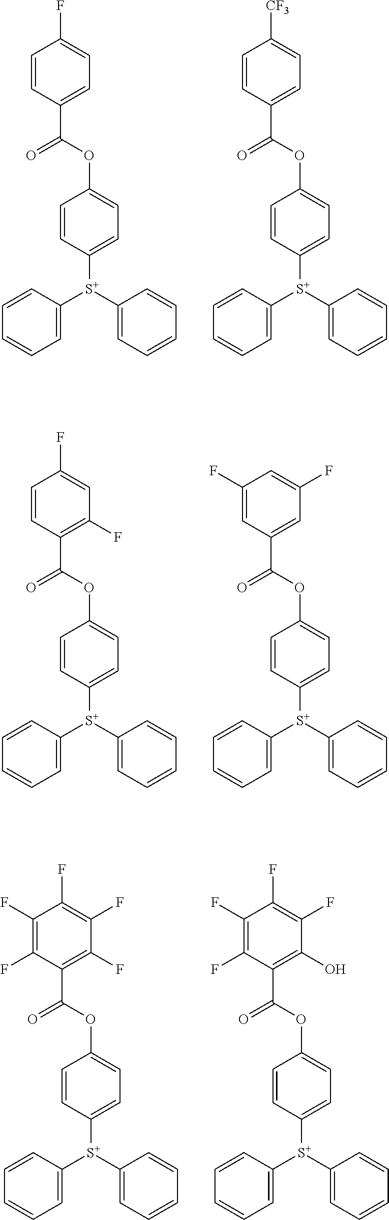

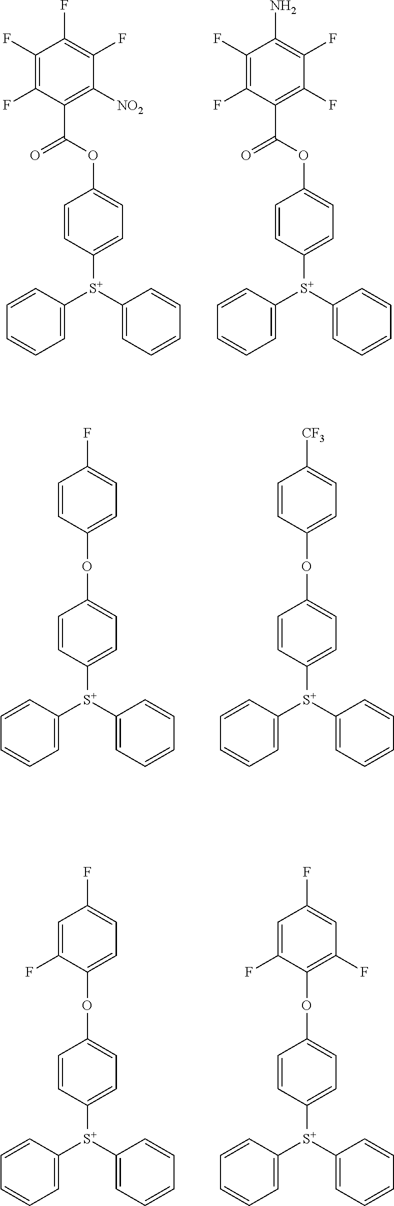

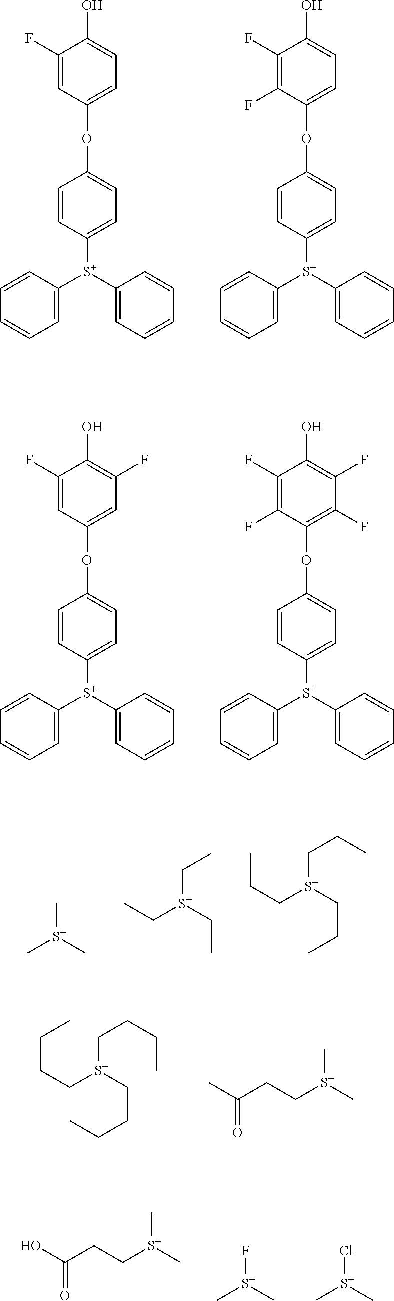

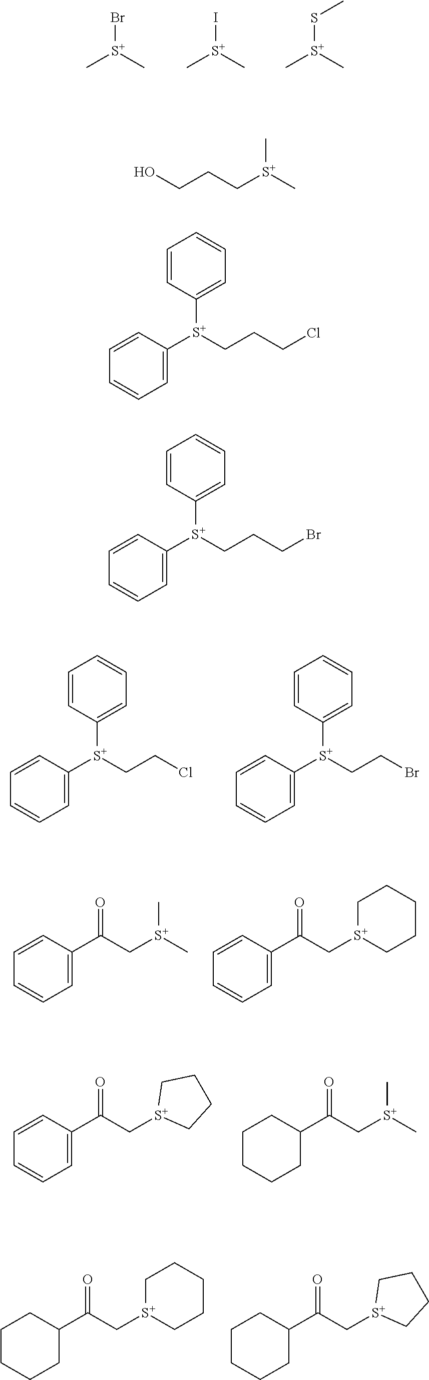

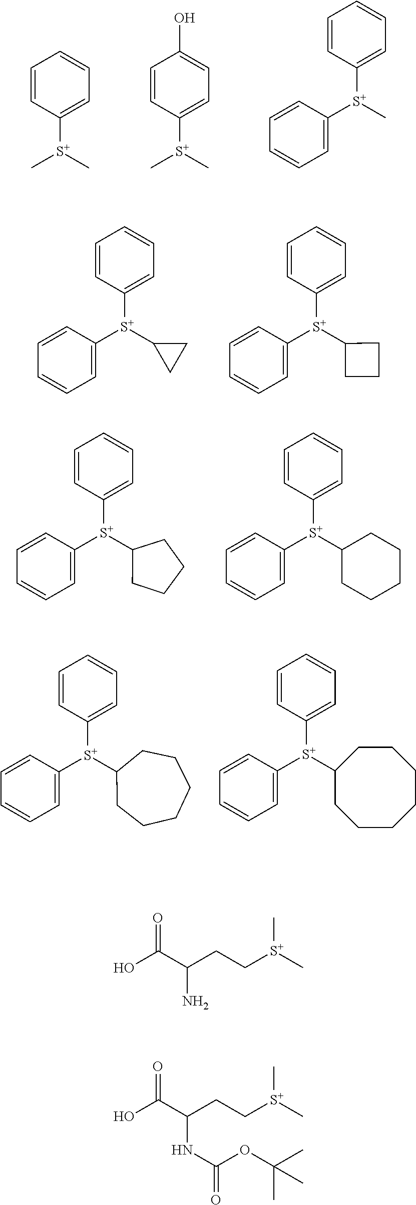

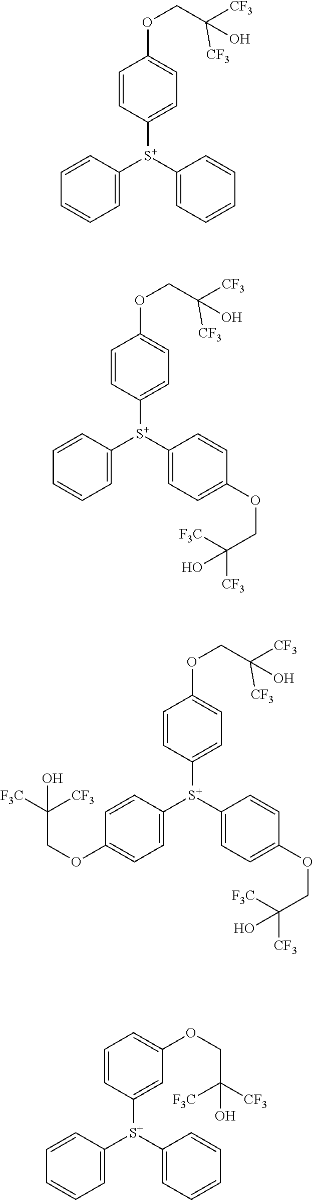

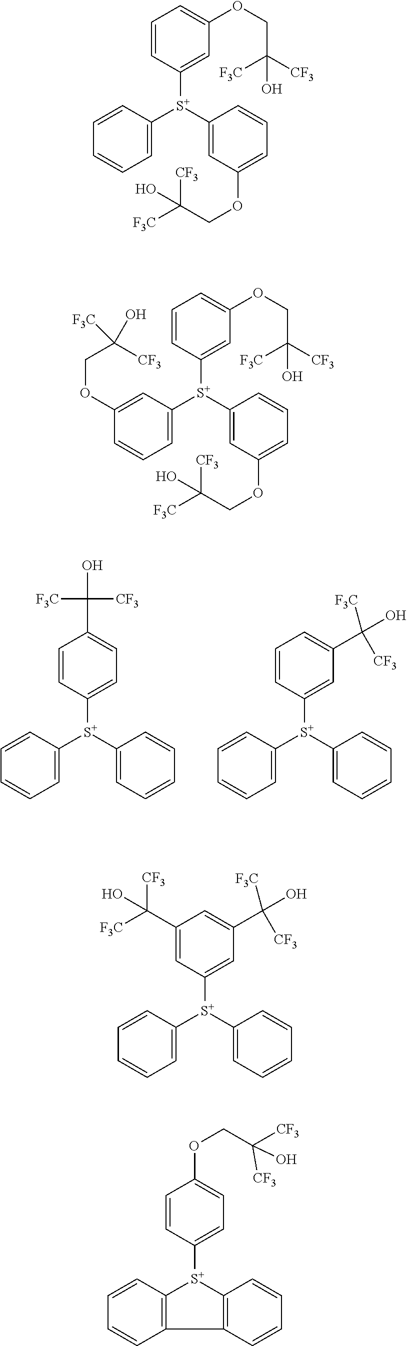

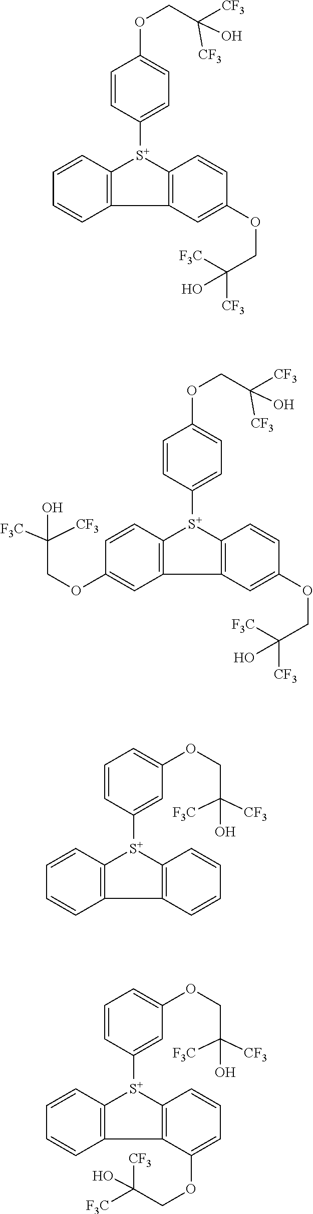

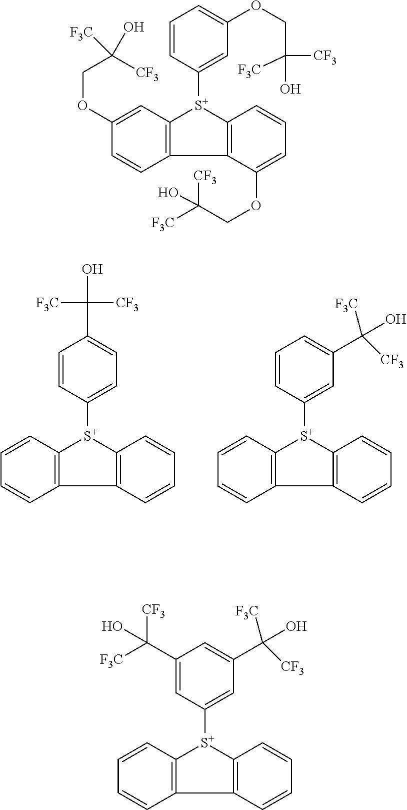

### (Sulfonium Cation Represented by General Formula (1))

M₁⁺ in the repeating unit (a1) preferably represents a sulfonium cation represented by the following formula (1).

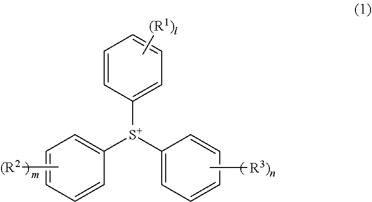

In the formula, R¹ represents a fluorine atom, an iodine atom, or a perfluoroalkyl group. R² and R³ each independently represent a fluorine atom or a perfluoroalkyl group. “l” represents an integer of 0 to 3, “m” represents an integer of 1 to 3, and “n” represents an integer of 1 to 3. When “l”, “m”, or “n” represents an integer of 2 or more, each of R¹, R², and R³ may be same or different. Provided that structure of the formula (1) has at least two or more fluorine atoms. When R² or R³ represents a fluorine atom, at least one fluorine atom is substituted at a meta-position relative to a sulfur atom.

The sulfonium cation as above can increase electrophilicity, and can efficiently convert the secondary electrons generated by exposure into the acid. Therefore, high sensitivity and high resolution are expected.

In the formula (1), “l” represents an integer of 0 to 3, preferably an integer of 1 to 2, and more preferably satisfies 1=1. “m” represents an integer of 1 to 3, preferably an integer of 1 to 2, and more preferably satisfies m=2. “n” represents an integer of 1 to 3, preferably an integer of 1 to 2, and more preferably satisfies n=2.

A number of fluorine atoms contained in the formula (1) is preferably three or more, and more preferably four or more.

R² and R³ in the formula (1) preferably represent a fluorine atom or a trifluoromethyl group, and more preferably a fluorine atom.

The sulfonium cation represented by the formula (1) preferably has one or more iodine atoms, and preferably only one iodine atom.

R¹ in the formula (1) preferably represents a fluorine atom or an iodine atom, and more preferably an iodine atom.

The iodine atom, which has large absorption of EUV light, can efficiently generate secondary electrons from photons given by EUV exposure, and therefore, high sensitivity and high resolution are expected. In addition, the iodine atom bonded to the triarylsulfonium cation without a linker is expected to allow an efficient photochemical reaction to proceed.

In typical, a compound having many iodine atoms can increase absorption of EUV light, but may lead to deterioration in lithographic performance due to decrease in solubility in a cast solvent and a developer.

The compound having an iodine atom in both the anion moiety and the cation moiety in the repeating unit (a1) can increase the EUV absorption efficiency without impairing the solvent solubility, and therefore, improvement of lithographic performance can be expected.

Specific examples of the sulfonium cation represented by the formula (1) include, but not limited to, the following sulfonium cations.

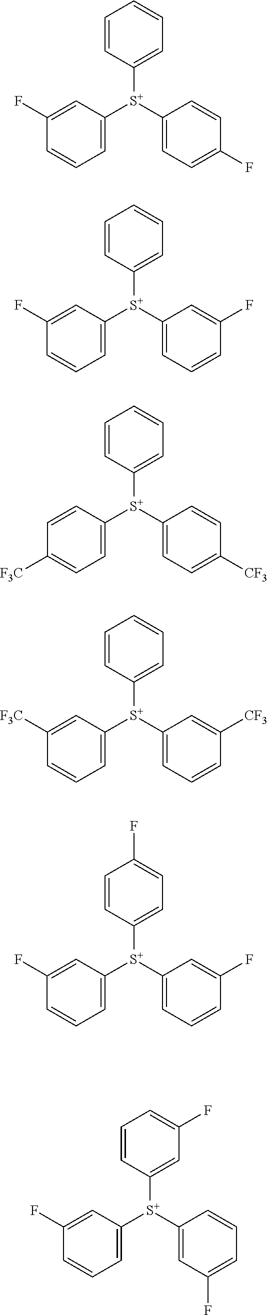 [SMILES: Fc1ccc([S+](c2ccccc2)c2cccc(F)c2)cc1 ; Fc1cccc([S+](c2ccccc2)c2cccc(F)c2)c1 ; FC(F)(F)c1ccc([S+](c2ccccc2)c2ccc(C(F)(F)F)cc2)cc1 ; FC(F)(F)c1cccc([S+](c2ccccc2)c2cccc(C(F)(F)F)c2)c1 ; Fc1ccc([S+](c2cccc(F)c2)c2cccc(F)c2)cc1 ; Fc1cccc([S+](c2cccc(F)c2)c2cccc(F)c2)c1]

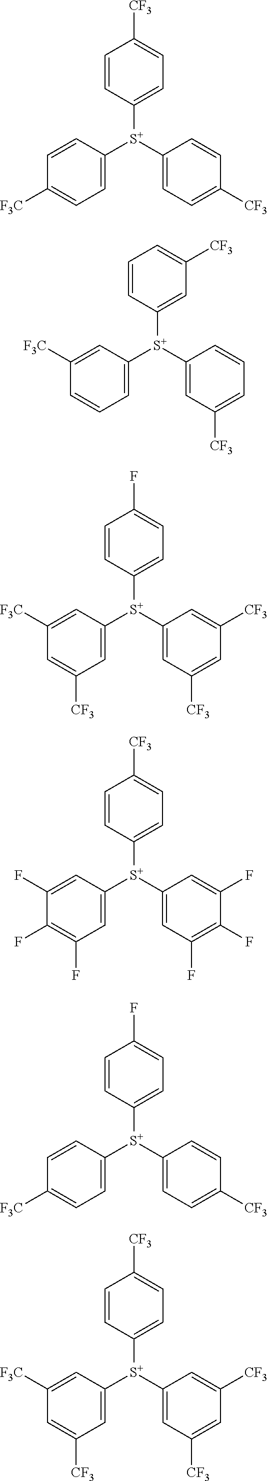 [SMILES: FC(F)(F)c1ccc([S+](c2ccc(C(F)(F)F)cc2)c2ccc(C(F)(F)F)cc2)cc1 ; FC(F)(F)c1cccc([S+](c2cccc(C(F)(F)F)c2)c2cccc(C(F)(F)F)c2)c1 ; Fc1ccc([S+](c2cc(C(F)(F)F)cc(C(F)(F)F)c2)c2cc(C(F)(F)F)cc(C(F)(F)F)c2)cc1 ; Fc1cc([S+](c2ccc(C(F)(F)F)cc2)c2cc(F)c(F)c(F)c2)cc(F)c1F ; Fc1ccc([S+](c2ccc(C(F)(F)F)cc2)c2ccc(C(F)(F)F)cc2)cc1 ; FC(F)(F)c1ccc([S+](c2cc(C(F)(F)F)cc(C(F)(F)F)c2)c2cc(C(F)(F)F)cc(C(F)(F)F)c2)cc1]

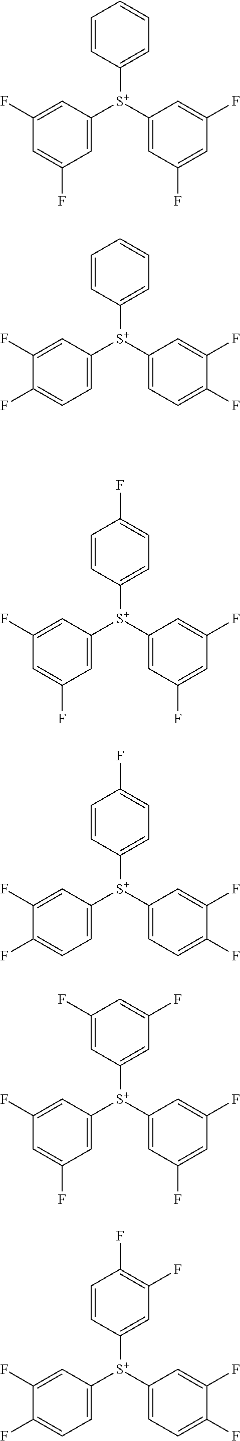 [SMILES: Fc1cc(F)cc([S+](c2ccccc2)c2cc(F)cc(F)c2)c1 ; Fc1ccc([S+](c2ccccc2)c2ccc(F)c(F)c2)cc1F ; Fc1ccc([S+](c2cc(F)cc(F)c2)c2cc(F)cc(F)c2)cc1 ; Fc1ccc([S+](c2ccc(F)c(F)c2)c2ccc(F)c(F)c2)cc1 ; Fc1cc(F)cc([S+](c2cc(F)cc(F)c2)c2cc(F)cc(F)c2)c1 ; Fc1ccc([S+](c2ccc(F)c(F)c2)c2ccc(F)c(F)c2)cc1F]

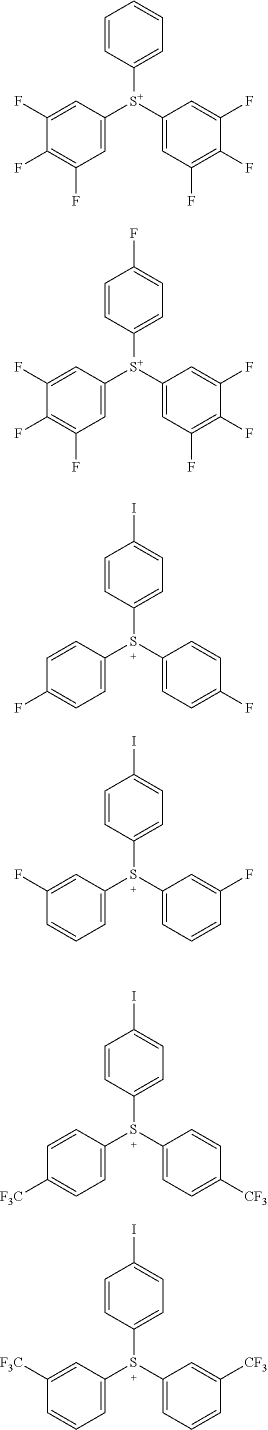

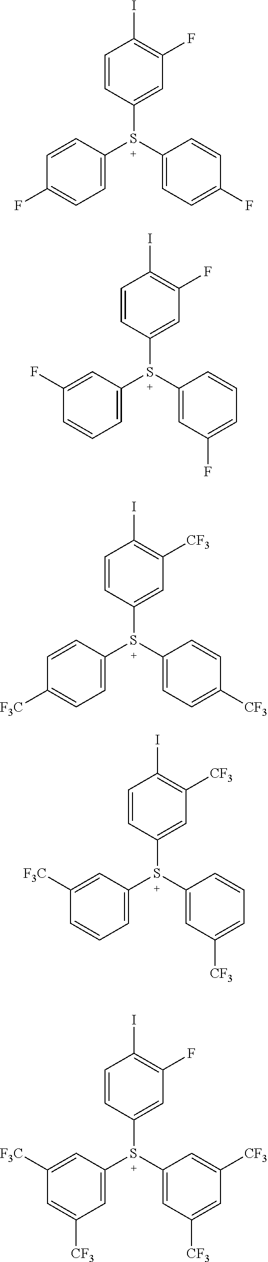

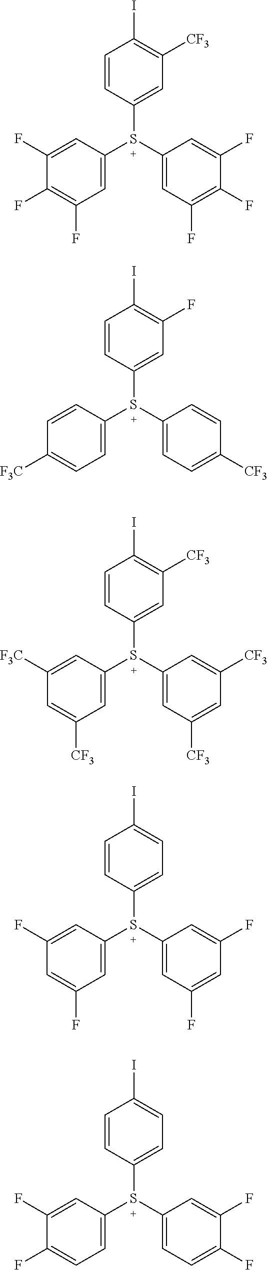

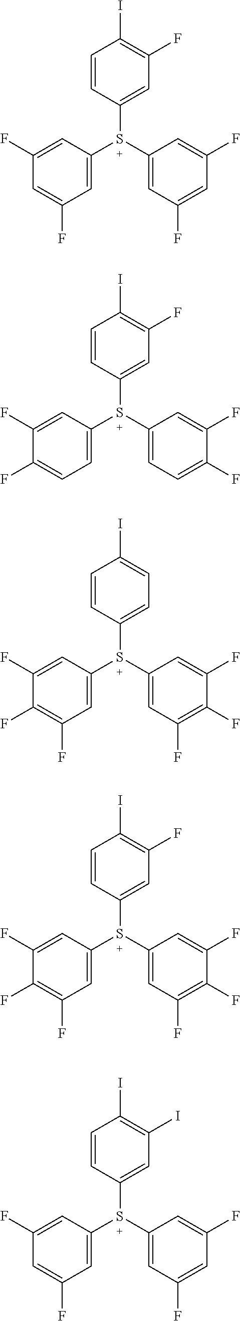

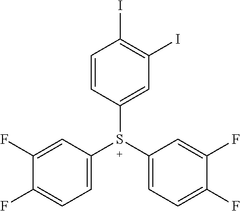

It is considered that electrophilicity of a triarylsulfonium cation can be estimated by calculating a lowest unoccupied molecular orbital (LUMO) level of the molecule. The LUMO level can be calculated by density functional method (DFT). Examples of a software that can perform the DFT calculation include Gaussian16.

The LUMO level of a triphenylsulfonium cation that is obtained as a result of DFT calculation using Gaussian16 with B3LYP as the functional, and 6-31G(d) as the basis function, is −4.72 eV. The energy of the LUMO level of the sulfonium cation represented by the formula (1) is lower than −4.72 eV, which indicates high electrophilicity, and the acid generation efficiency is considered to be improved.

The LUMO level of the sulfonium cation represented by the formula (1) is lower than −4.72 eV, more preferably −5.00 eV or lower, more preferably −5.10 eV or lower, more preferably −5.20 eV or lower, and more preferably −5.30 eV or lower.

Meanwhile, since storage stability deteriorates as the LUMO level becomes low, the LUMO level of the sulfonium cation represented by the formula (1) is preferably −5.50 eV or higher, more preferably −5.45 eV or higher, more preferably −5.40 eV or higher, and more preferably −5.35 eV or higher.

Calculation examples of the LUMO level of the sulfonium cation represented by the formula (1) are shown below, but the preferable structure is not limited thereto. For calculating the LUMO, Gaussian16 is used, B3LYP is used as the functional, and 6-31G(d) is used as the basis function. For the iodine atom, effective core potential approximation is performed, and LanL2DZ is applied for the basis function.

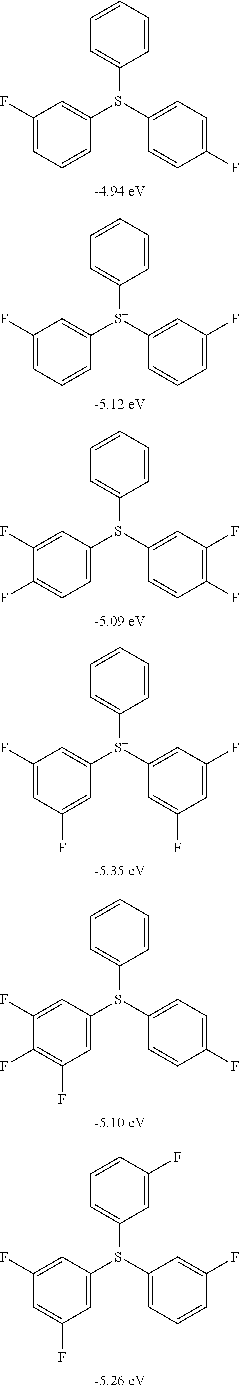 [SMILES: Fc1ccc([S+](c2ccccc2)c2cccc(F)c2)cc1 ; Fc1cccc([S+](c2ccccc2)c2cccc(F)c2)c1 ; Fc1ccc([S+](c2ccccc2)c2ccc(F)c(F)c2)cc1F ; Fc1cc(F)cc([S+](c2ccccc2)c2cc(F)cc(F)c2)c1 ; Fc1ccc([S+](c2ccccc2)c2cc(F)c(F)c(F)c2)cc1 ; Fc1cccc([S+](c2cccc(F)c2)c2cc(F)cc(F)c2)c1]

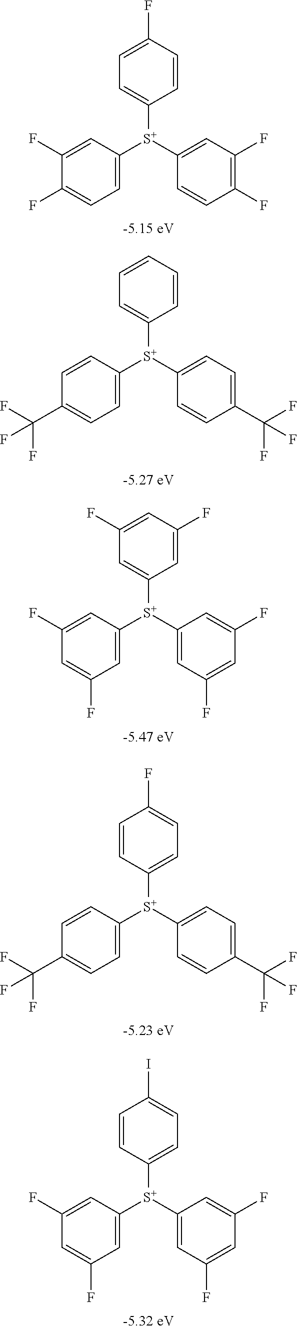 [SMILES: Fc1ccc([S+](c2ccc(F)c(F)c2)c2ccc(F)c(F)c2)cc1 ; FC(F)(F)c1ccc([S+](c2ccccc2)c2ccc(C(F)(F)F)cc2)cc1 ; Fc1cc(F)cc([S+](c2cc(F)cc(F)c2)c2cc(F)cc(F)c2)c1 ; Fc1ccc([S+](c2ccc(C(F)(F)F)cc2)c2ccc(C(F)(F)F)cc2)cc1 ; Fc1cc(F)cc([S+](c2ccc(I)cc2)c2cc(F)cc(F)c2)c1]

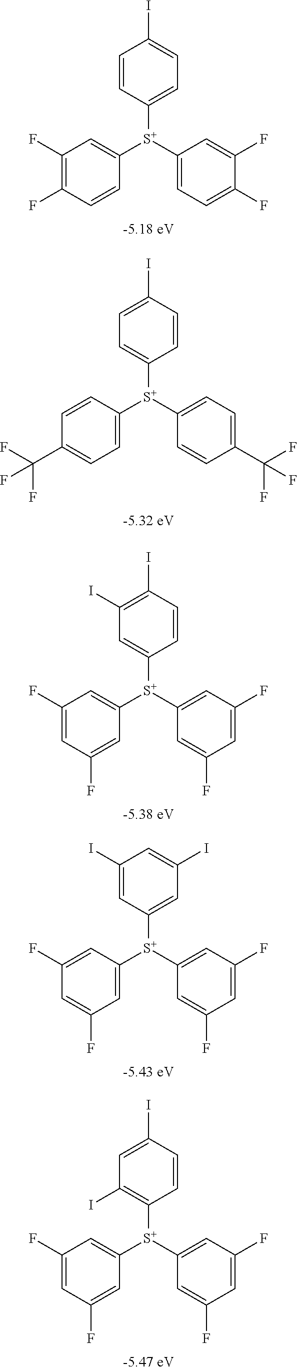 [SMILES: Fc1ccc([S+](c2ccc(I)cc2)c2ccc(F)c(F)c2)cc1F ; FC(F)(F)c1ccc([S+](c2ccc(I)cc2)c2ccc(C(F)(F)F)cc2)cc1 ; Fc1cc(F)cc([S+](c2cc(F)cc(F)c2)c2ccc(I)c(I)c2)c1 ; Fc1cc(F)cc([S+](c2cc(F)cc(F)c2)c2cc(I)cc(I)c2)c1 ; Fc1cc(F)cc([S+](c2cc(F)cc(F)c2)c2ccc(I)cc2I)c1]

The repeating unit represented by the formula (a1) is preferably represented by the following formula (a1-1).

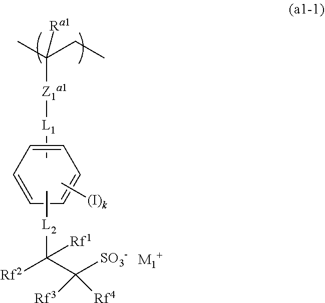

In the formula, Rai each independently represents a hydrogen atom or a methyl group. Z₁^{a1} represents a single bond or an ester bond. L₁ represents a single bond or a divalent linking group optionally having an ester bond, an ether bond, a lactone ring, an aromatic ring, a fluorine atom, a bromine atom, or an iodine atom. L₂ represents a single bond or a divalent linking group optionally having an ester bond or an ether bond. Rf¹ to Rf⁴ each independently represent a hydrogen atom, a fluorine atom, or a trifluoromethyl group. Provided that at least one of Rf¹ to Rf⁴ represents a fluorine atom. “k” represents an integer of 0 to 4. M₁⁺ represents a sulfonium cation.

The repeating unit with the structure as above yields high sensitivity and high resolution, reduced edge roughness and dimensional deviation, and a good pattern shape after exposure.

The repeating unit represented by the formula (a1) is preferably represented by the following formula (a1-2).

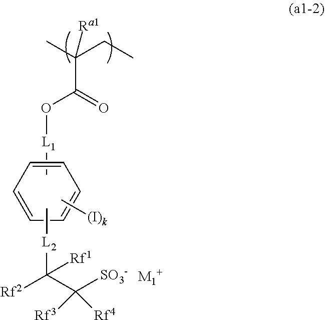

In the formula, Rai each independently represents a hydrogen atom or a methyl group. L₁ represents a single bond or a divalent linking group optionally having an ester bond, an ether bond, a lactone ring, an aromatic ring, a fluorine atom, a bromine atom, or an iodine atom. L₂ represents a single bond or a divalent linking group optionally having an ester bond or an ether bond. Rf¹ to Rf⁴ each independently represent a hydrogen atom, a fluorine atom, or a trifluoromethyl group, provided that at least one of Rf¹ to Rf⁴ represents a fluorine atom. “k” represents an integer of 0 to 4. M₁⁺ represents a sulfonium cation.

The resin as above in which the polymerizable group is a methacrylate allows the polymer main chain to be rigid, thereby raising the glass transition temperature. As a result, thermal diffusion of the strong acid component generated from the photoacid generator is inhibited to improve resolution.

(Repeating Unit Represented by Formula (a2))

The base polymer preferably further has a repeating unit represented by the following formula (a2).

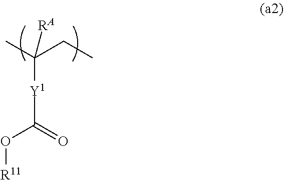

In the formula, R^{A} each independently represents a hydrogen atom or a methyl group. Y¹ represents a single bond, a phenylene group or a naphthylene group, or a linking group having 1 to 12 carbon atoms and having an ester bond, an ether bond, or a lactone ring. R¹¹ represents an acid-labile group.

The base polymer having the repeating unit represented by the formula (a2) in which a hydrogen atom in a carboxy group is substituted with the acid-labile group allows the resist composition to have high dissolution contrast, which is excellent.

Specific examples of a monomer to yield (a2) include, but not limited to, the following monomers. In the following formulae, R^{A} and R¹¹ are the same as defined in the formula (a2).

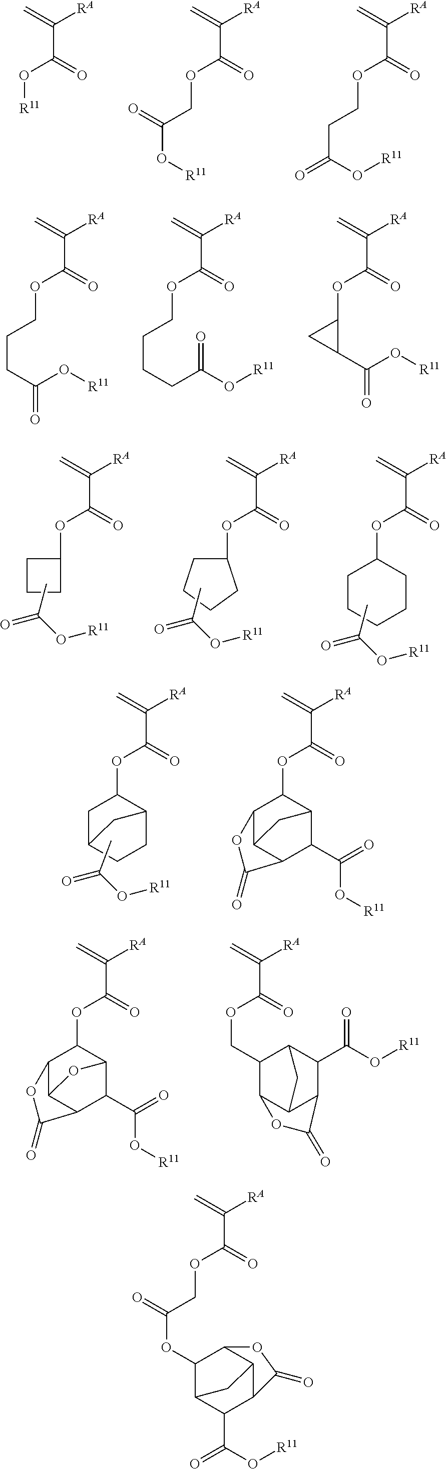

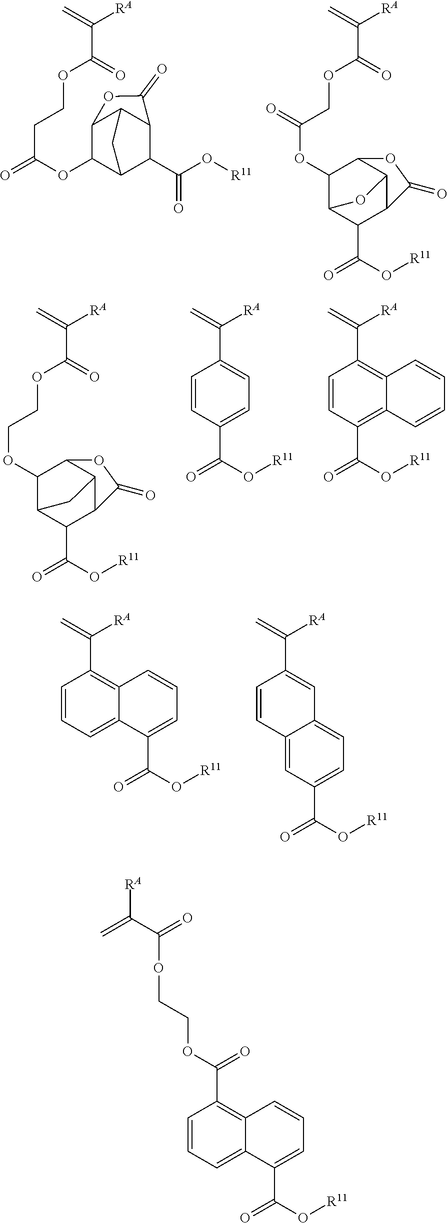

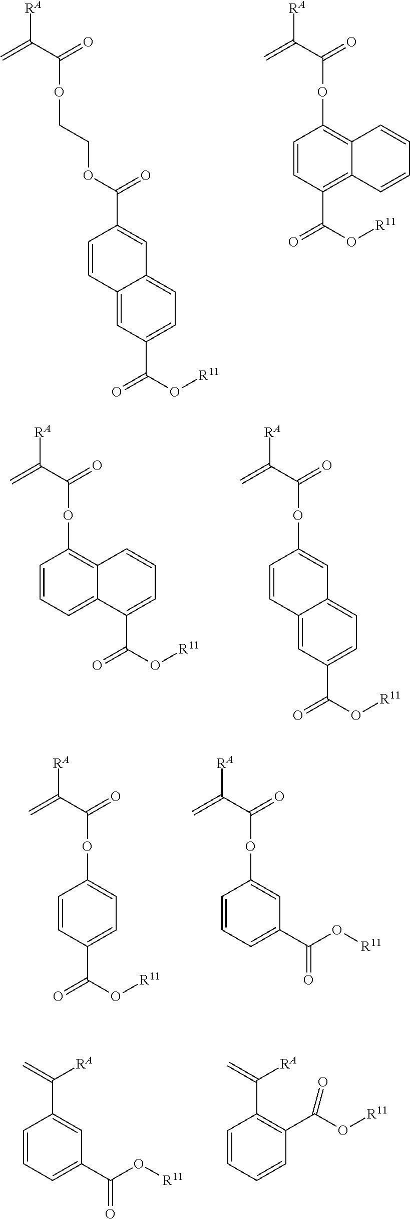

The base polymer may have a repeating unit (a2-2) in which a hydrogen atom of a phenolic hydroxy group is substituted with an acid-labile group.

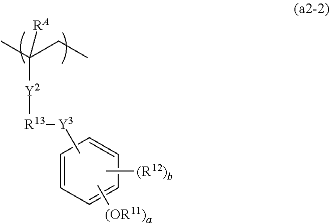

In the general formula (a2-2), R^{A} is the same as R^{A} in the formula (a2). Preferable examples thereof are also the same. Y² represents a single bond or an ester bond. Y³ represents a single bond, an ether bond, or an ester bond. R¹¹ represents an acid-labile group. R¹² represents a fluorine atom, a trifluoromethyl group, a cyano group, or a saturated hydrocarbyl group having 1 to 6 carbon atoms. R¹³ represents a single bond or an alkanediyl group having 1 to 6 carbon atoms, and a part of carbon atoms therein is optionally substituted with an ether bond or an ester bond. “a” represents 1 or 2. “b” represents an integer of 0 to 4. Note that 1≤a+b≤5.

Specific examples of a monomer to yield the repeating unit (a2-2) include, but not limited to, the following monomers. In the following formulae, R^{A} and R¹¹ are the same as R^{A} and R¹¹ in the formula (a2).

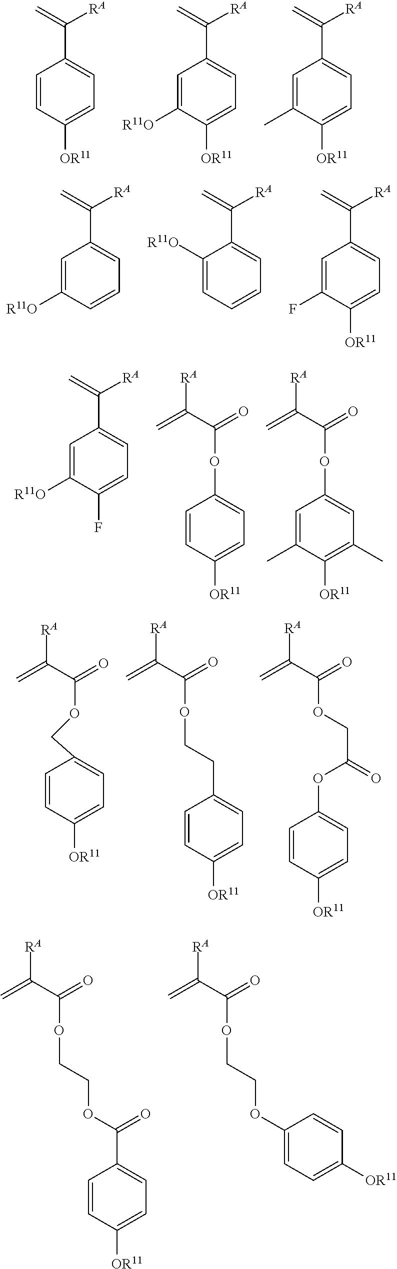

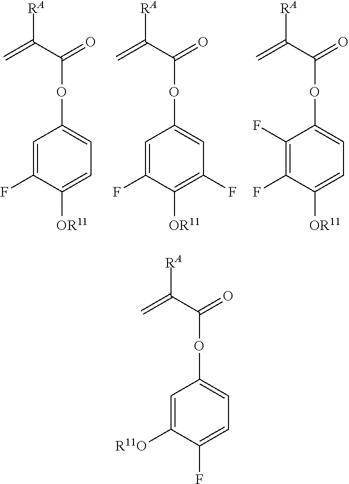

The acid-labile group represented by R¹¹ is variously selected, and examples thereof include groups represented by the following formulae (AL-1) to (AL-3).

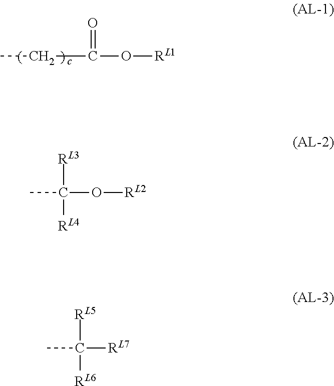

In the formula (AL-1), “c” represents an integer of 0 to 6. R^{L1} represents a tertiary hydrocarbyl group having 4 to 20, preferably 4 to 15, carbon atoms, a trihydrocarbylsilyl group in which each hydrocarbyl group is a saturated hydrocarbyl group having 1 to 6 carbon atoms, a saturated hydrocarbyl group having 4 to 20 carbon atoms and having a carbonyl group, an ether bond, or an ester bond, or a group represented by the formula (AL-3).

The tertiary hydrocarbyl group represented by R^{L1} may be saturated or unsaturated, and may be branched or cyclic. Specific examples thereof include a tert-butyl group, a tert-pentyl group, a 1,1-diethylpropyl group, a 1-ethylcyclopentyl group, a 1-butylcyclopentyl group, a 1-ethylcyclohexyl group, a 1-butylcyclohexyl group, a 1-ethyl-2-cyclopentenyl group, a 1-ethyl-2-cyclohexenyl group, and a 2-methyl-2-adamantyl group. Examples of the trihydrocarbylsilyl group include a trimethylsilyl group, a triethylsilyl group, and a dimethyl-tert-butylsilyl group. The saturated hydrocarbyl group having a carbonyl group, an ether bond, or an ester bond may be any of linear, branched, and cyclic, but preferably cyclic. Specific examples thereof include a 3-oxocyclohexyl group, a 4-methyl-2-oxooxan-4-yl group, a 5-methyl-2-oxooxolan-5-yl group, a 2-tetrahydropyranyl group, and a 2-tetrahydrofuranyl group.

Examples of the acid-labile group represented by the formula (AL-1) include a tert-butoxycarbonyl group, a tert-butoxycarbonylmethyl group, a tert-pentyloxycarbonyl group, a tert-pentyloxycarbonylmethyl group, a 1,1-diethylpropyloxycarbonyl group, a 1,1-diethylpropyloxycarbonylmethyl group, a 1-ethylcyclopentyloxycarbonyl group, a 1-ethylcyclopentyloxycarbonylmethyl group, a 1-ethyl-2-cyclopentenyloxycarbonyl group, a 1-ethyl-2-cyclopentenyloxycarbonylmethyl group, a 1-ethoxyethoxycarbonylmethyl group, a 2-tetrahydropyranyloxycarbonylmethyl group, and a 2-tetrahydrofuranyloxycarbonylmethyl group.

Examples of the acid-labile group represented by the formula (AL-1) further include groups represented by the following formulae (AL-1)-1 to (AL-1)-10.

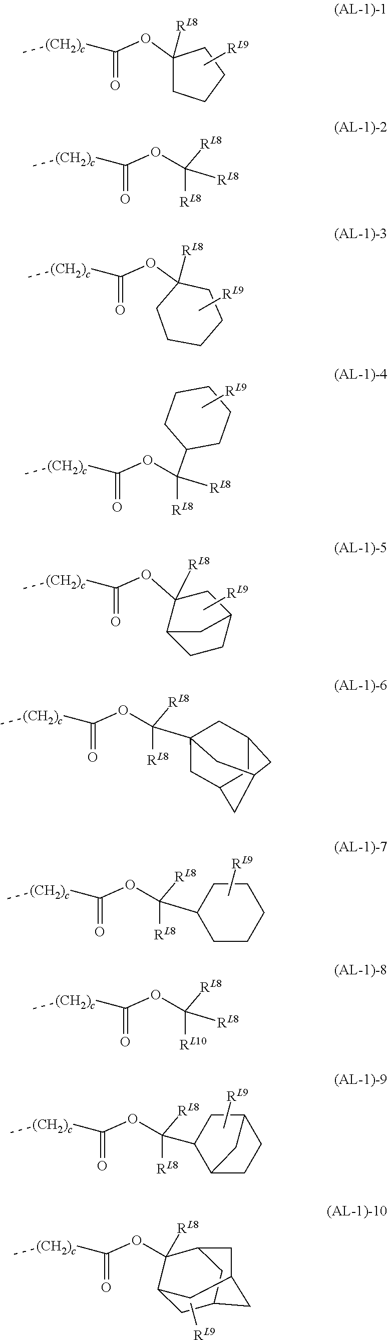

In the formulae, a broken line represents an attachment point.

In the formulae (AL-1)-1 to (AL-1)-10, “c” is the same as above. R^{L8} each independently represents a saturated hydrocarbyl group having 1 to 10 carbon atoms or an aryl group having 6 to 20 carbon atoms. R^{L9} represents a hydrogen atom or a saturated hydrocarbyl group having 1 to 10 carbon atoms. R^{L10} represents a saturated hydrocarbyl group having 2 to 10 carbon atoms or an aryl group having 6 to 20 carbon atoms. The saturated hydrocarbyl group may be any of linear, branched, and cyclic.

In the formula (AL-2), R^{L3} and R^{L4} each independently represent a hydrogen atom or a saturated hydrocarbyl group having 1 to 18, preferably 1 to 10, carbon atoms. Here, the saturated hydrocarbyl group may be any of linear, branched, and cyclic, and specific examples thereof include a methyl group, an ethyl group, a propyl group, an isopropyl group, a n-butyl group, a sec-butyl group, a tert-butyl group, a cyclopentyl group, a cyclohexyl group, a 2-ethylhexyl group, and a n-octyl group.

In the formula (AL-2), R^{L2} represents a hydrocarbyl group having 1 to 18, preferably 1 to 10, carbon atoms and optionally having a heteroatom. Here, the hydrocarbyl group may be saturated or unsaturated, and may be any of linear, branched, and cyclic. Examples of the hydrocarbyl group include a saturated hydrocarbyl group having 1 to 18 carbon atoms, and a part of hydrogen atoms therein may be substituted with a hydroxy group, an alkoxy group, an oxo group, an amino group, an alkylamino group, etc. Specific examples of these substituted saturated hydrocarbyl groups include the following groups.

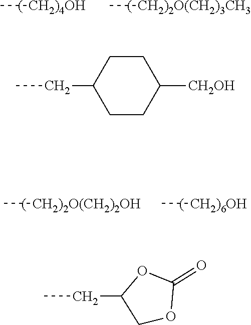

In the formulae, a broken line represents an attachment point.

R^{L2} and R^{L3}, R^{L2} and R^{L4}, or R^{L3} and R^{L4} may be bonded to each other to form a ring together with a carbon atom to which these are bonded or together with the carbon atom and an oxygen atom. In this case, R^{L2} and R^{L3}, R^{L2} and R^{L4}, or R^{L3} and R^{L4} that are involved with ring formation each independently represent an alkanediyl group having 1 to 18, preferably 1 to 10, carbon atoms. A number of carbon atoms of the ring obtained by bonding these groups is preferably 3 to 10, and more preferably 4 to 10.

Among the acid-labile groups represented by the formula (AL-2), examples of linear or branched groups include, but not limited to, groups represented by the following formulae (AL-2)-1 to (AL-2)-69. In the following formulae, a broken line represents an attachment point.

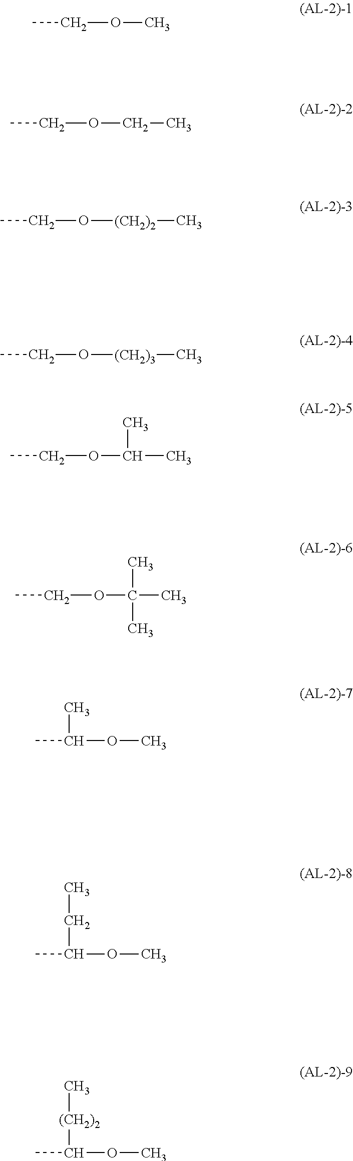

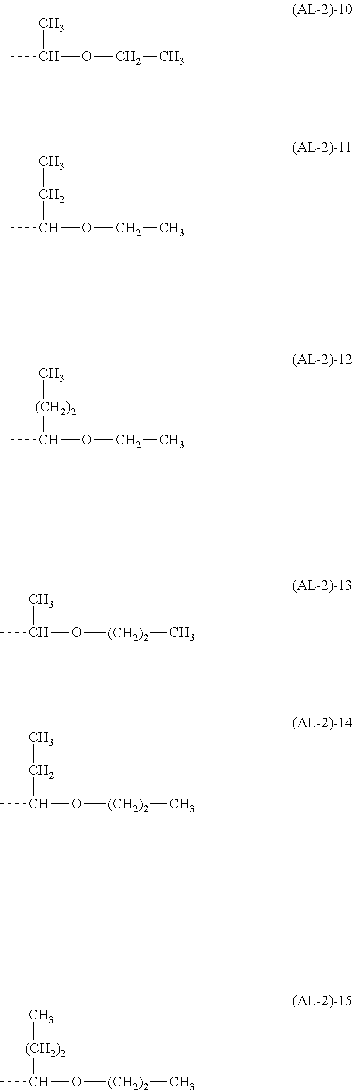

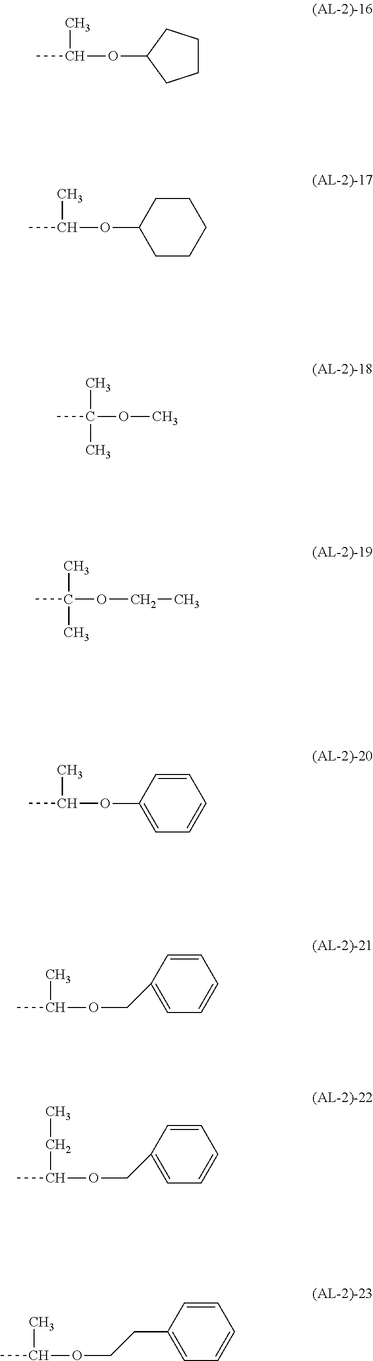

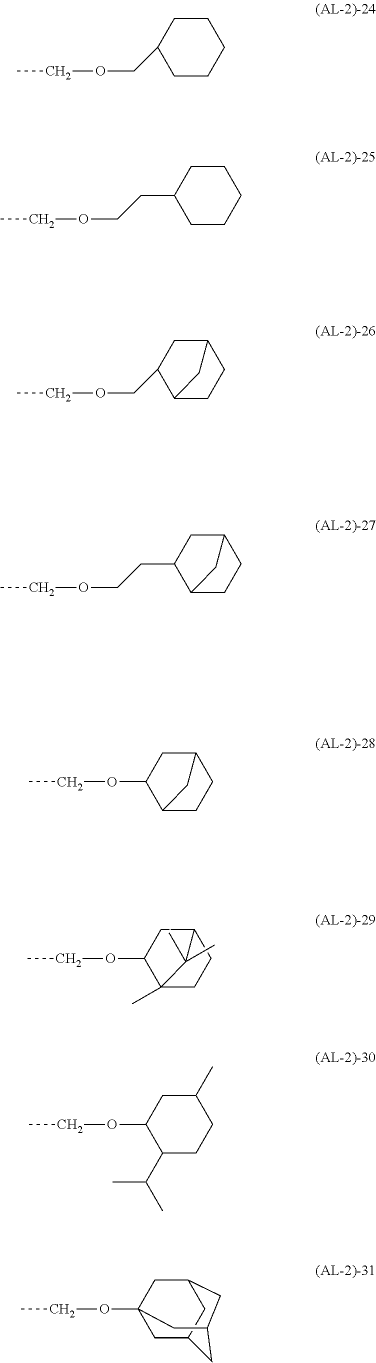

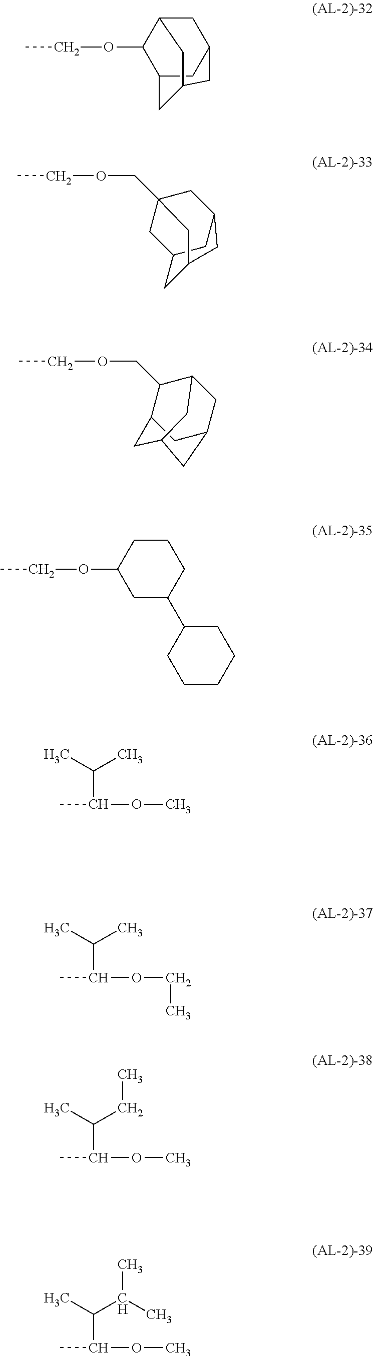

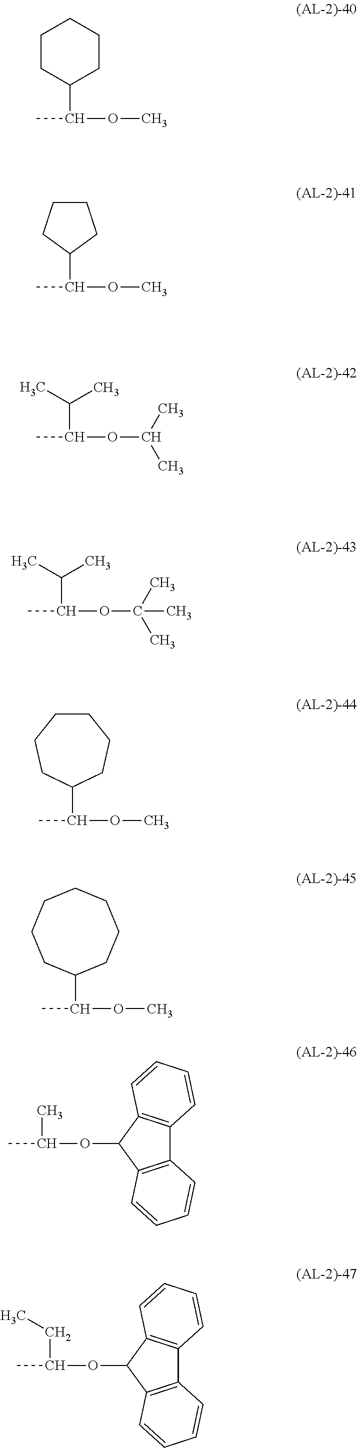

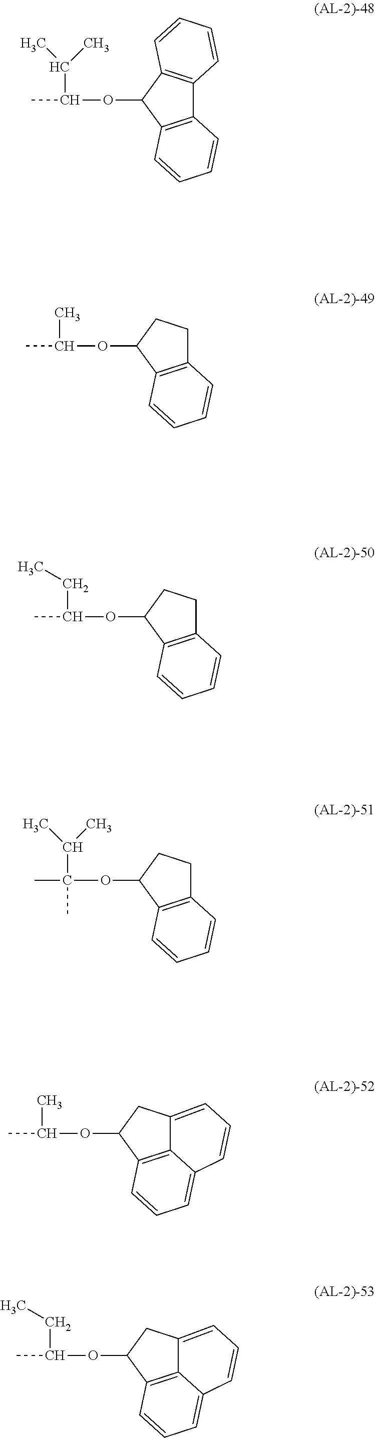

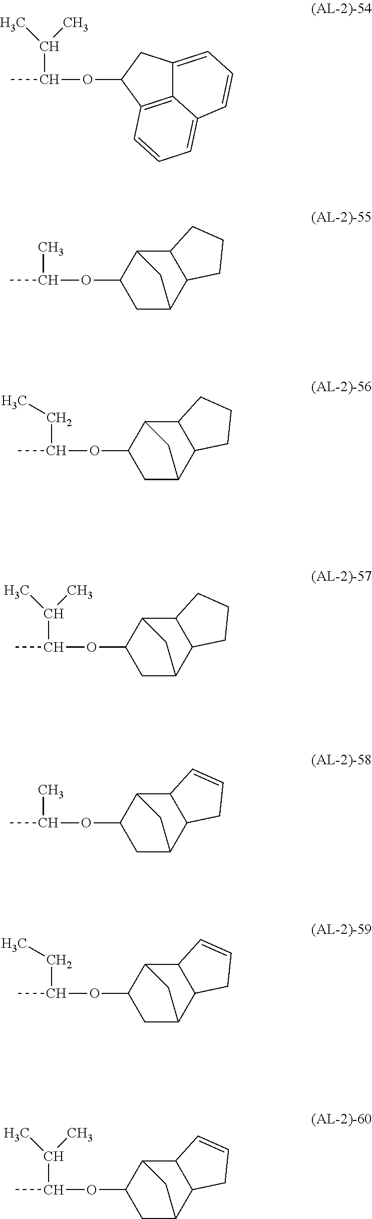

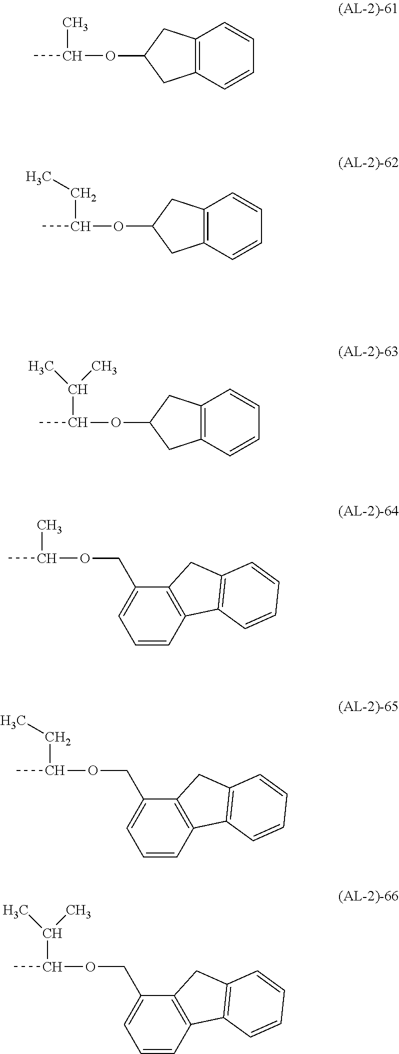

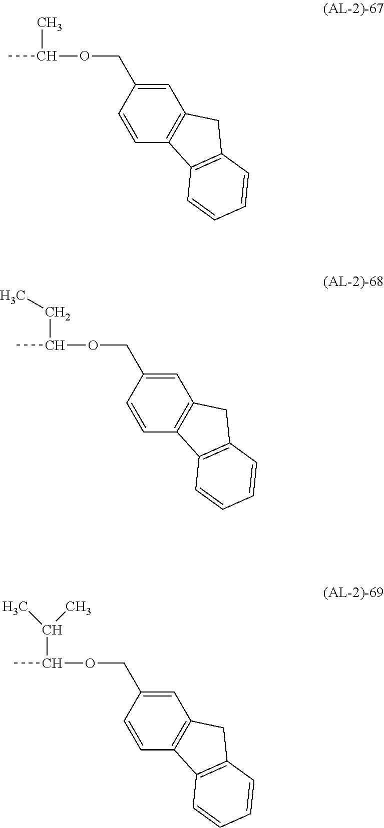

Among the acid-labile groups represented by the formula (AL-2), examples of cyclic groups include a tetrahydrofuran-2-yl group, a 2-methyltetrahydrofuran-2-yl group, a tetrahydropyran-2-yl group, and a 2-methyltetrahydropyran-2-yl group.

Examples of the acid-labile group include groups represented by the following formula (AL-2a) or (AL-2b). The base polymer may be subjected to intermolecular or intramolecular crosslinking with the acid-labile group.

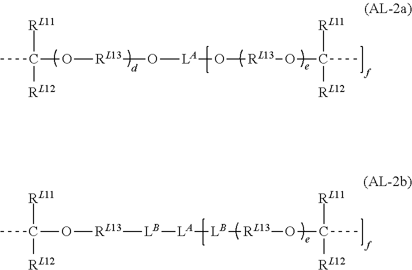

In the formulae, a broken line represents an attachment point.

In the formula (AL-2a) or (AL-2b), R^{L11} and R^{L12} each independently represent a hydrogen atom or a saturated hydrocarbyl group having 1 to 8 carbon atoms. The saturated hydrocarbyl group may be any of linear, branched, and cyclic. R^{L11} and R^{L12} may be bonded to each other to form a ring together with a carbon atom to which R^{L11} and R^{L12} are bonded. In this case, R^{L11} and R^{L12} each independently represent an alkanediyl group having 1 to 8 carbon atoms. R^{L13} each independently represents a saturated hydrocarbylene group having 1 to 10 carbon atoms. The saturated hydrocarbylene group may be any of linear, branched, and cyclic. “d” and “e” each independently represent an integer of 0 to 10, and preferably an integer of 0 to 5, and “f” represents an integer of 1 to 7, and preferably an integer of 1 to 3.

In the formula (AL-2a) or (AL-2b), L^{A} represents an (f+1)-valent aliphatic saturated hydrocarbon group having 1 to 50 carbon atoms, an (f+1)-valent alicyclic saturated hydrocarbon group having 3 to 50 carbon atoms, an (f+1)-valent aromatic hydrocarbon group having 6 to 50 carbon atoms, or an (f+1)-valent heterocyclic group having 3 to 50 carbon atoms. A part of carbon atoms in these groups may be substituted with a heteroatom-containing group. A part of hydrogen atoms bonded to a carbon atom in these groups may be substituted with a hydroxy group, a carboxy group, an acyl group, or a fluorine atom. L^{A} preferably represents a saturated hydrocarbon group such as a saturated hydrocarbylene group having 1 to 20 carbon atoms, a trivalent saturated hydrocarbon group, and a tetravalent saturated hydrocarbon group, an arylene group having 6 to 30 carbon atoms, etc. The saturated hydrocarbon group may be any of linear, branched, and cyclic. L^{B} represents —C(═O)—O—, —NH—C(═O)—O—, or —NH—C(═O)—NH—.

Examples of the divalent linking group represented by the formula (AL-2a) or (AL-2b) include groups represented by the following formulae (AL-2)-70 to (AL-2) -77.

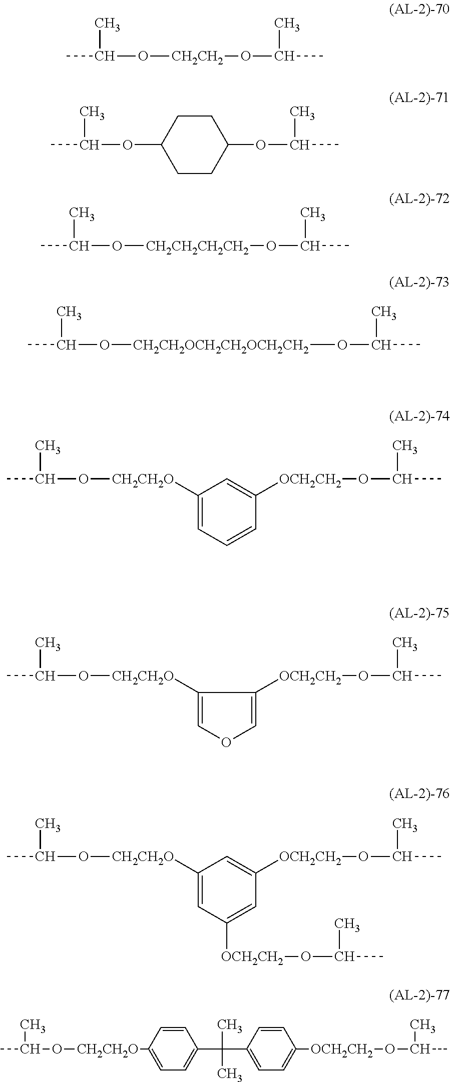

In the formulae, a broken line represents an attachment point.

In the formula (AL-3), R^{L5}, R^{L6}, and R^{L7} each independently represent a hydrocarbyl group having 1 to 20 carbon atoms and optionally having a heteroatom such as an oxygen atom, a sulfur atom, a nitrogen atom, and a fluorine atom. The hydrocarbyl group may be saturated or unsaturated, and may be any of linear, branched, and cyclic. Specific examples thereof include an alkyl group having 1 to 20 carbon atoms, a cyclic saturated hydrocarbyl group having 3 to 20 carbon atoms, an alkenyl group having 2 to 20 carbon atoms, a cyclic unsaturated hydrocarbyl group having 3 to 20 carbon atoms, and aryl group having 6 to 10 carbon atoms. R^{L5} and R^{L6}, R^{L5} and R^{L7}, or R^{L6} and R^{L7} may be bonded to each other to form an aliphatic ring having 3 to 20 carbon atoms together with a carbon atom to which these are bonded.

Examples of the group represented by the formula (AL-3) include a tert-butyl group, a 1,1-diethylpropyl group, a 1-ethylnorbornyl group, a 1-methylcyclopentyl group, a 1-isopropylcyclopentyl group, a 1-ethylcyclopentyl group, a 1-methylcyclohexyl group, a 2-(2-methyl)adamantyl group, a 2-(2-ethyl)adamantyl group, and a tert-pentyl group.

Examples of the group represented by the formula (AL-3) also include groups represented by the following formulae (AL-3)-1 to (AL-3)-19.

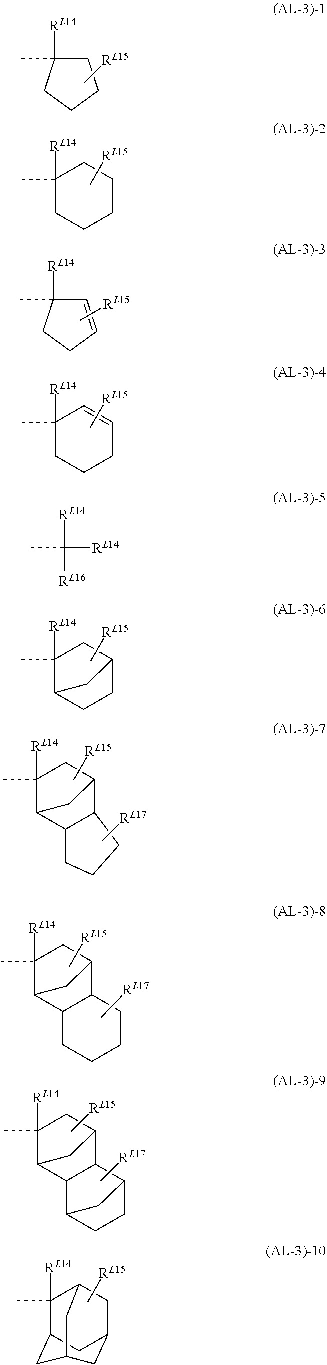

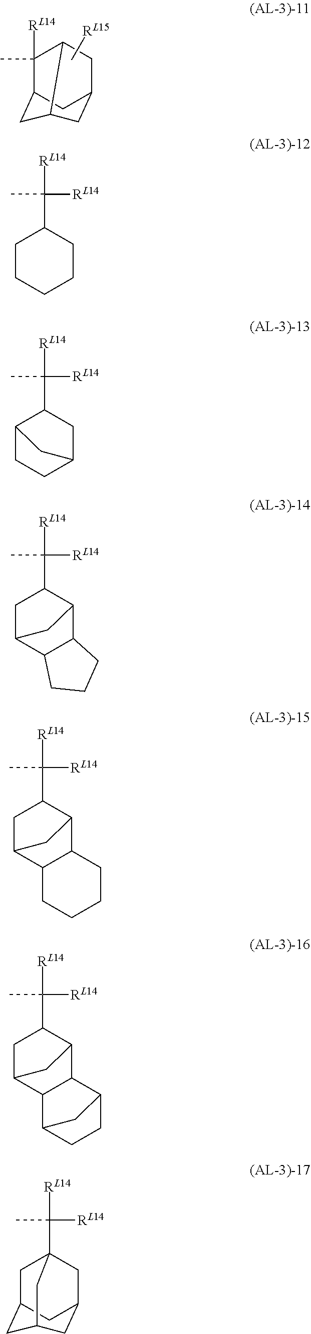

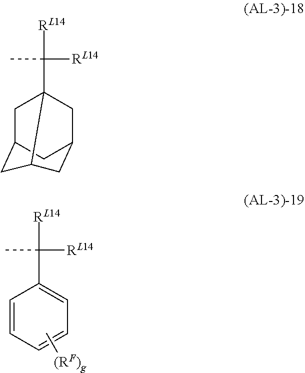

In the formulae, a broken line represents an attachment point.

In the formulae (AL-3)-1 to (AL-3)-19, R^{L14} each independently represents a saturated hydrocarbyl group having 1 to 8 carbon atoms or an aryl group having 6 to 20 carbon atoms. R^{L15} and R^{L17} each independently represent a hydrogen atom or a saturated hydrocarbyl group having 1 to 20 carbon atoms. RL¹⁶ represents an aryl group having 6 to 20 carbon atoms. The saturated hydrocarbyl group may be any of linear, branched, and cyclic. The aryl group is preferably a phenyl group, etc. R^{F} represents a fluorine atom or a trifluoromethyl group. “g” represents an integer of 1 to 5.

Examples of the acid-labile group further include groups represented by the following formula (AL-3)-20 or (AL-3)-21. The polymer may be subjected to intramolecular or intermolecular crosslinking with the acid-labile group.

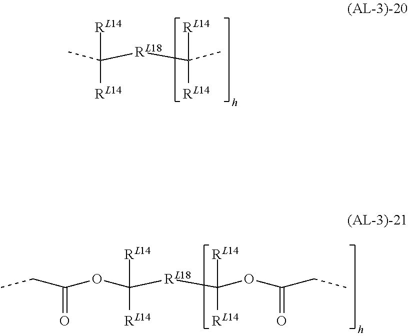

In the formula, a broken line represents an attachment point.

In the formulae (AL-3)-20 and (AL-3)-21, R^{L14} is the same as above. RL¹⁸ represents an (h+1)-valent saturated hydrocarbylene group having 1 to 20 carbon atoms or an (h+1)-valent arylene group having 6 to 20 carbon atoms, and optionally having a heteroatom such as an oxygen atom, a sulfur atom, and a nitrogen atom. The saturated hydrocarbylene group may be any of linear, branched, and cyclic. “h” represents an integer of 1 to 3.

Examples of a monomer to yield the repeating unit having the acid-labile group represented by the formula (AL-3) include (meth)acrylate esters having an exo-form structure represented by the following formula (AL-3)-22.

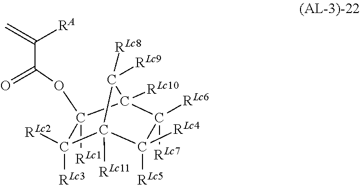

In the formula (AL-3)-22, R^{A} is the same as above. R^{Lc1} represents a saturated hydrocarbyl group having 1 to 8 carbon atoms or an optionally substituted aryl group having 6 to 20 carbon atoms. The saturated hydrocarbyl group may be any of linear, branched, and cyclic. R^{Lc2} to R^{Lc11} each independently represent a hydrogen atom or a hydrocarbyl group having 1 to 15 carbon atoms and optionally having a heteroatom. Examples of the heteroatom include an oxygen atom. Examples of the hydrocarbyl group include an alkyl group having 1 to 15 carbon atoms and an aryl group having 6 to 15 carbon atoms. R^{Lc2} and R^{Lc3}, R^{Lc4} and R^{Lc6}, R^{Lc4} and R^{Lc7}, R^{Lc5} and R^{Lc7}, R^{Lc5} and R^{Lc11}, R^{Lc6} and R^{Lc10}, R^{Lc8} and R^{Lc9}, or R^{Lc9} and R^{Lc10} may be bonded to each other to form a ring together with a carbon atom to which these are bonded. In this case, the groups involved with bonding are a hydrocarbylene group having 1 to 15 carbon atoms and optionally having a heteroatom. R^{Lc2} and R^{Lc11}, R^{Lc8} and R^{Lc11}, or R^{Lc4} and R^{Lc6}, substituted on adjacent carbon atoms, may be bonded to each other without any intervening group to form a double bond. This formula also represents an enantiomer.

Examples of a monomer to yield a repeating unit represented by the formula (AL-3)-22 include monomers described in JP 2000-327633 A. Specific examples thereof include, but not limited to, the following monomers. In the following formulae, R^{A} is the same as above.

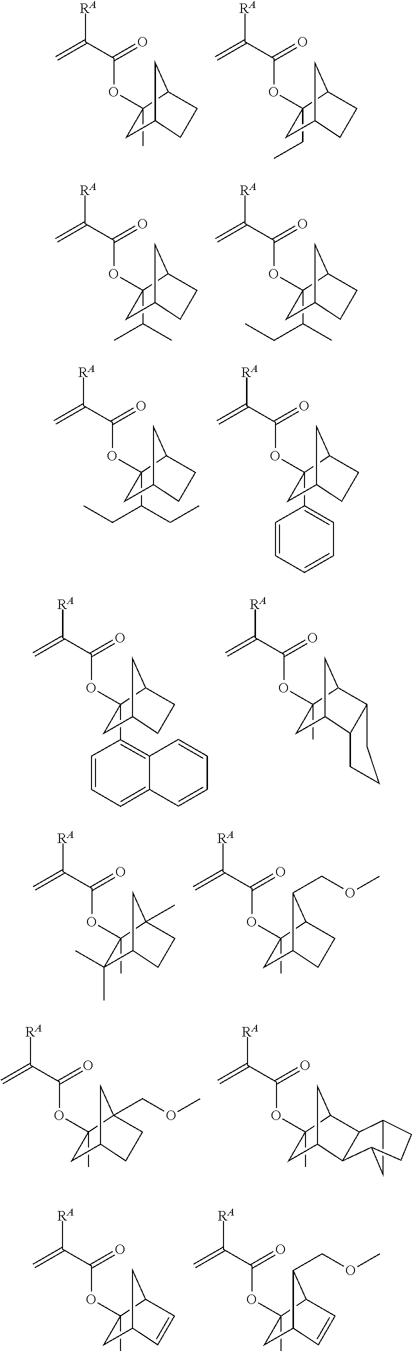

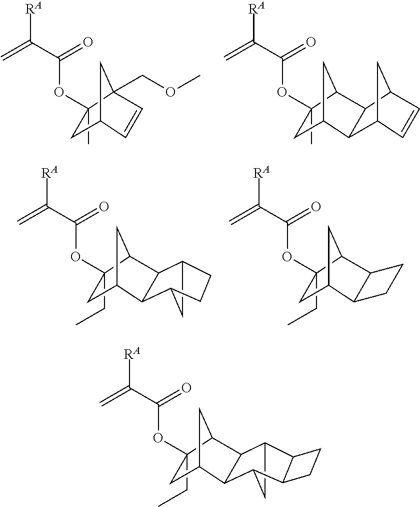

Examples of the monomer to yield the repeating unit having the acid-labile group represented by the formula (AL-3) also include (meth)acrylate esters having a furandiyl group, a tetrahydrofurandiyl group, or an oxanorbornanediyl group, represented by the following formula (AL-3)-23.

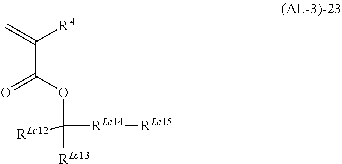

In the formula (AL-3)-23, R^{A} is the same as above. R^{Lc12} and R^{Lc13} each independently represent a hydrocarbyl group having 1 to 10 carbon atoms. R^{Lc12} and R^{Lc13} may be bonded to each other to form an aliphatic ring together with a carbon atom to which R^{Lc12} and R^{Lc13} are bonded. R^{Lc14} represents a furandiyl group, a tetrahydrofurandiyl group, or an oxanorbornanediyl group. R^{Lc15} represents a hydrogen atom or a hydrocarbyl group having 1 to 10 carbon atoms and optionally having a heteroatom. The hydrocarbyl group may be any of linear, branched, and cyclic. Specific examples thereof include a saturated hydrocarbyl group having 1 to 10 carbon atoms.

Specific examples of the monomer to yield the repeating unit represented by the formula (AL-3)-23 include, but not limited to, the following monomers. In the following formulae, R^{A} is the same as above, Ac represents an acetyl group, and Me represents a methyl group.

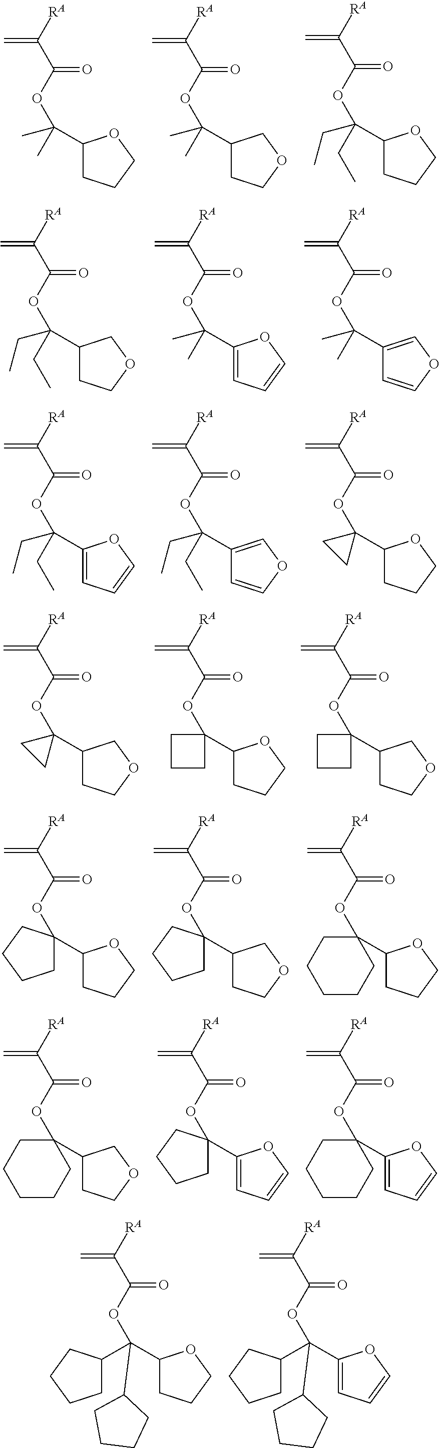

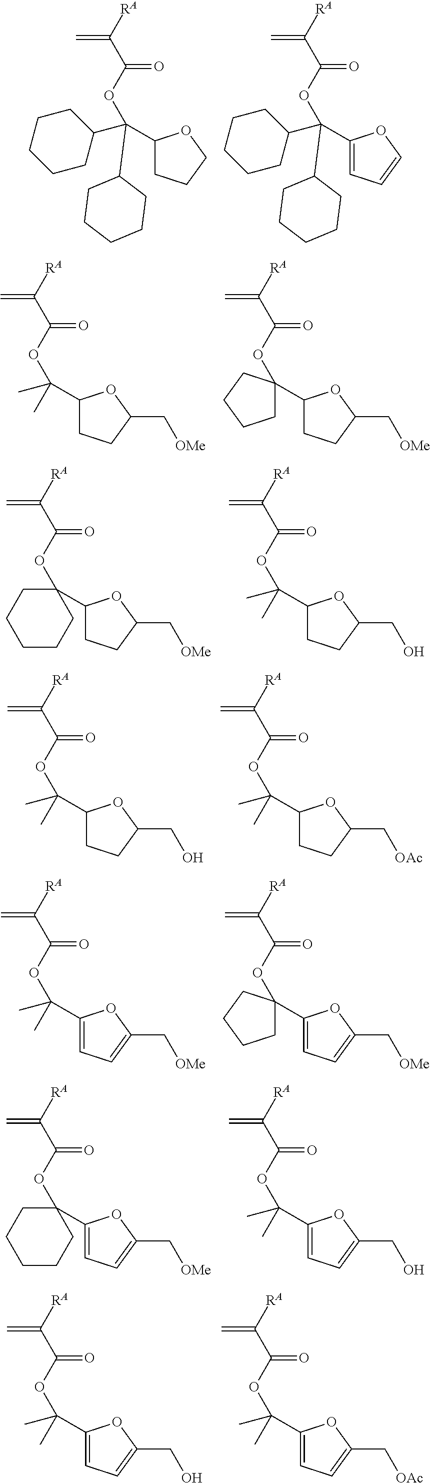

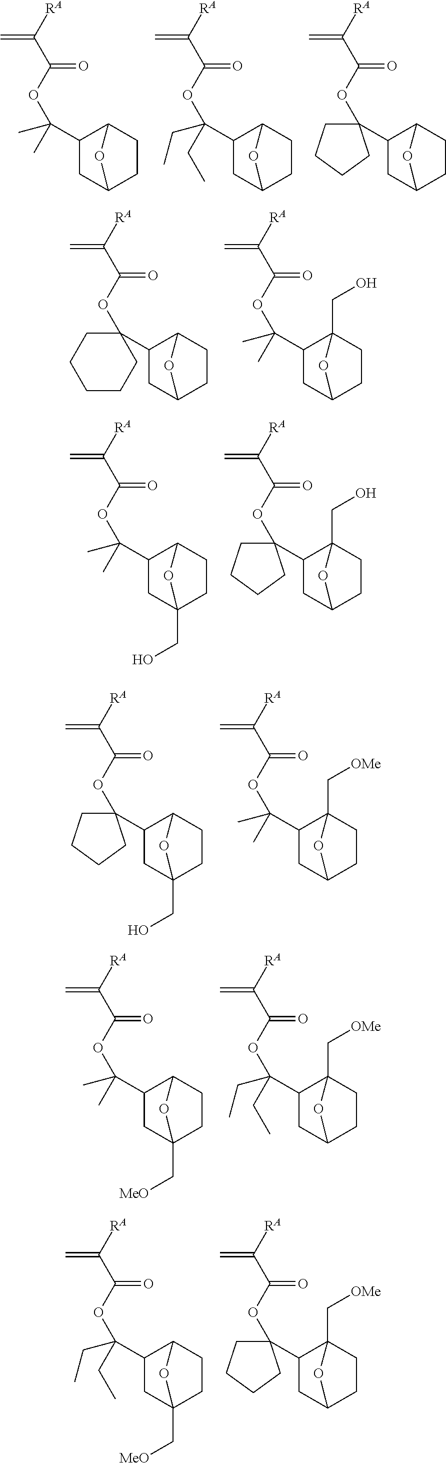

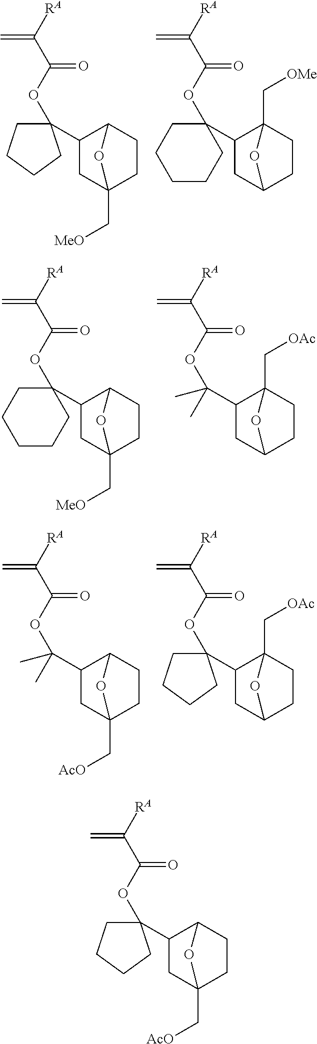

(Repeating Unit “d”)

The base polymer may further have a repeating unit “d” having an adhesion group selected from a hydroxy group, a carboxyl group, a lactone ring, a carbonate group, a thiocarbonate group, a carbonyl group, a cyclic acetal group, a hemiacetal group, an ether bond, an ester bond, a sulfonate ester bond, a cyano group, an amide group, —O—C(═O)—S—, and —O—C(═O)—NH—.

Specific examples of a monomer to yield the repeating unit “d” include, but not limited to, the following monomers. In the formulae, R^{A} is the same as above.

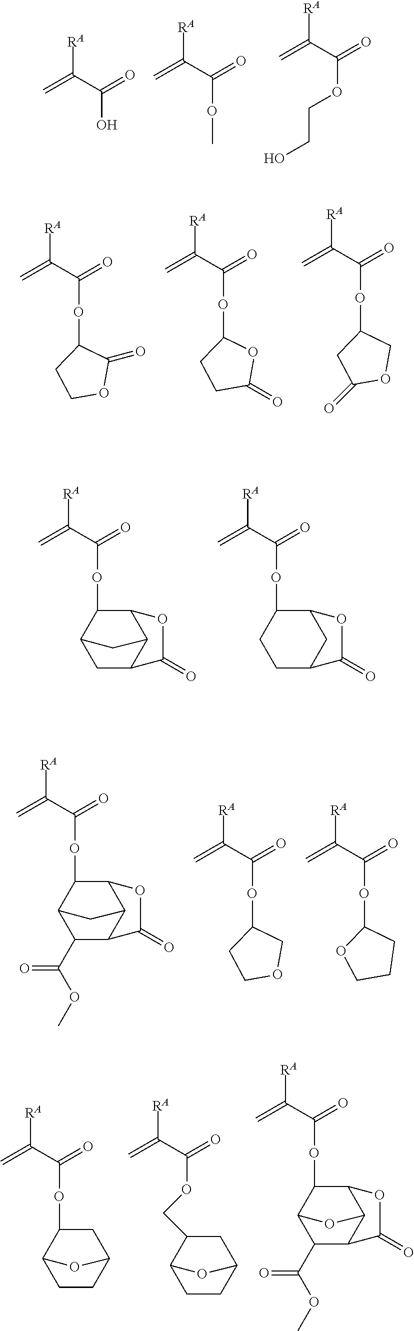

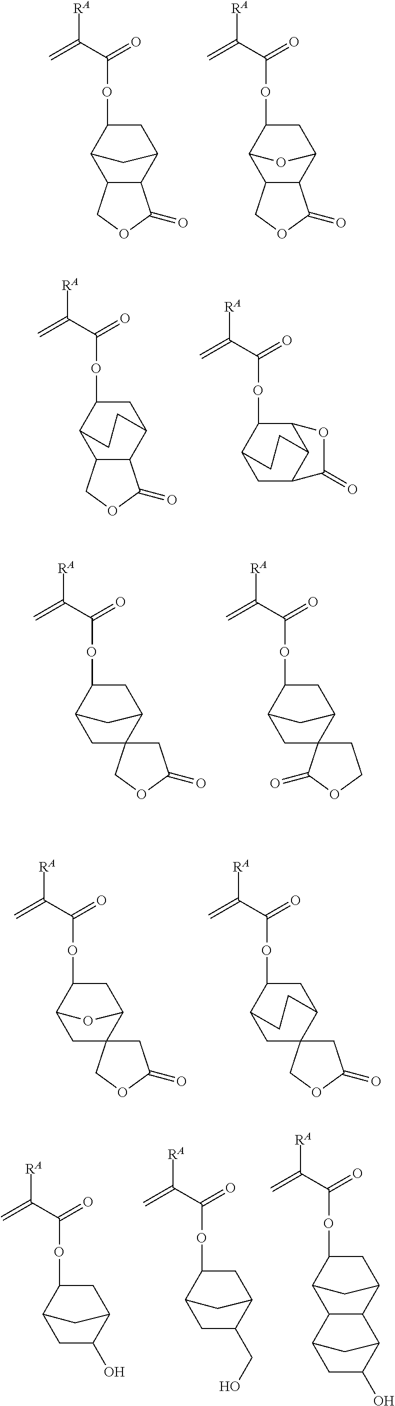

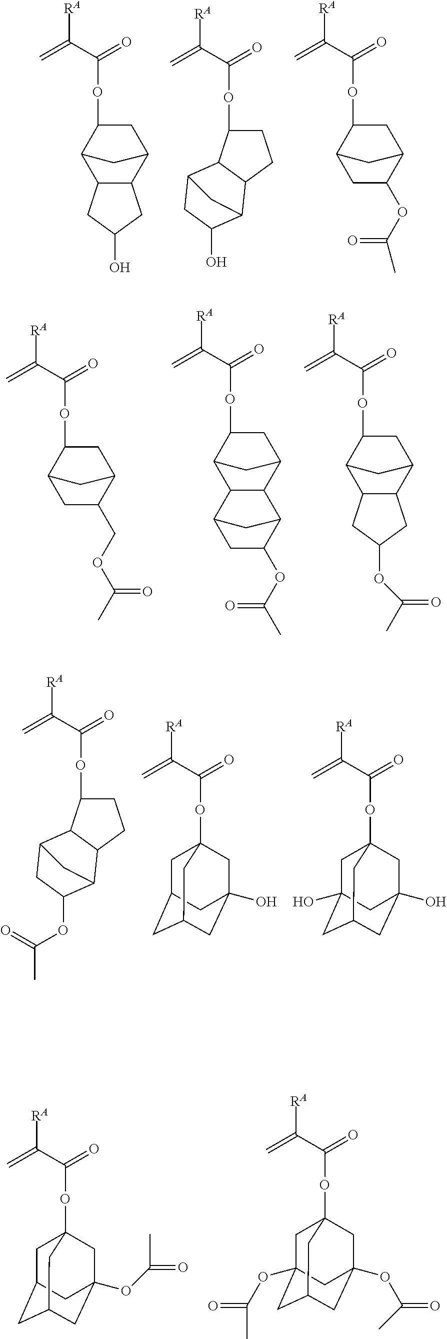

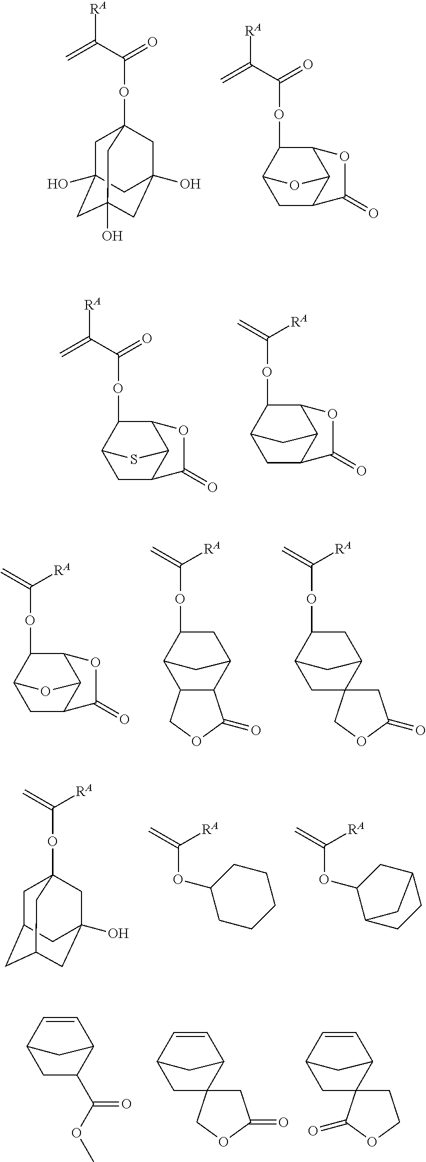

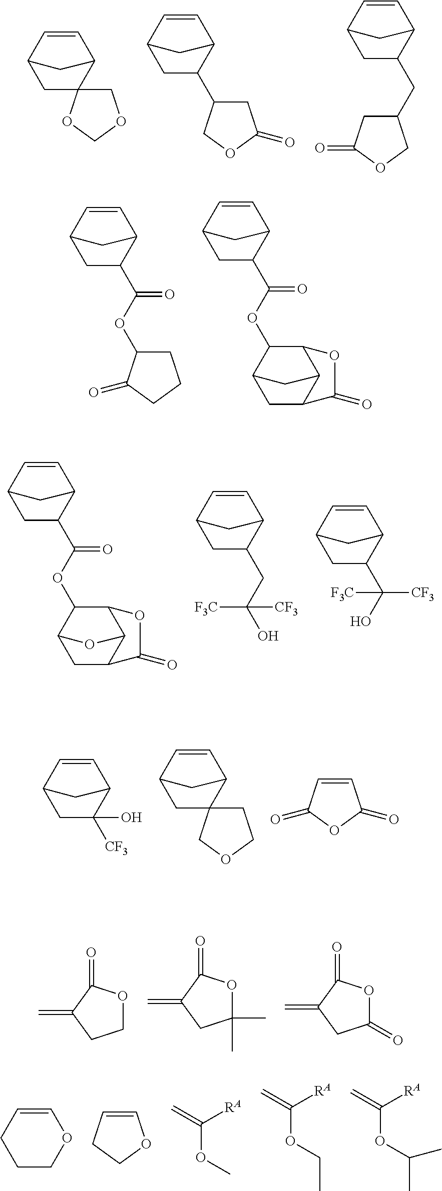

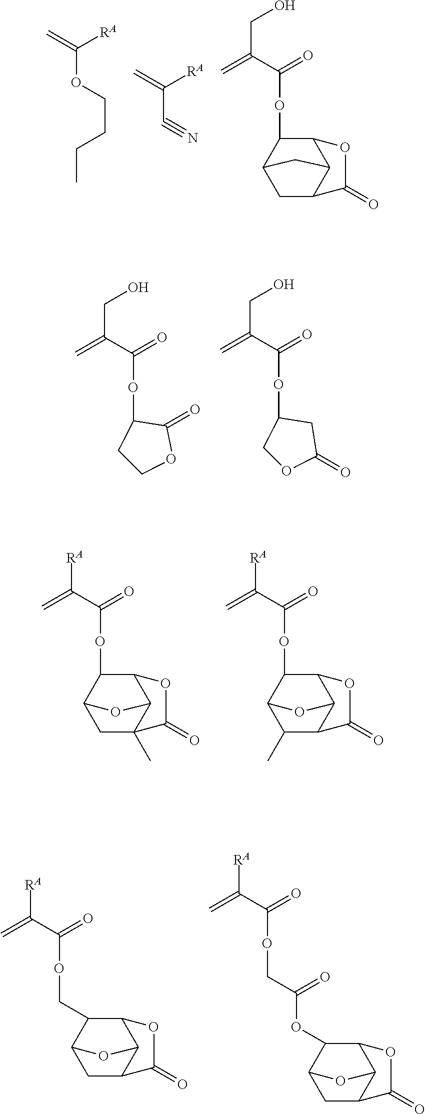

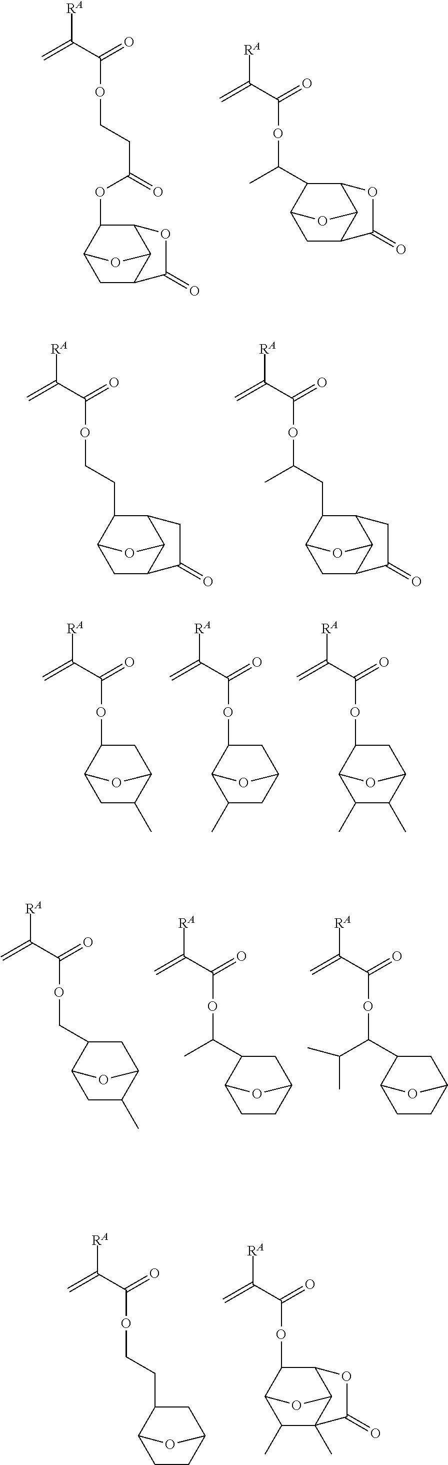

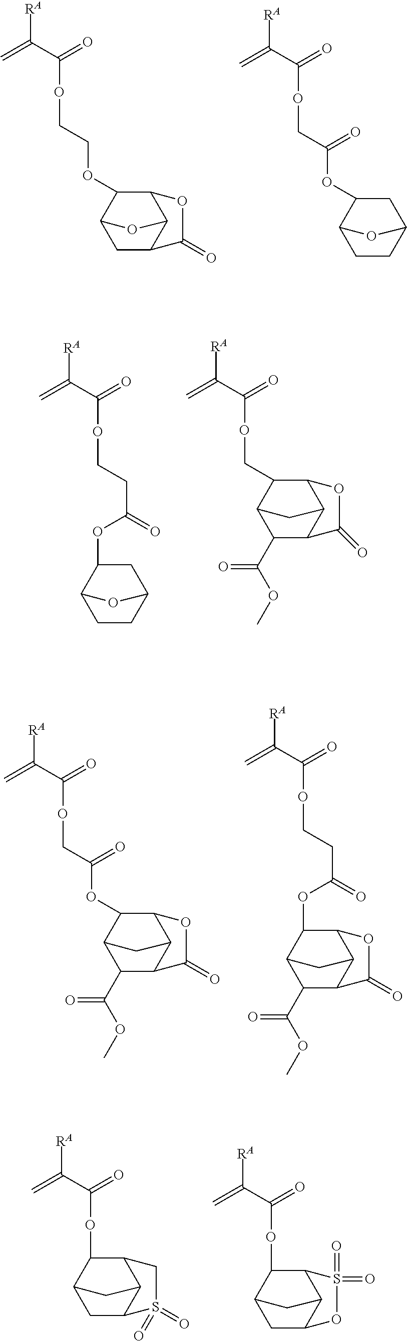

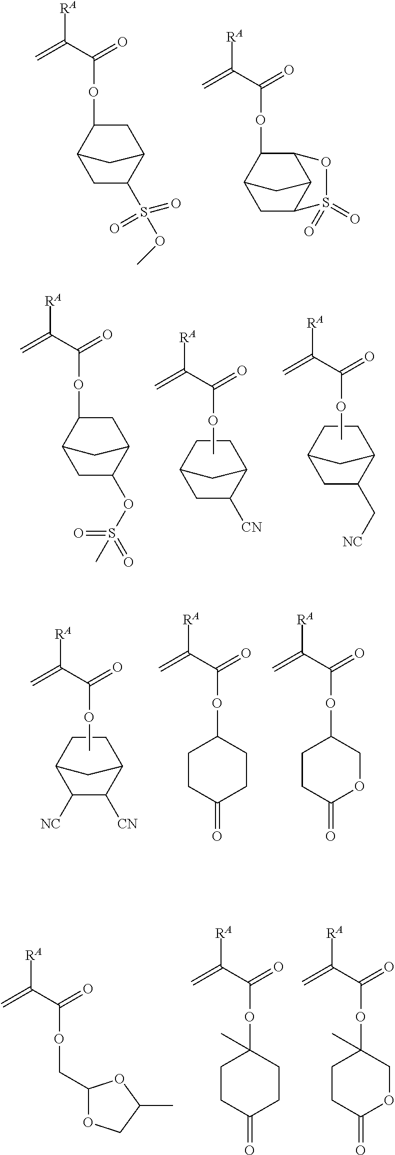

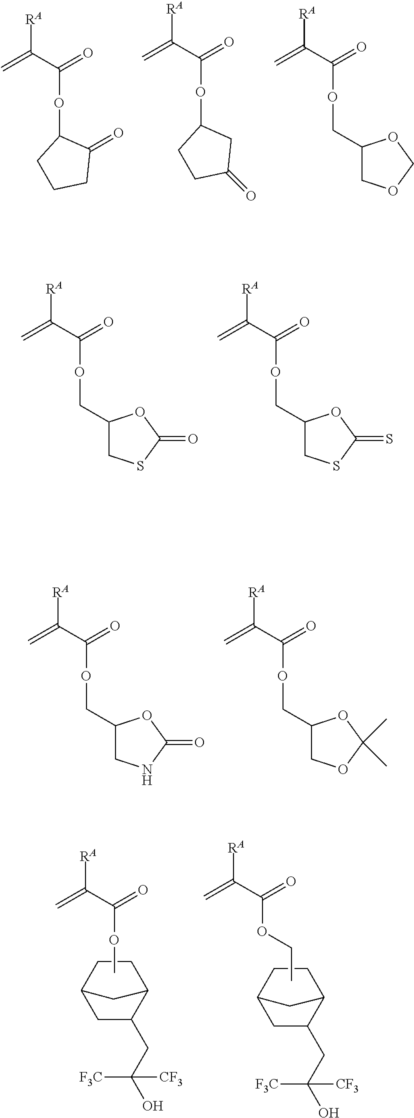

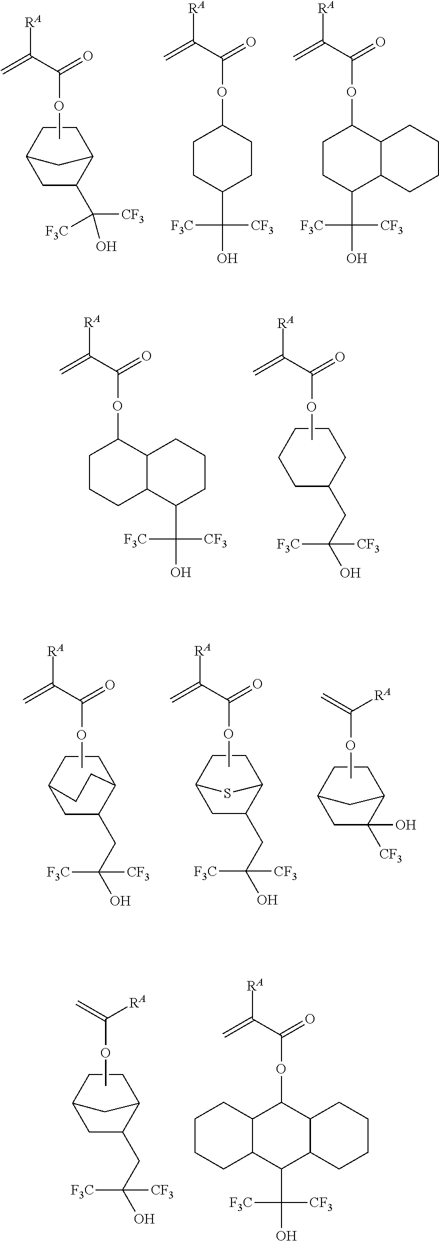

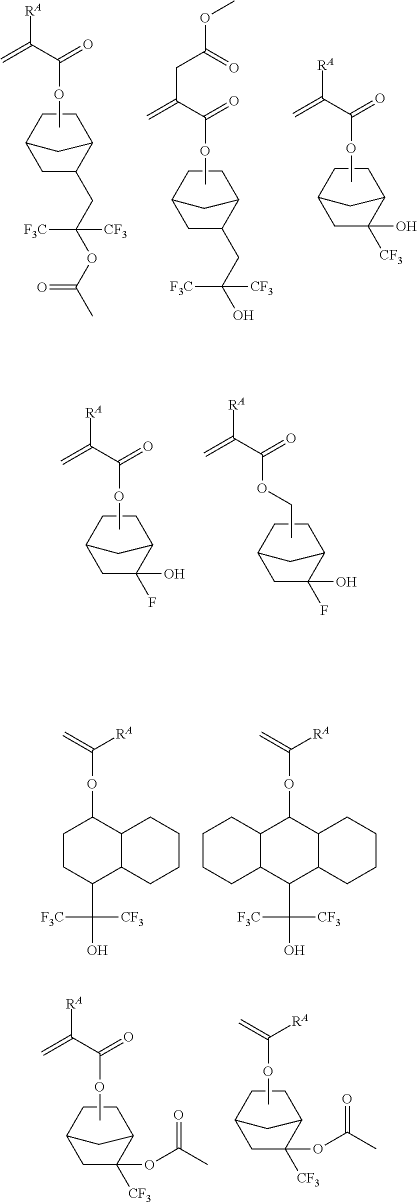

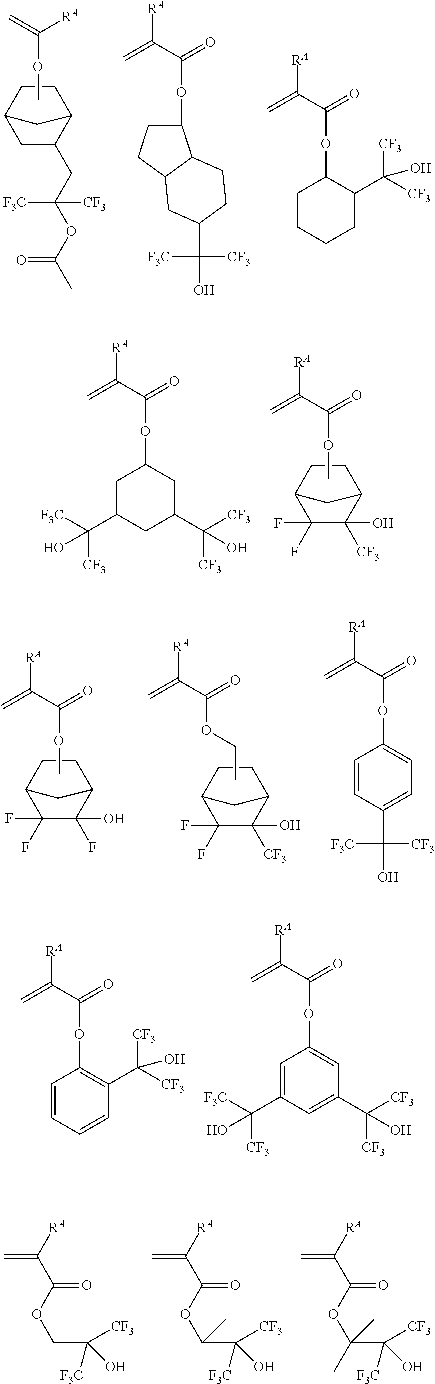

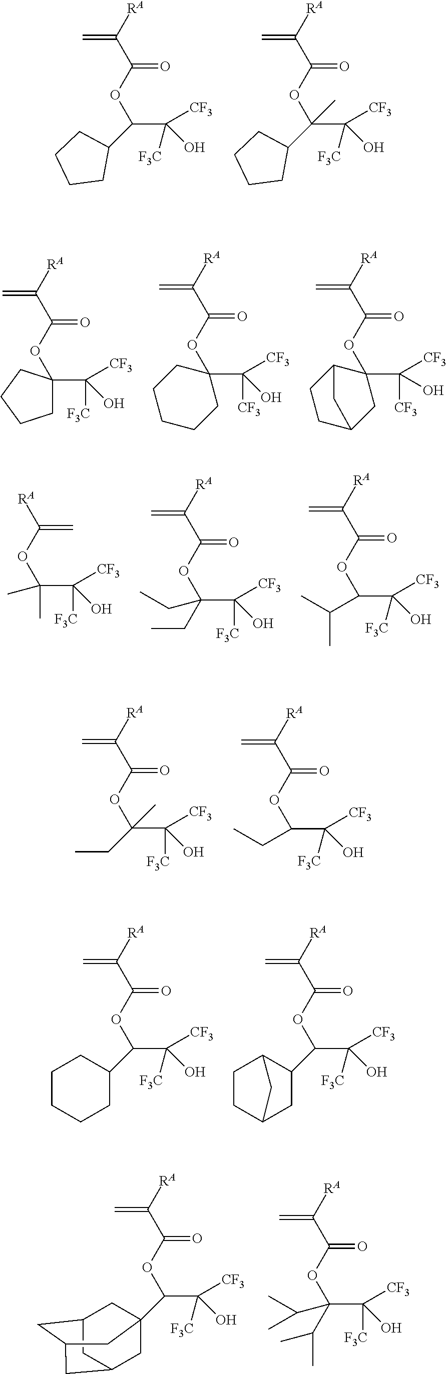

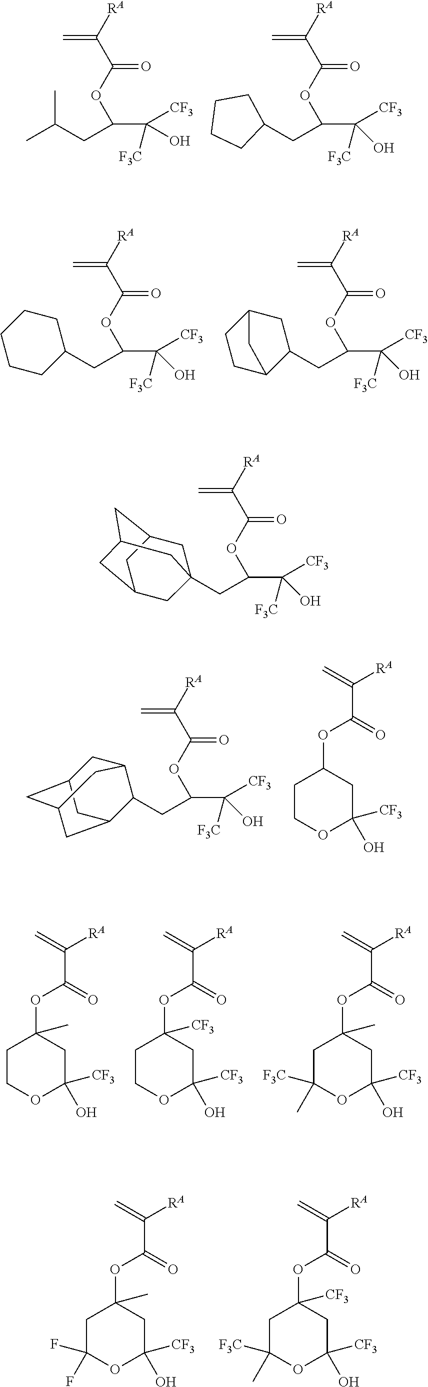

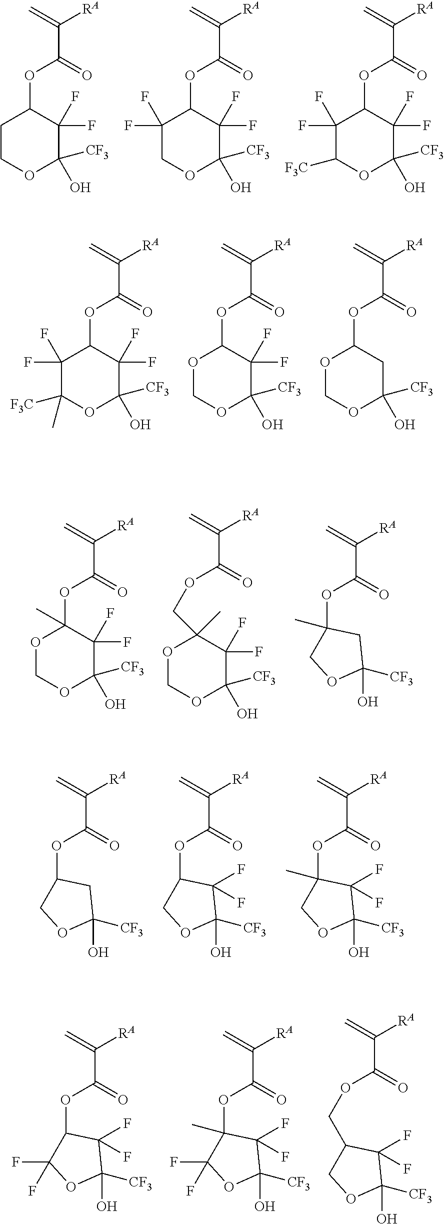

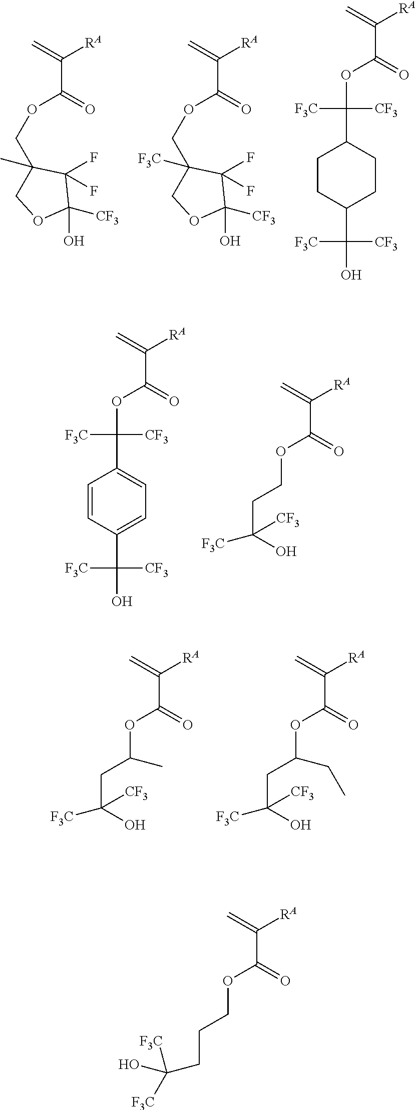

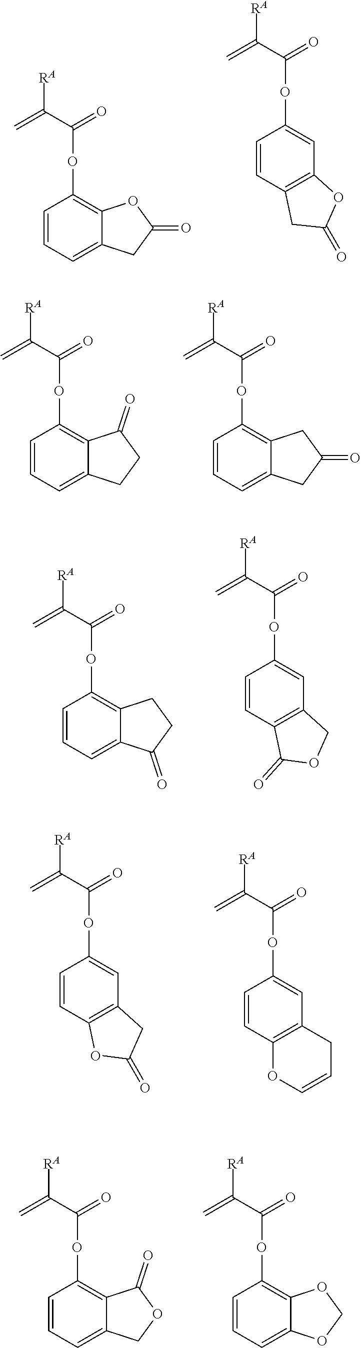

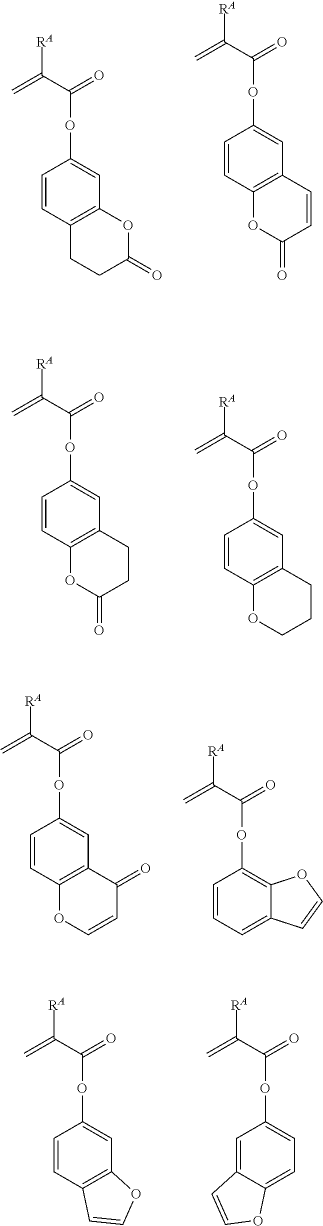

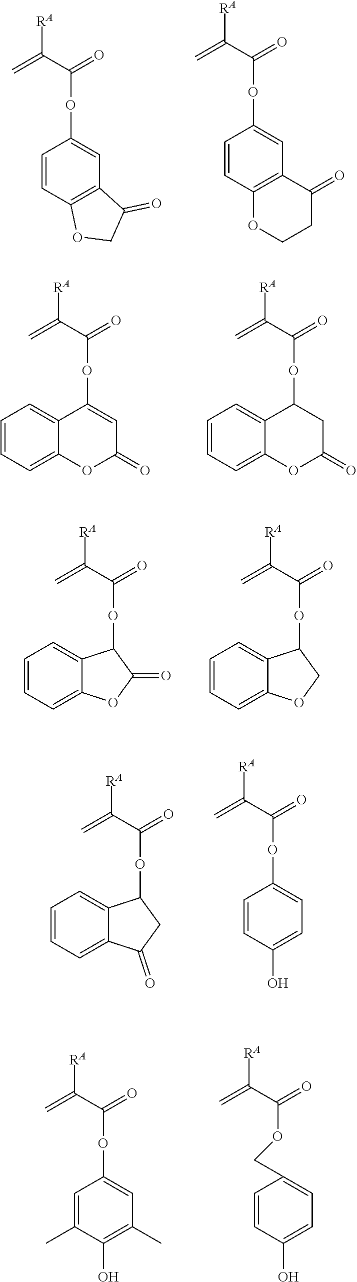

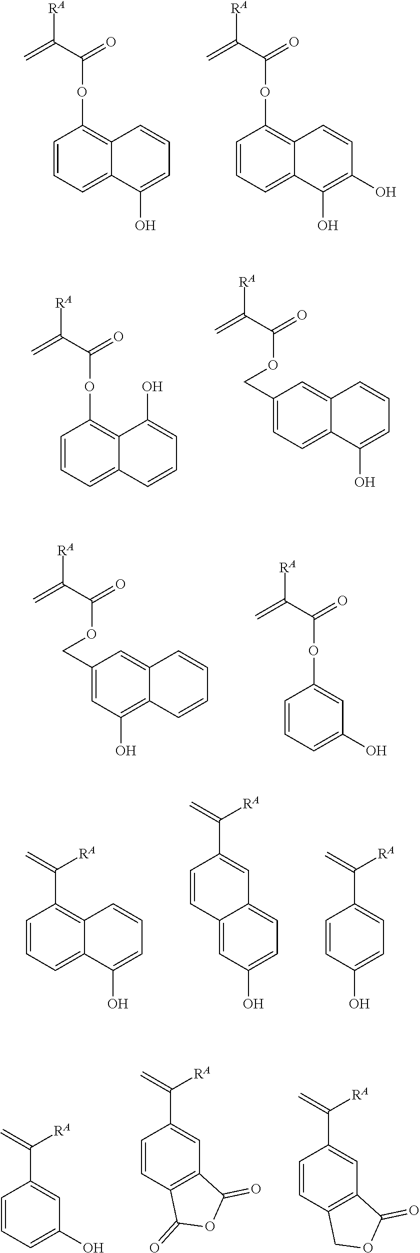

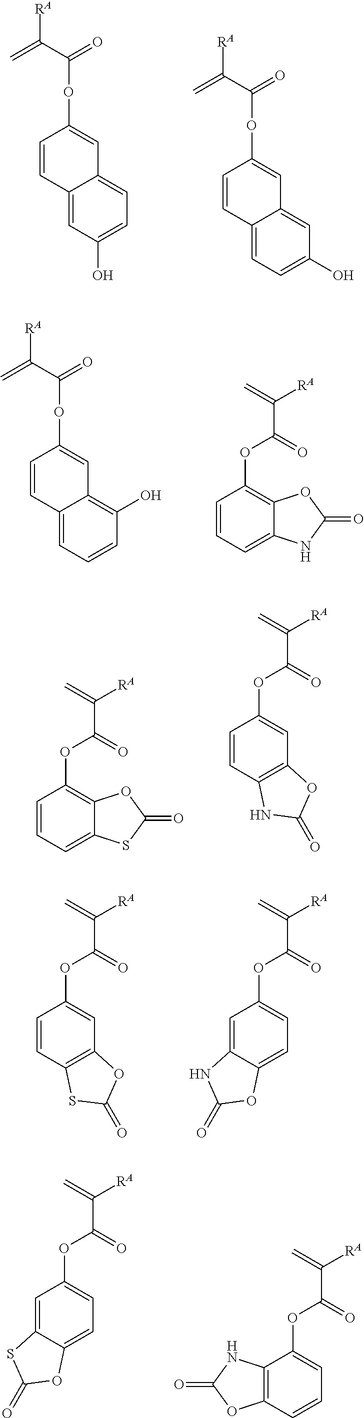

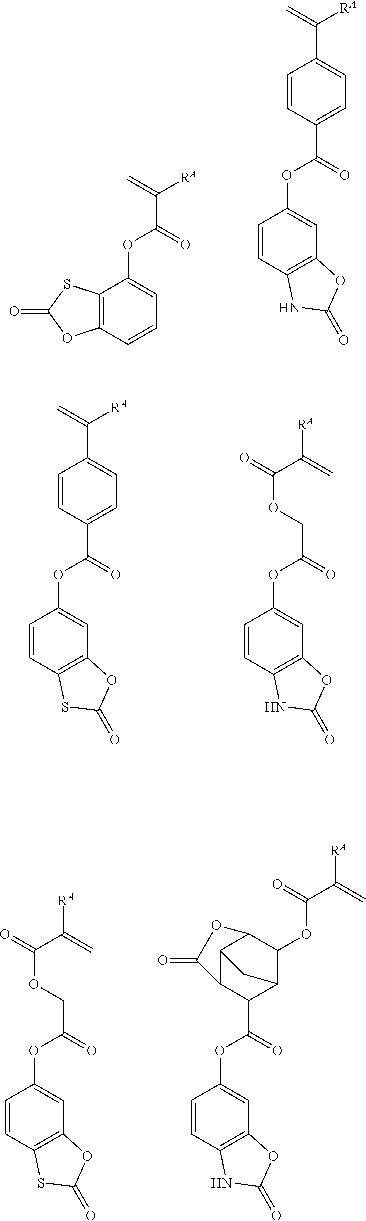

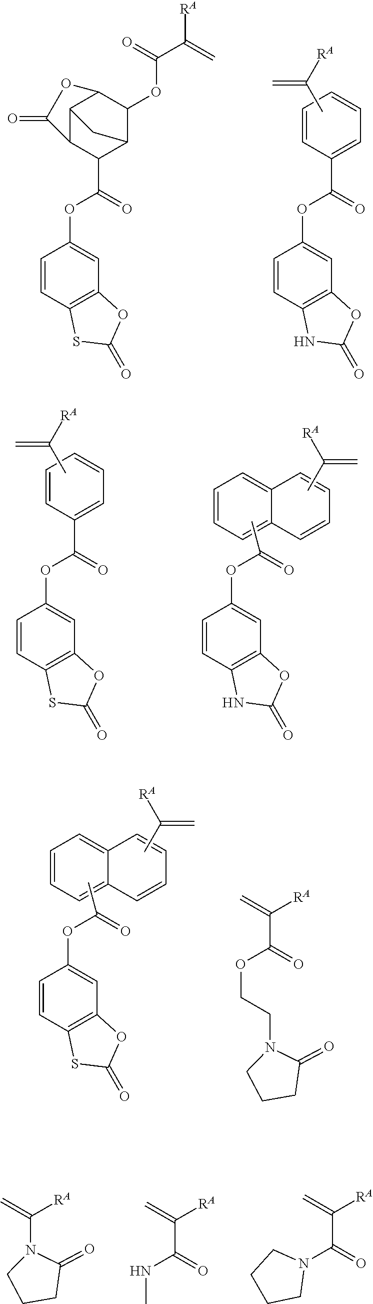

### (Repeating Unit e)

The base polymer may further have a repeating unit e having no amino group and having an iodine atom. Specific examples of a monomer to yield the repeating unit e include, but not limited to, the following monomers. In the formulae, R^{A} is the same as above.

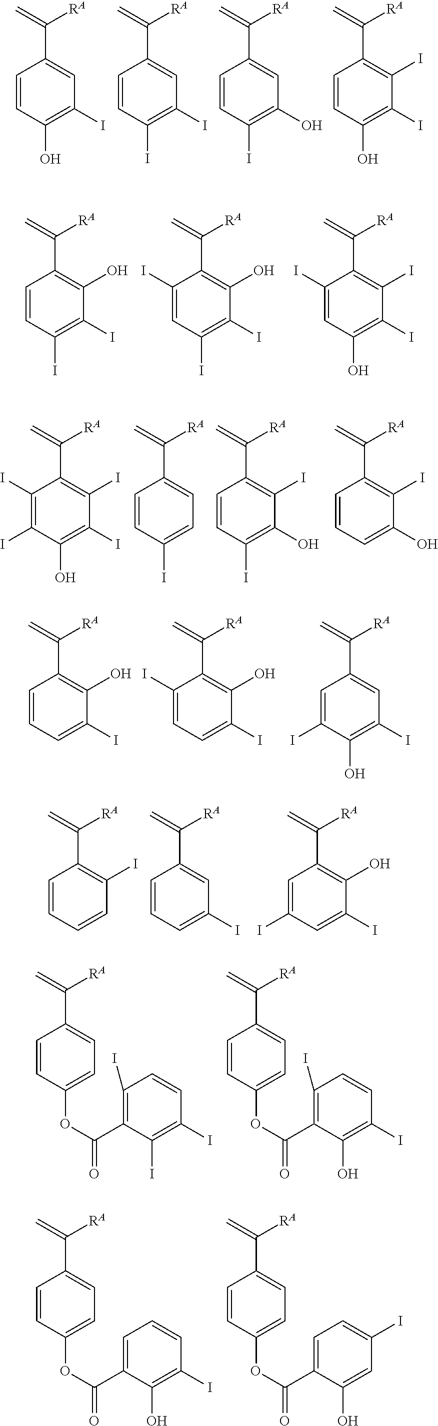

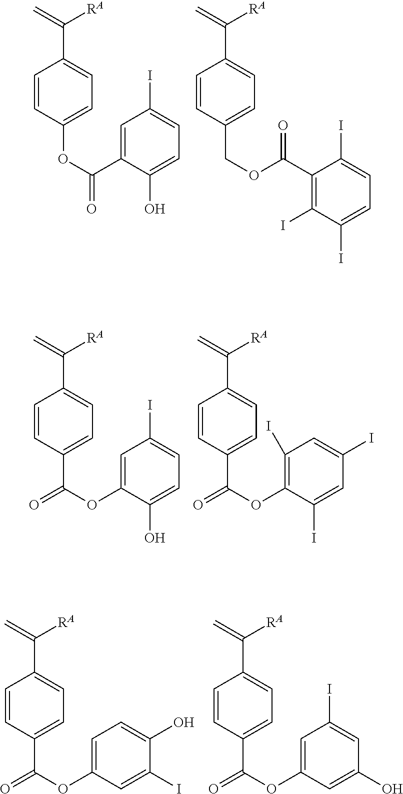

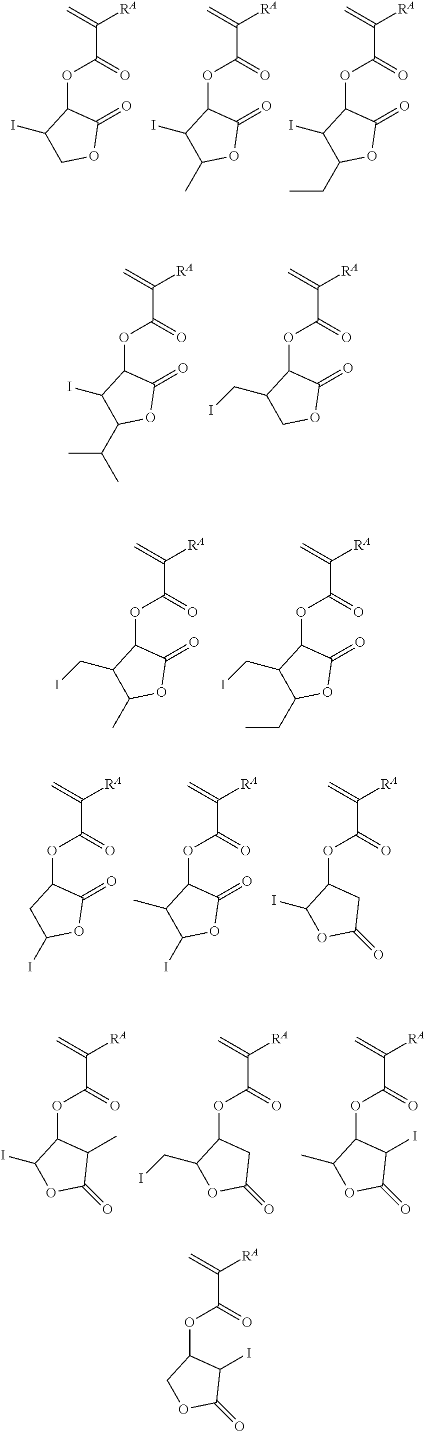

### (Repeating Unit f)

The base polymer may have a repeating unit f other than the aforementioned repeating units. Examples of the repeating unit f include a unit derived from styrene, vinylnaphthalene, indene, acenaphthylene, coumarin, coumarone, etc.

In the base polymer, content ratios of the repeating units a1, a2, d, e, and f preferably satisfy 0≤a1≤1.0, 0≤a2≤1.0, 0≤d≤0.8, 0≤e≤0.8, and 0≤f≤0.8, more preferably satisfy 0.001≤a1≤0.8, 0.001≤a2≤0.8, 0≤d≤0.5, 0≤e≤0.4, and 0≤f≤0.4, and further preferably satisfy 0.005≤a≤0.7, 0.005≤a2≤0.7, 0≤d1≤0.4, 0≤e≤0.3, and 0≤f≤0.3. Provided that a1+a2+d+e+f=1.0.

For synthesizing the base polymer, for example, the monomers to yield the aforementioned repeating units are heated with an added radical polymerization initiator in an organic solvent for polymerization.

Examples of the organic solvent used in the polymerization include toluene, benzene, tetrahydrofuran (THF), diethyl ether, dioxane, propylene glycol monomethyl ether, γ-butyrolactone, and a mixed solvent thereof. Examples of the polymerization initiator include 2,2′-azobisisobutyronitrile (AIBN), 2,2′-azobis(2,4-dimethylvaleronitrile), dimethyl 2,2-azobis(2-methylpropionate), benzoyl peroxide, and lauroyl peroxide. The temperature in the polymerization is preferably 50 to 80° C. The reaction time is preferably 2 to 100 hours, and more preferably 5 to 20 hours.

When a monomer having a hydroxy group is copolymerized, the hydroxy group may be substituted with an acetal group easily deprotectable by an acid, such as an ethoxyethyl group, during the polymerization, and the protected hydroxy group may be deprotected by a weak acid and water after the polymerization. Alternatively, the hydroxy group may be substituted with an acetyl group, a formyl group, a pivaloyl group during the polymerization, etc. and hydrolyzed with an alkali after the polymerization.

When hydroxystyrene or hydroxyvinylnaphthalene is copolymerized, it is acceptable that acetoxystyrene or acetoxyvinylnaphthalene is used instead of hydroxystyrene or hydroxyvinylnaphthalene, and after the polymerization, the acetoxy group is deprotected by the above alkaline hydrolysis to form hydroxystyrene or hydroxyvinylnaphthalene.

As a base in the alkaline hydrolysis, aqueous ammonia, triethylamine, etc. may be used. The reaction temperature is preferably −20 to 100° C., and more preferably 0 to 60° C. The reaction time is preferably 0.2 to 100 hours, and more preferably 0.5 to 20 hours.

The base polymer has a weight-average molecular weight (Mw), in terms of polystyrene measured by gel permeation chromatography (GPC) using THF as a solvent, of preferably 1,000 to 500,000, and more preferably 2,000 to 30,000. An excessively small Mw causes the resist material to have deteriorated heat resistance. An excessively large Mw deteriorates alkali solubility to tend to cause a bottom footing phenomenon after patterning.

Further, molecular weight distribution (Mw/Mn) of the base polymer is preferably 1.0 to 2.0, more preferably 1.0 to 1.7, and more preferably 1.0 to 1.5, which indicates narrow distribution. The molecular weight distribution within this range causes no risk of a foreign matter observed on a pattern after exposure or a deteriorated pattern shape due to the presence of a polymer having a low molecular weight or a high molecular weight. The resist material as above is suitably used for fine pattern dimension.

The base polymer may contain two or more polymers having different composition ratios, Mw, and Mw/Mn. The polymer having the repeating unit “a” and a polymer having no repeating unit “a” may be blended.

### Photodegradable Quencher

The resist material of the present invention contains a photodegradable quencher represented by the following formula (b1).

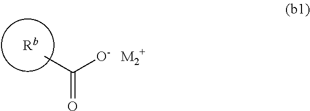

In the formula, Rb represents an organic group having 1 to 30 carbon atoms and optionally having a substituent. M₂⁺ represents a sulfonium cation.

The formula (b1) represents the sulfonium salt of a carboxylic acid, and causes ion exchange with a strong acid component generated from the photoacid generator to inhibit acid diffusion.

In the formula (b1), R^{b} preferably represents a group having an aromatic cyclic group or a cyclic hydrocarbon group. R^{b} more preferably represents a group having an aromatic cyclic group.

In the formula (b1), R^{b} preferably represents a group having one or more iodine atoms, and more preferably represents a group having two or more iodine atoms.

The photodegradable quencher represented by the formula (b1) is preferably represented by the following formula (b1-1).

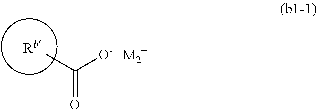

In the formula, Rb′ represents an organic group having 1 to 22 carbon atoms, optionally having a substituent, and optionally having an ester bond, an ether bond, an amide bond, a lactone ring, a sultone ring, an aromatic cyclic group, an aliphatic cyclic group, a hydroxy group, an alkoxy group, a fluoroalkyl group, a nitro group, a cyano group, a trifluoromethoxy group, a carbonyl group, an amino group, an alkylamino group, a fluorine atom, a bromine atom, or an iodine atom. M₂⁺ represents a sulfonium cation.

In the formula (b1-1), R^{b′} preferably represents a group having an aromatic cyclic group.

In the formula (b1-1), R^{b′} preferably represents a group having one or more iodine atoms, and more preferably represents a group having two or more iodine atoms.

The iodine atom, which has large absorption of EUV light, can efficiently generate secondary electrons from photons given by EUV exposure, and therefore, high sensitivity and high resolution are expected.

Specific examples of the anion moiety of the repeating units (b1) and (b1-1) include, but not limited to, the following moieties.

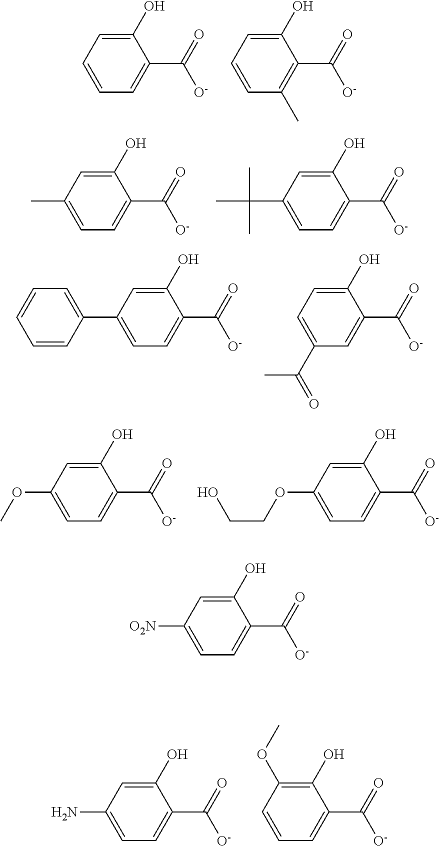

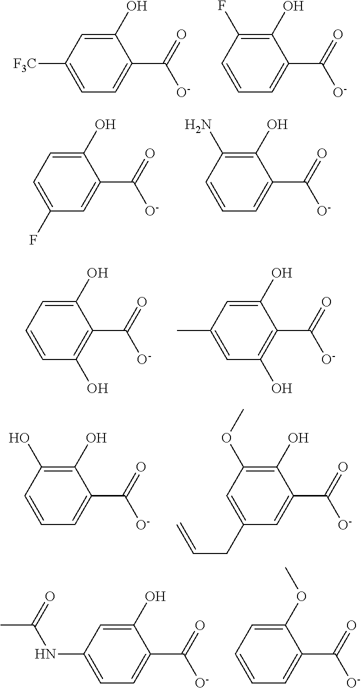

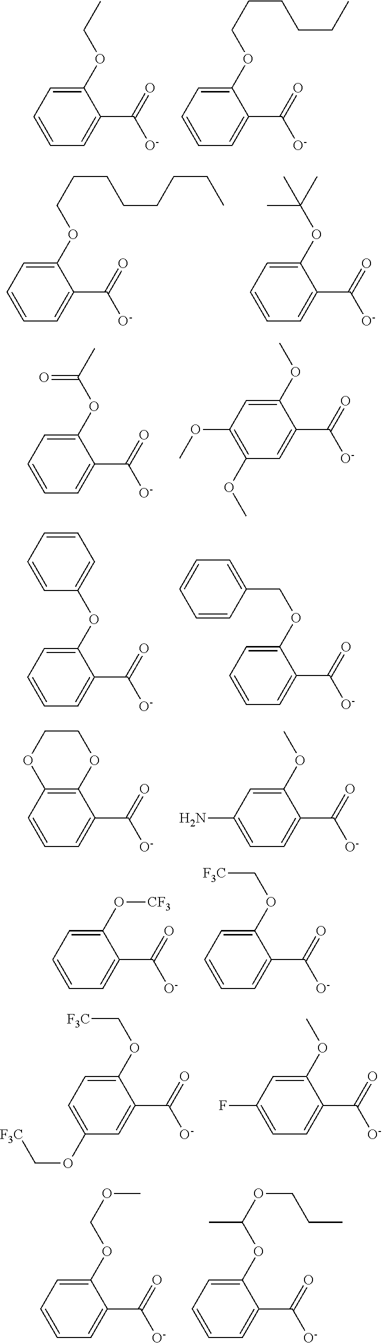

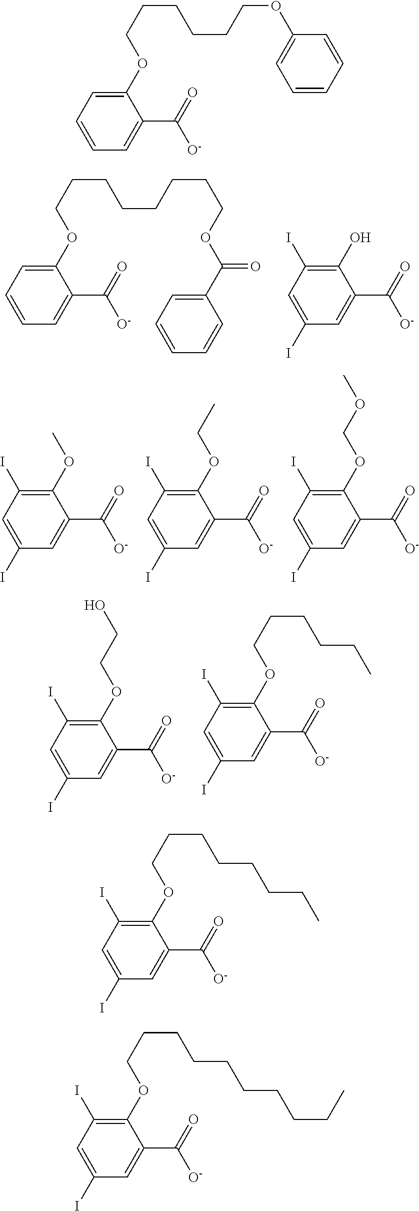

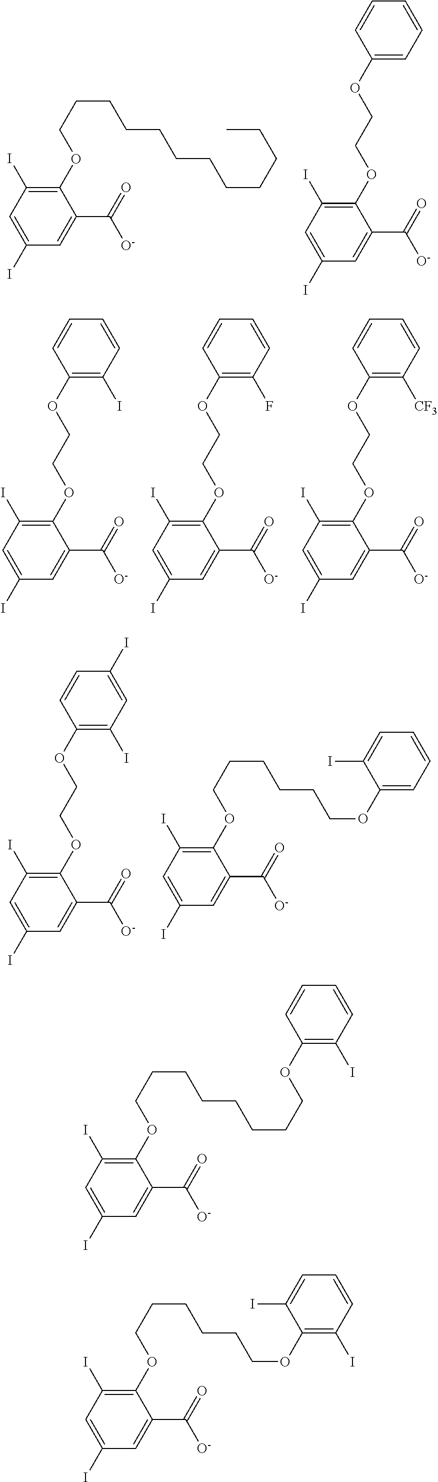

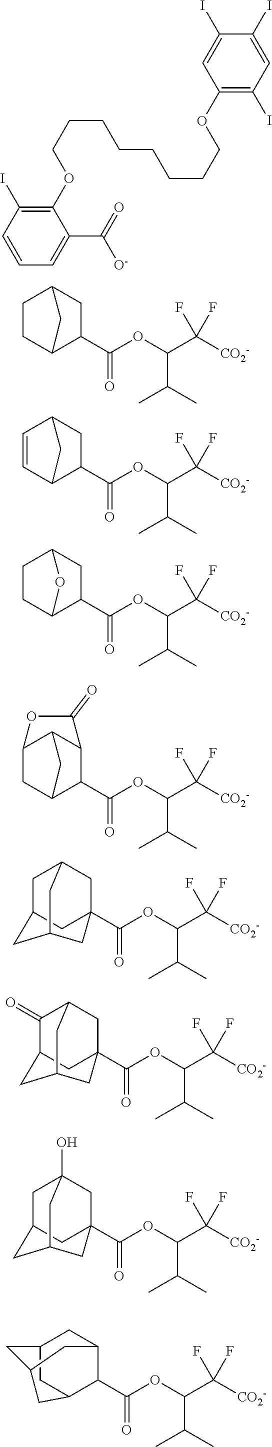

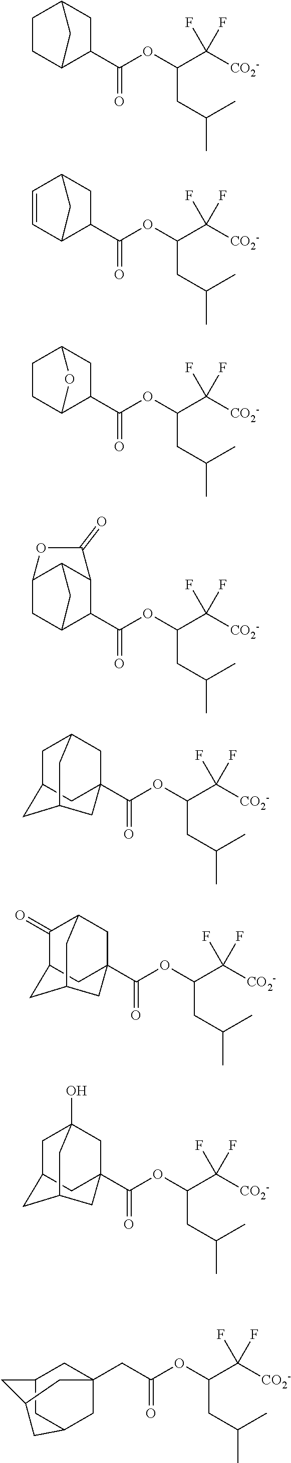

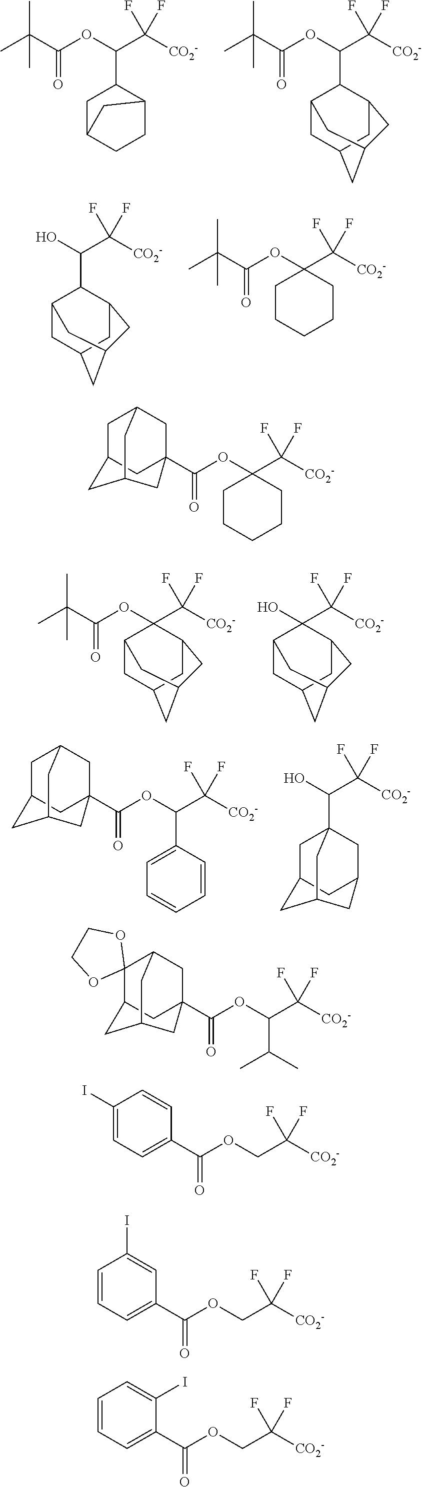

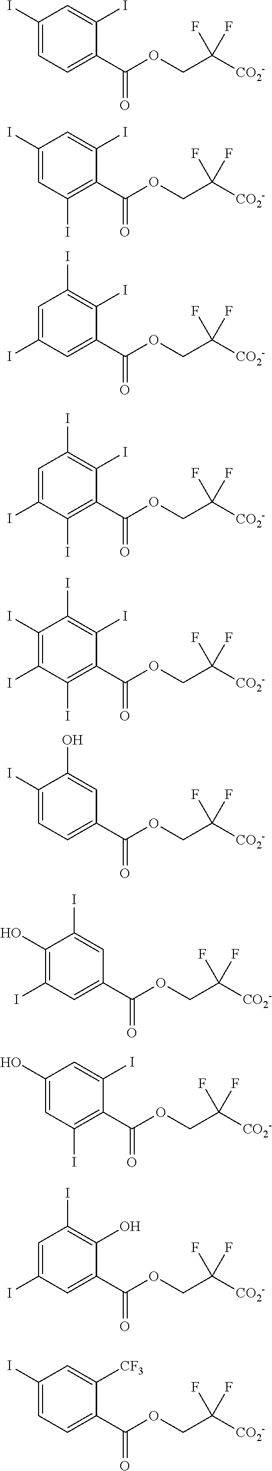

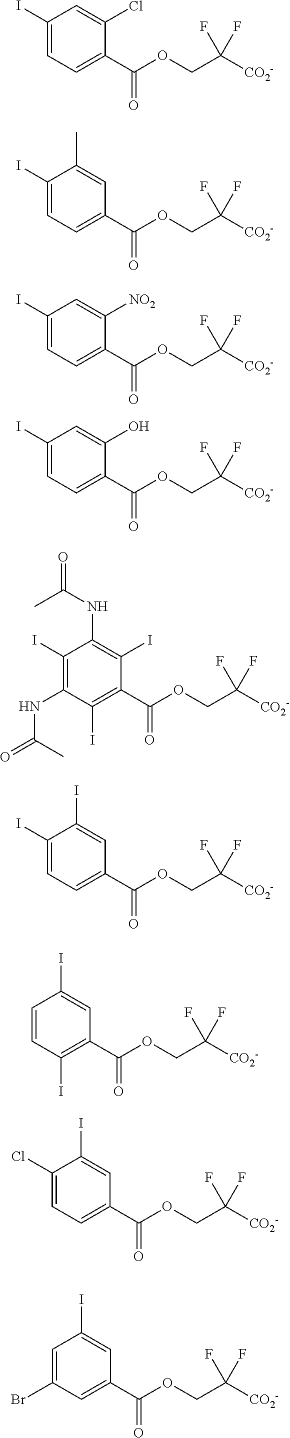

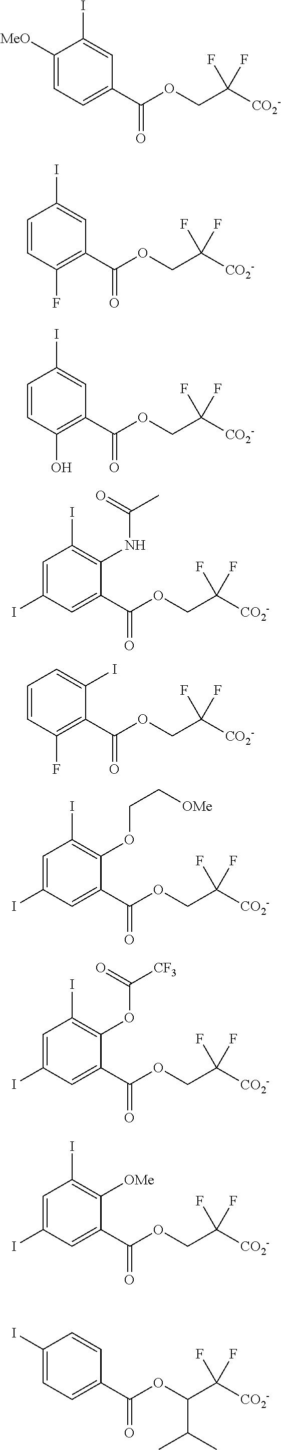

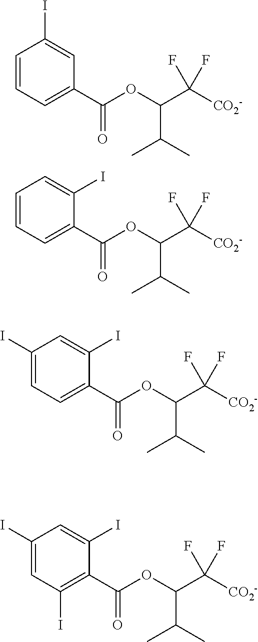

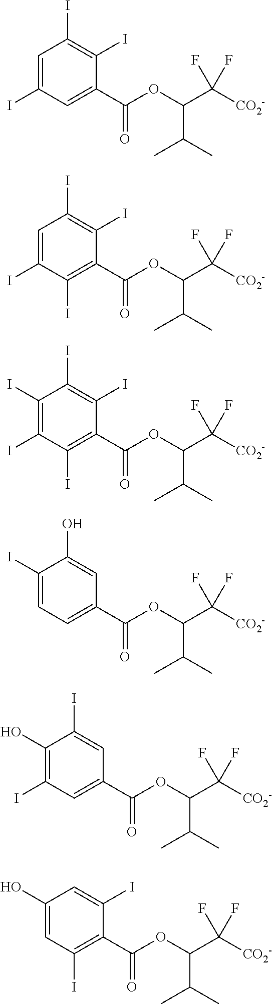

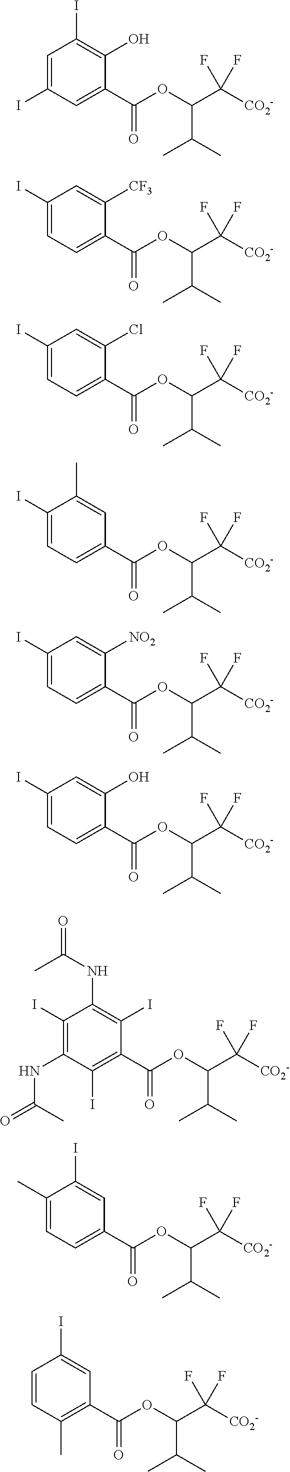

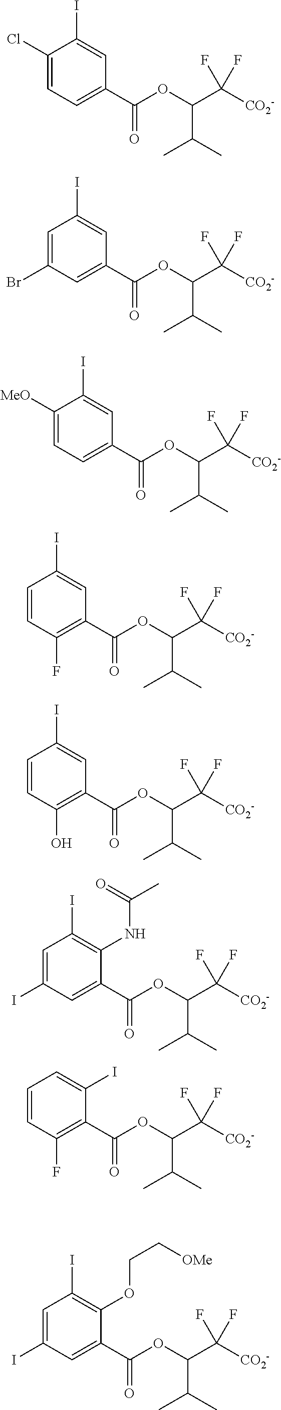

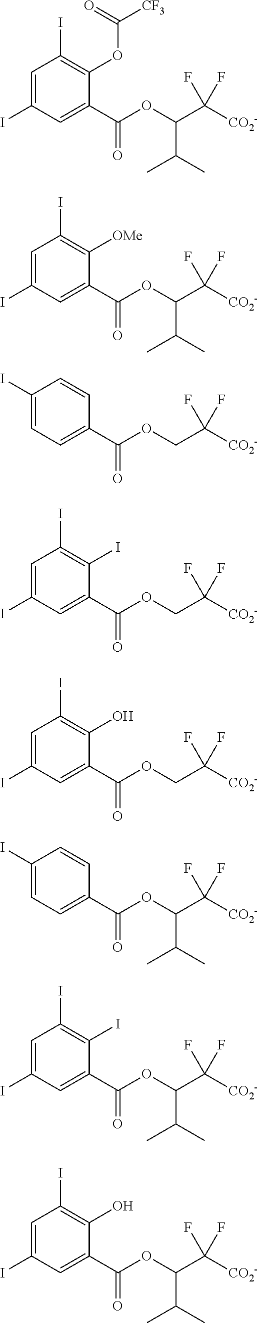

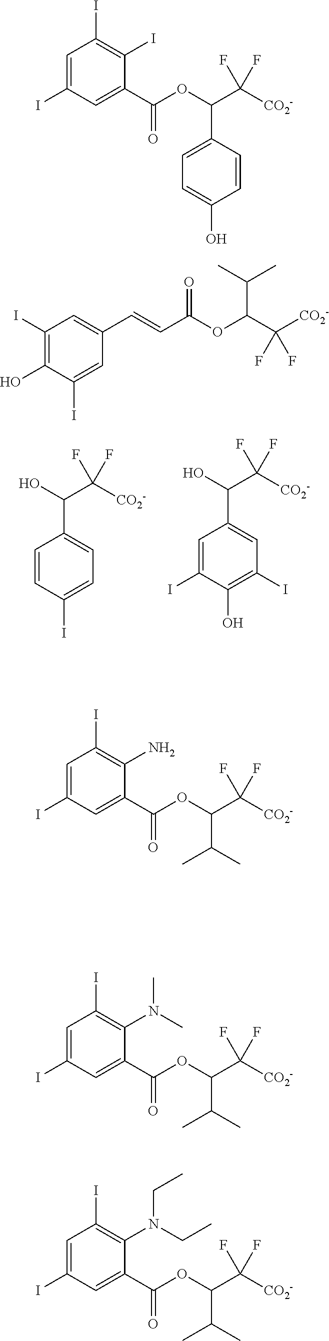

Examples of the cation moiety of the photodegradable quencher represented by the formula (b1) include, but not limited to, the same moieties exemplified as the cation moiety of the repeating unit (a1).

The sulfonium cation of M₂⁺ in the photodegradable quencher represented by the formula (b1) is preferably represented by the following formula (1).

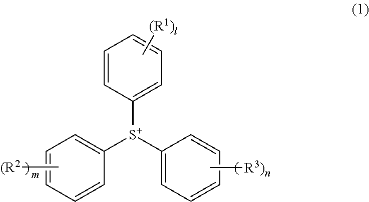

In the formula, R¹ represents a fluorine atom, an iodine atom, or a perfluoroalkyl group. R² and R³ each independently represent a fluorine atom or a perfluoroalkyl group. “l” represents an integer of 0 to 3, “m” represents an integer of 1 to 3, and “n” represents an integer of 1 to 3. When “l”, “m”, or “n” represents an integer of 2 or more, each of R¹, R², and R³ may be same or different, provided that structure of the formula (1) has at least two or more fluorine atoms. When R² or R³ represents a fluorine atom, at least one fluorine atom is substituted at a meta-position relative to a sulfur atom.

Examples of the sulfonium cation of the photodegradable quencher represented by the formula (1) include, but not limited to, the same cations exemplified as the preferable cation moiety of the repeating unit (a1).

In typical, a compound having many iodine atoms can increase absorption of EUV light, but may lead to deterioration in lithographic performance due to decrease in solubility in a cast solvent and a developer. The compound having an iodine atom in both the anion moiety and the cation moiety in the photodegradable quencher (b1) can increase the EUV absorption efficiency without impairing the solvent solubility, and therefore, improvement of lithographic performance can be expected.

It is preferable that both the cation moiety M¹⁺ of the repeating unit (a1) and the cation moiety M²⁺ of the photodegradable quencher (b1), contained in the resist composition of the present invention, have the structure represented by the formula (1). It is considered that the composition as above can increase a generation amount of secondary electrons by EUV exposure, can efficiently utilize the generated secondary electrons to generate an acid, and can improve chemical contrast between the exposed portion and the unexposed portion.

The composition as above can be a resist that yields high sensitivity, high resolution, and reduced edge roughness and dimensional deviation.

### Acid Generator

The positive-type resist material of the present invention may further contain an acid generator that generates a strong acid (hereinafter, which is also referred to as “addition-type acid generator”). The strong acid herein means a compound having sufficient acidity to cause the deprotection reaction of the acid-labile group in the base polymer. Examples of the acid generator include a compound that is sensitized by active ray or radiation to generate the acid (a photoacid generator). The photoacid generator may be any compound that generates the acid by irradiation with high-energy ray, but preferably a compound that generates a sulfonic acid, an imide acid, or a methide acid. Examples of preferable photoacid generators include sulfonium salt, iodonium salt, sulfonyldiazomethane, N-sulfonyloxyimide, and oxime-O-sulfonate acid generators. Specific examples of the photoacid generator include compounds described in paragraphs 0122 to 0142 of JP 2008-111103 A.

As the photoacid generator, sulfonium salts represented by the following formula (1-1) and iodonium salts represented by the following formula (1-2) may also be preferably used.

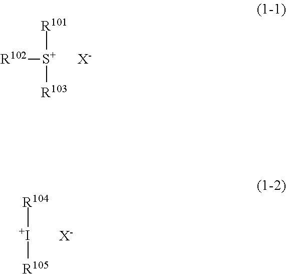

In the formulae (1-1) and (1-2), R¹⁰¹ to R¹⁰⁵ each independently represent a monovalent hydrocarbon group having 1 to 20 carbon atoms and optionally having a heteroatom. Any two of R¹⁰¹, R¹⁰², and R¹⁰³ may be bonded to each other to form a ring together with a sulfur atom to which these are bonded. The monovalent hydrocarbon group may be any of linear, branched, and cyclic, and specific examples thereof include the same groups as the aforementioned groups.

In the formulae (1-1) and (1-2), X⁻ represents an anion selected from the following formulae (1A) to (1D).

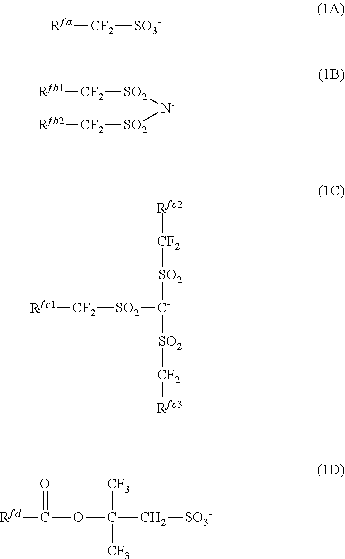

In the formula (1A), R^{fa} represents a fluorine atom or a hydrocarbyl group having 1 to 40 carbon atoms and optionally having a heteroatom. The hydrocarbyl group may be saturated or unsaturated, and may be any of linear, branched, and cyclic. Specific examples thereof include the same groups as a hydrocarbyl group represented by R¹⁰⁷ in the formula (1A′), described later.

The anion represented by the formula (1A) is preferably an anion represented by the following formula (1A′).

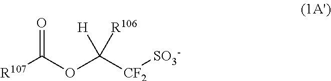

In the formula (1A′), R¹⁰⁶ represents a hydrogen atom or a trifluoromethyl group, and preferably represents a trifluoromethyl group. R¹⁰⁷ represents a hydrocarbyl group having 1 to 38 carbon atoms and optionally having a heteroatom. The heteroatom is preferably an oxygen atom, a nitrogen atom, a sulfur atom, a halogen atom, etc., and more preferably an oxygen atom. The hydrocarbyl group particularly preferably has 6 to 30 carbon atoms in terms of obtaining high resolution in fine patterning.

The hydrocarbyl group represented by R¹⁰⁷ may be saturated or unsaturated, and may be any of linear, branched, and cyclic. Specific examples thereof include: alkyl groups such as a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosanyl group; cyclic saturated hydrocarbyl groups such as a cyclopentyl group, a cyclohexyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group; unsaturated hydrocarbyl groups such as an allyl group and a 3-cyclohexenyl group; aryl groups such as a phenyl group, a 1-naphthyl group, and a 2-naphthyl group; and aralkyl groups such as a benzyl group and a diphenylmethyl group.

A part or all of hydrogen atoms in these groups may be substituted with a group having a heteroatom such as an oxygen atom, a sulfur atom, a nitrogen atom, and a halogen atom. A part of carbon atoms in these groups may be substituted with a group having a heteroatom such as an oxygen atom, a sulfur atom, and a nitrogen atom. As a result, these groups may have a hydroxy group, a cyano group, a carbonyl group, an ether bond, an ester bond, a sulfonate ester bond, a carbonate group, a lactone ring, a sultone ring, a carboxylic anhydride, and a haloalkyl group. Specific examples of the hydrocarbyl group having the heteroatom include a tetrahydrofuryl group, a methoxymethyl group, an ethoxymethyl group, a methylthiomethyl group, an acetamidomethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group.

Synthesis of the sulfonium salt having the anion represented by the formula (1A′) is described in detail in JP 2007-145797 A, JP 2008-106045 A, JP 2009-7327 A, JP 2009-258695 A, etc. Sulfonium salts described in JP 2010-215608 A, JP 2012-41320 A, JP 2012-106986 A, JP 2012-153644 A, etc. may also be preferably used.

Examples of the anion represented by the formula (1A) include the same anions exemplified as anions represented by the formula (1A) in JP 2018-197853 A.

In the formula (1B), R^{fb1} and R^{fb2} each independently represent a fluorine atom or a hydrocarbyl group having 1 to 40 carbon atoms and optionally having a heteroatom. The hydrocarbyl group may be saturated or unsaturated, and may be any of linear, branched, and cyclic. Specific examples thereof include the same groups exemplified in the description about R¹⁰⁷ in the formula (1A′). R^{fb1} and R^{fb2} preferably represent a fluorine atom or a linear fluorinated alkyl group having 1 to 4 carbon atoms. R^{fb1} and R^{fb2} may be bonded to each other to form a ring together with a group to which R^{fb1} and R^{fb2} are bonded (—CF₂—SO₂—N—SO₂—CF₂—). In this case, the group obtained by bonding R^{fb1} and R^{fb2} each other is preferably a fluorinated ethylene group or a fluorinated propylene group.

In the formula (1C), R^{fc1}, R^{fc2}, and R^{fc3} each independently represent a fluorine atom or a hydrocarbyl group having 1 to 40 carbon atoms and optionally having a heteroatom. The hydrocarbyl group may be saturated or unsaturated, and may be any of linear, branched, and cyclic. Specific examples thereof include the same groups exemplified in the description about R¹⁰⁷ in the formula (1A′). R^{fc1}, R^{fc2}, and R^{fc3} preferably represent a fluorine atom or a linear fluorinated alkyl group having 1 to 4 carbon atoms. R^{fc1} and R^{fc2} may be bonded to each other to form a ring together with a group to which R^{fc1} and R^{fc2} are bonded (—CF₂—SO₂—C—SO₂—CF₂—). In this case, the group obtained by bonding R^{fc1} and R^{fc2} each other is preferably a fluorinated ethylene group or a fluorinated propylene group.

In the formula (1D), R^{fd} represents a hydrocarbyl group having 1 to 40 carbon atoms and optionally having a heteroatom. The hydrocarbyl group may be saturated or unsaturated, and may be any of linear, branched, and cyclic. Specific examples thereof include the same groups exemplified in the description about R¹⁰⁷ in the formula (1A′).

Synthesis of the sulfonium salt having the anion represented by the formula (1D) is described in detail in JP 2010-215608 A and JP 2014-133723 A.

Examples of the anion represented by the formula (1D) include the same anions exemplified as anions represented by the formula (1D) of JP 2018-197853 A.

Although the photoacid generator having the anion represented by the formula (1D) has no fluorine at the α-position of the sulfo group, the photoacid generator has acidity sufficient for cleaving the acid-labile group in the base polymer due to the two trifluoromethyl groups at the β-position. Therefore, the above photoacid generator can be used as the photoacid generator.

Further, compounds represented by the following formula (2) may also be preferably used as the photoacid generator.

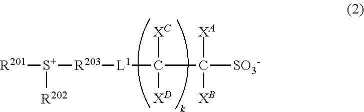

In the formula (2), R²⁰¹ and R²⁰² each independently represent a hydrocarbyl group having 1 to 30 carbon atoms and optionally having a heteroatom. R²⁰³ represents a hydrocarbylene group having 1 to 30 carbon atoms and optionally having a heteroatom. R²⁰¹ and R²⁰² or R²⁰¹ and R²⁰³ may be bonded to each other to form a ring together with a sulfur atom to which these are bonded. In this case, examples of the ring include the same rings exemplified as the ring that can be formed by bonding R¹⁰¹ and R¹⁰² together with the sulfur atom to which R¹⁰¹ and R¹⁰² are bonded, in the description about the formula (1-1).

The hydrocarbyl group represented by R²⁰¹ and R²⁰² may be saturated or unsaturated, and may be any of linear, branched, and cyclic. Specific examples thereof include: alkyl groups such as a methyl group, an ethyl group, a propyl group, an isopropyl group, a n-butyl group, a sec-butyl group, a tert-butyl group, a n-pentyl group, a tert-pentyl group, a n-hexyl group, a n-octyl group, a 2-ethylhexyl group, a n-nonyl group, and n-decyl group; cyclic saturated hydrocarbyl groups such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, and an adamantyl group; and aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, a naphthyl group, a methylnaphthyl group, an ethylnaphthyl group, a n-propylnaphthyl group, an isopropylnaphthyl group, a n-butylnaphthyl group, an isobutylnaphthyl group, a sec-butylnaphthyl group, a tert-butylnaphthyl group, and anthracenyl group. A part or all of hydrogen atoms in these groups may be substituted with a group having a heteroatom such as an oxygen atom, a sulfur atom, a nitrogen atom, and a halogen atom. A part of carbon atoms in these groups may be substituted with a group having a heteroatom such as an oxygen atom, a sulfur atom, and a nitrogen atom. As a result, the hydrocarbyl group may have a hydroxy group, a cyano group, a carbonyl group, an ether bond, an ester bond, a sulfonate ester bond, a carbonate group, a lactone ring, a sulfone ring, a carboxylic anhydride, a haloalkyl group, etc.

The hydrocarbylene group represented by R²⁰³ may be saturated or unsaturated, and may be any of linear, branched, and cyclic. Specific examples thereof include: alkanediyl groups such as a methylene group, an ethylene group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group, and a heptadecane-1,17-diyl group; cyclic saturated hydrocarbylene groups such as a cyclopentanediyl group, a cyclohexanediyl group, a norbornanediyl group, and an adamantanediyl group; and arylene groups such as a phenylene group, a methylphenylene group, an ethylphenylene group, a n-propylphenylene group, an isopropylphenylene group, a n-butylphenylene group, an isobutylphenylene group, a sec-butylphenylene group, a tert-butylphenylene group, a naphthylene group, a methylnaphthylene group, an ethylnaphthylene group, a n-propylnaphthylene group, an isopropylnaphthylene group, a n-butylnaphthylene group, an isobutylnaphthylene group, a sec-butylnaphthylene group, and a tert-butylnaphthylene group. A part or all of hydrogen atoms in these groups may be substituted with a group having a heteroatom such as an oxygen atom, a sulfur atom, a nitrogen atom, and a halogen atom. A part of carbon atoms in these groups may be substituted with a group having a heteroatom such as an oxygen atom, a sulfur atom, and a nitrogen atom. As a result, the hydrocarbylene group may have a hydroxy group, a cyano group, a carbonyl group, an ether bond, an ester bond, a sulfonate ester bond, a carbonate group, a lactone ring, a sulfone ring, a carboxylic anhydride, a haloalkyl group, etc. The heteroatom is preferably an oxygen atom.

In the formula (2), L₁ represents a single bond, an ether bond, or a hydrocarbylene group having 1 to 20 carbon atoms and optionally having a heteroatom. The hydrocarbylene group may be saturated or unsaturated, and may be any of linear, branched, and cyclic. Specific examples thereof include the same groups exemplified as the hydrocarbylene group represented by R²⁰³.

In the formula (2), X^{A}, X^{B}, XC, and X^{D} each independently represent a hydrogen atom, a fluorine atom, or a trifluoromethyl group. Provided that at least one of X^{A}, X^{B}, X^{C}, and X^{D} represents a fluorine atom or a trifluoromethyl group.

In the formula (2), “k” represents an integer of 0 to 3.

The photoacid generator represented by the formula (2) is preferably represented by the following formula (2′).

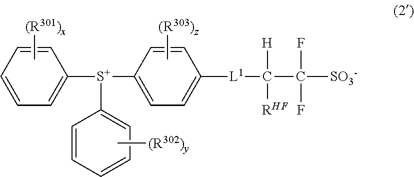

In the formula (2′), L¹ is the same as above. R^{HF} represents a hydrogen atom or a trifluoromethyl group, and preferably represents a trifluoromethyl group. R³⁰¹, R³⁰², and R³⁰³ each independently represent a hydrogen atom or a hydrocarbyl group having 1 to 20 carbon atoms and optionally having a heteroatom. The hydrocarbyl group may be saturated or unsaturated, and may be any of linear, branched, and cyclic. Specific examples thereof include the same groups exemplified in the description about R¹⁰⁷ in the formula (1A′). “x” and “y” each independently represent an integer of 0 to 5, and “z” represents an integer of 0 to 4.

Examples of the photoacid generator represented by the formula (2) include the same compounds exemplified as photoacid generators represented by the formula (2) in JP 2017-026980 A.

Among the above photoacid generators, the photoacid generators having the anion represented by the formula (1A′) or (1D) reduce acid diffusion and have excellent solubility in a resist solvent, which are particularly preferable. The photoacid generators represented by the formula (2′) extremely reduce acid diffusion, which are particularly preferable.

Further, sulfonium salts or iodonium salts having an anion having an aromatic ring substituted with an iodine atom or a bromine atom may also be used as the photoacid generator. Examples of such salts include salts represented by the following formula (3-1) or (3-2).

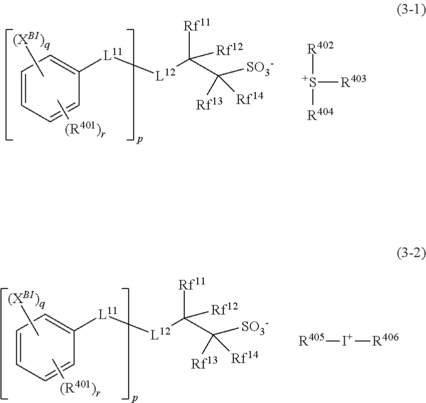

In the formulae (3-1) and (3-2), “p” represents an integer satisfying 1≤p≤3. “q” and “r” represent integers satisfying 1≤q≤5, 0≤r≤3, and 1≤q+r≤5. “q” preferably represents an integer satisfying 1≤q≤3, and more preferably represents 2 or 3. “r” preferably represents an integer satisfying 0≤r≤2.

In the formulae (3-1) and (3-2), X^{BI} represents an iodine atom or a bromine atom. When “q” represents 2 or more, X^{BI} may be same as or different from each other.

In the formulae (3-1) and (3-2), L¹¹ represents a single bond, an ether bond, an ester bond, or a saturated hydrocarbylene group having 1 to 6 carbon atoms and optionally having an ether bond or an ester bond. The saturated hydrocarbylene group may be any of linear, branched, and cyclic.

In the formulae (3-1) and (3-2), Liz represents a single bond or a divalent linking group having 1 to 20 carbon atoms when “p” represents 1, and L¹² represents a trivalent or tetravalent linking group having 1 to 20 carbon atoms when “p” represents 2 or 3. The linking group may have a chlorine atom, a bromine atom, an iodine atom, an oxygen atom, a sulfur atom, or a nitrogen atom.

In the formulae (3-1) and (3-2), R⁴⁰¹ represents a hydroxy group, a carboxy group, a fluorine atom, a chlorine atom, a bromine atom, an amino group, a saturated hydrocarbyl group having 1 to 20 carbon atoms, a saturated hydrocarbyloxy group having 1 to 20 carbon atoms, an unsaturated hydrocarbyloxy group having 2 to 20 carbon atoms, a saturated hydrocarbyloxycarbonyl group having 2 to 10 carbon atoms, a saturated hydrocarbyloxycarbonyloxy group having 1 to 10 carbon atoms, a saturated hydrocarbylcarbonyloxy group having 2 to 20 carbon atoms, an unsaturated hydrocarbylcarbonyloxy group having 2 to 20 carbon atoms, or a saturated hydrocarbylsulfonyloxy group having 1 to 20 carbon atoms, the groups optionally having a fluorine atom, a chlorine atom, a bromine atom, a hydroxy group, an amino group, a carbonyl group, an oxycarbonyl group, or an ether bond, or —NR⁴⁰¹A-C(═O)—R^{401B} or —NR^{401A}-C(═O)—O—R^{401B}. R^{401A} represents a hydrogen atom or a saturated hydrocarbyl group having 1 to 6 carbon atoms, and optionally having a halogen atom, a hydroxy group, an alkoxy group having 1 to 6 carbon atoms, a saturated hydrocarbylcarbonyl group having 2 to 6 carbon atoms, or a saturated hydrocarbylcarbonyloxy group having 2 to 6 carbon atoms. R^{401B} represents an aliphatic hydrocarbyl group having 1 to 16 carbon atoms or an aryl group having 6 to 12 carbon atoms, and optionally having a halogen atoms, a hydroxy group, a saturated hydrocarbyloxy group having 1 to 6 carbon atoms, a saturated hydrocarbylcarbonyl group having 2 to 6 carbon atoms, or a saturated hydrocarbylcarbonyloxy group having 2 to 6 carbon atoms. The aliphatic hydrocarbyl group may be saturated or unsaturated, and may be any of linear, branched, and cyclic. The saturated hydrocarbyl group, the saturated hydrocarbyloxy group, the saturated hydrocarbyloxycarbonyl group, the saturated hydrocarbylcarbonyl group, and the saturated hydrocarbylcarbonyloxy group may be any of linear, branched, and cyclic. When “p” and/or “r” represent 2 or more, each of R⁴⁰¹ may be same as or different from each other.

Among these, R⁴⁰¹ preferably represents a hydroxy group, —NR⁴⁰¹A-C(═O)—R^{401B}, —NR⁴⁰¹A-C(═O)—O—R^{401B}, a fluorine atom, a chlorine atom, a bromine atom, a methyl group, a methoxy group, etc.

In the formulae (3-1) and (3-2), Rf¹¹ to Rf¹⁴ each independently represent a hydrogen atom, a fluorine atom, or a trifluoromethyl group, and at least one of them represents a fluorine atom or a trifluoromethyl group. Rf¹¹ and Rf¹² may further represent an oxygen atom, and when Rf¹¹ represents an oxygen atom, Rf¹² also represents the oxygen atom to form a carbonyl group together with the bonded carbon atom. Particularly, both Rf¹³ and Rf¹⁴ preferably represent a fluorine atom.

In the formulae (3-1) and (3-2), R⁴⁰², R⁴⁰³, R⁴⁰⁴, R⁴⁰⁵, and R⁴⁰⁶ each independently represent a fluorine atom, a chlorine atom, a bromine atom, an iodine atom, or a hydrocarbyl group having 1 to 20 carbon atoms and optionally having a heteroatom. The hydrocarbyl group may be saturated or unsaturated, and may be any of linear, branched, and cyclic. Specific examples thereof include the same groups exemplified as the hydrocarbyl group represented by R¹⁰¹ to R¹⁰⁵ in the description about the formulae (1-1) and (1-2). A part or all of hydrogen atoms in these groups may be substituted with a hydroxy group, a carboxy group, a halogen atom, a cyano group, a nitro group, a mercapto group, a sultone group, a sulfone group, or a sulfonium-salt-containing group. A part of carbon atoms in these groups may be substituted with an ether bond, an ester bond, a carbonyl group, an amide bond, a carbonate group, or a sulfonate ester bond. R⁴⁰² and R⁴⁰³ may be bonded to each other to form a ring together with the sulfur atom to which R⁴⁰² and R⁴⁰³ are bonded. In this case, examples of the ring include the same rings exemplified as the ring that can be formed by bonding R¹⁰¹ and R¹⁰² each other together with the sulfur atom to which R¹⁰¹ and R¹⁰² are bonded, in the description about the formula (1-1).

Examples of the cation of the sulfonium salt represented by the formula (3-1) include the same cations exemplified as the cations of the sulfonium salts represented by the formula (1-1). Examples of the cation of the iodonium salt represented by the formula (3-2) include the same cations exemplified as the cations of the iodonium salts represented by the formula (1-2).

Specific examples of the anions of the onium salts represented by the formula (3-1) or (3-2) include, but not limited to, the following anions. In the following formulae, X^{BI} is the same as above.

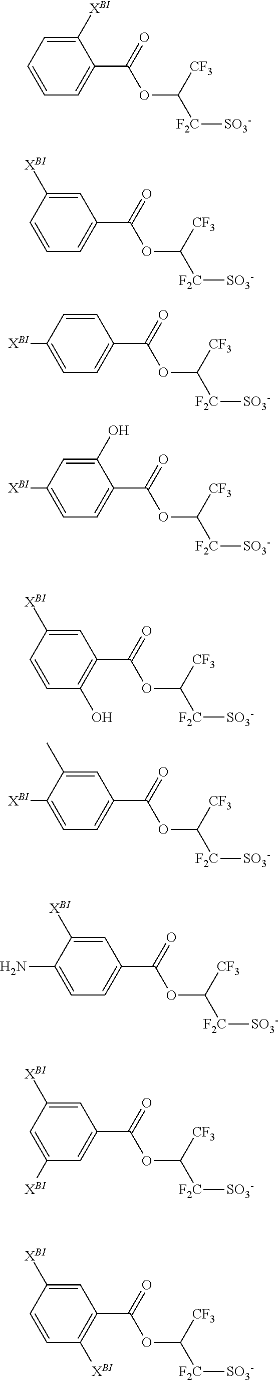

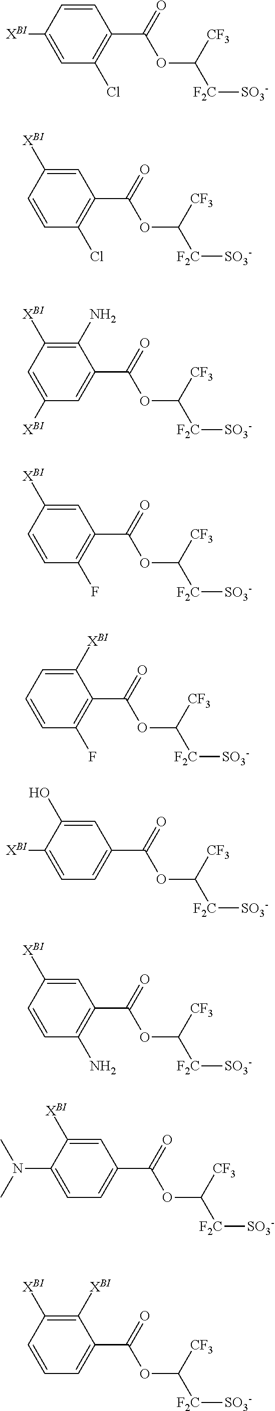

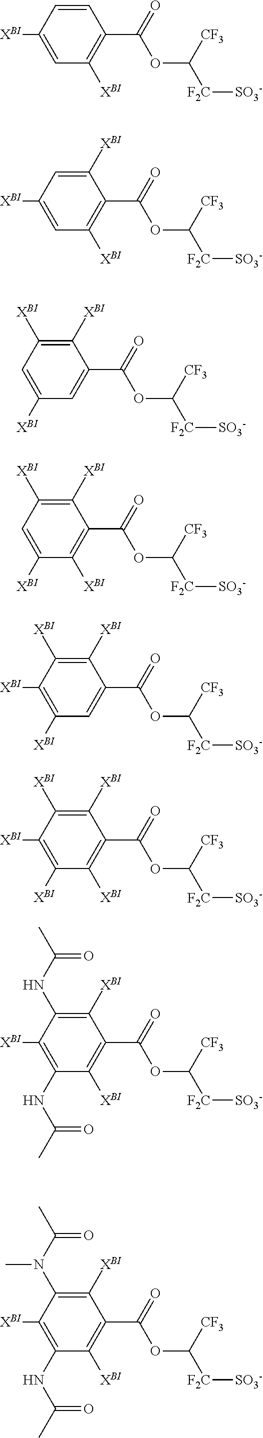

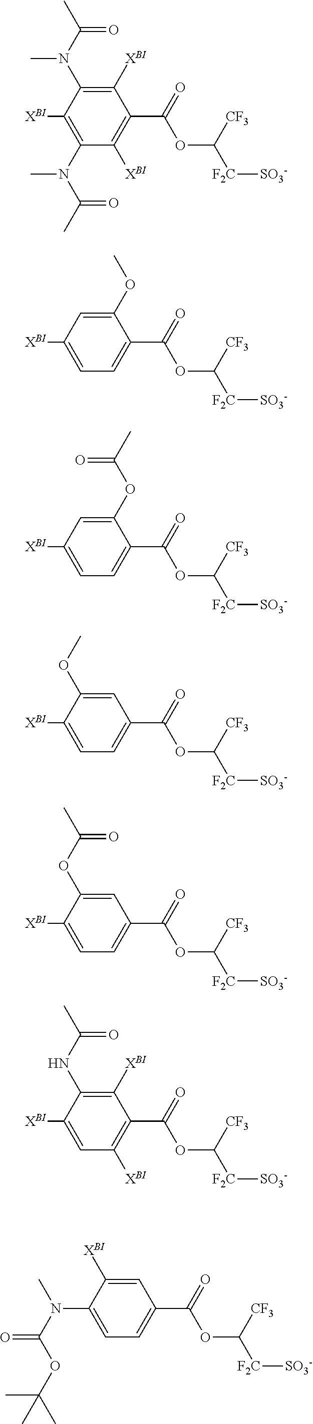

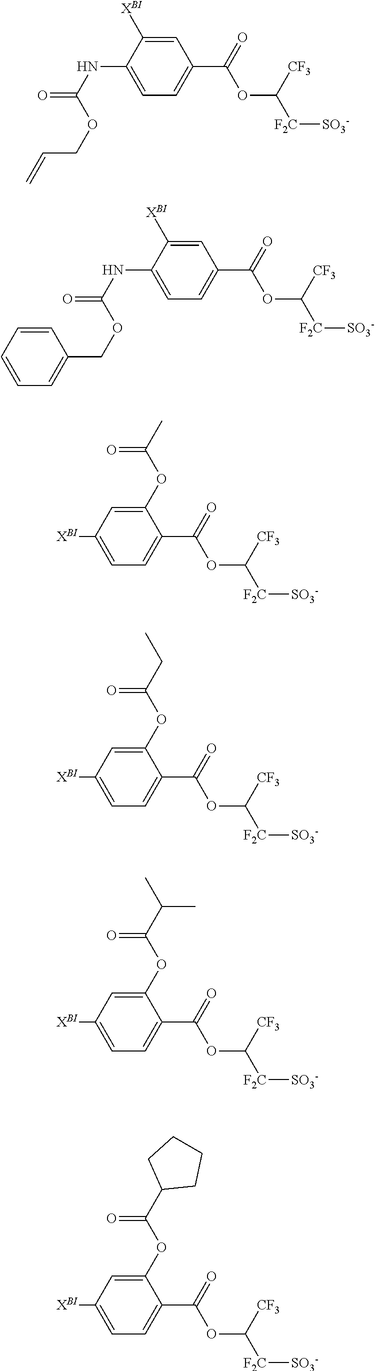

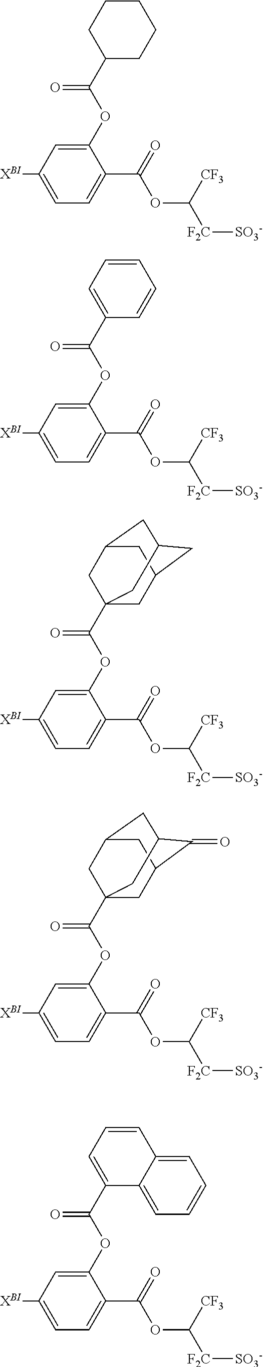

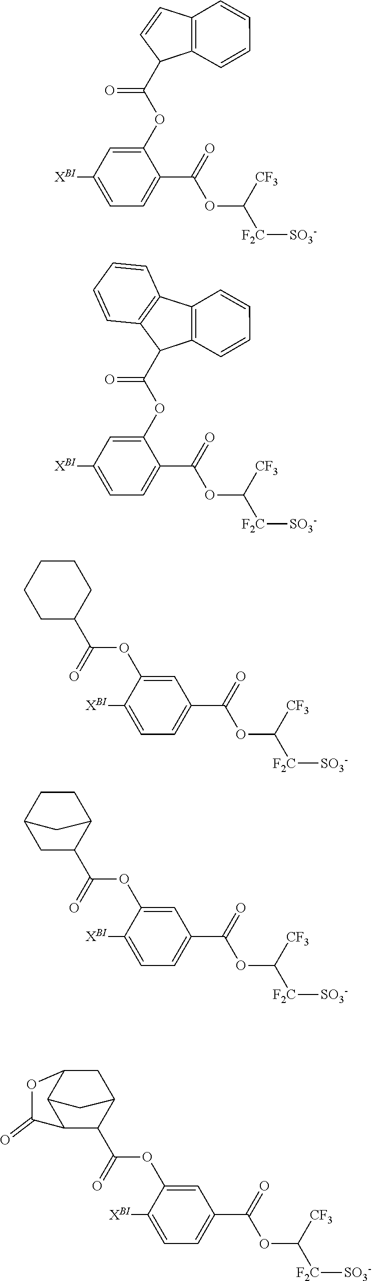

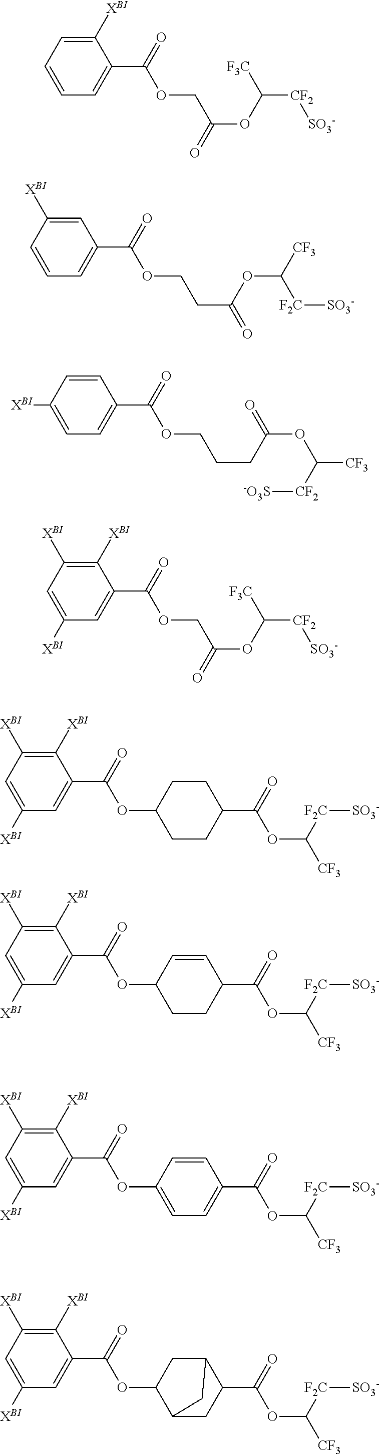

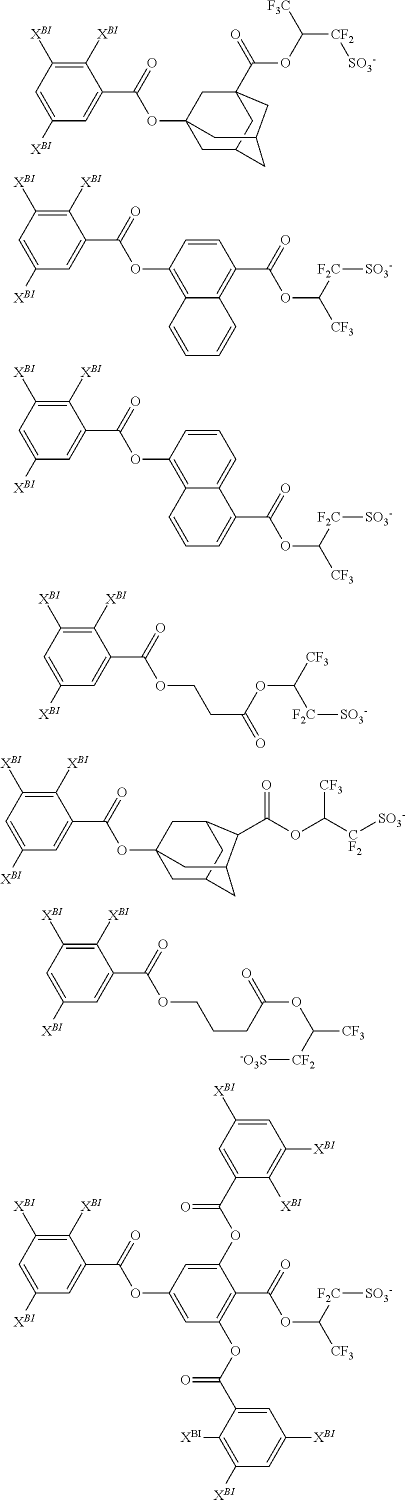

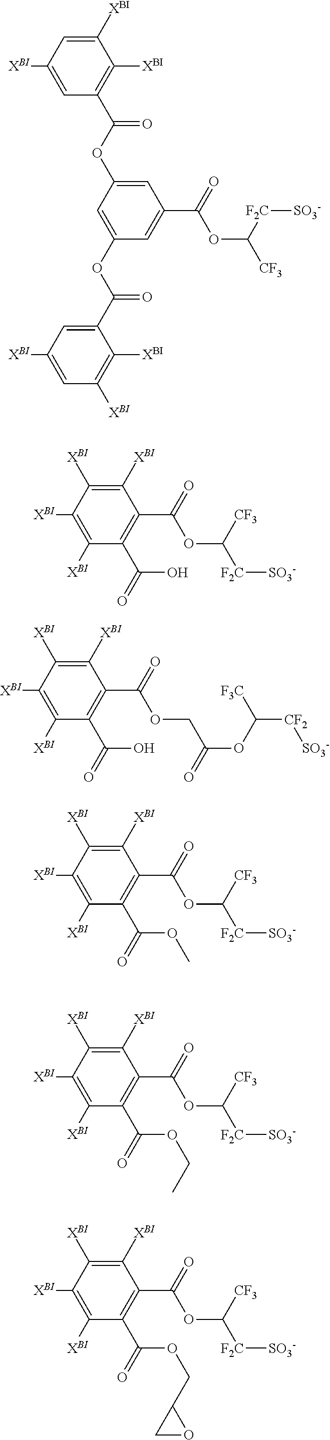

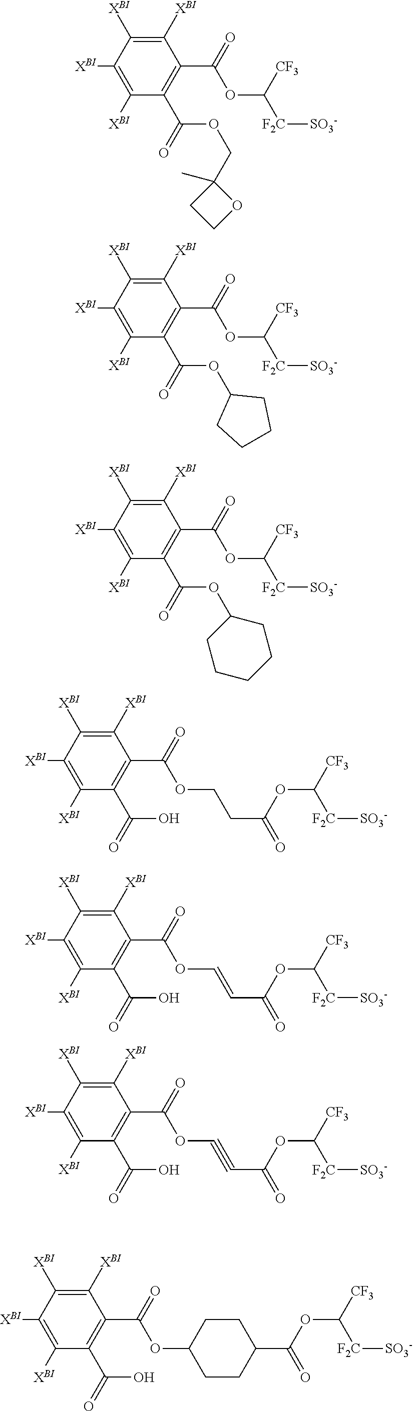

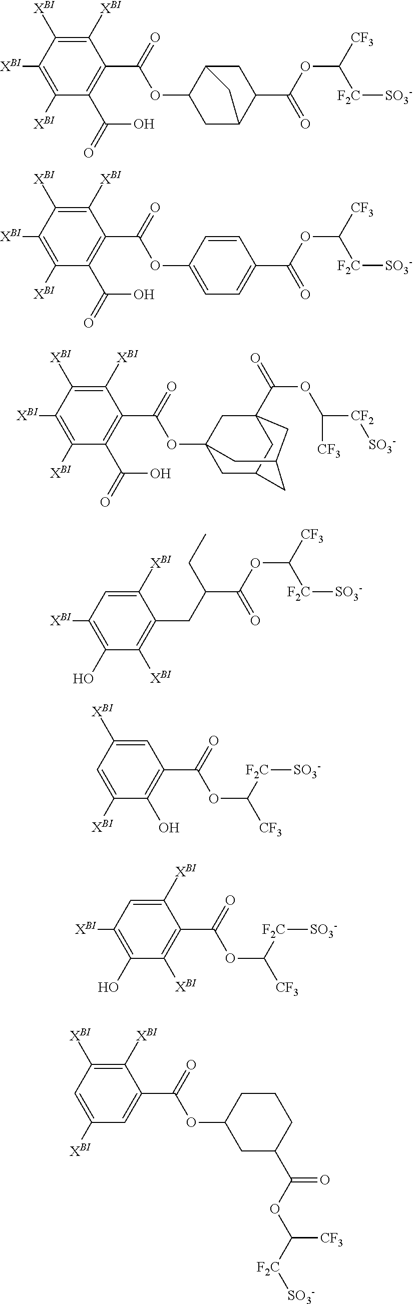

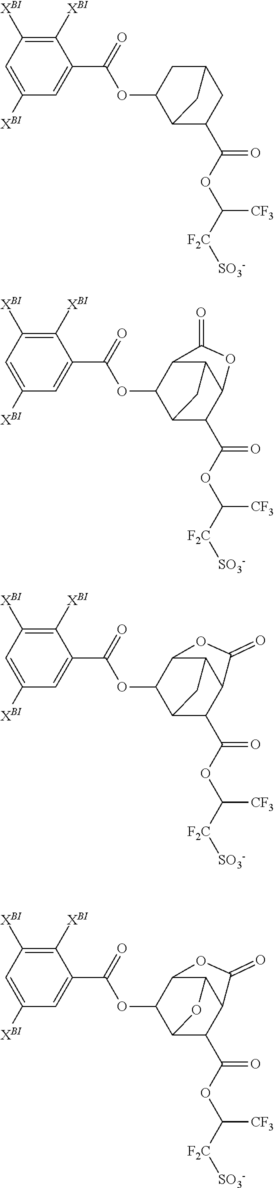

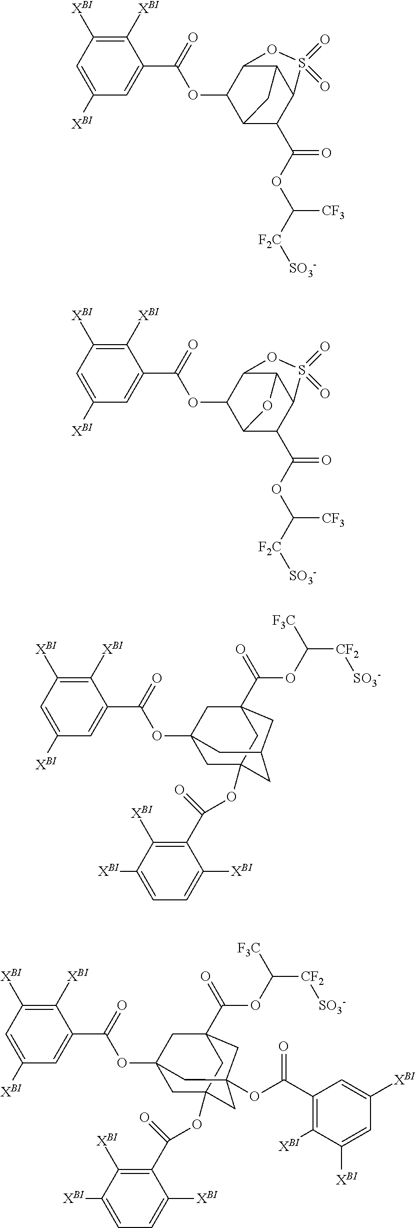

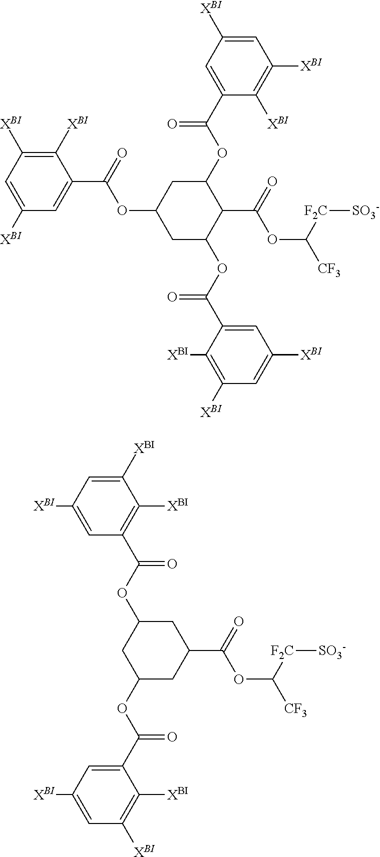

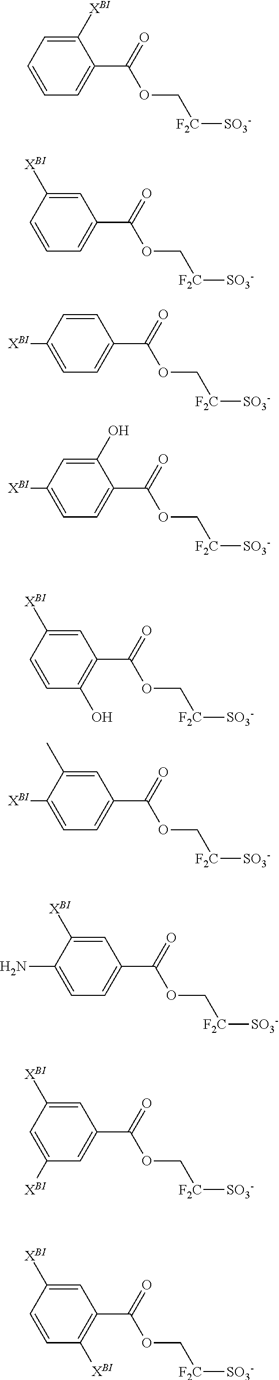

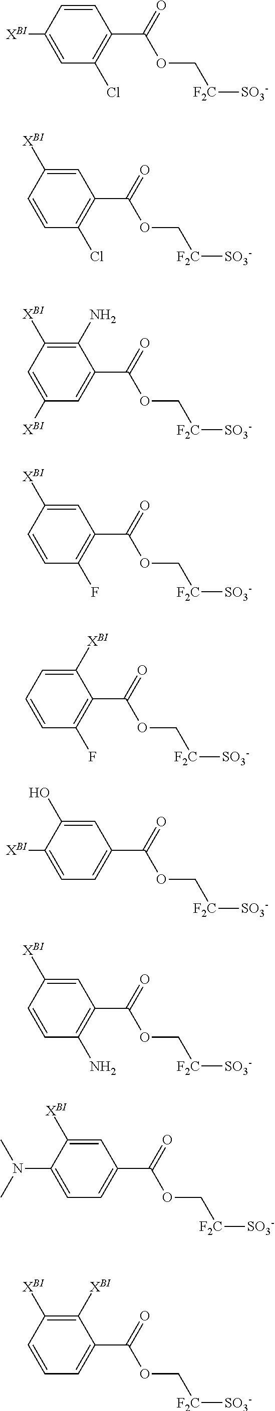

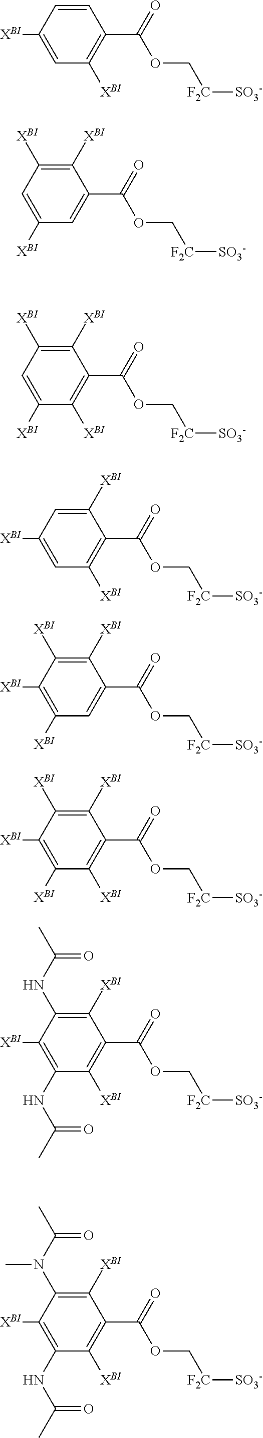

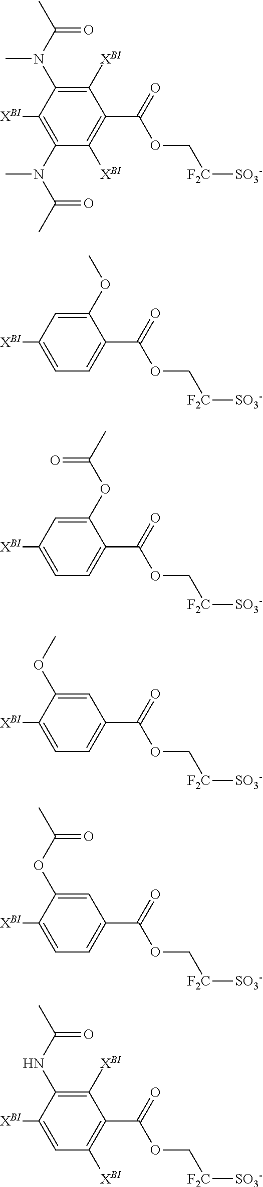

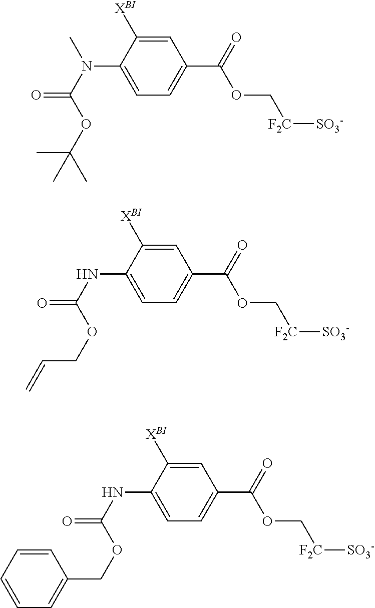

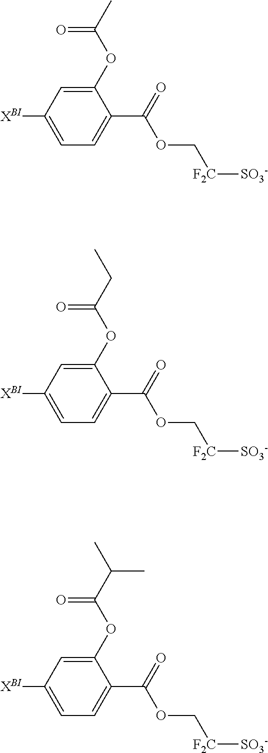

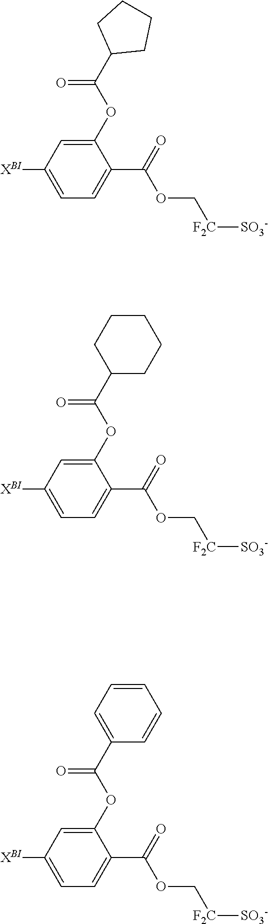

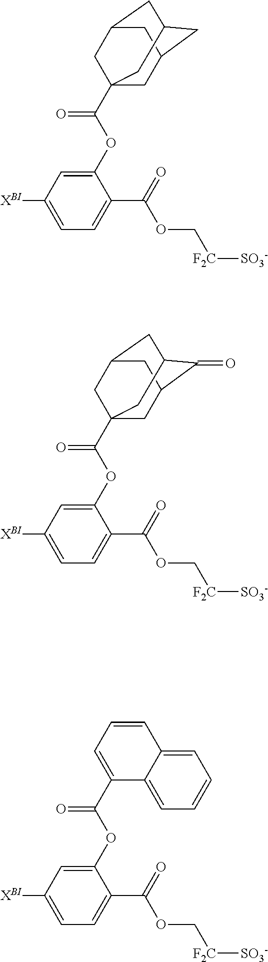

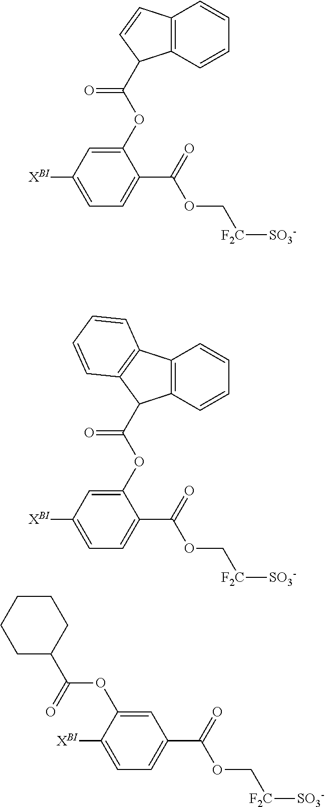

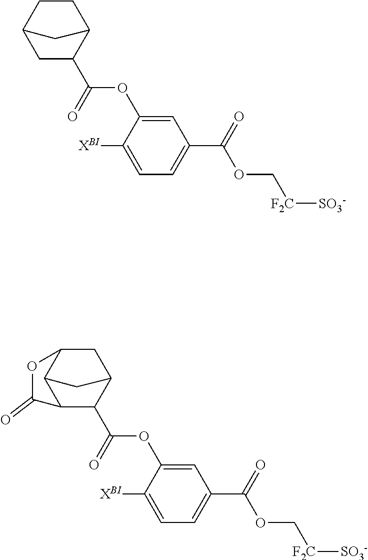

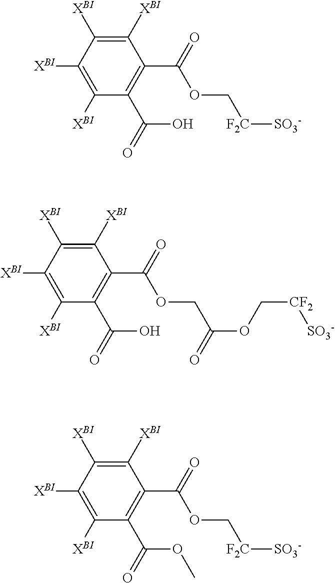

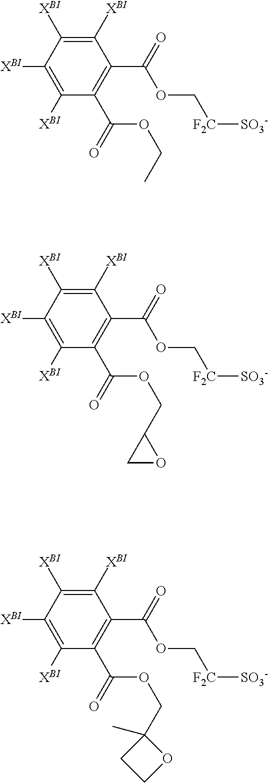

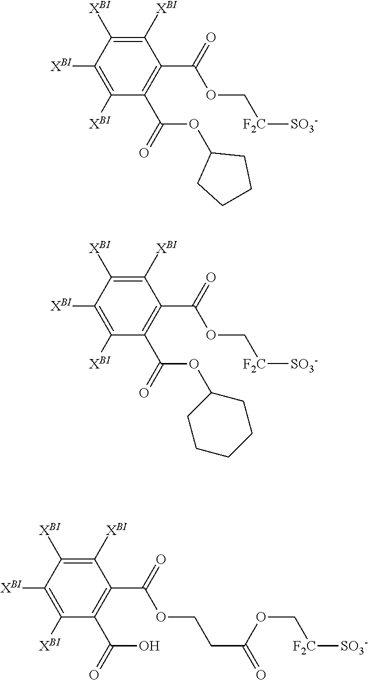

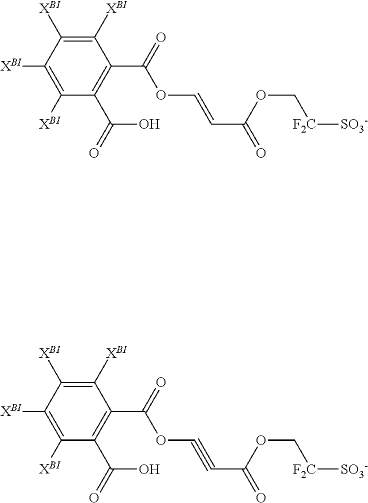

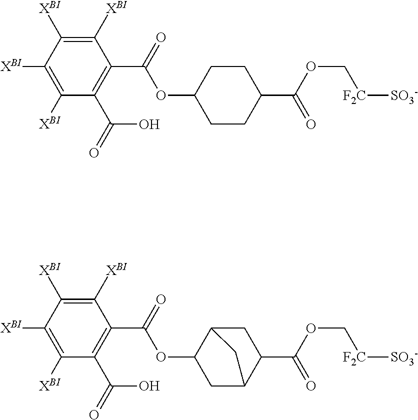

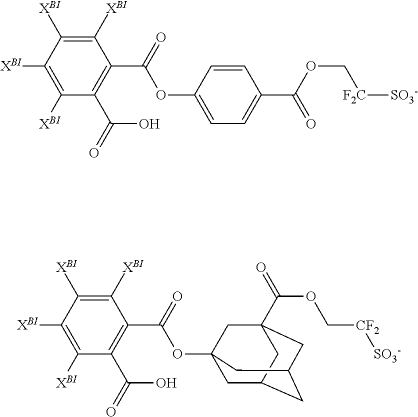

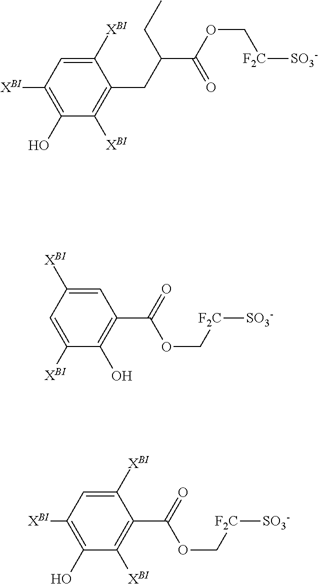

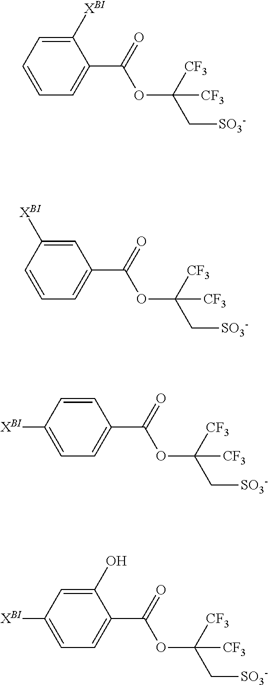

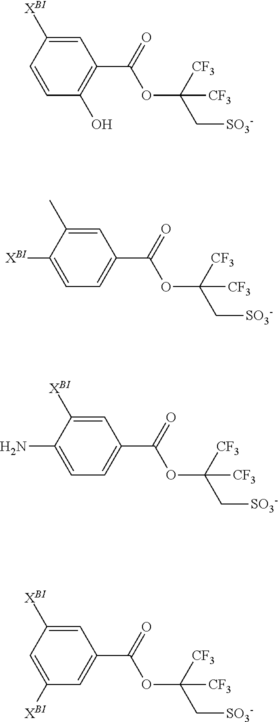

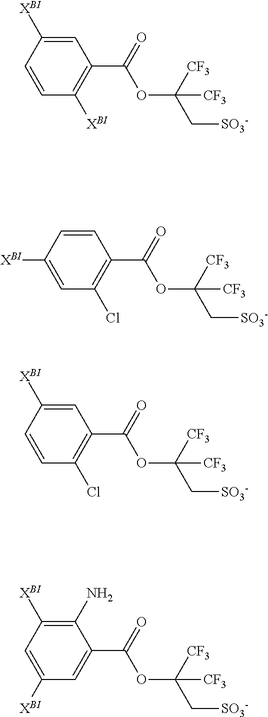

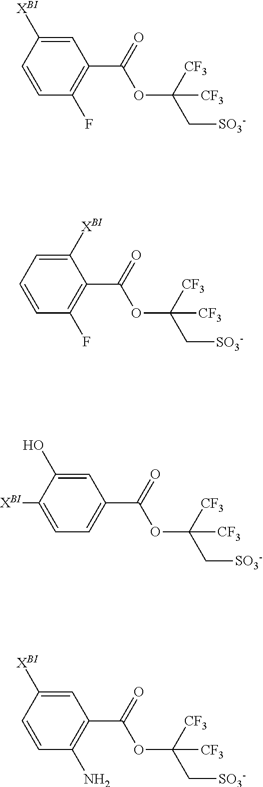

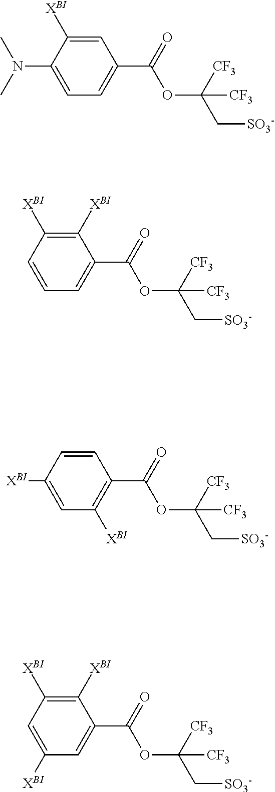

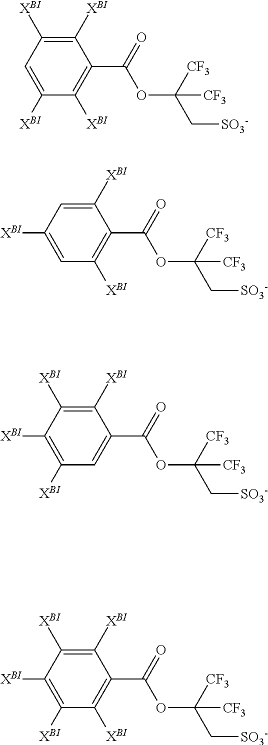

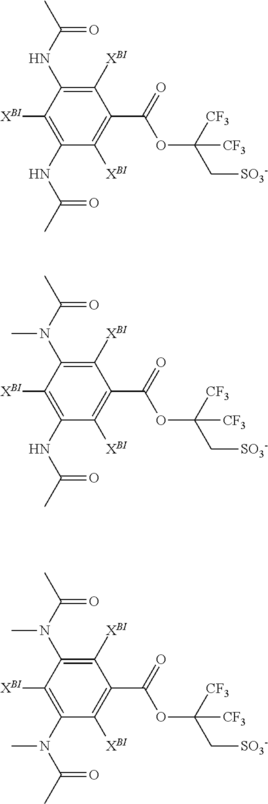

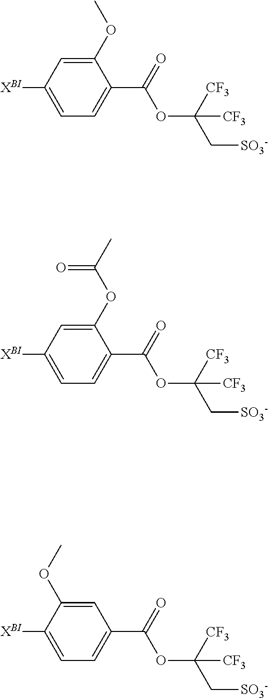

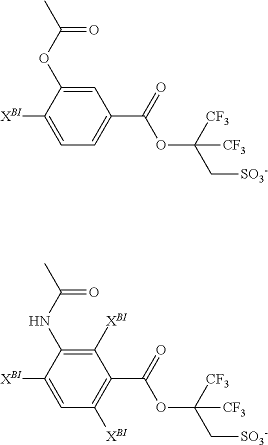

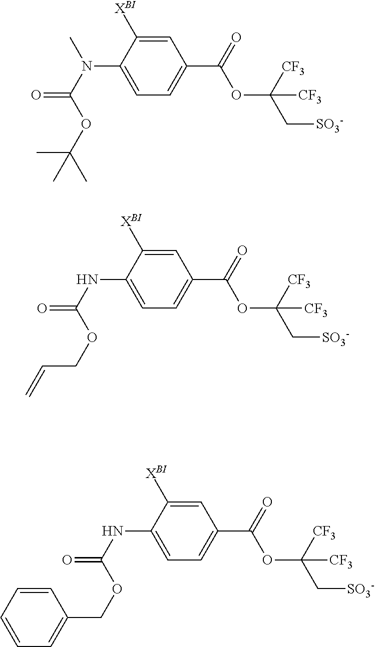

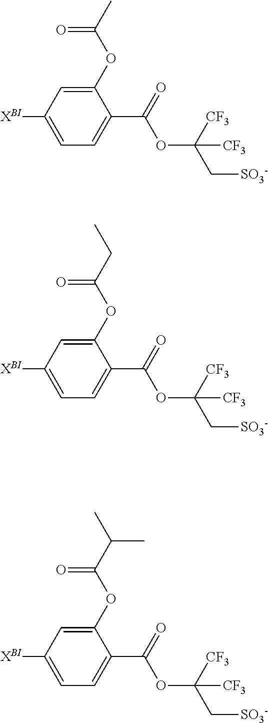

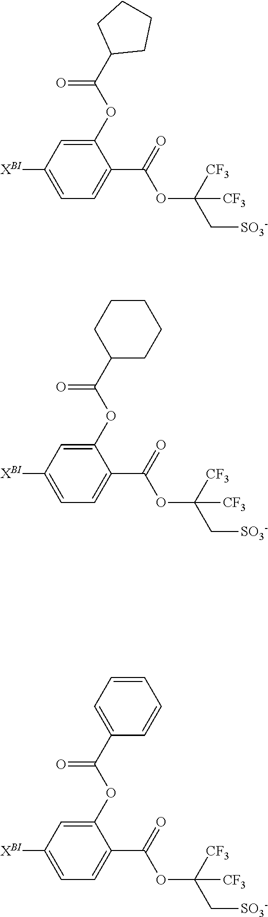

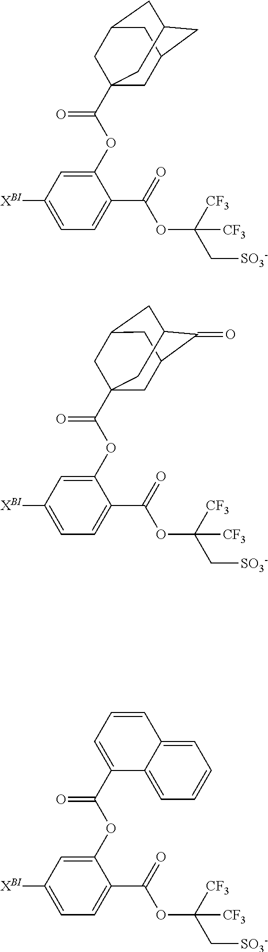

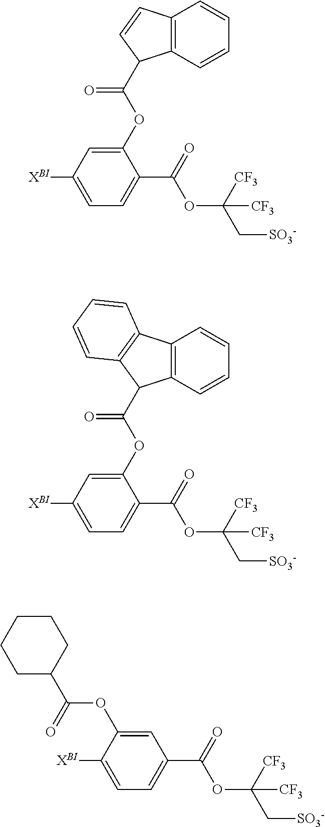

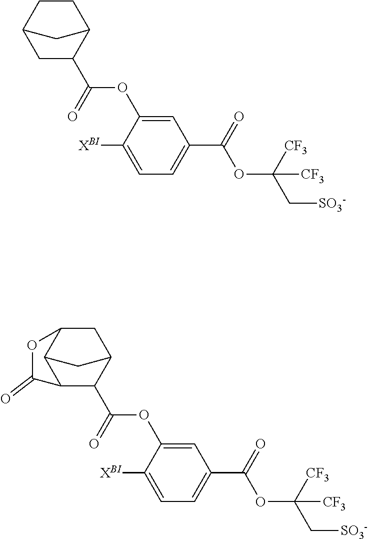

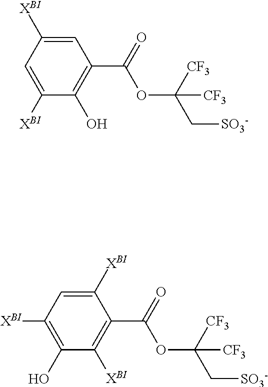

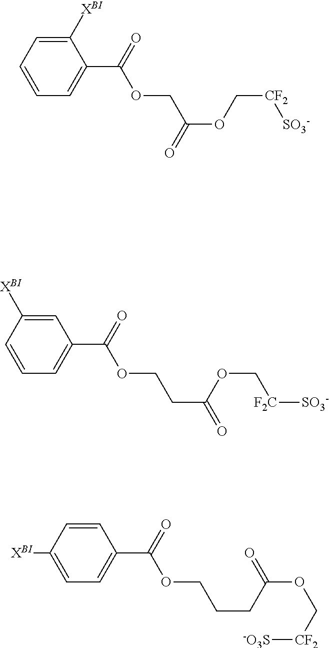

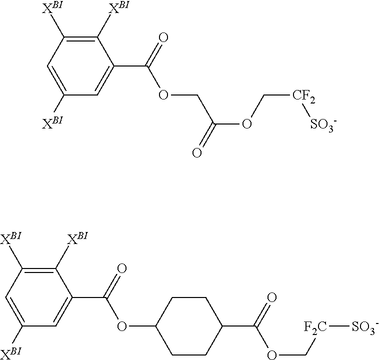

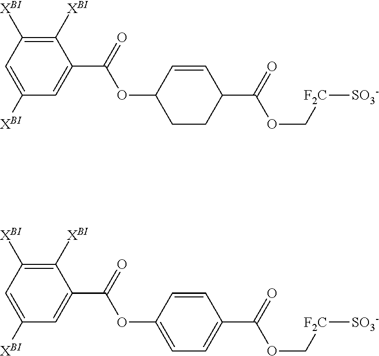

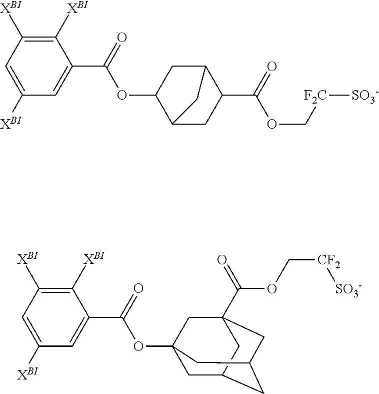

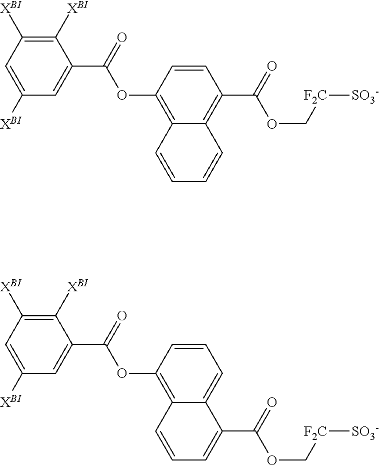

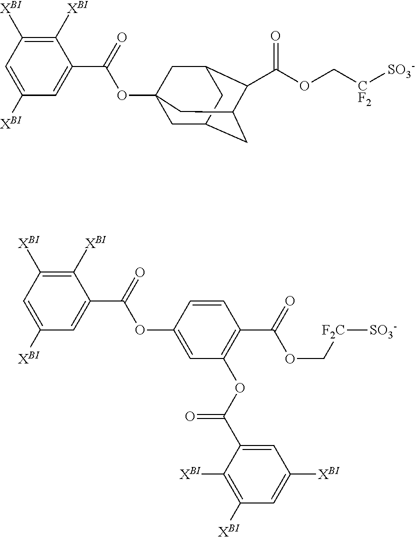

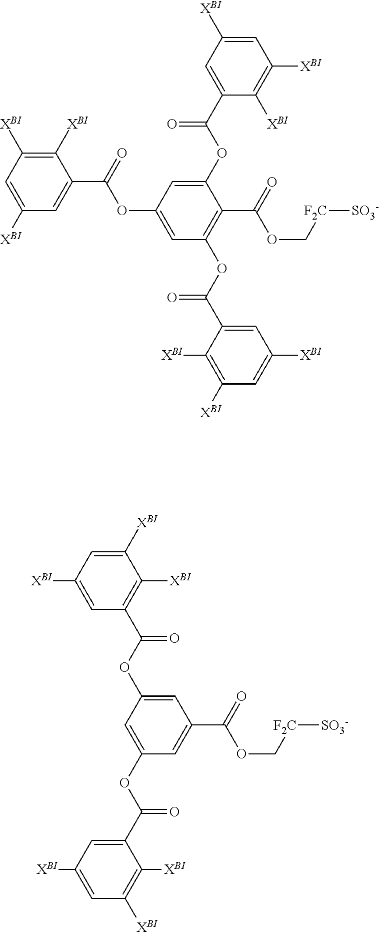

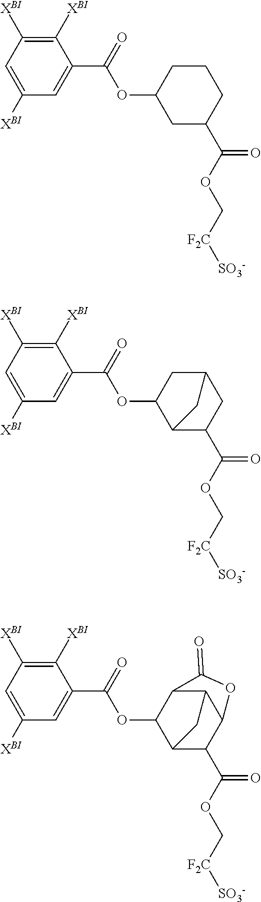

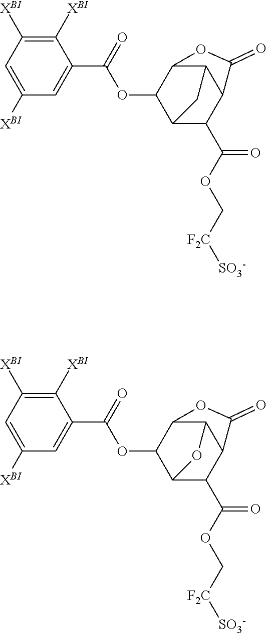

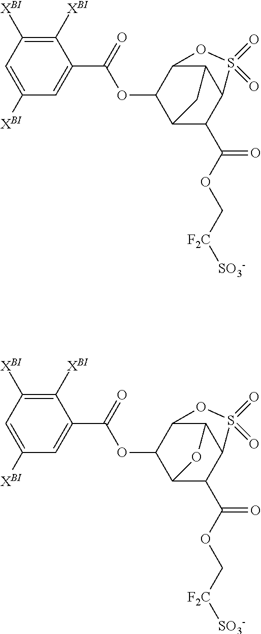

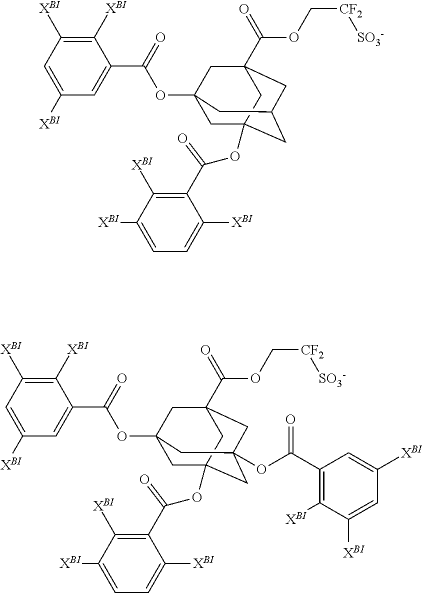

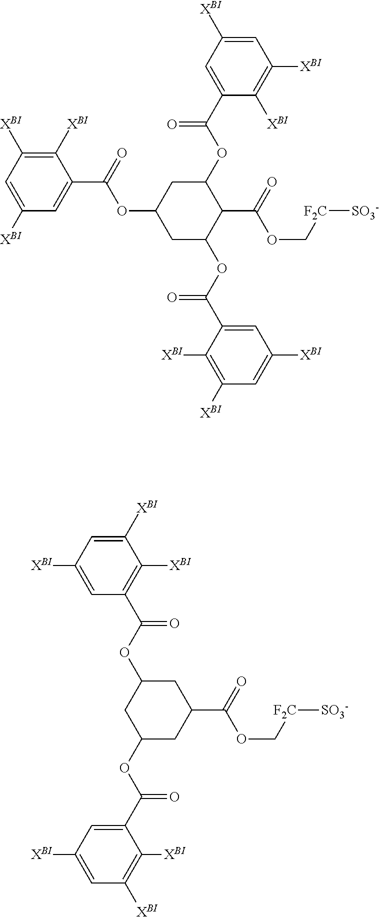

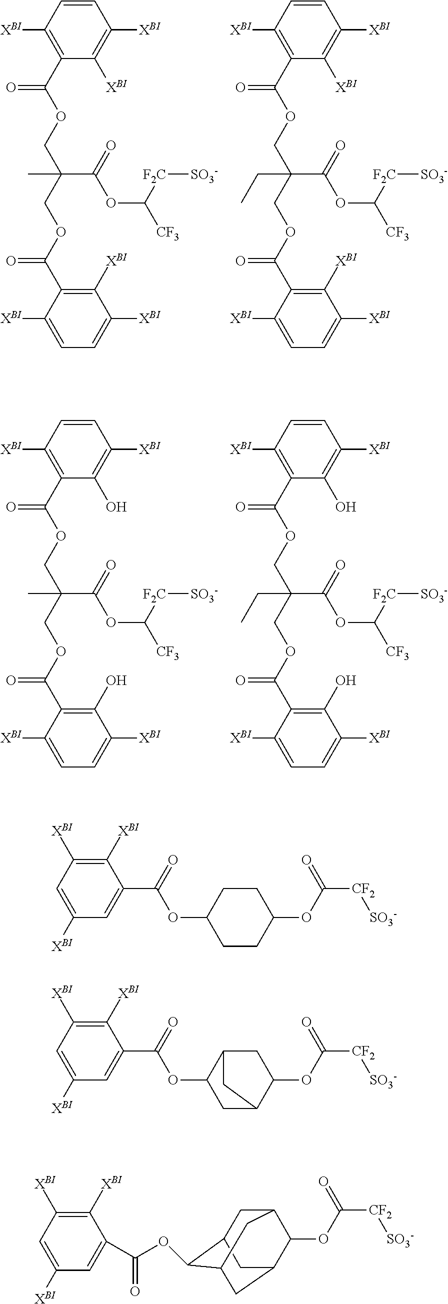

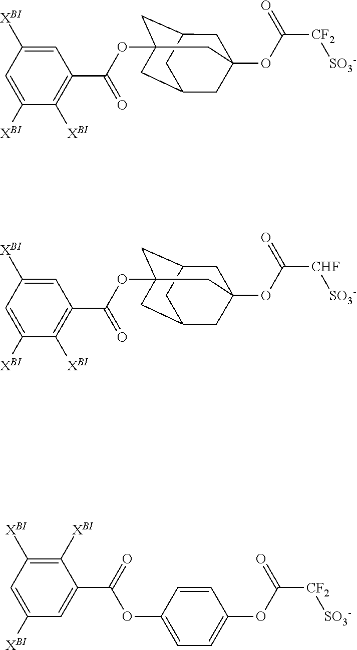

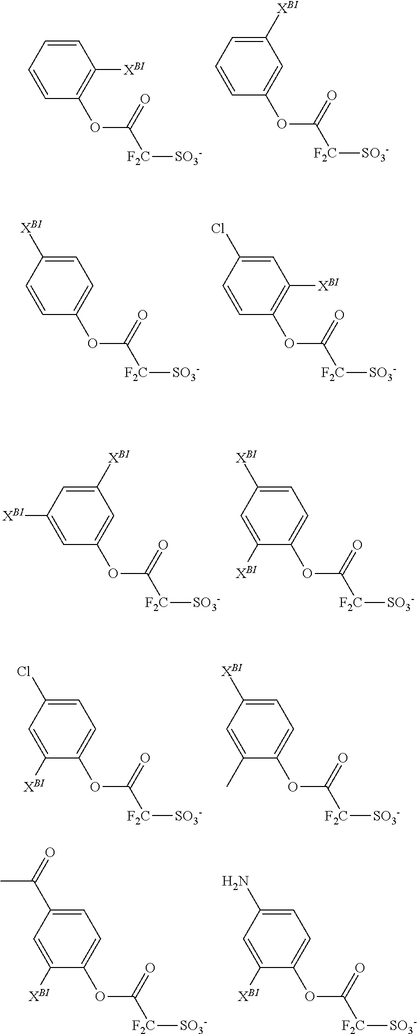

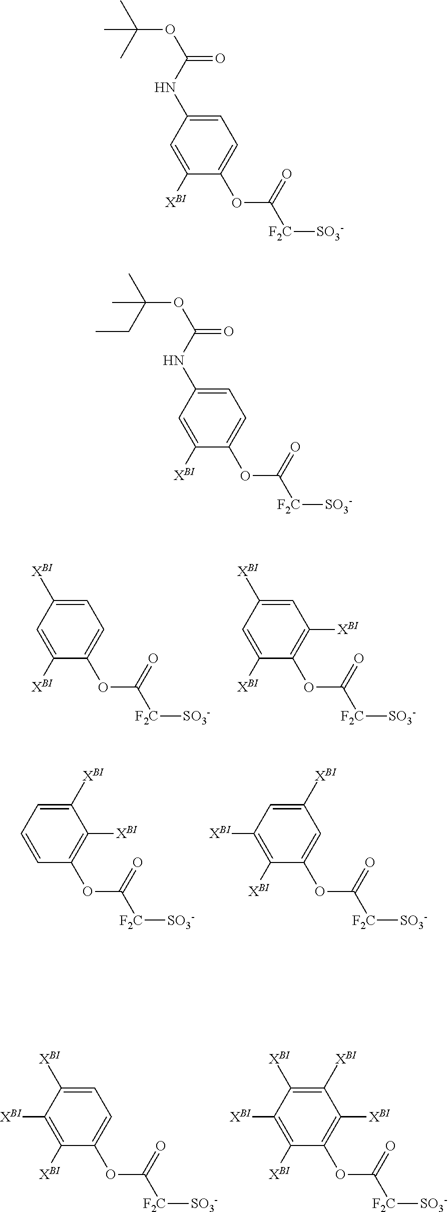

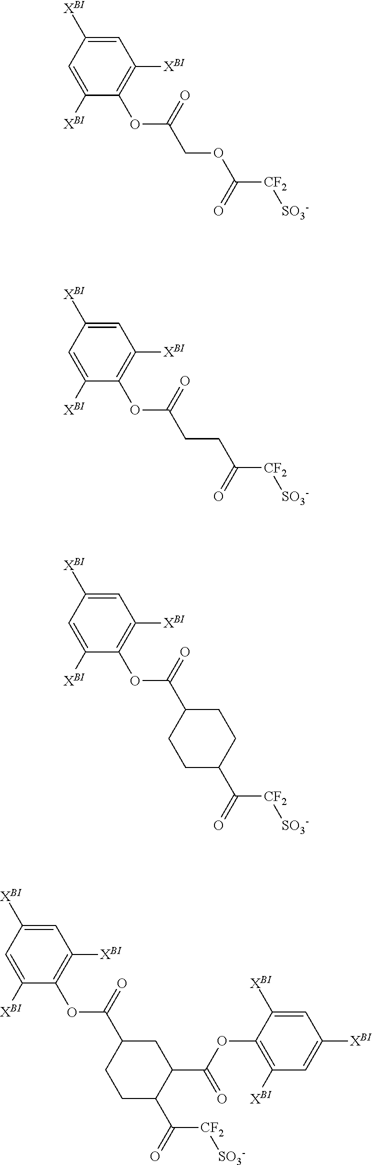

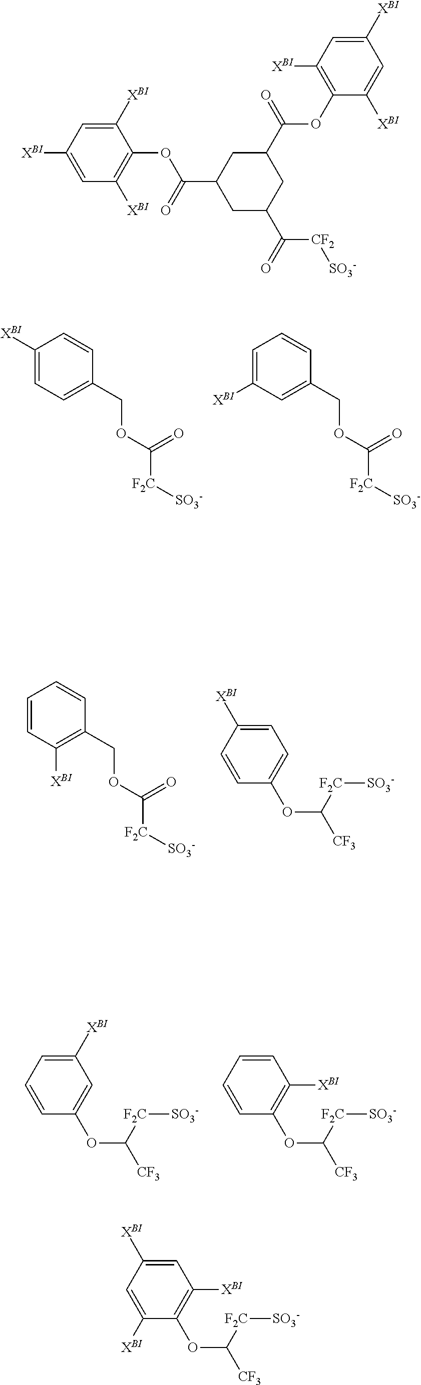

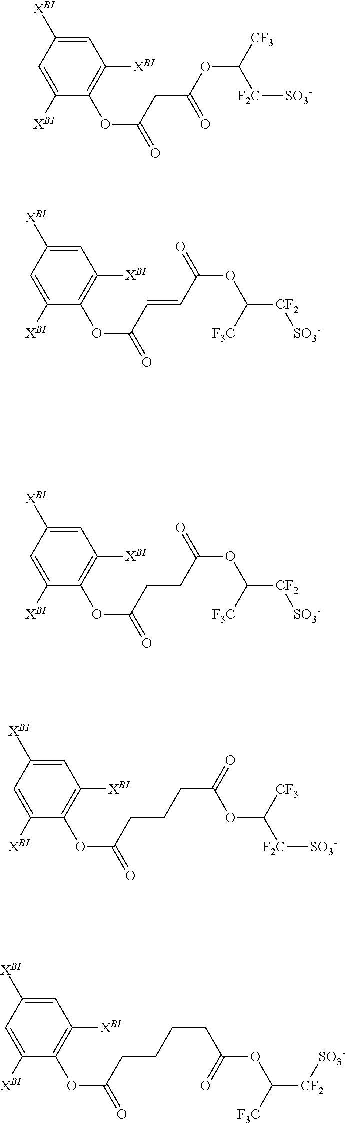

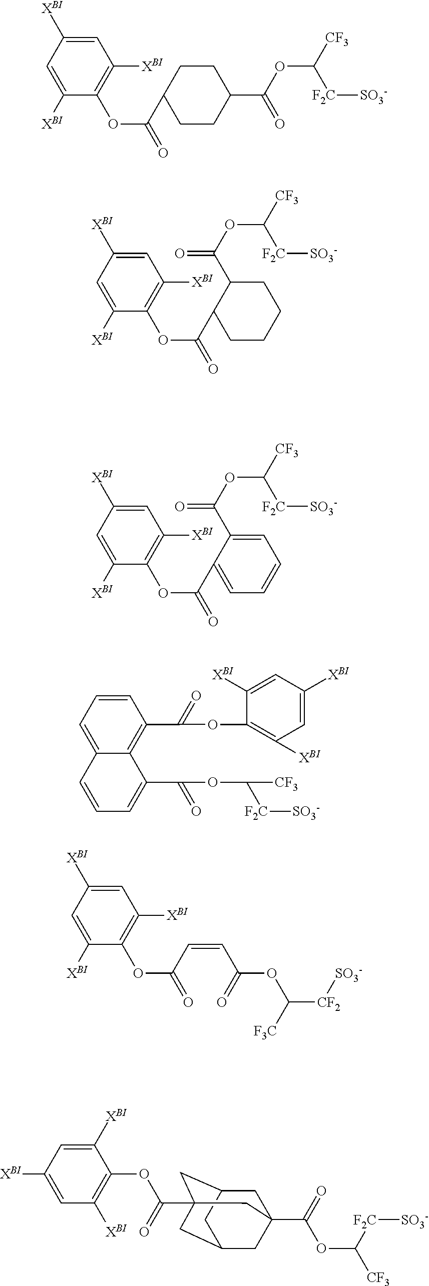

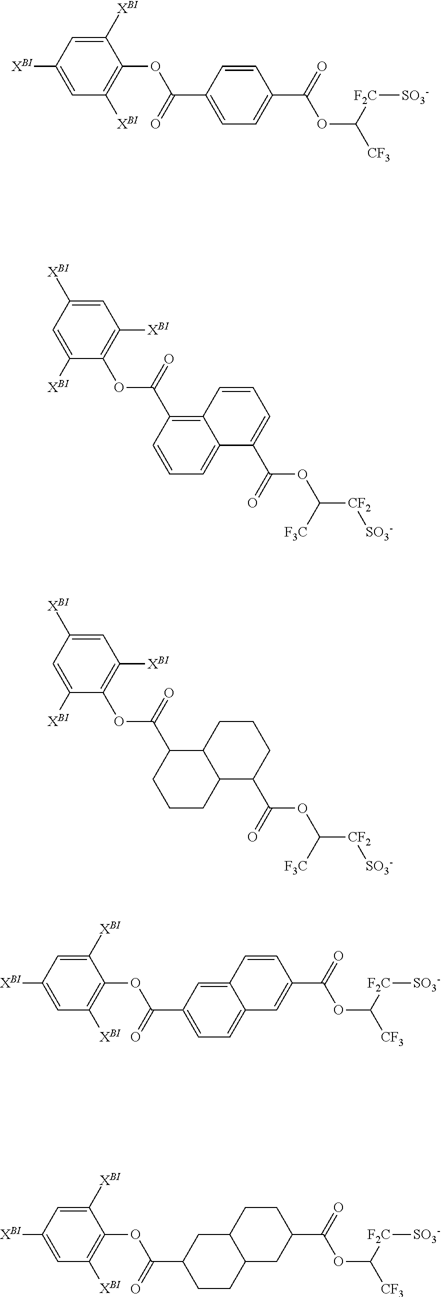

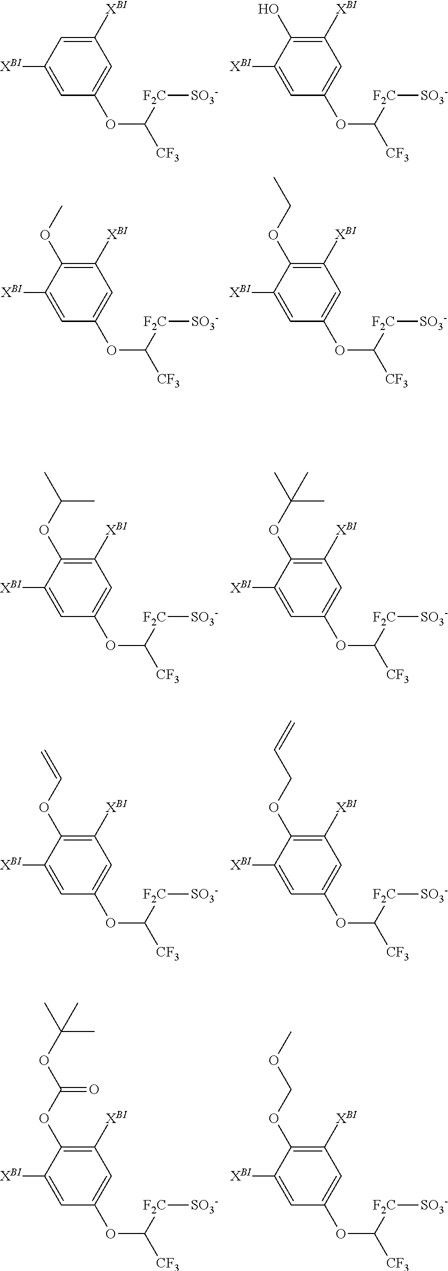

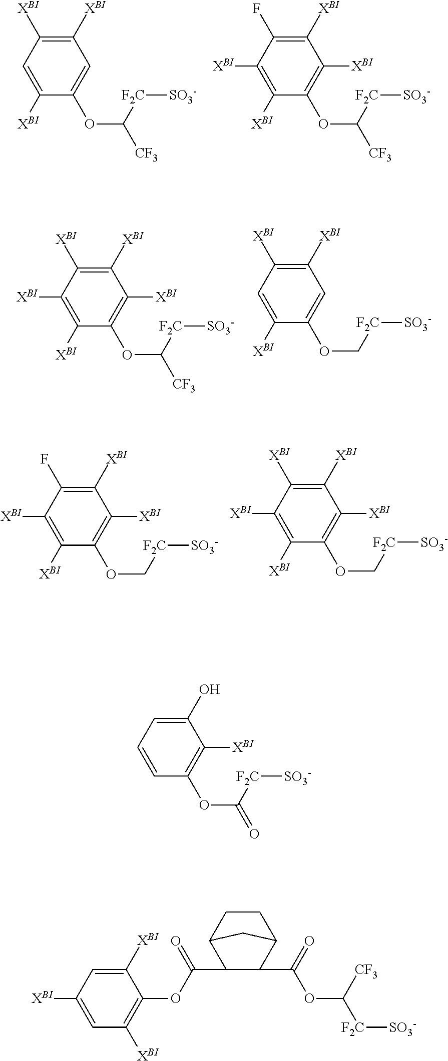

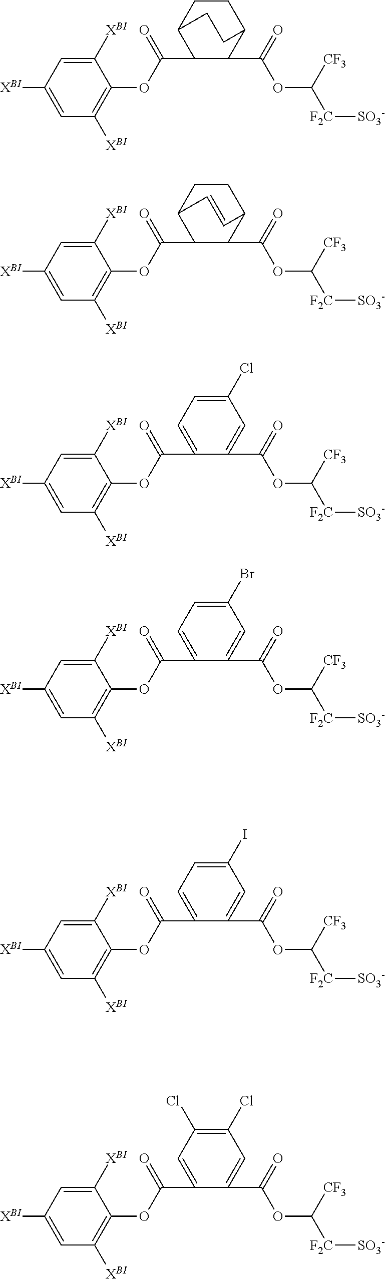

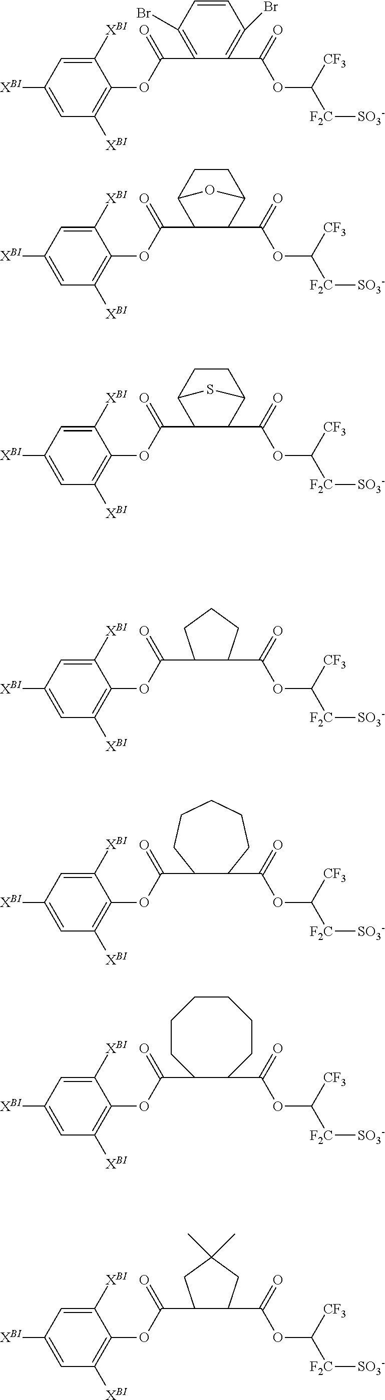

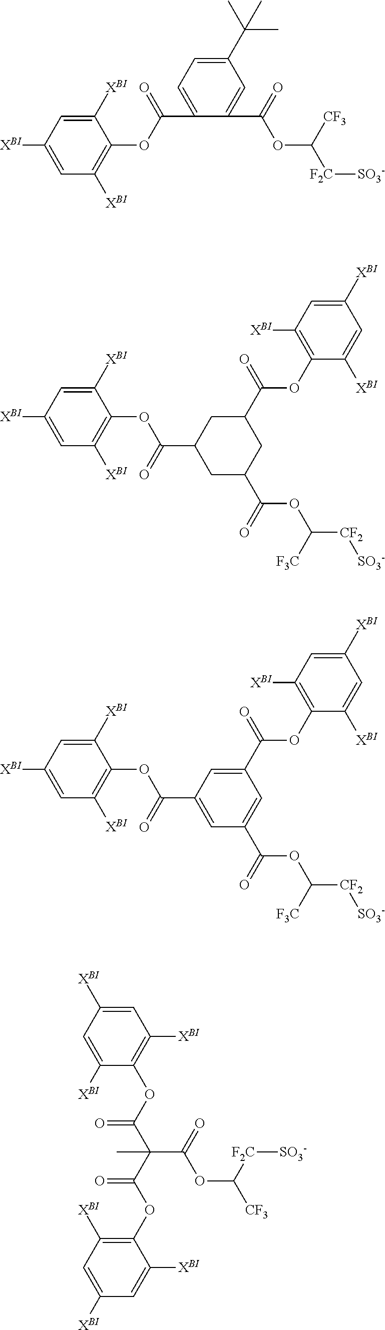

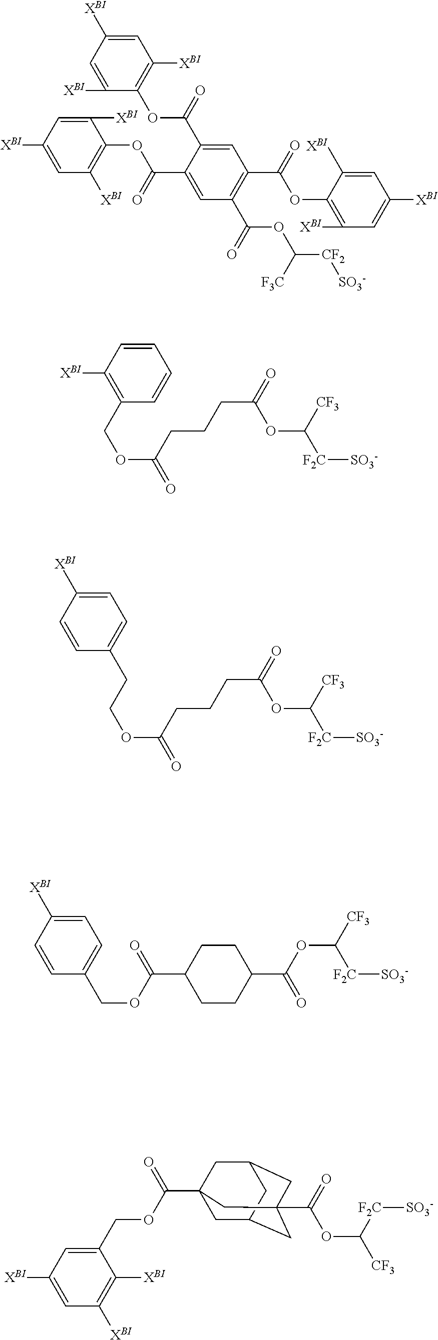

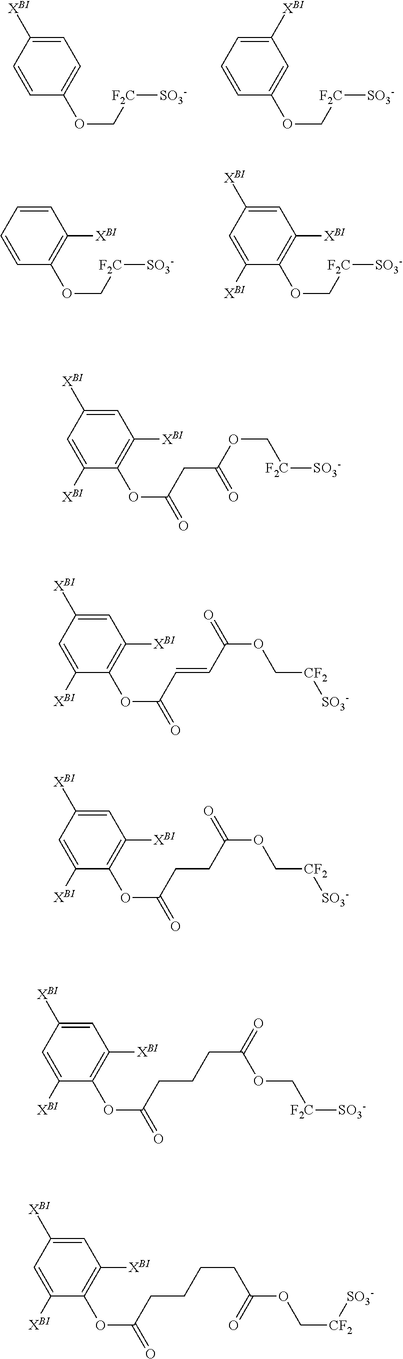

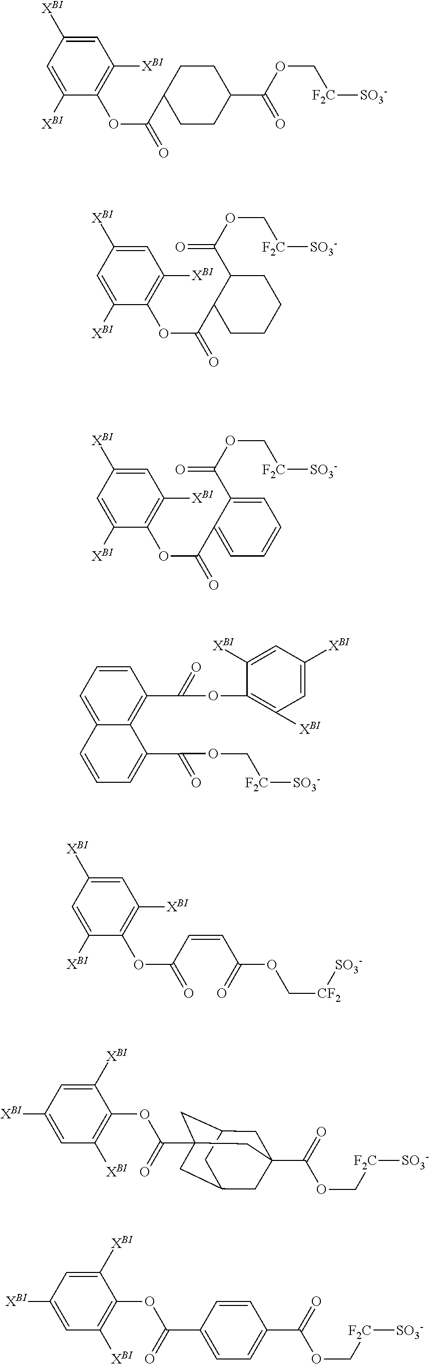

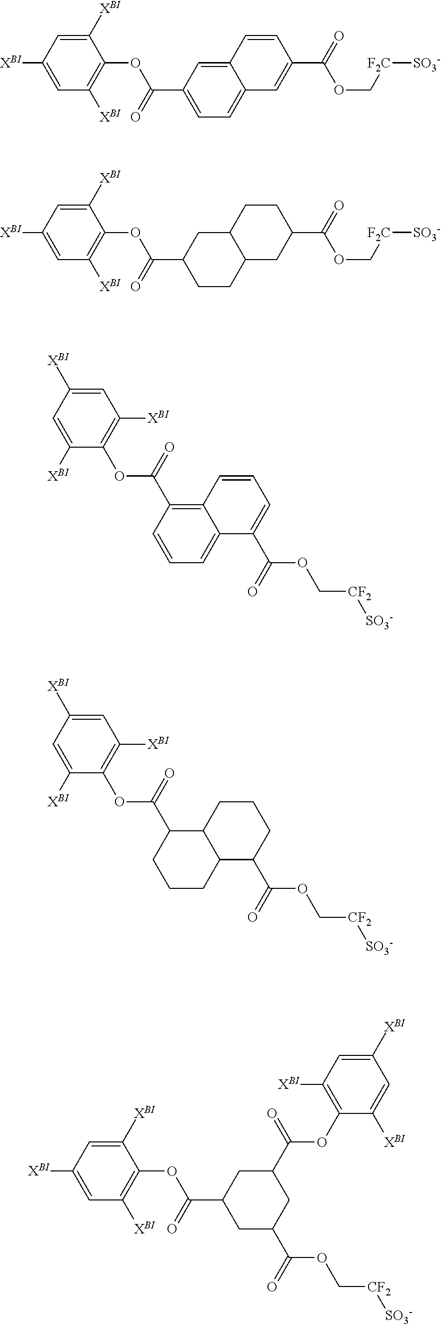

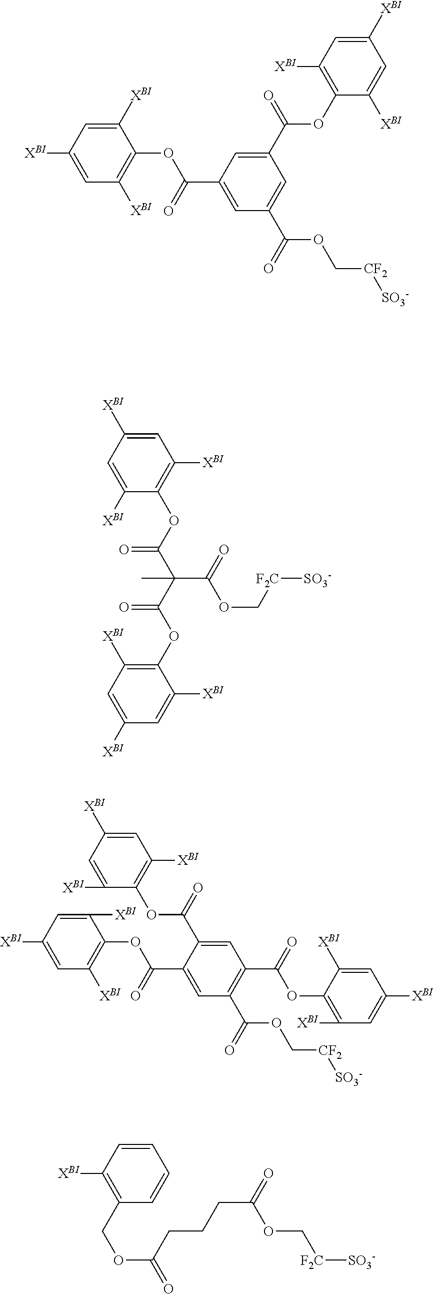

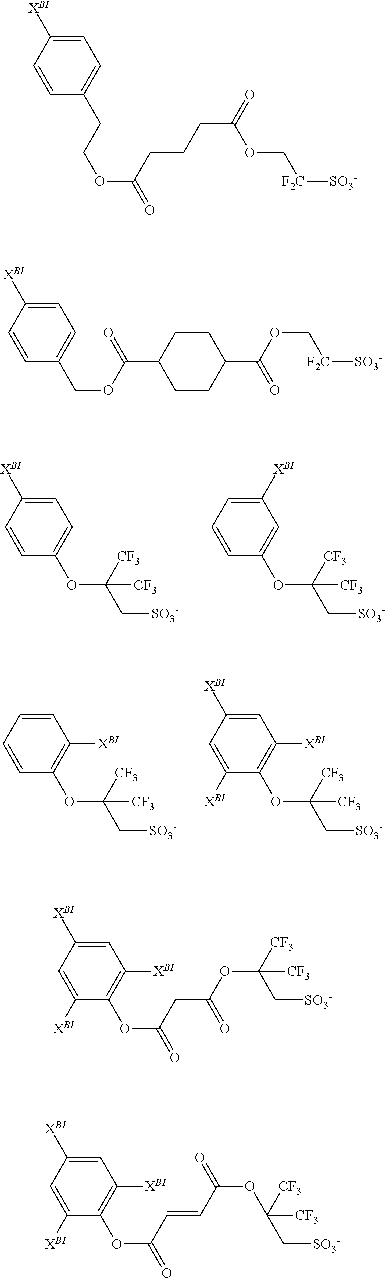

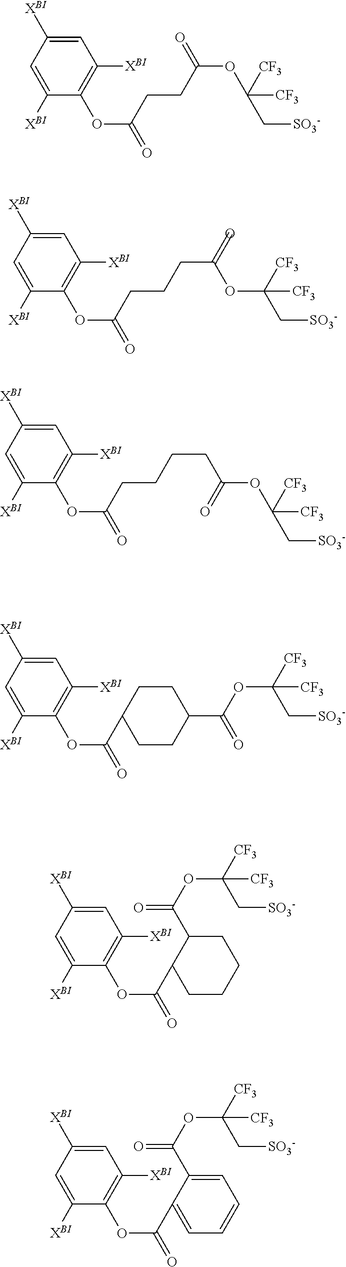

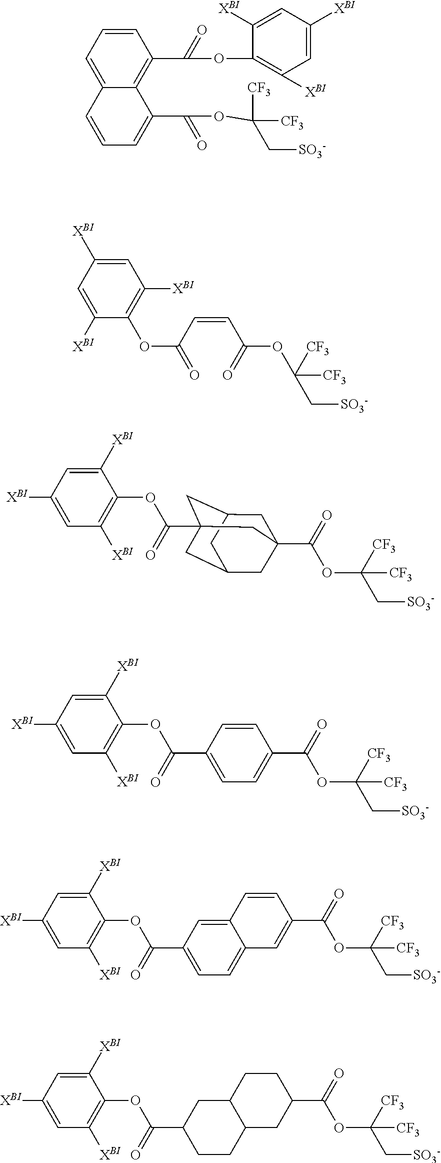

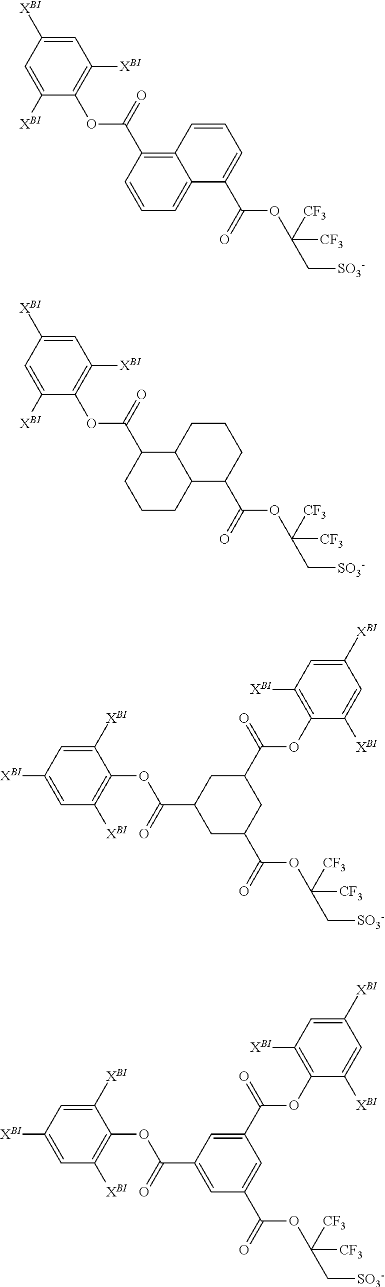

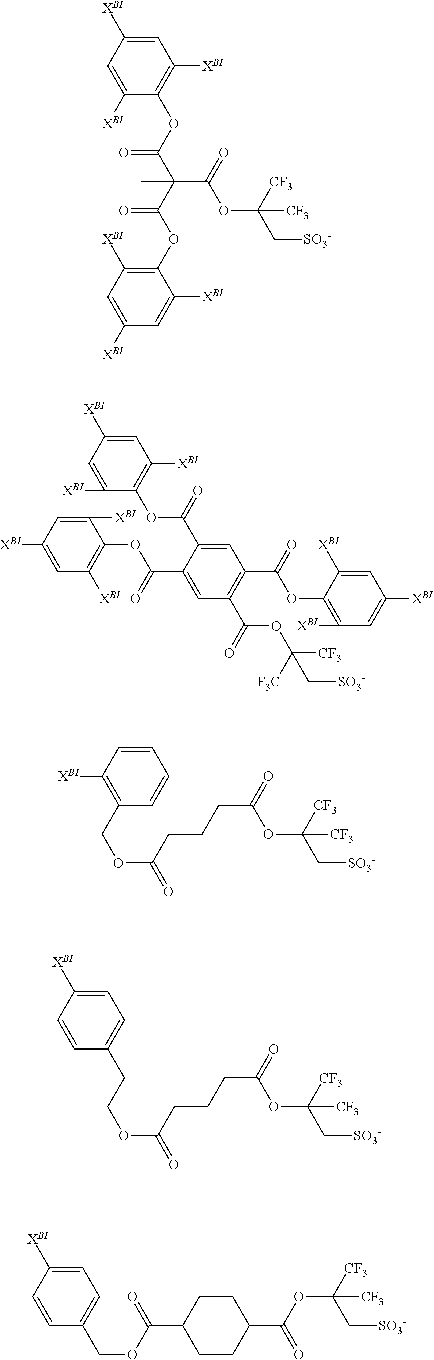

### Organic Solvent

In the resist material of the present invention, an organic solvent may be blended. The organic solvent is not particularly limited as long as the organic solvent can dissolve the aforementioned components and components described later. Examples of such an organic solvent include: ketones such as cyclohexanone, cyclopentanone, methyl-2-n-pentyl ketone, and 2-heptanone; alcohols such as 3-methoxybutanol, 3-methyl-3-methoxybutanol, 1-methoxy-2-propanol, 1-ethoxy-2-propanol, and diacetone alcohol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones such as γ-butyrolactone; and a mixed solvent thereof, described in paragraphs 0144 to 0145 of JP 2008-111103 A.

In the resist material of the present invention, a content of the organic solvent is preferably 100 to 10,000 parts by mass, and more preferably 200 to 8,000 parts by mass relative to 100 parts by mass of the base polymer.

### Other Components

In addition to the aforementioned components, a surfactant, a dissolution inhibitor, etc. may be appropriately blended in combination according to the purposes to prepare the resist composition.

Examples of the surfactant include surfactants described in paragraphs 0165 to 0166 of JP 2008-111103 A. Adding the surfactant can furthermore improve or control coatability of the resist material. The surfactant may be used singly or in combination of two or more thereof. In the resist material of the present invention, a content of the surfactant is preferably 0.0001 to 10 parts by mass relative to 100 parts by mass of the base polymer.

Blending the dissolution inhibitor can furthermore increase a difference in a dissolution rate between the exposed portion and the unexposed portion to furthermore improve resolution.

Examples of the dissolution inhibitor include a compound having a molecular weight of preferably 100 to 1,000, more preferably 150 to 800, and in which, in a compound having two or more phenolic hydroxy groups in a molecule, a hydrogen atom of the phenolic hydroxy group is substituted with an acid-labile group at a proportion of 0 to 100 mol % in the entirety or in which, in a compound having a carboxy group in a molecule, a hydrogen atom of the carboxy group is substituted with an acid-labile group at a proportion of 50 to 100 mol % in average in the entirety. Specific examples thereof include compounds in which a hydrogen atom of a hydroxy group or a carboxy group of bisphenol A, trisphenol, phenolphthalein, cresol novolac, naphthalenecarboxylic acid, adamantanecarboxylic acid, or cholic acid is substituted with an acid-labile group. The examples are described in paragraphs 0155 to 0178 in JP 2008-122932 A.

A content of the dissolution inhibitor is preferably 0 to 50 parts by mass, and more preferably 5 to 40 parts by mass relative to 100 parts by mass of the base polymer. The dissolution inhibitor may be used singly or in combination of two or more thereof.

In the resist composition of the present invention, a water-repellency improver to improve water repellency on the resist surface after spin-coating may be blended. The water-repellency improver may be used for immersion lithography without a top coat. The water-repellency improver is preferably a polymer compound having a fluorinated alkyl group, a polymer compound having a specific structure 1,1,1,3,3,3-hexafluoro-2-propanol residual group, etc., and more preferably compounds exemplified in JP 2007-297590 A, JP 2008-111103 A, etc. The water-repellency improver needs to be dissolved in an organic solvent developer. The aforementioned water-repellency improver having the specific 1,1,1,3,3,3-hexafluoro-2-propanol residual group has good solubility in the developer. As the water-repellency improver, a polymer compound having an amino group or a repeating unit having an amine salt has a high effect of preventing evaporation of the acid during post exposure baking (PEB) to prevent aperture failure of a hole pattern after development. The water-repellency improver may be used singly or in combination of two or more thereof. A content of the water-repellency improver in the resist material of the present invention is preferably 0 to 20 parts by mass, and more preferably 0.5 to 10 parts by mass relative to 100 parts by mass of the base polymer.

In the resist composition of the present invention, acetylene alcohols may also be blended. Examples of the acetylene alcohols include compounds described in paragraphs 0179 to 0182 of JP 2008-122932 A. In the resist material of the present invention, a content of the acetylene alcohols is preferably 0 to 5 parts by mass relative to 100 parts by mass of the base polymer.

### Patterning Process

When the resist composition of the present invention is used for each integrated circuit production, known lithographic technology can be applied.

For example, the resist material of the present invention is applied on a substrate for integrated circuit production (such as Si, SiO₂, SiN, SiON, TiN, WSi, BPSG, SOG, and an organic anti-reflective film) or a substrate for mask circuit production (such as Cr, CrO, CrON, MoSi₂, and SiO₂) by an appropriate coating method such as spin-coating, roll-coating, flow-coating, dip-coating, spray-coating, and doctor-coating so that the coating film thickness is 0.01 to 2 μm. This film is prebaked on a hotplate at preferably 60 to 150° C. for 10 seconds to 30 minutes, more preferably at 80 to 120° C. for 30 seconds to 20 minutes to form a resist film.

Then, the resist film is exposed by using high-energy ray. Examples of the high-energy ray include ultraviolet ray, far ultraviolet ray, EB, EUV, X-ray, soft X-ray, excimer laser, γ-ray, and synchrotron radiation. When ultraviolet ray, far ultraviolet ray, EUV, X-ray, soft X-ray, excimer laser, γ-ray, synchrotron radiation, etc. is used as the high-energy ray, irradiation is performed by using a mask for forming a target pattern so that an exposure dose is preferably about 1 to 200 mJ/cm², and more preferably about 10 to 100 mJ/cm². When EB is used as the high-energy ray, writing is performed directly or by using a mask for forming a target pattern at an exposure dose of preferably about 0.1 to 100 μC/cm², and more preferably about 0.5 to 50 μC/cm². The resist material of the present invention is particularly suitable for fine pattering with, among the high-energy ray, i-line, KrF excimer laser, ArF excimer laser, EB, EUV, X-ray, soft X-ray, γ-ray, or synchrotron radiation, and particularly suitable for fine patterning with EB or EUV.

After the exposure, PEB may be performed on a hotplate at preferably 50 to 150° C. for 10 seconds to 30 minutes, and more preferably 60 to 130° C. for 30 seconds to 20 minutes.

After the exposure or the PEB, the exposed resist film is developed by a common method such as a dip method, a puddle method, and a spray method for 3 seconds to 3 minutes, preferably 5 seconds to 2 minutes, to form a positive-type target pattern. In the common method, used are a developer of a 0.1 to 10 mass %, preferably 2 to 5 mass % alkaline aqueous solution such as tetramethylammonium hydroxide (TMAH), tetraethylammonium hydroxide (TEAH), tetrapropylammonium hydroxide (TPAH), and tetrabutylammonium hydroxide (TBAH). By the development, the light-irradiated portion is dissolved in the developer and the unexposed portion is not dissolved to form the target positive-type pattern on the substrate.

By using the positive-type resist material containing the base polymer having the acid-labile group, negative development to obtain a negative-type pattern can be performed with organic solvent development. Examples of the developer used in this case include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate. These organic solvents can be used singly or used with mixing two or more thereof.

When the development is finished, rinsing is performed. The rinsing liquid is preferably a solvent that mixes with the developer and that does not dissolve the resist film. Preferably used as such a solvent are alcohols having 3 to 10 carbon atoms, ether compounds having 8 to 12 carbon atoms, alkanes, alkenes, or alkynes having 6 to 12 carbon atoms, and aromatic solvents.

Specific examples of the alcohols having 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol.

Examples of the ether compounds having 8 to 12 carbon atoms include di-n-butyl ether, diisobutyl ether, di-sec-butyl ether, di-n-pentyl ether, diisopentyl ether, di-sec-pentyl ether, di-tert-pentyl ether, and di-n-hexyl ether.

Examples of the alkanes having 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Examples of the alkenes having 6 to 12 carbon atoms include hexene, heptene, octene, cyclohexene, methylcyclohexene, dimethylcyclohexene, cycloheptene, and cyclooctene. Examples of the alkynes having 6 to 12 carbon atoms include hexyne, heptyne, and octyne.

Examples of the aromatic solvents include toluene, xylene, ethylbenzene, isopropylbenzene, tert-butylbenzene, and mesitylene.

The rinsing can reduce collapse of the resist pattern and occurrence of defects. The rinsing is not essential, and no rinsing can reduce a use amount of the solvent.

A hole pattern or a trench pattern after the development can be shrunk by thermal flow, RELACS technology, or DSA technology. A shrinking agent is applied on the hole pattern, and during baking, an acid catalyst is diffused from the resist film to cause crosslinking of the shrinking agent on the resist film surface, and the shrinking agent adheres to the side wall of the hole pattern. The baking temperature is preferably 70 to 180° C., and more preferably 80 to 170° C. The time is preferably 10 to 300 seconds. The extra shrinking agent is removed to shrink the hole pattern.

### EXAMPLE

Hereinafter, the present invention will be specifically described with showing Examples and Comparative Examples, but the present invention is not limited to the following Examples.

### 1: Synthesis of Polymer

PAG monomers 1 to 8 to yield the repeating unit represented by the formula (a1) and acid-labile group monomers (ALG monomers) 1 to 4 to yield the repeating unit represented by the formula (a2), used for synthesizing polymers, are as follows. Mw of the polymer is a measured value in terms of polystyrene by GPC using THF as a solvent.

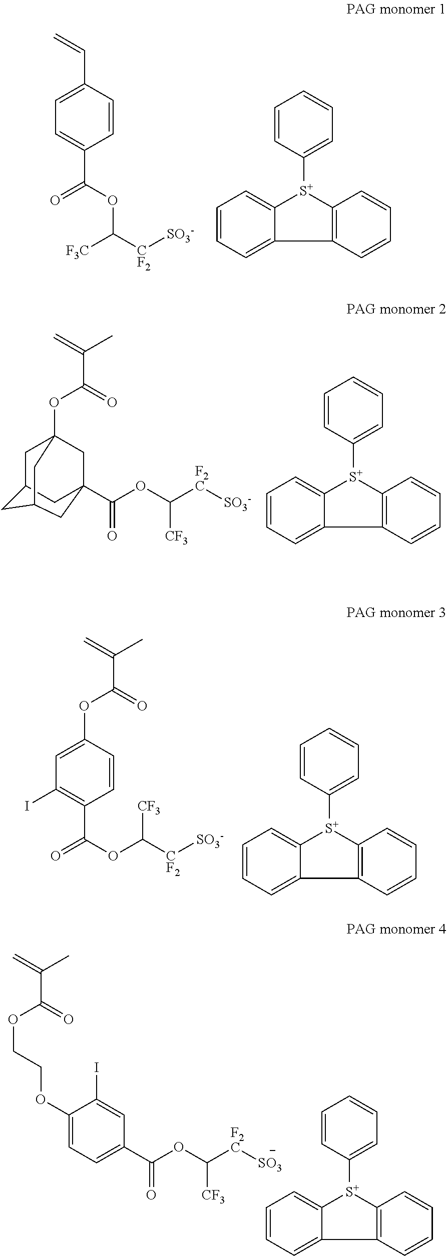

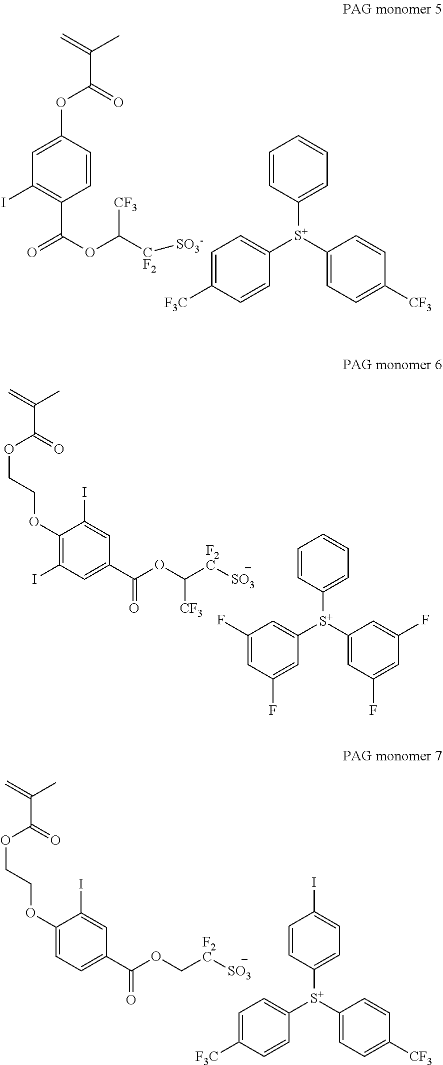

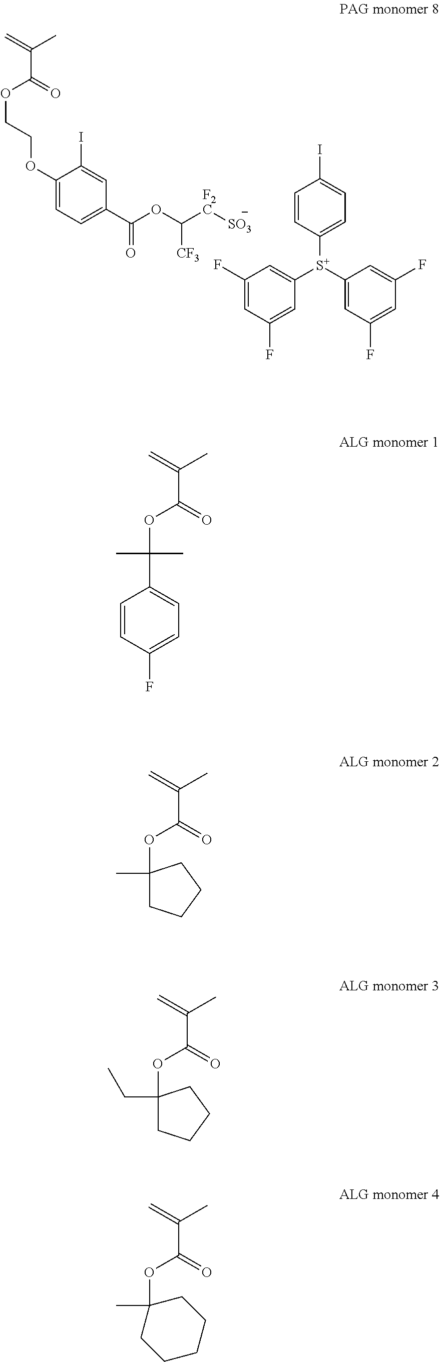

### Synthesis Example 1-1: Synthesis of Polymer 1

Into a 2-L flask, 6.0 g of the PAG monomer 1, 7.9 g of the ALG monomer 4, 5.2 g of 4-hydroxystyrene, which was a monomer to yield a structure corresponding to the repeating unit “d”, and 40 g of THF as a solvent were added. This reaction vessel was cooled to −70° C. under a nitrogen atmosphere, and degassing under a reduced pressure and nitrogen blowing were repeated three times. The temperature was raised to room temperature, 1.2 g of AIBN as a polymerization initiator was then added, the temperature was raised to 60° C., and the reaction was performed for 15 hours. This reaction solution was added into 1 L of isopropyl alcohol, and a precipitated white solid was filtered. The obtained white solid was dried at 60° C. under a reduced pressure to obtain a polymer 1. Composition of the polymer 1 was determined by ¹³C-NMR and ¹H-NMR, and Mw and Mw/Mn of the polymer 1 were determined by GPC.

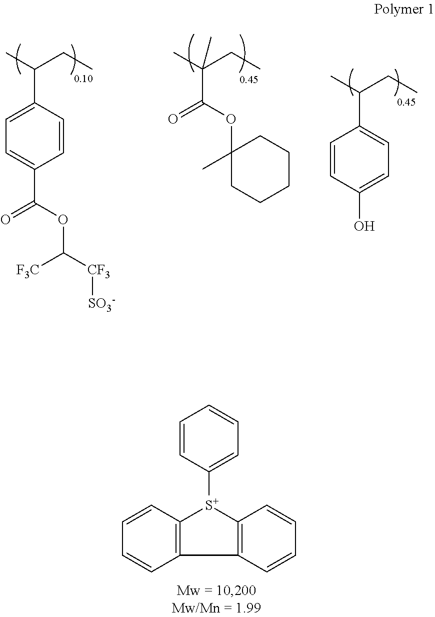

### Synthesis Example 1-2: Synthesis of Polymer 2

Into a 2-L flask, 7.1 g of the PAG monomer 2, 7.3 g of the ALG monomer 2, 5.2 g of 3-hydroxystyrene, which was a monomer to yield a structure corresponding to the repeating unit “d”, and 40 g of THF as a solvent were added. This reaction vessel was cooled to −70° C. under a nitrogen atmosphere, and degassing under a reduced pressure and nitrogen blowing were repeated three times. The temperature was raised to room temperature, 1.2 g of AIBN as a polymerization initiator was then added, the temperature was raised to 60° C., and the reaction was performed for 15 hours. This reaction solution was added into 1 L of isopropyl alcohol, and a precipitated white solid was filtered. The obtained white solid was dried at 60° C. under a reduced pressure to obtain a polymer 2. Composition of the polymer 2 was determined by ¹³C-NMR and ¹H-NMR, and Mw and Mw/Mn of the polymer 2 were determined by GPC.

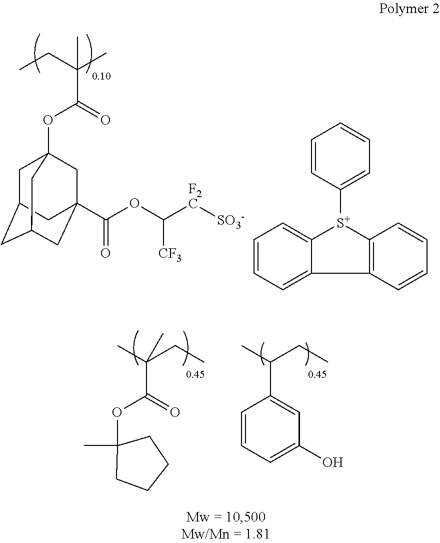

### Synthesis Example 1-3: Synthesis of Polymer 3

Into a 2-L flask, 7.8 g of the PAG monomer 3, 7.9 g of the ALG monomer 3, 5.8 g of 4-hydroxy-3-methylstyrene, which was a monomer to yield a structure corresponding to the repeating unit “d”, and 40 g of THF as a solvent were added. This reaction vessel was cooled to −70° C. under a nitrogen atmosphere, and degassing under a reduced pressure and nitrogen blowing were repeated three times. The temperature was raised to room temperature, 1.2 g of AIBN as a polymerization initiator was then added, the temperature was raised to 60° C., and the reaction was performed for 15 hours. This reaction solution was added into 1 L of isopropyl alcohol, and a precipitated white solid was filtered. The obtained white solid was dried at 60° C. under a reduced pressure to obtain a polymer 3. Composition of the polymer 3 was determined by ¹³C-NMR and ¹H-NMR, and Mw and Mw/Mn of the polymer 3 were determined by GPC.

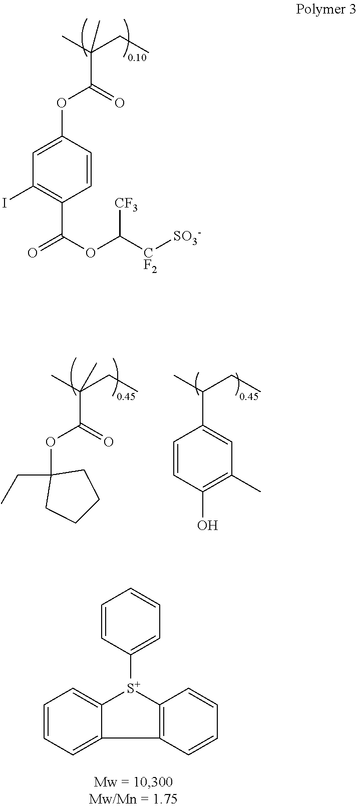

### Synthesis Example 1-4: Synthesis of Polymer 4

Into a 2-L flask, 9.8 g of the PAG monomer 4, 8.1 g of the ALG monomer 2, 4.4 g of 3-hydroxystyrene, which was a monomer to yield a structure corresponding to the repeating unit “d”, and 40 g of THF as a solvent were added. This reaction vessel was cooled to −70° C. under a nitrogen atmosphere, and degassing under a reduced pressure and nitrogen blowing were repeated three times. The temperature was raised to room temperature, 1.2 g of AIBN as a polymerization initiator was then added, the temperature was raised to 60° C., and the reaction was performed for 15 hours. This reaction solution was added into 1 L of isopropyl alcohol, and a precipitated white solid was filtered. The obtained white solid was dried at 60° C. under a reduced pressure to obtain a polymer 4. Composition of the polymer 4 was determined by ¹³C-NMR and ¹H-NMR, and Mw and Mw/Mn of the polymer 4 were determined by GPC.

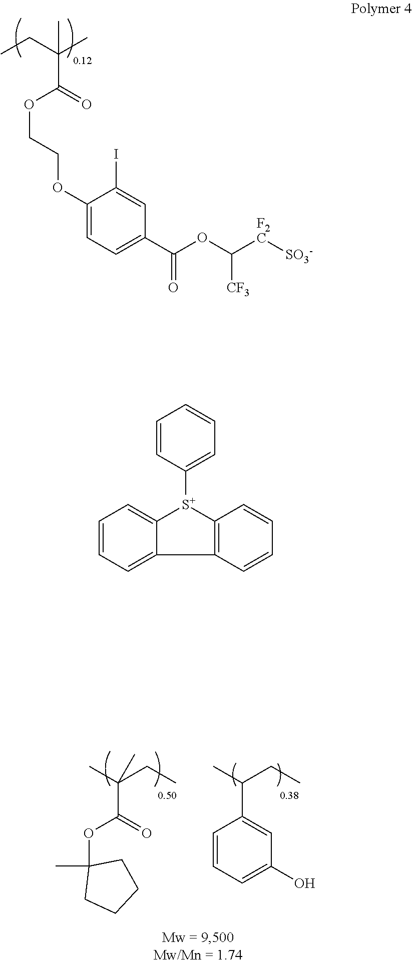

### Synthesis Example 1-5: Synthesis of Polymer 5

Into a 2-L flask, 9.1 g of the PAG monomer 5, 8.1 g of the ALG monomer 2, 5.2 g of 4-hydroxy-3-methylstyrene, which was a monomer to yield a structure corresponding to the repeating unit “d”, and 40 g of THF as a solvent were added. This reaction vessel was cooled to −70° C. under a nitrogen atmosphere, and degassing under a reduced pressure and nitrogen blowing were repeated three times. The temperature was raised to room temperature, 1.2 g of AIBN as a polymerization initiator was then added, the temperature was raised to 60° C., and the reaction was performed for 15 hours. This reaction solution was added into 1 L of isopropyl alcohol, and a precipitated white solid was filtered. The obtained white solid was dried at 60° C. under a reduced pressure to obtain a polymer 5. Composition of the polymer 5 was determined by ¹³C-NMR and ¹H-NMR, and Mw and Mw/Mn of the polymer 5 were determined by GPC.

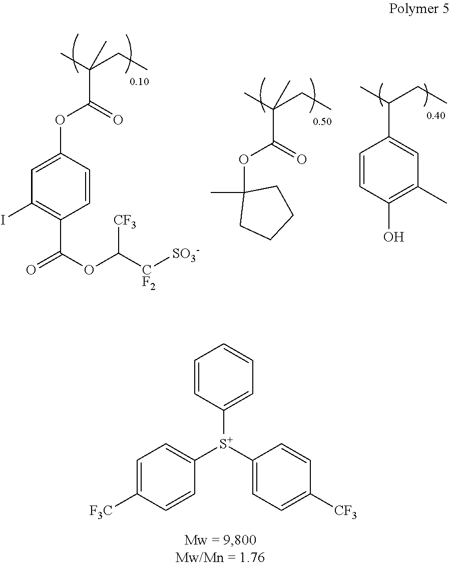

### Synthesis Example 1-6: Synthesis of Polymer 6

Into a 2-L flask, 12.2 g of the PAG monomer 6, 10.7 g of the ALG monomer 1, 4.4 g of 3-hydroxystyrene, which was a monomer to yield a structure corresponding to the repeating unit “d”, and 40 g of THF as a solvent were added. This reaction vessel was cooled to −70° C. under a nitrogen atmosphere, and degassing under a reduced pressure and nitrogen blowing were repeated three times. The temperature was raised to room temperature, 1.2 g of AIBN as a polymerization initiator was then added, the temperature was raised to 60° C., and the reaction was performed for 15 hours. This reaction solution was added into 1 L of isopropyl alcohol, and a precipitated white solid was filtered. The obtained white solid was dried at 60° C. under a reduced pressure to obtain a polymer 6. Composition of the polymer 6 was determined by ¹³C-NMR and ¹H-NMR, and Mw and Mw/Mn of the polymer 6 were determined by GPC.

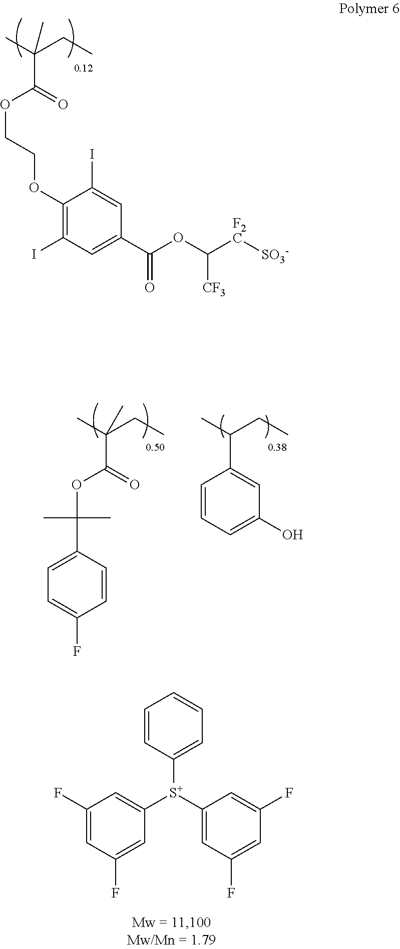

### Synthesis Example 1-7: Synthesis of Polymer 7

Into a 2-L flask, 12.1 g of the PAG monomer 7, 8.1 g of the ALG monomer 2, 4.4 g of 3-hydroxystyrene, which was a monomer to yield a structure corresponding to the repeating unit “d”, and 40 g of THF as a solvent were added. This reaction vessel was cooled to −70° C. under a nitrogen atmosphere, and degassing under a reduced pressure and nitrogen blowing were repeated three times. The temperature was raised to room temperature, 1.2 g of AIBN as a polymerization initiator was then added, the temperature was raised to 60° C., and the reaction was performed for 15 hours. This reaction solution was added into 1 L of isopropyl alcohol, and a precipitated white solid was filtered. The obtained white solid was dried at 60° C. under a reduced pressure to obtain a polymer 7. Composition of the polymer 7 was determined by ¹³C-NMR and ¹H-NMR, and Mw and Mw/Mn of the polymer 7 were determined by GPC.

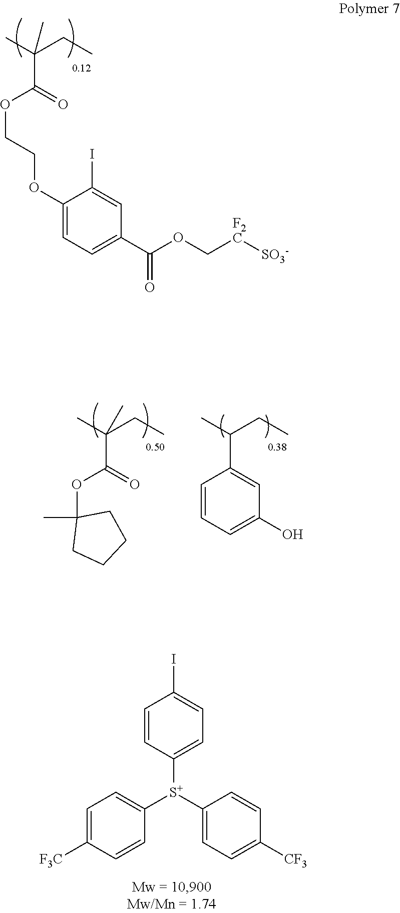

### Synthesis Example 1-8: Synthesis of Polymer 8

Into a 2-L flask, 12.2 g of the PAG monomer 8, 8.1 g of the ALG monomer 2, 4.4 g of 3-hydroxystyrene, which was a monomer to yield a structure corresponding to the repeating unit “d”, and 40 g of THF as a solvent were added. This reaction vessel was cooled to −70° C. under a nitrogen atmosphere, and degassing under a reduced pressure and nitrogen blowing were repeated three times. The temperature was raised to room temperature, 1.2 g of AIBN as a polymerization initiator was then added, the temperature was raised to 60° C., and the reaction was performed for 15 hours. This reaction solution was added into 1 L of isopropyl alcohol, and a precipitated white solid was filtered. The obtained white solid was dried at 60° C. under a reduced pressure to obtain a polymer 8. Composition of the polymer 8 was determined by ¹³C-NMR and ¹H-NMR, and Mw and Mw/Mn of the polymer 8 were determined by GPC.

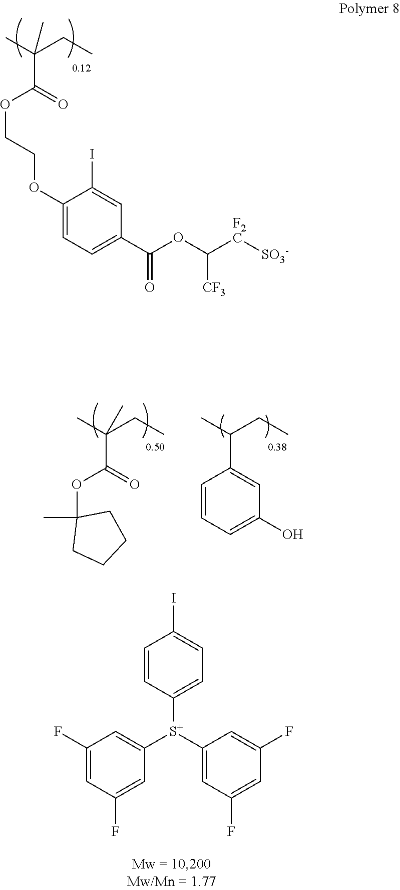

### Synthesis Example 1-9: Synthesis of Comparative Polymer 1

A comparative polymer 1 was obtained by the same manner as in Synthesis Example 1-2 except that the PAG monomer 2 was not used. Composition of the comparative polymer 1 was determined by ¹³C-NMR and ¹H-NMR, and Mw and Mw/Mn of the comparative polymer 1 were determined by GPC.

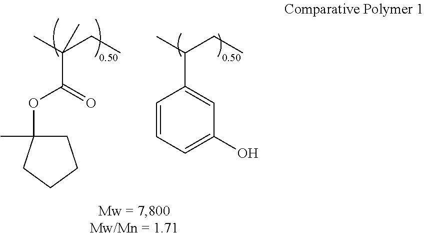

### Examples 1 to 46 and Comparative Examples 1 to 26

The components were dissolved at composition shown in Tables 1 to 5 into a solution in which a surfactant Polyfox636, available from OMNOVA Solutions Inc., was dissolved as a surfactant at 50 ppm, and this solution was filtered through a 0.2-μm filter to prepare a positive-type resist material.

In Tables 1 to 5, the components are as follows.
Organic Solvent:
   PGMEA (propylene glycol monomethyl ether acetate)
   DAA (diacetone alcohol)
   EL (ethyl lactate)
Quencher: Q-1 to 12
PAG: PAG-1

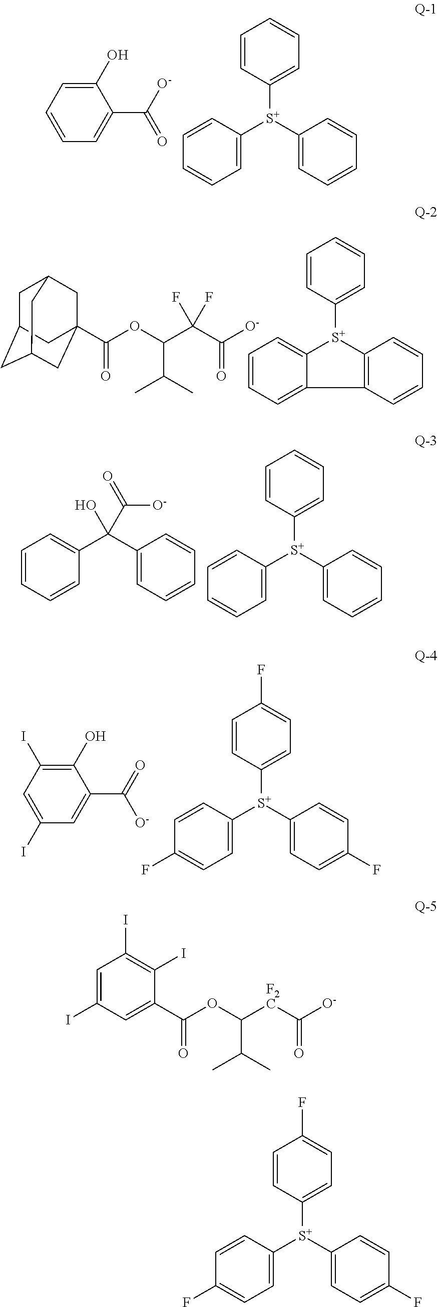

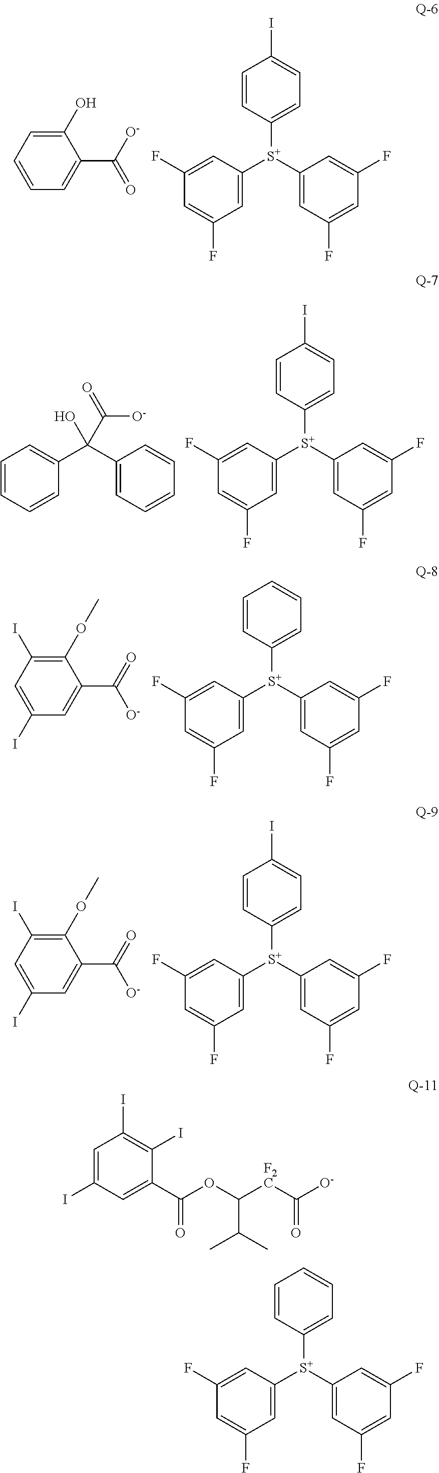

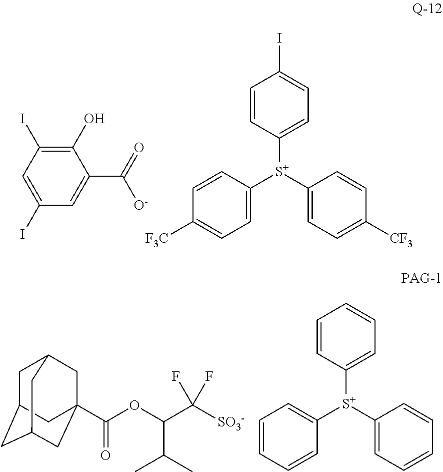

### EUV Exposure Evaluation

Each of the resist materials shown in Table 1 to Table 5 was applied on a Si substrate by spin-coating on which a silicon-containing spin-on hard mask SHB-A940 (silicon content: 43 mass %) was formed with 20 nm in film thickness, and prebaked by using a hotplate at 105° C. for 60 seconds to produce a resist film with 40 nm in film thickness. This resist film was subjected to exposure with a LS pattern having a pitch size on wafer of 36 nm by using an EUV scanner NXE34000 (NA: 0.33, σ: 0.9/0.6, dipole illumination), available from ASML Holding N.V. The resist film was subjected to PEB on a hotplate at a temperature shown in Table 1 for 60 seconds, and developed for 30 seconds with a 2.38-mass % TMAH aqueous solution to form a LS pattern with 18 nm in size. The obtained pattern was observed with a length-measurement SEM (CG6300), available from Hitachi High-Technologies Corporation, to evaluate sensitivity and LWR in accordance with the following methods.

### Sensitivity Evaluation

An optimal exposure dose Eₒₚ(mJ/cm²) at which the LS pattern with 18 nm in line width and 36 nm in pitch was obtained was determined, and specified as a sensitivity. A smaller value thereof indicates higher sensitivity.

### LWR Evaluation

Dimensions in the LS pattern obtained by irradiation at Eₒₚ were measured at 10 positions along the longitudinal direction of the line, and a tripled value (3σ) of a standard deviation (σ) from the results was determined as LWR. A smaller value thereof indicates that a pattern having smaller roughness and uniform line width can be obtained.

TABLE 1

| | | Quencher | | PEB | | | |
|---|---|---|---|---|---|---|---|
| | | (parts | Organic | temperature | Sensitivity | LWR | |
| | | by mass) | solvent | (° C.) | (mj/cm²) | (nm) | Judgement |
| Example 1 | Polymer 6 | Q1 | PGMEA (2000) | 95 | 37.4 | 2.71 | Good |
| | (80) | (8.3) | DAA (500) | | | | |
| | | | EL (2500) | | | | |
| Example 2 | Polymer 6 | Q2 | PGMEA (2000) | 95 | 37.2 | 2.71 | Good |
| | (80) | (12.2) | DAA (500) | | | | |
| | | | EL (2500) | | | | |
| Example 3 | Polymer 6 | Q3 | PGMEA (2000) | 95 | 37.0 | 2.73 | Good |
| | (80) | (10.2) | DAA (500) | | | | |
| | | | EL (2500) | | | | |
| Example 4 | Polymer 6 | Q4 | PGMEA (2000) | 95 | 36.1 | 2.62 | Good |
| | (80) | (14.6) | DAA (500) | | | | |
| | | | EL (2500) | | | | |
| Example 5 | Polymer 6 | Q5 | PGMEA (2000) | 95 | 36.1 | 2.62 | Good |
| | (80) | (20.0) | DAA (500) | | | | |
| | | | EL (2500) | | | | |
| Example 6 | Polymer 8 | Q1 | PGMEA (2000) | 95 | 36.3 | 2.62 | Good |
| | (80) | (8.3) | DAA (500) | | | | |
| | | | EL (2500) | | | | |
| Example 7 | Polymer 8 | Q2 | PGMEA (2000) | 95 | 36.1 | 2.61 | Good |
| | (80) | (12.2) | DAA (500) | | | | |
| | | | EL (2500) | | | | |
| Example 8 | Polymer 8 | Q3 | PGMEA (2000) | 95 | 36.3 | 2.62 | Good |
| | (80) | (10.2) | DAA (500) | | | | |
| | | | EL (2500) | | | | |
| Example 9 | Polymer 8 | Q4 | PGMEA (2000) | 95 | 35.6 | 2.53 | Good |
| | (80) | (14.6) | DAA (500) | | | | |
| | | | EL (2500) | | | | |
| Example 10 | Polymer 8 | Q5 | PGMEA (2000) | 95 | 35.4 | 2.51 | Good |
| | (80) | (20.0) | DAA (500) | | | | |
| | | | EL (2500) | | | | |
| Example 11 | Polymer 1 | Q10 | PGMEA (2000) | 95 | 37.2 | 2.77 | Good |
| | (80) | (20.4) | DAA (500) | | | | |
| | | | EL (2500) | | | | |
| Example 12 | Polymer 2 | Q10 | PGMEA (2000) | 95 | 37.1 | 2.72 | Good |
| | (80) | (20.4) | DAA (500) | | | | |
| | | | EL (2500) | | | | |
| Example 13 | Polymer 3 | Q10 | PGMEA (2000) | 95 | 36.6 | 2.6 | Good |
| | (80) | (20.4) | DAA (500) | | | | |
| | | | EL (2500) | | | | |
| Example 14 | Polymer 4 | Q10 | PGMEA (2000) | 95 | 36.4 | 2.62 | Good |
| | (80) | (20.4) | DAA (500) | | | | |
| | | | EL (2500) | | | | |

TABLE 2

| | Polymer | Quencher | | PEB | | | |
|---|---|---|---|---|---|---|---|
| | (parts | (parts | Organic | temperature | Sensitivity | LWR | |
| | by mass) | by mass) | solvent | (° C.) | (mJ/cm²) | (nm) | Judgement |
| Example 15 | Polymer 1 | Q11 | PGMEA (2000) | 95 | 36.1 | 2.68 | Good |
| | (80) | (23.0) | DAA (500) | | | | |
| | | | EL (2500) | | | | |
| Example 16 | Polymer 2 | Q11 | PGMEA (2000) | 95 | 36.3 | 2.62 | Good |
| | (80) | (23.0) | DAA (500) | | | | |
| | | | EL (2500) | | | | |
| Example 17 | Polymer 3 | Q11 | PGMEA (2000) | 95 | 35.2 | 2.53 | Good |
| | (80) | (23.0) | DAA (500) | | | | |
| | | | EL (2500) | | | | |
| Example 18 | Polymer 4 | Q11 | PGMEA (2000) | 95 | 35.1 | 2.52 | Good |
| | (80) | (23.0) | DAA (500) | | | | |
| | | | EL (2500) | | | | |
| Example 19 | Polymer 5 | Q6 | PGMEA (2000) | 95 | 34.9 | 2.47 | Excellent |
| | (80) | (12.4) | DAA (500) | | | | |
| | | | EL (2500) | | | | |
| Example 20 | Polymer 5 | Q7 | PGMEA (2000) | 95 | 34.7 | 2.48 | Excellent |
| | (80) | (14.3) | DAA (500) | | | | |
| | | | EL (2500) | | | | |
| Example 21 | Polymer 5 | Q8 | PGMEA (2000) | 95 | 34.6 | 2.45 | Excellent |
| | (80) | (15.0) | DAA (500) | | | | |
| | | | EL (2500) | | | | |
| Example 22 | Polymer 5 | Q9 | PGMEA (2000) | 95 | 34 | 2.35 | Excellent |
| | (80) | (17.6) | DAA (500) | | | | |
| | | | EL (2500) | | | | |
| Example 23 | Polymer 5 | Q10 | PGMEA (2000) | 95 | 34.8 | 2.48 | Excellent |
| | (80) | (20.4) | DAA (500) | | | | |
| | | | EL (2500) | | | | |
| Example 24 | Polymer 5 | Q11 | PGMEA (2000) | 95 | 34.1 | 2.35 | Excellent |
| | (80) | (23.0) | DAA (500) | | | | |
| | | | EL (2500) | | | | |
| Example 25 | Polymer 5 | Q12 | PGMEA (2000) | 95 | 34.6 | 2.43 | Excellent |
| | (80) | (18.9) | DAA (500) | | | | |
| | | | EL (2500) | | | | |
| Example 26 | Polymer 6 | Q6 | PGMEA (2000) | 95 | 34.1 | 2.41 | Excellent |
| | (80) | (12.4) | DAA (500) | | | | |
| | | | EL (2500) | | | | |
| Example 27 | Polymer 6 | Q7 | PGMEA (2000) | 95 | 34.4 | 2.42 | Excellent |
| | (80) | (14.3) | DAA (500) | | | | |
| | | | EL (2500) | | | | |
| Example 28 | Polymer 6 | Q8 | PGMEA (2000) | 95 | 34.5 | 2.42 | Excellent |
| | (80) | (15.0) | DAA (500) | | | | |
| | | | EL (2500) | | | | |
| Example 29 | Polymer 6 | Q9 | PGMEA (2000) | 95 | 33.1 | 2.31 | Excellent |
| | (80) | (17.6) | DAA (500) | | | | |
| | | | EL (2500) | | | | |
| Example 30 | Polymer 6 | Q10 | PGMEA (2000) | 95 | 34.2 | 2.43 | Excellent |
| | (80) | (20.4) | DAA (500) | | | | |
| | | | EL (2500) | | | | |
| Example 31 | Polymer 6 | Q11 | PGMEA (2000) | 95 | 33.3 | 2.33 | Excellent |
| | (80) | (23.0) | DAA (500) | | | | |
| | | | EL (2500) | | | | |

TABLE 3

| | Polymer | Quencher | | PEB | | | |
|---|---|---|---|---|---|---|---|
| | (parts | (parts | Organic | temperature | Sensitivity | LWR | |
| | by mass) | by mass) | solvent | (° C.) | (mJ/cm²) | (nm) | Judgement |
| Example 32 | Polymer 6 | Q12 | PGMEA (2000) | 95 | 33.7 | 2.36 | Excellent |
| | (80) | (18.9) | DAA (500) | | | | |
| | | | EL (2500) | | | | |
| Example 33 | Polymer 7 | Q6 | PGMEA (2000) | 95 | 33.7 | 2.35 | Excellent |
| | (80) | (12.4) | DAA (500) | | | | |
| | | | EL (2500) | | | | |
| Example 34 | Polymer 7 | Q7 | PGMEA (2000) | 95 | 33.9 | 2.37 | Excellent |
| | (80) | (14.3) | DAA (500) | | | | |
| | | | EL (2500) | | | | |
| Example 35 | Polymer 7 | Q8 | PGMEA (2000) | 95 | 33.9 | 2.36 | Excellent |
| | (80) | (15.0) | DAA (500) | | | | |
| | | | EL (2500) | | | | |
| Example 36 | Polymer 7 | Q9 | PGMEA (2000) | 95 | 33.1 | 2.27 | Excellent |
| | (80) | (17.6) | DAA (500) | | | | |
| | | | EL (2500) | | | | |
| Example 37 | Polymer 7 | Q10 | PGMEA (2000) | 95 | 33.5 | 2.36 | Excellent |
| | (80) | (20.4) | DAA (500) | | | | |
| | | | EL (2500) | | | | |
| Example 38 | Polymer 7 | Q11 | PGMEA (2000) | 95 | 32.8 | 2.28 | Excellent |
| | (80) | (23.0) | DAA (500) | | | | |
| | | | EL (2500) | | | | |
| Example 39 | Polymer 7 | Q12 | PGMEA (2000) | 95 | 33.2 | 2.31 | Excellent |
| | (80) | (18.9) | DAA (500) | | | | |
| | | | EL (2500) | | | | |
| Example 40 | Polymer 8 | Q6 | PGMEA (2000) | 95 | 33.4 | 2.31 | Excellent |
| | (80) | (12.4) | DAA (500) | | | | |
| | | | EL (2500) | | | | |
| Example 41 | Polymer 8 | Q7 | PGMEA (2000) | 95 | 33.4 | 2.31 | Excellent |
| | (80) | (14.3) | DAA (500) | | | | |
| | | | EL (2500) | | | | |
| Example 42 | Polymer 8 | Q8 | PGMEA (2000) | 95 | 33.6 | 2.31 | Excellent |
| | (80) | (15.0) | DAA (500) | | | | |
| | | | EL (2500) | | | | |
| Example 43 | Polymer 8 | Q9 | PGMEA (2000) | 95 | 32.4 | 2.21 | Excellent |
| | (80) | (17.6) | DAA (500) | | | | |
| | | | EL (2500) | | | | |
| Example 44 | Polymer 8 | Q10 | PGMEA (2000) | 95 | 33.1 | 2.31 | Excellent |
| | (80) | (20.4) | DAA (500) | | | | |
| | | | EL (2500) | | | | |
| Example 45 | Polymer 8 | Q11 | PGMEA (2000) | 95 | 32.3 | 2.2 | Excellent |
| | (80) | (23.0) | DAA (500) | | | | |
| | | | EL (2500) | | | | |
| Example 46 | Polymer 8 | Q12 | PGMEA (2000) | 95 | 32.7 | 2.26 | Excellent |
| | (80) | (18.9) | DAA (500) | | | | |
| | | | EL (2500) | | | | |

TABLE 4

| | Polymer | Quencher | | PEB | | | |
|---|---|---|---|---|---|---|---|
| | (parts | (parts | Organic | temperature | Sensitivity | LWR | |
| | by mass) | by mass) | solvent | (° C.) | (mJ/cm²) | (nm) | Judgement |
| Comparative | Polymer 1 | Q1 | PGMEA (2000) | 95 | 40.1 | 3.15 | Poor |
| Example 1 | (80) | (8.3) | DAA (500) | | | | |
| | | | EL (2500) | | | | |
| Comparative | Polymer 1 | Q2 | PGMEA (2000) | 95 | 40.3 | 3.11 | Poor |
| Example 2 | (80) | (12.2) | DAA (500) | | | | |
| | | | EL (2500) | | | | |
| Comparative | Polymer 1 | Q3 | PGMEA (2000) | 95 | 40 | 3.22 | Poor |
| Example 3 | (80) | (10.2) | DAA (500) | | | | |
| | | | EL (2500) | | | | |
| Comparative | Polymer 1 | Q4 | PGMEA (2000) | 95 | 39.3 | 2.97 | Poor |
| Example 4 | (80) | (14.6) | DAA (500) | | | | |
| | | | EL (2500) | | | | |
| Comparative | Polymer 1 | Q5 | PGMEA (2000) | 95 | 39.3 | 2.95 | Poor |
| Example 5 | (80) | (20.0) | DAA (500) | | | | |
| | | | EL (2500) | | | | |
| Comparative | Polymer 2 | Q1 | PGMEA (2000) | 95 | 40.1 | 3.03 | Poor |
| Example 6 | (80) | (8.3) | DAA (500) | | | | |
| | | | EL (2500) | | | | |
| Comparative | Polymer 2 | Q2 | PGMEA (2000) | 95 | 40.2 | 3.02 | Poor |
| Example 7 | (80) | (12.2) | DAA (500) | | | | |
| | | | EL (2500) | | | | |
| Comparative | Polymer 2 | Q3 | PGMEA (2000) | 95 | 40.2 | 3.02 | Poor |
| Example 8 | (80) | (10.2) | DAA (500) | | | | |
| | | | EL (2500) | | | | |
| Comparative | Polymer 2 | Q4 | PGMEA (2000) | 95 | 39 | 2.9 | Poor |
| Example 9 | (80) | (14.6) | DAA (500) | | | | |
| | | | EL (2500) | | | | |
| Comparative | Polymer 2 | Q5 | PGMEA (2000) | 95 | 39.2 | 2.93 | Poor |
| Example 10 | (80) | (20.0) | DAA (500) | | | | |
| | | | EL (2500) | | | | |
| Comparative | Polymer 3 | Q1 | PGMEA (2000) | 95 | 39.6 | 2.92 | Poor |
| Example 11 | (80) | (8.3) | DAA (500) | | | | |
| | | | EL (2500) | | | | |
| Comparative | Polymer 3 | Q2 | PGMEA (2000) | 95 | 39.5 | 2.9 | Poor |
| Example 12 | (80) | (12.2) | DAA (500) | | | | |
| | | | EL (2500) | | | | |
| Comparative | Polymer 3 | Q3 | PGMEA (2000) | 95 | 39.5 | 2.93 | Poor |
| Example 13 | (80) | (10.2) | DAA (500) | | | | |
| | | | EL (2500) | | | | |
| Comparative | Polymer 3 | Q4 | PGMEA (2000) | 95 | 38.4 | 2.83 | Poor |
| Example 14 | (80) | (14.6) | DAA (500) | | | | |
| | | | EL (2500) | | | | |
| Comparative | Polymer 3 | Q5 | PGMEA (2000) | 95 | 38.3 | 2.81 | Poor |
| Example 15 | (80) | (20.0) | DAA (500) | | | | |
| | | | EL (2500) | | | | |
| Comparative | Polymer 4 | Q1 | PGMEA (2000) | 95 | 39.4 | 2.93 | Poor |
| Example 16 | (80) | (8.3) | DAA (500) | | | | |
| | | | EL (2500) | | | | |
| Comparative | Polymer 4 | Q2 | PGMEA (2000) | 95 | 39.4 | 2.92 | Poor |
| Example 17 | (80) | (12.2) | DAA (500) | | | | |
| | | | EL (2500) | | | | |
| Comparative | Polymer 4 | Q3 | PGMEA (2000) | 95 | 39 | 2.93 | Poor |
| Example 18 | (80) | (10.2) | DAA (500) | | | | |
| | | | EL (2500) | | | | |
| Comparative | Polymer 4 | Q4 | PGMEA (2000) | 95 | 38.7 | 2.83 | Poor |
| Example 19 | (80) | (14.6) | DAA (500) | | | | |
| | | | EL (2500) | | | | |
| Comparative | Polymer 4 | Q5 | PGMEA (2000) | 95 | 38.1 | 2.82 | Poor |
| Example 20 | (80) | (20.0) | DAA (500) | | | | |
| | | | EL (2500) | | | | |

TABLE 5

| | Polymer | | Quencher | | PEB | | | |
|---|---|---|---|---|---|---|---|---|
| | (parts | | (parts | Organic | temperature | Sensitivity | LWR | |
| | by mass) | PAG | by mass) | solvent | (° C.) | (mJ/cm²) | (nm) | Judgement |
| Comparative | Comparative | PAG-1 | Q1 | PGMEA (2000) | 95 | 42.5 | 3.54 | Poor |
| Example 21 | Polymer 1 | (22) | (10.0) | DAA (500) | | | | |
| | (80) | | | EL (2500) | | | | |
| Comparative | Comparative | PAG-1 | Q2 | PGMEA (2000) | 95 | 40.1 | 3.57 | Poor |
| Example 22 | Polymer 1 | (22) | (14.6) | DAA (500) | | | | |
| | (80) | | | EL (2500) | | | | |
| Comparative | Comparative | PAG-1 | Q3 | PGMEA (2000) | 95 | 42.9 | 3.51 | Poor |
| Example 23 | Polymer 1 | (22) | (12.2) | DAA (500) | | | | |
| | (80) | | | EL (2500) | | | | |
| Comparative | Comparative | PAG-1 | Q4 | PGMEA (2000) | 95 | 41.3 | 3.36 | Poor |
| Example 24 | Polymer 1 | (22) | (17.5) | DAA (500) | | | | |
| | (80) | | | EL (2500) | | | | |
| Comparative | Comparative | PAG-1 | Q5 | PGMEA (2000) | 95 | 40.2 | 3.45 | Poor |
| Example 25 | Polymer 1 | (22) | (24.0) | DAA (500) | | | | |
| | (80) | | | EL (2500) | | | | |
| Comparative | Comparative | PAG-1 | Q6 | PGMEA (2000) | 95 | 39.3 | 3.4 | Poor |
| Example 26 | Polymer 1 | (22) | (14.9) | DAA (500) | | | | |
| | (80) | | | EL (2500) | | | | |

From the results in Tables 1 to 5, the resist compositions of Comparative Examples 1 to 26, which had no sulfonium cation having the structure represented by the formula (1) in the polymer moiety nor the quencher moiety, were judged as “Poor”. Meanwhile, the resist composition of the present invention, which had the sulfonium cation having the structure represented by the formula (1) in at least one of the polymer moiety and the quencher moiety, had good sensitivity and LWR performance, and demonstrated to be suitable as the material for EUV lithography. Further, Examples 19 to 46, which had the sulfonium cation having the structure represented by the formula (1) in both the polymer moiety and the quencher moiety, were judged as “Excellent”, and demonstrated particularly excellent performance.

The present description includes the following embodiments.

[1]: A resist composition, comprising: a resin (A) represented by the following formula (a1) and comprising a repeating unit that generates an acid by exposure;
a photodegradable quencher represented by the following formula (b1); and
an organic solvent,
wherein at least one of M₁⁺ in the formula (a1) and M₂⁺ in the formula (b1) represents a sulfonium cation represented by the following formula (1),

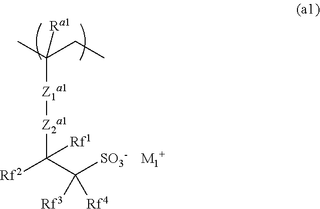

wherein R^{a1} each independently represents a hydrogen atom or a methyl group; Z₁^{a1} represents a single bond or an ester bond; Z₂ₐ1 represents a single bond or a divalent organic group having 1 to 20 carbon atoms and optionally having an ester bond, an ether bond, a lactone ring, an aromatic ring, a fluorine atom, a bromine atom, or an iodine atom; Rf¹ to Rf⁴ each independently represent a hydrogen atom, a fluorine atom, or a trifluoromethyl group, provided that at least one of Rf¹ to Rf⁴ represents a fluorine atom; and M₁⁺ represents a sulfonium cation,

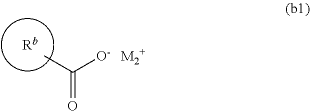

wherein Rb represents an organic group having 1 to 30 carbon atoms and optionally having a substituent; and M₂⁺ represents a sulfonium cation,

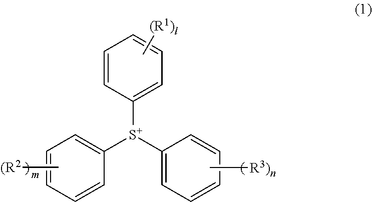

wherein R¹ represents a fluorine atom, an iodine atom, or a perfluoroalkyl group; R² and R³ each independently represent a fluorine atom or a perfluoroalkyl group; “l” represents an integer of 0 to 3; “m” represents an integer of 1 to 3; “n” represents an integer of 1 to 3; when “l”, “m”, or “n” represents an integer of 2 or more, each of R¹, R², and R³ may be same or different; provided that structure of the formula (1) has at least two or more fluorine atoms; when R² or R³ represents a fluorine atom, at least one fluorine atom is substituted at a meta-position relative to a sulfur atom.

[2]: The resist composition of the above [1], wherein the photodegradable quencher represented by the formula (b1) is represented by the following formula (b1-1),

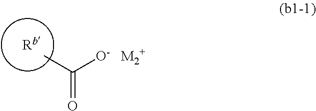

wherein Rb′ represents an organic group having 1 to 22 carbon atoms, optionally having a substituent, and optionally having an ester bond, an ether bond, an amide bond, a lactone ring, a sultone ring, an aromatic cyclic group, an aliphatic cyclic group, a hydroxy group, an alkoxy group, a fluoroalkyl group, a nitro group, a cyano group, a trifluoromethoxy group, a carbonyl group, an amino group, an alkylamino group, a fluorine atom, a bromine atom, or an iodine atom; and M₂⁺ represents a sulfonium cation.

[3]: The resist composition of the above [1] or [2], wherein the resin (A) is a resin further comprising a repeating unit represented by the following formula (a2),

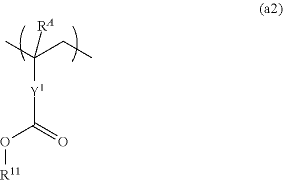

wherein R^{A} each independently represents a hydrogen atom or a methyl group; Y¹ represents a single bond, a phenylene group or a naphthylene group, or a linking group having 1 to 12 carbon atoms and having an ester bond, an ether bond, or a lactone ring; and R¹¹ represents an acid-labile group.

[4]: The resist composition of the above [1], [2] or [3], wherein the repeating unit represented by the formula (a1) is represented by the following formula (a1-1),

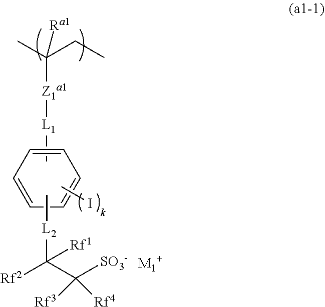

wherein R^{a1} each independently represents a hydrogen atom or a methyl group; Z₁^{a1} represents a single bond or an ester bond; L₁ represents a single bond or a divalent linking group optionally having an ester bond, an ether bond, a lactone ring, an aromatic ring, a fluorine atom, a bromine atom, or an iodine atom; L₂ represents a single bond or a divalent linking group optionally having an ester bond or an ether bond; Rf¹ to Rf⁴ each independently represent a hydrogen atom, a fluorine atom, or a trifluoromethyl group, provided that at least one of Rf¹ to Rf⁴ represents a fluorine atom; “k” represents an integer of 0 to 4; and M₁⁺ represents a sulfonium cation.

[5]: The resist composition of the above [1] to [4], wherein the repeating unit represented by the formula (a1) is represented by the following formula (a1-2),

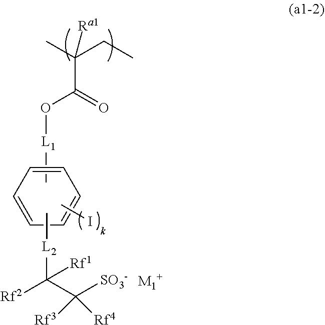

wherein Rai each independently represents a hydrogen atom or a methyl group; L₁ represents a single bond or a divalent linking group optionally having an ester bond, an ether bond, a lactone ring, an aromatic ring, a fluorine atom, a bromine atom, or an iodine atom; L₂ represents a single bond or a divalent linking group optionally having an ester bond or an ether bond; Rf¹ to Rf⁴ each independently represent a hydrogen atom, a fluorine atom, or a trifluoromethyl group, provided that at least one of Rf¹ to Rf⁴ represents a fluorine atom; “k” represents an integer of 0 to 4; and M₁⁺ represents a sulfonium cation.

[6]: The resist composition of the above [1] to [5], wherein an anion moiety in the formula (a1) and the formula (b1) comprises an iodine atom.

[7]: The resist composition of the above [1] to [6], wherein both the M₁⁺ in the formula (a1) and M₂⁺ in the formula (b1) represent the sulfonium cation represented by the formula (1).

[8]: The resist composition of the above [1] to [7], wherein “l” in the formula (1) represents an integer of 1 to 3.

[9]: The resist composition of the above [1] to [8], wherein the cation represented by the formula (1) comprises an iodine atom.

[10]: A patterning process, comprising steps of: forming a resist film on a substrate by using the resist composition of any one of the [1] to [9]; exposing the resist film to high-energy ray; and developing the exposed resist film by using a developer.

[11]: The patterning process of the above [10], wherein the high-energy ray used in the exposing step is i-line, KrF excimer laser light, ArF excimer laser light, electron beam, or extreme ultraviolet ray having a wavelength of 3 to 15 nm.

It should be noted that the present invention is not limited to the above-described embodiments. The embodiments are just examples, and any examples that substantially have the same feature and demonstrate the same functions and effects as those in the technical concept disclosed in claims of the present invention are included in the technical scope of the present invention.

1. A resist composition, comprising:
a resin (A) represented by the following formula (a1) and comprising a repeating unit that generates an acid by exposure;
a photodegradable quencher represented by the following formula (b1); and
an organic solvent,
wherein at least one of M₁⁺ in the formula (a1) and M₂⁺ in the formula (b1) represents a sulfonium cation represented by the following formula (1), 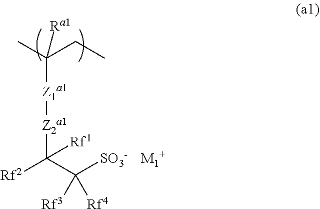
wherein R^{a1} each independently represents a hydrogen atom or a methyl group; Z₁^{a1} represents a single bond or an ester bond; Z₂^{a1} represents a single bond or a divalent organic group having 1 to 20 carbon atoms and optionally having an ester bond, an ether bond, a lactone ring, an aromatic ring, a fluorine atom, a bromine atom, or an iodine atom; Rf¹ to Rf⁴ each independently represent a hydrogen atom, a fluorine atom, or a trifluoromethyl group, provided that at least one of Rf¹ to Rf⁴ represents a fluorine atom; and M₁⁺ represents a sulfonium cation, 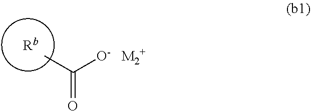
wherein Rb represents an organic group having 1 to 30 carbon atoms and optionally having a substituent; and M₂⁺ represents a sulfonium cation, 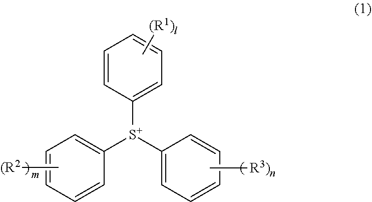
wherein R¹ represents a fluorine atom, an iodine atom, or a perfluoroalkyl group; R² and R³ each independently represent a fluorine atom or a perfluoroalkyl group; “l” represents an integer of 0 to 3; “m” represents an integer of 1 to 3; “n” represents an integer of 1 to 3; when “l”, “m”, or “n” represents an integer of 2 or more, each of R¹, R², and R³ may be same or different; provided that structure of the formula (1) has at least two or more fluorine atoms; when R² or R³ represents a fluorine atom, at least one fluorine atom is substituted at a meta-position relative to a sulfur atom.

2. The resist composition according to claim 1, wherein the photodegradable quencher represented by the formula (b1) is represented by the following formula (b1-1), 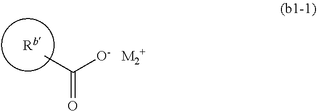
wherein Rb′ represents an organic group having 1 to 22 carbon atoms, optionally having a substituent, and optionally having an ester bond, an ether bond, an amide bond, a lactone ring, a sultone ring, an aromatic cyclic group, an aliphatic cyclic group, a hydroxy group, an alkoxy group, a fluoroalkyl group, a nitro group, a cyano group, a trifluoromethoxy group, a carbonyl group, an amino group, an alkylamino group, a fluorine atom, a bromine atom, or an iodine atom; and M₂⁺ represents a sulfonium cation.

3. The resist composition according to claim 1, wherein the resin (A) is a resin further comprising a repeating unit represented by the following formula (a2), 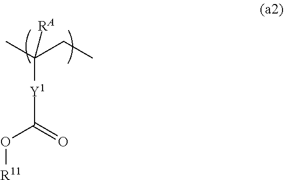
wherein R^{A} each independently represents a hydrogen atom or a methyl group; Y¹ represents a single bond, a phenylene group or a naphthylene group, or a linking group having 1 to 12 carbon atoms and having an ester bond, an ether bond, or a lactone ring; and R¹¹ represents an acid-labile group.

4. The resist composition according to claim 2, wherein the resin (A) is a resin further comprising a repeating unit represented by the following formula (a2), 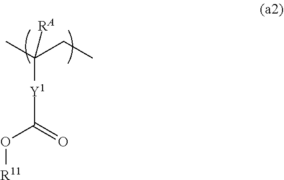
wherein R^{A} each independently represents a hydrogen atom or a methyl group; Y¹ represents a single bond, a phenylene group or a naphthylene group, or a linking group having 1 to 12 carbon atoms and having an ester bond, an ether bond, or a lactone ring; and R¹¹ represents an acid-labile group.

5. The resist composition according to claim 1, wherein the repeating unit represented by the formula (a1) is represented by the following formula (a1-1), 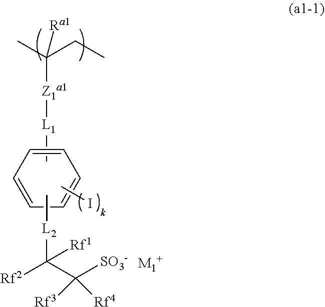
wherein R^{a1} each independently represents a hydrogen atom or a methyl group; Z₁^{a1} represents a single bond or an ester bond; L₁ represents a single bond or a divalent linking group optionally having an ester bond, an ether bond, a lactone ring, an aromatic ring, a fluorine atom, a bromine atom, or an iodine atom; L₂ represents a single bond or a divalent linking group optionally having an ester bond or an ether bond; Rf¹ to Rf⁴ each independently represent a hydrogen atom, a fluorine atom, or a trifluoromethyl group, provided that at least one of Rf¹ to Rf⁴ represents a fluorine atom; “k” represents an integer of 0 to 4; and M₁⁺ represents a sulfonium cation.

6. The resist composition according to claim 2, wherein the repeating unit represented by the formula (a1) is represented by the following formula (a1-1), 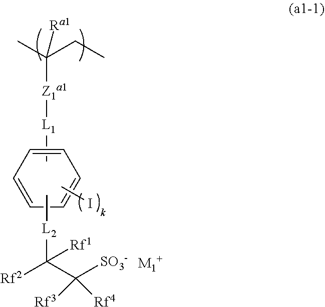
wherein R^{a1} each independently represents a hydrogen atom or a methyl group; Z₁^{a1} represents a single bond or an ester bond; L₁ represents a single bond or a divalent linking group optionally having an ester bond, an ether bond, a lactone ring, an aromatic ring, a fluorine atom, a bromine atom, or an iodine atom; L₂ represents a single bond or a divalent linking group optionally having an ester bond or an ether bond; Rf¹ to Rf⁴ each independently represent a hydrogen atom, a fluorine atom, or a trifluoromethyl group, provided that at least one of Rf¹ to Rf⁴ represents a fluorine atom; “k” represents an integer of 0 to 4; and M₁⁺ represents a sulfonium cation.

7. The resist composition according to claim 3, wherein the repeating unit represented by the formula (a1) is represented by the following formula (a1-1), 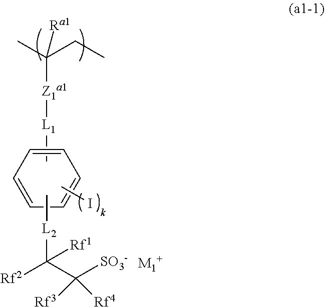
wherein R^{a1} each independently represents a hydrogen atom or a methyl group; Z₁^{a1} represents a single bond or an ester bond; L₁ represents a single bond or a divalent linking group optionally having an ester bond, an ether bond, a lactone ring, an aromatic ring, a fluorine atom, a bromine atom, or an iodine atom; L₂ represents a single bond or a divalent linking group optionally having an ester bond or an ether bond; Rf¹ to Rf⁴ each independently represent a hydrogen atom, a fluorine atom, or a trifluoromethyl group, provided that at least one of Rf¹ to Rf⁴ represents a fluorine atom; “k” represents an integer of 0 to 4; and M₁⁺ represents a sulfonium cation.

8. The resist composition according to claim 1, wherein the repeating unit represented by the formula (a1) is represented by the following formula (a1-2), 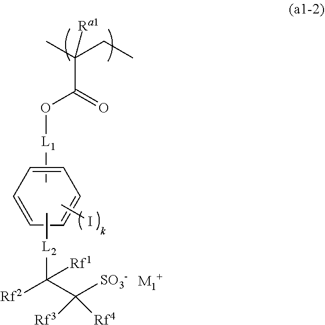
wherein R^{a1} each independently represents a hydrogen atom or a methyl group; L₁ represents a single bond or a divalent linking group optionally having an ester bond, an ether bond, a lactone ring, an aromatic ring, a fluorine atom, a bromine atom, or an iodine atom; L₂ represents a single bond or a divalent linking group optionally having an ester bond or an ether bond; Rf¹ to Rf⁴ each independently represent a hydrogen atom, a fluorine atom, or a trifluoromethyl group, provided that at least one of Rf¹ to Rf⁴ represents a fluorine atom; “k” represents an integer of 0 to 4; and M₁⁺ represents a sulfonium cation.

9. The resist composition according to claim 2, wherein the repeating unit represented by the formula (a1) is represented by the following formula (a1-2), 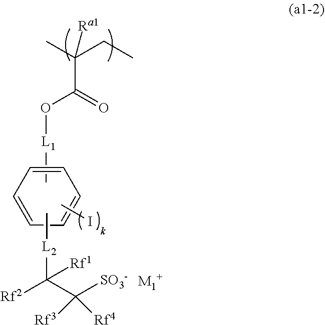
wherein R^{a1} each independently represents a hydrogen atom or a methyl group; L₁ represents a single bond or a divalent linking group optionally having an ester bond, an ether bond, a lactone ring, an aromatic ring, a fluorine atom, a bromine atom, or an iodine atom; L₂ represents a single bond or a divalent linking group optionally having an ester bond or an ether bond; Rf¹ to Rf⁴ each independently represent a hydrogen atom, a fluorine atom, or a trifluoromethyl group, provided that at least one of Rf¹ to Rf⁴ represents a fluorine atom; “k” represents an integer of 0 to 4; and M₁⁺ represents a sulfonium cation.

10. The resist composition according to claim 3, wherein the repeating unit represented by the formula (a1) is represented by the following formula (a1-2), 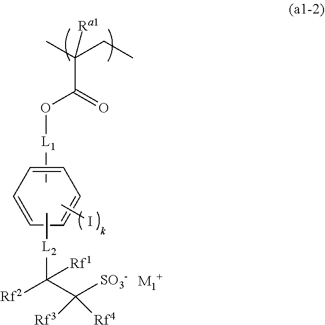
wherein R^{a1} each independently represents a hydrogen atom or a methyl group; L₁ represents a single bond or a divalent linking group optionally having an ester bond, an ether bond, a lactone ring, an aromatic ring, a fluorine atom, a bromine atom, or an iodine atom; L₂ represents a single bond or a divalent linking group optionally having an ester bond or an ether bond; Rf¹ to Rf⁴ each independently represent a hydrogen atom, a fluorine atom, or a trifluoromethyl group, provided that at least one of Rf¹ to Rf⁴ represents a fluorine atom; “k” represents an integer of 0 to 4; and M₁⁺ represents a sulfonium cation.

11. The resist composition according to claim 4, wherein the repeating unit represented by the formula (a1) is represented by the following formula (a1-2), 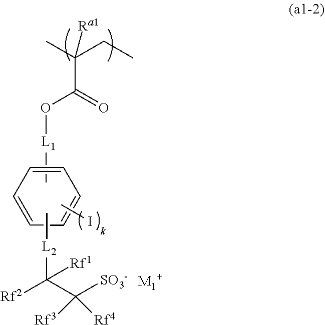
wherein R^{a1} each independently represents a hydrogen atom or a methyl group; L₁ represents a single bond or a divalent linking group optionally having an ester bond, an ether bond, a lactone ring, an aromatic ring, a fluorine atom, a bromine atom, or an iodine atom; L₂ represents a single bond or a divalent linking group optionally having an ester bond or an ether bond; Rf¹ to Rf⁴ each independently represent a hydrogen atom, a fluorine atom, or a trifluoromethyl group, provided that at least one of Rf¹ to Rf⁴ represents a fluorine atom; “k” represents an integer of 0 to 4; and M₁⁺ represents a sulfonium cation.

12. The resist composition according to claim 1, wherein an anion moiety in the formula (a1) and the formula (b1) comprises an iodine atom.

13. The resist composition according to claim 2, wherein an anion moiety in the formula (a1) and the formula (b1) comprises an iodine atom.

14. The resist composition according to claim 1, wherein both the M₁⁺ in the formula (a1) and M₂⁺ in the formula (b1) represent the sulfonium cation represented by the formula (1).

15. The resist composition according to claim 2, wherein both the M₁⁺ in the formula (a1) and M₂⁺ in the formula (b1) represent the sulfonium cation represented by the formula (1).

16. The resist composition according to claim 1, wherein “l” in the formula (1) represents an integer of 1 to 3.

17. The resist composition according to claim 2, wherein “l” in the formula (1) represents an integer of 1 to 3.

18. The resist composition according to claim 1, wherein the cation represented by the formula (1) comprises an iodine atom.

19. A patterning process, comprising steps of:
forming a resist film on a substrate by using the resist composition according to claim 1;
exposing the resist film to high-energy ray; and
developing the exposed resist film by using a developer.

20. The patterning process according to claim 19, wherein the high-energy ray used in the exposing step is i-line, KrF excimer laser light, ArF excimer laser light, electron beam, or extreme ultraviolet ray having a wavelength of 3 to 15 nm.
